(19) United States
(12) Patent Application Publication
(10) Pub. No.: US 2025/0120312 A1
(43) Pub. Date: Apr. 10, 2025

(54) ORGANIC LIGHT-EMITTING ELEMENT AND DISPLAY APPARATUS INCLUDING THE SAME

(71) Applicant: CANON KABUSHIKI KAISHA, Tokyo (JP)

(72) Inventors: YOSUKE NISHIDE, Kanagawa (JP); HITOSHI NAGASHIMA, Kanagawa (JP); MASAHITO MIYABE, Kanagawa (JP); HIROKAZU MIYASHITA, Miyagi (JP); NAOKI YAMADA, Tokyo (JP)

(21) Appl. No.: 18/987,755

(22) Filed: Dec. 19, 2024

Related U.S. Application Data
(63) Continuation of application No. PCT/JP2023/020572, filed on Jun. 2, 2023.

(30) Foreign Application Priority Data
Jun. 27, 2022 (JP) 2022-102760

(51) Int. Cl. H10K 85/60; C09K 11/02; H10K 50/12; H10K 101/30

(52) U.S. Cl. CPC H10K 85/657; C09K 11/02; H10K 85/622; H10K 85/654; H10K 85/6572; H10K 85/6574; H10K 85/6576; H10K 50/12; H10K 2101/30

(57) ABSTRACT

An organic light-emitting element including a first electrode and a second electrode, and an organic compound layer disposed between the first electrode and the second electrode. The organic compound layer includes a light-emitting layer. The light-emitting layer contains at least a first organic compound, a second organic compound, and a luminescent compound that emits phosphorescence. Lowest excited triplet energies of the first organic compound and the second organic compound are higher than a lowest excited triplet energy of the luminescent compound. In the first organic compound and the second organic compound, all freely rotatable single bonds are carbon-carbon bonds. The organic light-emitting element satisfies a relation of formula (1):

|HOMO(H2)|>|HOMO(H1)| (1).

### CROSS-REFERENCE TO RELATED APPLICATIONS

This application is a Continuation of International Patent Application No. PCT/JP2023/020572, filed Jun. 2, 2023, which claims the benefit of Japanese Patent Application No. 2022-102760, filed Jun. 27, 2022, both of which are hereby incorporated by reference herein in their entirety.

### TECHNICAL FIELD

The present invention relates to an organic light-emitting element and a display apparatus including the organic light-emitting element.

### BACKGROUND ART

An organic electroluminescent element (hereinafter also referred to as an “organic light-emitting element” or an “organic EL element”) is an electronic element including a pair of electrodes and an organic compound layer disposed between the electrodes. By injecting electrons and holes through the pair of electrodes, excitons of a luminescent organic compound in the organic compound layer are generated. The organic light-emitting element emits light when the excitons return to their ground state.

Recent progress in organic light-emitting elements has been noticeable, and low driving voltages, various emission wavelengths, high-speed response, and thinner and lighter light-emitting elements have been enabled.

For an organic light-emitting element having higher efficiency, the use of a material such as a phosphorescent material or a delayed fluorescent material is known. It is known that any of these materials has a light-emission mechanism involving a triplet excited state and thus will degrade due to transition energy from the triplet excited state to a higher excited state. Such an organic light-emitting element obtained using a material that utilizes a triplet state has been required to have improved element durability.

PTL 1 describes, as a configuration for improving element durability, a ternary fluorescent light-emitting layer containing two light-emitting materials each having HOMO and LUMO levels different from those of a light-emitting layer host. PTL 2 and PTL 3 describes improvement in element durability by using, as highly stable materials, organic compounds 1-a and 2-a having nitrogen-containing fused-ring skeletons.

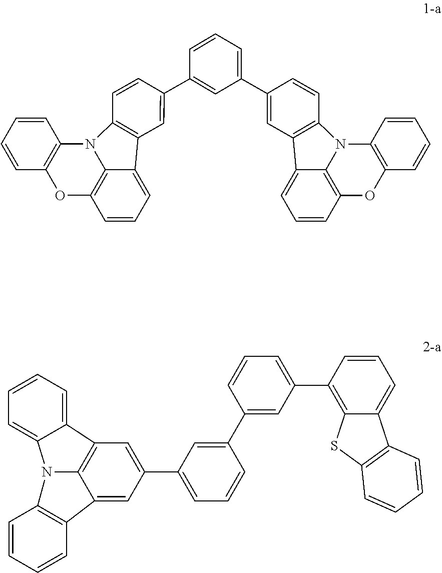 [SMILES: c1cc(-c2ccc3c(c2)c2cccc4c2n3-c2ccccc2O4)cc(-c2ccc3c(c2)c2cccc4c2n3-c2ccccc2O4)c1 ; c1cc(-c2cccc(-c3cccc4c3sc3ccccc34)c2)cc(-c2cc3c4ccccc4n4c5ccccc5c(c2)c34)c1]

### CITATION LIST

### Patent Literature

PTL 1 Japanese Patent Laid-Open No. 2011-71194
PTL 2 International Publication No. 2012/077582
PTL 3 Japanese Patent Laid-Open No. 2012-72099

However, the configuration of the light-emitting layer described in PTL 1 is a light-emitting layer that emits fluorescence, and an organic light-emitting element that utilizes a triplet state is not disclosed. The configurations of the light-emitting layers described in PTL 2 and 3 lead to insufficient element durability and are not preferred.

### SUMMARY OF INVENTION

The present invention has been made in view of the foregoing problems, and an object thereof is to provide an organic light-emitting element having high element durability.

The organic light-emitting element according to the present invention is an organic light-emitting element including a first electrode and a second electrode, and an organic compound layer disposed between the first electrode and the second electrode. The organic compound layer includes a light-emitting layer. The light-emitting layer contains at least a first organic compound, a second organic compound, and a luminescent compound that emits phosphorescence. Lowest excited triplet energies of the first organic compound and the second organic compound are higher than a lowest excited triplet energy of the luminescent compound. All freely rotatable single bonds in the first organic compound are carbon-carbon bonds. The organic light-emitting element satisfies a relation of formula (1).

|HOMO(H2)|>|HOMO(H1)| (1)

Further features of the present invention will become apparent from the following description of exemplary embodiments with reference to the attached drawings.

### BRIEF DESCRIPTION OF DRAWINGS

FIG. 1A is a schematic sectional view showing an example of a pixel of a display apparatus according to an embodiment of the present invention.

FIG. 1B is a schematic sectional view of an example of a display apparatus including an organic light-emitting element according to an embodiment of the present invention.

FIG. 2 is a schematic view showing an example of a display apparatus according to an embodiment of the present invention.

FIG. 3A is a schematic view showing an example of an image pickup apparatus according to an embodiment of the present invention.

FIG. 3B is a schematic view showing an example of an electronic apparatus according to an embodiment of the present invention.

FIG. 4A is a schematic view showing an example of a display apparatus according to an embodiment of the present invention.

FIG. 4B is a schematic view showing an example of a foldable display apparatus.

FIG. 5A is a schematic view showing an example of a lighting apparatus according to an embodiment of the present invention.

FIG. 5B is a schematic view showing an example of an automobile including a vehicle lighting fixture according to an embodiment of the present invention.

FIG. 6A is a schematic view showing an example of a wearable device according to an embodiment of the present invention.

FIG. 6B is a schematic view of an example of a wearable device according to an embodiment of the present invention, the wearable device including an image pickup apparatus.

FIG. 7A is a schematic view showing an example of image-forming apparatus according to an embodiment of the present invention.

FIG. 7B is a schematic view showing an example of an exposure light source of an image-forming apparatus according to an embodiment of the present invention.

FIG. 7C is a schematic view showing an example of an exposure light source of an image-forming apparatus according to an embodiment of the present invention.

### DESCRIPTION OF EMBODIMENTS

In this specification, examples of halogen atoms include fluorine, chlorine, bromine, and iodine, but are not limited thereto. Of these, a fluorine atom is preferred.

An alkyl group may be an alkyl group having 1 to 20 carbon atoms. Examples include a methyl group, an ethyl group, a n-propyl group, an isopropyl group, a n-butyl group, a tertiary butyl group, a secondary butyl group, an octyl group, a cyclohexyl group, a 1-adamantyl group, and a 2-adamantyl group, but are not limited thereto.

An alkoxy group may be an alkoxy group having 1 to 10 carbon atoms. Examples include a methoxy group, an ethoxy group, a propoxy group, a 2-ethyl-octyloxy group, and a benzyloxy group, but are not limited thereto.

Examples of silyl groups include a trimethylsilyl group and a triphenylsilyl group, but are not limited thereto.

An aryl group may be an aryl group having 6 to 20 carbon atoms. Examples include a phenyl group, a naphthyl group, an indenyl group, a biphenyl group, a terphenyl group, a fluorenyl group, a phenanthryl group, a fluoranthenyl group, and a triphenylenyl group, but are not limited thereto.

A heteroaryl group may be a heteroaryl group having 3 to 20 carbon atoms. Examples include a pyridyl group, a pyrimidyl group, a pyrazyl group, a triazolyl group, an oxazolyl group, an oxadiazolyl group, a thiazolyl group, a thiadiazolyl group, a carbazolyl group, an acridinyl group, a phenanthrolyl group, a dibenzofuranyl group, and a dibenzothiophenyl group, but are not limited thereto.

Examples of amino groups include an N-methylamino group, an N-ethylamino group, an N, N-dimethylamino group, an N, N-diethylamino group, an N-methyl-N-ethylamino group, an N-benzylamino group, an N-methyl-N-benzylamino group, an N, N-dibenzylamino group, an anilino group, an N, N-diphenylamino group, an N, N-dinaphthylamino group, an N, N-difluorenylamino group, an N-phenyl-N-tolylamino group, an N, N-ditolylamino group, an N-methyl-N-phenylamino group, an N, N-dianisolylamino group, an N-mesityl-N-phenylamino group, N, N-dimesitylamino group, an N-phenyl-N-(4-tertiary butylphenyl)amino group, an N-phenyl-N-(4-trifluoromethylphenyl)amino group, an N-piperidyl group, and a carbazolyl group, but are not limited thereto.

Examples of aryloxy groups and heteroaryloxy groups include a phenoxy group and a thienyloxy group, but are not limited thereto.

Examples of substituents that the alkyl group, the alkoxy group, the silyl group, the aryl group, the heteroaryl group, the amino group, the aryloxy group, and the heteroaryloxy group may further have include a deuterium atom; halogen atoms such as fluorine, chlorine, bromine, and iodine; alkyl groups such as a methyl group, an ethyl group, a n-propyl group, an isopropyl group, a n-butyl group, and a tertiary butyl group; alkoxy groups such as a methoxy group, an ethoxy group, and a propoxy group; amino groups such as a dimethylamino group, a diethylamino group, a dibenzylamino group, a diphenylamino group, and a ditolylamino group; aryloxy groups such as a phenoxy group; aromatic hydrocarbon groups such as a phenyl group and a biphenyl group; heteroaryl groups such as a pyridyl group and a pyrrolyl group; a cyano group, a hydroxy group, and a thiol group, but are not limited thereto.

In this specification, HOMO (H1), HOMO (H2), and HOMO (D) represent a HOMO level of a first organic compound, a HOMO level of a second organic compound, and a HOMO level of a luminescent compound, respectively. LUMO (H1), LUMO (H2), and LUMO (D) represent a LUMO level of the first organic compound, a LUMO level of the second organic compound, and a LUMO level of the luminescent compound, respectively. For example, an expression |HOMO (H1)| means the absolute value of the HOMO level of the first organic compound.

### (1) Organic Light-Emitting Element

An organic light-emitting element according to the present invention is an organic light-emitting element including a first electrode and a second electrode, and an organic compound layer disposed between the first electrode and the second electrode. The organic compound layer includes a light-emitting layer. The light-emitting layer contains at least a first organic compound, a second organic compound, and a luminescent compound that emits phosphorescence. Lowest excited triplet energies of the first organic compound and the second organic compound are higher than a lowest excited triplet energy of the luminescent compound. All freely rotatable single bonds in the first organic compound are carbon-carbon bonds. The organic light-emitting element satisfies a relation of formula (1).

|HOMO(H2)|>|HOMO(H1)| (1)

The light-emitting layer of the organic light-emitting element according to the present invention has the following configurations.

(1-1) The light-emitting layer contains at least a first organic compound, a second organic compound, and a luminescent compound

(1-2) Lowest excited triplet energies of the first organic compound and the second organic compound are higher than a lowest excited triplet energy of the luminescent compound

(1-3) All freely rotatable single bonds in the first organic compound are carbon-carbon bonds

(1-4) The first organic compound and the second organic compound satisfy |HOMO(H2)|>|HOMO(H1)|

Hereinafter, these configurations will be described.

### (1-1) The Light-Emitting Layer Contains at Least a First Organic Compound, a Second Organic Compound, and a Luminescent Compound

The organic light-emitting element according to the present invention contains, in the light-emitting layer, at least a first organic compound, a second organic compound, and a luminescent compound. Here, the effect of the presence of the first organic compound and the second organic compound in the light-emitting layer will be described with reference to Table 1.

Table 1 shows the configuration of light-emitting layers and element durability. The element durability is a value based on the element durability of Comparative Example B taken as 1.0.

TABLE 1

| | | | Second organic | Luminescent | Element |
|---|---|---|---|---|---|
| | | First organic compound | compound | compound | durability |
| Present Invention A | Molecular structure | 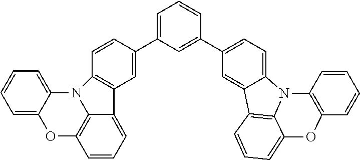 [SMILES: c1cc(-c2ccc3c(c2)c2cccc4c2n3-c2ccccc2O4)cc(-c2ccc3c(c2)c2cccc4c2n3-c2ccccc2O4)c1] | 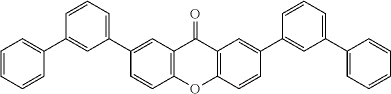 [SMILES: O=c1c2cc(-c3cccc(-c4ccccc4)c3)ccc2oc2ccc(-c3cccc(-c4ccccc4)c3)cc12] | 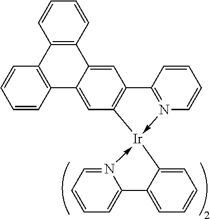 | 1.9 |
| | LUMO | −2.72 | −3.33 | −3.04 | |
| Comparative Example A | Molecular structure | 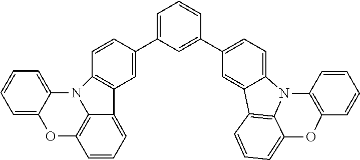 [SMILES: c1cc(-c2ccc3c(c2)c2cccc4c2n3-c2ccccc2O4)cc(-c2ccc3c(c2)c2cccc4c2n3-c2ccccc2O4)c1] | | 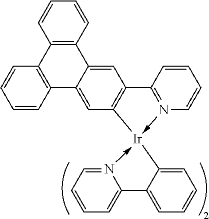 | 0.6 |
| | LUMO | −2.72 | | −3.04 | |
| Comparative Example B | Molecular structure | 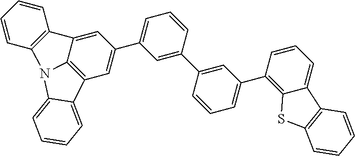 [SMILES: c1cc(-c2cccc(-c3cccc4c3sc3ccccc34)c2)cc(-c2cc3c4ccccc4n4c5ccccc5c(c2)c34)c1] | | 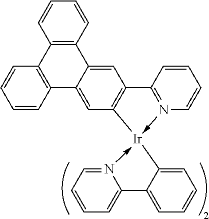 | 1.0 |
| | LUMO | −2.96 | | −3.04 | |
| Comparative Example C | Molecular structure | 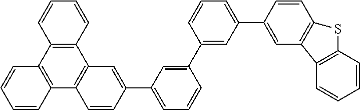 [SMILES: c1cc(-c2cccc(-c3ccc4c5ccccc5c5ccccc5c4c3)c2)cc(-c2ccc3sc4ccccc4c3c2)c1] | | 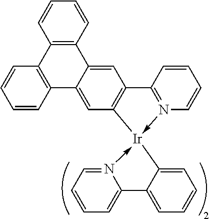 | 0.9 |
| | LUMO | −2.92 | | −3.04 | |
| Comparative Example D | Molecular structure | 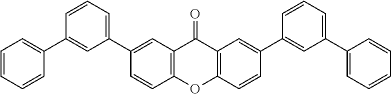 [SMILES: O=c1c2cc(-c3cccc(-c4ccccc4)c3)ccc2oc2ccc(-c3cccc(-c4ccccc4)c3)cc12] | | 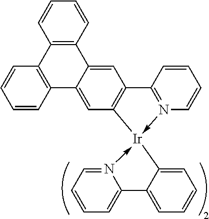 | 0.7 |
| | LUMO | −3.33 | | −3.04 | |

In Table 1, Comparative Examples A to C each have an element configuration in which the absolute value of the LUMO level of the luminescent compound is the largest. Electrons are likely to be trapped by a compound whose absolute value of the LUMO level is large, and thus in the case of the element configurations of Comparative Examples A to C, electrons are likely to be trapped by the luminescent compound. As will be described in detail later, when a luminescent compound is likely to trap electrons or holes, exciton generation is likely to concentrate on the luminescent compound, so that the element durability is likely to decrease.

Although Comparative Example D has an element configuration in which the absolute value of the LUMO level of the first organic compound is the largest, the value of element durability is low. When the absolute value of the LUMO level of an organic compound is large, the absolute value of the HOMO level of the organic compound also tends to be large, and thus the absolute value of the HOMO level of the first organic compound is large. Holes are likely to be trapped by a compound whose absolute value of the HOMO level is small. In the case of the element configuration of Comparative Example D, the absolute value of the HOMO level of the first organic compound is large, and thus holes are unlikely to be injected into the light-emitting layer. Therefore, the carrier balance between electrons and holes in the light-emitting layer is disrupted, and as a result, the element durability decreases due to carriers remaining in the light-emitting layer.

By contrast, in Present Invention A, the absolute value of the LUMO level of the second organic compound is the largest, and thus electrons are unlikely to be trapped by the luminescent compound. In addition, the absolute value of the LUMO level of the first organic compound is the smallest, and thus the absolute value of the HOMO level of the first organic compound is also low. Thus, holes are likely to be injected into the light-emitting layer. Therefore, the presence of the first organic compound and the second organic compound in the light-emitting layer can adjust the carrier balance between electrons and holes, thus leading to improved element durability.

(1-2) Lowest Excited Triplet Energies of the First Organic Compound and the Second Organic Compound are Higher than a Lowest Excited Triplet Energy of the Luminescent Compound

To provide an organic light-emitting element with improved light-emission efficiency, it is necessary to use the lowest excited triplet energy (T1) of a luminescent compound efficiently for light emission. To achieve this, the luminescent compound needs to have a lowest T1 in a light-emitting layer. In the organic light-emitting element according to the present invention, T1 of the first organic compound and T1 of the second organic compound are higher than T1 of the luminescent compound. In other words, T1 of the luminescent compound is lower than T1's of the first organic compound and the second organic compound.

Table 2 shows the configuration and external quantum yield (E.Q.E.) of light-emitting layers.

TABLE 2

| | | | Second organic | Luminescent | Emission | |
|---|---|---|---|---|---|---|
| | | First organic compound | compound | compound | color | E.Q.E. |
| Present Invention B | Molecular structure | 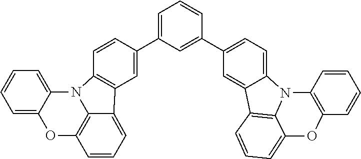 [SMILES: c1cc(-c2ccc3c(c2)c2cccc4c2n3-c2ccccc2O4)cc(-c2ccc3c(c2)c2cccc4c2n3-c2ccccc2O4)c1] | 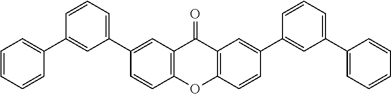 [SMILES: O=c1c2cc(-c3cccc(-c4ccccc4)c3)ccc2oc2ccc(-c3cccc(-c4ccccc4)c3)cc12] | 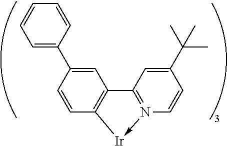 | green | 2.5 |
| | Energy | T1 = 2.8 eV | T1 = 2.8 eV | T1 = 2.4 eV | | |
| | level | | | | | |
| Comparative Example E | Molecular structure | 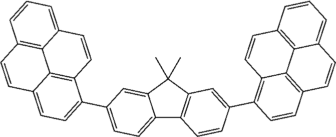 [SMILES: CC1(C)c2cc(-c3ccc4ccc5cccc6ccc3c4c56)ccc2-c2ccc(-c3ccc4ccc5cccc6ccc3c4c56)cc21] | 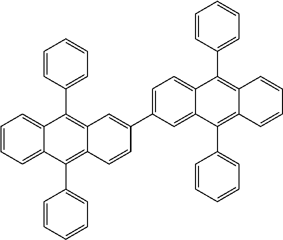 [SMILES: c1ccc(-c2c3ccccc3c(-c3ccccc3)c3cc(-c4ccc5c(-c6ccccc6)c6ccccc6c(-c6ccccc6)c5c4)ccc23)cc1] | 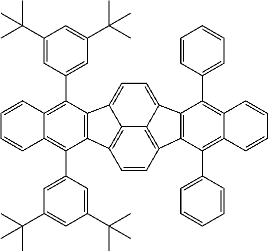 [SMILES: CC(C)(C)c1cc(-c2c3c(c(-c4cc(C(C)(C)C)cc(C(C)(C)C)c4)c4ccccc24)-c2ccc4c5c(ccc-3c25)-c2c-4c(-c3ccccc3)c3ccccc3c2-c2ccccc2)cc(C(C)(C)C)c1] | green | 1.0 |
| | Energy | T1 = 2.0 eV | T1 = 1.9 eV | S1 = 2.4 eV | | |
| | level | | | | | |
| Comparative Example F | Molecular structure | 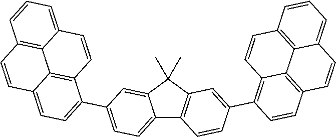 [SMILES: CC1(C)c2cc(-c3ccc4ccc5cccc6ccc3c4c56)ccc2-c2ccc(-c3ccc4ccc5cccc6ccc3c4c56)cc21] | 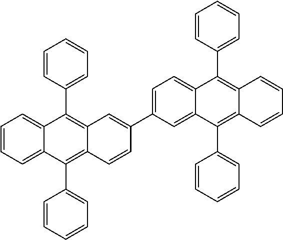 [SMILES: c1ccc(-c2c3ccccc3c(-c3ccccc3)c3cc(-c4ccc5c(-c6ccccc6)c6ccccc6c(-c6ccccc6)c5c4)ccc23)cc1] | 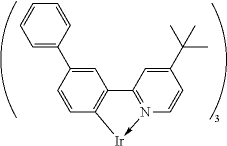 | — | <0.1 |
| | Energy | T1 = 2.0 eV | T1 = 1.9 eV | T1 = 2.4 eV | | |
| | level | | | | | |

In Comparative Example E, the luminescent compound is a luminescent compound that emits fluorescence and loses most of its T1 as thermal inactivation, and thus the E.Q.E is low. Comparative Example F is an organic light-emitting element in which the luminescent compound is a luminescent compound that emits phosphorescence and T1 of the luminescent compound is higher than T1's of the first organic compound and the second organic compound. The organic light-emitting element of Comparative Example F does not have a configuration in which T1 of the luminescent compound is the lowest and thus cannot efficiently use T1 of the luminescent compound. Thus, E.Q.E is low.

By contrast, in Present Invention B, which is an embodiment of the present invention, the luminescent compound is a luminescent compound that emits phosphorescence, and T1 of the luminescent compound is lower than T1's of the first organic compound and the second organic compound. Thus, T1 of the luminescent compound can be efficiently used for light emission, and thus E.Q.E. is high. Therefore, the organic light-emitting element according to the present invention is an organic light-emitting element having high light-emission efficiency because T1 of the luminescent compound is lower than T1's of the first organic compound and the second organic compound.

### (1-3) All Freely Rotatable Single Bonds in the First Organic Compound are Carbon-Carbon Bonds

In this specification, the first organic compound is responsible for most of the exciton generation in the organic light-emitting element. Thus, the first organic compound is required to have a skeleton that is not easily decomposable even in a high-energy excited state. Here, the skeleton that is not easily decomposable refers to a skeleton including a freely rotatable single bond having a high binding energy. In this specification, the term “freely rotatable single bond” refers to a bond represented as “A-B” where a unit A and a unit B are singly bonded, the unit A and the unit B not forming a fused-ring. The units A and B may each be an atom such as a carbon atom or a nitrogen atom or a molecule such as benzene or carbazole. Table 3 shows the binding energy of various bonds.

TABLE 3

| F1 | F2 | F3 | F4 |
|---|---|---|---|
| 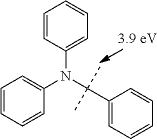 | 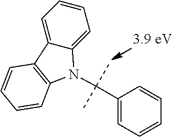 | 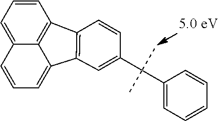 | 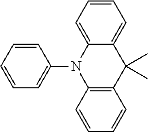 |

The binding energy of F1 and F2, which have a carbon-nitrogen bond, is 3.9 eV. The binding energy of F4, which has a freely rotatable carbon-carbon bond, is 4.5 eV, and the binding energy of F3, which has a freely rotatable bond between sp2 carbons, is 5.0 eV. Therefore, when all freely rotatable single bonds are carbon-carbon bonds, a skeleton that is not easily decomposable is formed, which is preferred. Among carbon-carbon bonds, the bond between sp2 carbons has a particularly high binding energy, and thus a skeleton in which all freely rotatable single bonds are bonds between sp2 carbons is more preferred because it is less easily decomposable.

In the organic light-emitting element according to the present invention, recombination of electrons and holes occurs not only on the first organic compound but also on the second organic compound. Thus, also in the second organic compound in addition to the first organic compound, all freely rotatable single bonds are preferably carbon-carbon bonds. From the viewpoint of binding stability, it is more preferred that all freely rotatable single bonds be bonds between sp2 carbons.

Table 4 compares the element durability of organic light-emitting elements in terms of first organic compounds having different skeletons.

TABLE 4

| | | | | Luminescent | Element |
|---|---|---|---|---|---|
| | | First organic compound | Second organic compound | compound | durability |
| Present Invention C | Molecular structure | 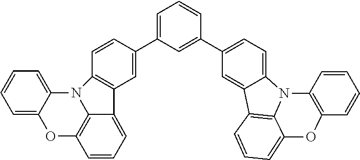 [SMILES: c1cc(-c2ccc3c(c2)c2cccc4c2n3-c2ccccc2O4)cc(-c2ccc3c(c2)c2cccc4c2n3-c2ccccc2O4)c1] | 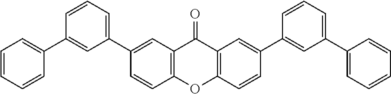 [SMILES: O=c1c2cc(-c3cccc(-c4ccccc4)c3)ccc2oc2ccc(-c3cccc(-c4ccccc4)c3)cc12] | 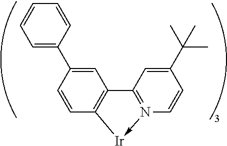 | 1.8 |
| | LUMO | −2.72 | −3.33 | −2.35 | |
| | HOMO | −5.76 | −6.43 | −5.08 | |
| Present Invention D | Molecular structure | 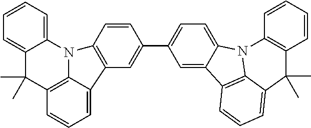 | 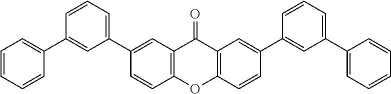 [SMILES: O=c1c2cc(-c3cccc(-c4ccccc4)c3)ccc2oc2ccc(-c3cccc(-c4ccccc4)c3)cc12] | 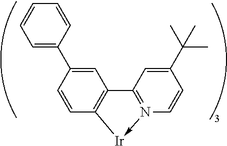 | 1.5 |
| | LUMO | −2.37 | −3.33 | −2.35 | |
| | HOMO | −5.83 | −6.43 | −5.08 | |
| Comparative Example G | Molecular structure | 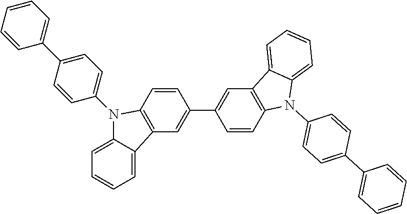 [SMILES: c1ccc(-c2ccc(-n3c4ccccc4c4cc(-c5ccc6c(c5)c5ccccc5n6-c5ccc(-c6ccccc6)cc5)ccc43)cc2)cc1] | 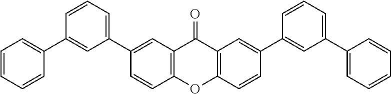 [SMILES: O=c1c2cc(-c3cccc(-c4ccccc4)c3)ccc2oc2ccc(-c3cccc(-c4ccccc4)c3)cc12] | 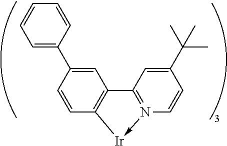 | 1.0 |
| | LUMO | −2.47 | −3.33 | −2.35 | |
| | HOMO | −5.73 | −6.43 | −5.08 | |

Comparative Example G, in which some of the freely rotatable single bonds in the first organic compound are carbon-nitrogen bonds with a low binding energy, is inferior to the present invention in element durability. By contrast, Present Inventions C and D, in which freely rotatable single bonds in the first organic compound are carbon-carbon bonds with a high binding energy, have high element durability. In particular, Present Invention C, in which freely rotatable single bonds are bonds between sp2 carbons with a higher binding energy, exhibits higher element durability. Therefore, the organic light-emitting element according to the present invention is an organic light-emitting element having high element durability because all freely rotatable single bonds in the first organic compound are carbon-carbon bonds.

### (1-4) The First Organic Compound and the Second Organic Compound Satisfy |HOMO(H2)|>|HOMO(H1)|

In the organic light-emitting element according to the present invention, the first organic compound is mainly responsible for hole transport, and thus the hole injectability into the first organic compound is required to be higher than the hole injectability into the second organic compound. Thus, the organic light-emitting element according to the present invention needs to satisfy the relation of formula (1).

|HOMO(H2)|>|HOMO(H1)| (1)

When the absolute value of the HOMO level of the first organic compound is smaller than the absolute value of the HOMO level of the second organic compound, the hole injectability into the first organic compound can be expected to improve.

In the organic light-emitting element according to the present invention, the second organic compound is mainly responsible for electron transport. Examples of skeletons having electron transportability include azine derivatives and ketone derivatives, but these skeletons have poor stability in a radical cation state and thus are not suitable for hole transport. Therefore, it is preferred that holes can be efficiently injected from the second organic compound to the first organic compound. Also from this viewpoint, it is preferable to satisfy formula (1).

The organic light-emitting element according to the present invention preferably further has the following configurations. Only one of the following configurations may be satisfied, or two or more of the configurations may be satisfied.

### (1-5) At Least One of Formula (2) or (3) is Satisfied

|LUMO(H2)|>|LUMO(D)| (2)

|HOMO(D)|>|HOMO(H1)| (3)

### (1-6) Formulas (2) and (4) are Satisfied

|LUMO(H2)|>|LUMO(D)| (2)

|LUMO(H1)|>|LUMO(D)| (4)

(1-7) Formulas (3) to (5) are satisfied

|HOMO(D)|>|HOMO(H1)| (3)

|LUMO(H1)|>|LUMO(D)| (4)

|LUMO(H1)|>|LUMO(H2)| (5)

These will be described below.

### (1-5) At Least One of Formula (2) or Formula (3) is Satisfied

|LUMO(H2)|>|LUMO(D)| (2)

|HOMO(D)|>|HOMO(H1)| (3)

In the organic light-emitting element according to the present invention, electrons and holes are preferably less likely to concentrate on the luminescent compound. In other words, exciton generation is preferably less likely to concentrate on the luminescent compound. This is because concentration of exciton generation on the luminescent compound may cause transition of the luminescent compound to a higher-energy state. As a result, the luminescent compound undergoes bond cleavage so that the concentration of the luminescent compound in the light-emitting layer decreases, thus resulting in luminance degradation. Thus, at least one of formula (2) or (3) is preferably satisfied. Satisfying one of them reduces the likelihood that electrons and holes are simultaneously trapped on the luminescent compound, thus reducing the likelihood of concentration of exciton generation. Thus, the organic light-emitting element has higher element durability.

More preferably, formulas (2) and (3) are simultaneously satisfied. Simultaneously satisfying formulas (2) and (3) reduces the likelihood that electrons and holes concentrate on the luminescent compound, which is more preferred from the viewpoint of the element durability of the organic light-emitting element.

Tables 5 to 7 show the configuration of organic light-emitting elements according to the present invention and the relative value of element durability. In Table 5, the element durability of Present Invention E is a value based on the element durability of Present Invention F taken as 1.0. In Table 6, the element durability of Present Invention G is a value based on the element durability of Present Invention H taken as 1.0. In Table 7, the element durability of Comparative Example H is a value based on the element durability of Comparative Example I taken as 1.0.

TABLE 5

| | | | | | Ele- |
|---|---|---|---|---|---|
| | | | | | ment |
| | | First organic | Second organic | Luminescent | dura- |
| | | compound | compound | compound | bility |
| Pres- ent In- ven- tion E | Mo- lec- ular struc- ture | 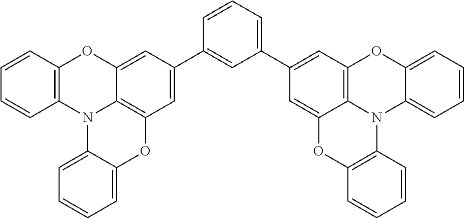 [SMILES: c1cc(-c2cc3c4c(c2)Oc2ccccc2N4c2ccccc2O3)cc(-c2cc3c4c(c2)Oc2ccccc2N4c2ccccc2O3)c1] | 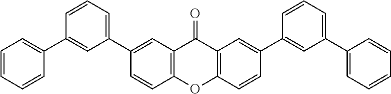 [SMILES: O=c1c2cc(-c3cccc(-c4ccccc4)c3)ccc2oc2ccc(-c3cccc(-c4ccccc4)c3)cc12] | 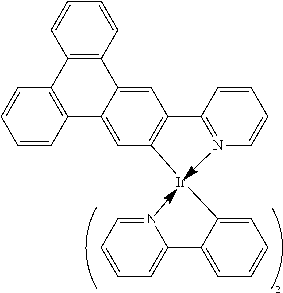 | 1.2 |
| | LU- | −2.74 | −3.33 | −3.04 | |
| | MO | | | | |
| | HO- | −5.63 | −6.43 | −5.68 | |
| | MO | | | | |
| Pres- ent In- ven- tion F | Mo- lec- ular struc- ture | 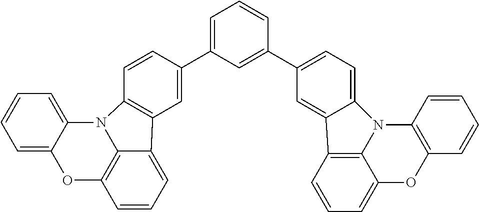 [SMILES: c1cc(-c2ccc3c(c2)c2cccc4c2n3-c2ccccc2O4)cc(-c2ccc3c(c2)c2cccc4c2n3-c2ccccc2O4)c1] | 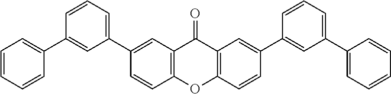 [SMILES: O=c1c2cc(-c3cccc(-c4ccccc4)c3)ccc2oc2ccc(-c3cccc(-c4ccccc4)c3)cc12] | 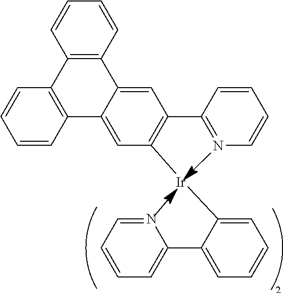 | 1.0 |
| | LU- | 2.72 | −3.33 | −3.04 | |
| | MO | | | | |
| | HO- | −5.76 | −6.43 | −5.68 | |
| | MO | | | | |

TABLE 6

| | | | | | Ele |
|---|---|---|---|---|---|
| | | | | | ment |
| | | First organic | Second organic | Luminescent | dura- |
| | | compound | compound | compound | bility |
| Pres- ent In- ven- tion G | Molec- ular struc- ture | 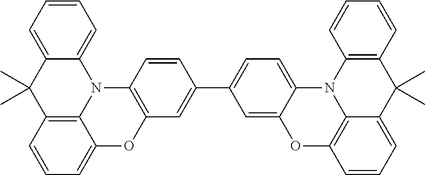 | 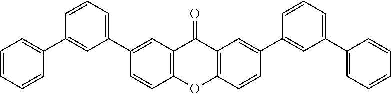 [SMILES: O=c1c2cc(-c3cccc(-c4ccccc4)c3)ccc2oc2ccc(-c3cccc(-c4ccccc4)c3)cc12] | 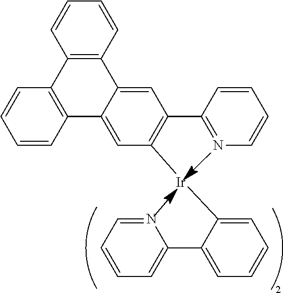 | 1.1 |
| | LUMO | −2.72 | −3.33 | −3.04 | |
| | HOMO | −5.66 | −6.43 | −5.68 | |
| Pres- ent In- ven- tion H | Molec- ular struc- ture | 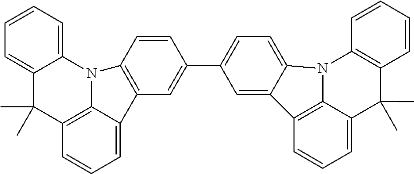 | 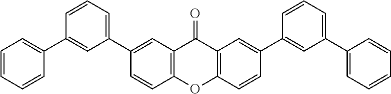 [SMILES: O=c1c2cc(-c3cccc(-c4ccccc4)c3)ccc2oc2ccc(-c3cccc(-c4ccccc4)c3)cc12] | 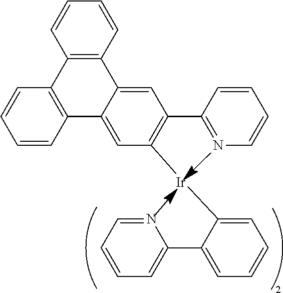 | 1.0 |
| | LUMO | −2.37 | −3.33 | −3.04 | |
| | HOMO | −5.83 | −6.43 | −5.68 | |

TABLE 7

| | | | | | Ele- |
|---|---|---|---|---|---|
| | | | | | ment |
| | | First organic | Second organic | Luminescent | dura- |
| | | compound | compound | compound | bility |
| Com- para- tive Ex- am- ple H | Molec- ular struc- ture | 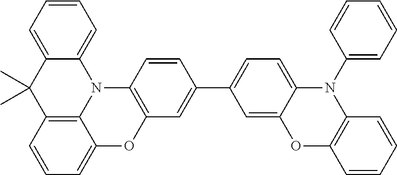 [SMILES: CC1(C)c2ccccc2N2c3ccc(-c4ccc5c(c4)Oc4ccccc4N5c4ccccc4)cc3Oc3cccc1c32] | 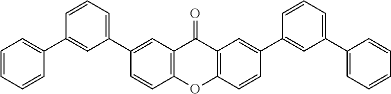 [SMILES: O=c1c2cc(-c3cccc(-c4ccccc4)c3)ccc2oc2ccc(-c3cccc(-c4ccccc4)c3)cc12] | 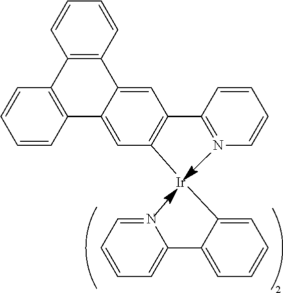 | 1.0 |
| | LUMO | −2.71 | −3.33 | −3.04 | |
| | HOMO | −5.64 | −6.43 | −5.68 | |
| Com- para- tive Ex- am- ple I | Molec- ular struc- ture | 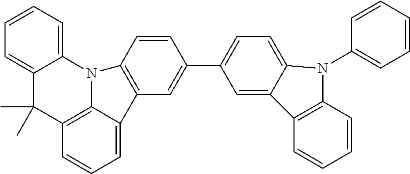 [SMILES: CC1(C)c2ccccc2-n2c3ccc(-c4ccc5c(c4)c4ccccc4n5-c4ccccc4)cc3c3cccc1c32] | 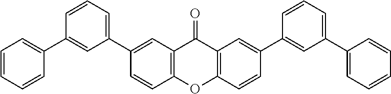 [SMILES: O=c1c2cc(-c3cccc(-c4ccccc4)c3)ccc2oc2ccc(-c3cccc(-c4ccccc4)c3)cc12] | 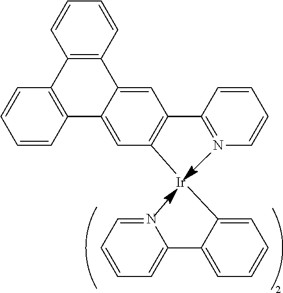 | 1.0 |
| | LUMO | −2.36 | −3.33 | −3.04 | |
| | HOMO | −5.82 | −6.43 | −5.68 | |

In Tables 5 and 6, Present Inventions E and G are configurations satisfying formulas (2) and (3). By contrast, Present Inventions F and H are configurations satisfying formula (2) alone. Although the configurations satisfying formula (2) alone can provide high element durability, the configurations satisfying formulas (2) and (3) exhibit higher element durability. This is because electrons and holes are less likely to concentrate on the luminescent compound as described above, so that deterioration of the luminescent compound can be suppressed.

Furthermore, referring to Present Inventions E and G in Tables 5 and 6, the value of element durability of Present Invention E, in which all freely rotatable single bonds in the first organic compound are bonds between sp2 carbons, is 1.2, which is higher than that of Present Invention G. Therefore, the higher the binding stability of the skeleton of the first organic compound, the larger the effect of the configuration (1-4).

In Table 7, Comparative Example H satisfies formulas (2) and (3), and Comparative Example I satisfies formula (2) alone. However, since a carbon-nitrogen bond is included as a freely rotatable single bond in the first organic compound, the binding stability is low, and no improvement in element durability is observed. Therefore, the element durability-improving effect of this configuration can be sufficiently produced in the case of an organic light-emitting element containing an organic compound in which all freely rotatable single bonds are carbon-carbon bonds.

### (1-6) Formulas (2) and (4) are Satisfied

|LUMO(H2)|>|LUMO(D)| (2)

|LUMO(H1)|>|LUMO(D)| (4)

In the organic light-emitting element according to the present invention, the absolute value of the LUMO level of the luminescent compound is preferably the lowest. This is because the above configuration further reduces the likelihood that electrons are trapped on the luminescent compound. As a result, exciton generation on the luminescent compound can be suppressed, thus leading to further improved element durability.

Table 8 shows the configuration and element durability of organic light-emitting elements. Present Invention I is a configuration in which the compound whose absolute value of the LUMO level is the smallest is the luminescent compound. Present Invention J is a configuration in which the compound whose absolute value of the LUMO level is the smallest is the first organic compound.

TABLE 8

| | | | | | Ele- |
|---|---|---|---|---|---|
| | | | | | ment |
| | | | | Luminescent | dura- |
| | | First organic compound | Second organic compound | compound | bility |
| Pres- ent In- ven- tion I | Molec- ular struc- ture | 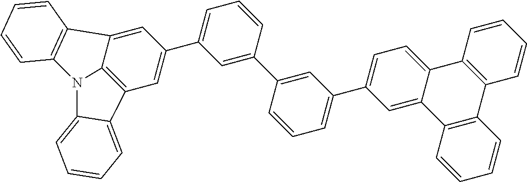 [SMILES: c1cc(-c2cccc(-c3cc4c5ccccc5n5c6ccccc6c(c3)c45)c2)cc(-c2ccc3c4ccccc4c4ccccc4c3c2)c1] | 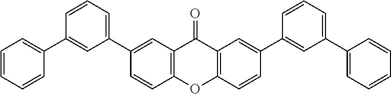 [SMILES: O=c1c2cc(-c3cccc(-c4ccccc4)c3)ccc2oc2ccc(-c3cccc(-c4ccccc4)c3)cc12] | 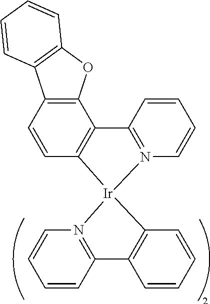 | 1.3 |
| | LUMO | −2.97 | −3.33 | −2.95 | |
| | HOMO | −6.10 | −6.43 | −5.62 | |
| Pres- ent In- ven- tion J | Molec- ular struc- ture | 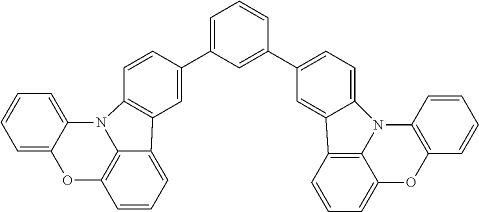 [SMILES: c1cc(-c2ccc3c(c2)c2cccc4c2n3-c2ccccc2O4)cc(-c2ccc3c(c2)c2cccc4c2n3-c2ccccc2O4)c1] | 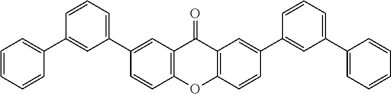 [SMILES: O=c1c2cc(-c3cccc(-c4ccccc4)c3)ccc2oc2ccc(-c3cccc(-c4ccccc4)c3)cc12] | 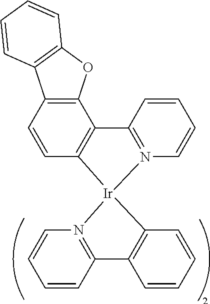 | 1.0 |
| | LUMO | −2.72 | −3.33 | −2.95 | |
| | HOMO | −5.76 | −6.43 | −5.62 | |

Table 8 shows that the element durability of Present Invention I is higher than the element durability of Present Invention J. This is because in Configuration I of the present invention, the compound whose absolute value of the LUMO level is the smallest is the luminescent compound, so that exciton generation on the luminescent compound can be suppressed.

### (1-7) Formulas (3) to (5) are Satisfied

|HOMO(D)|>|HOMO(H1)| (3)

|LUMO(H1)|>|LUMO(D)| (4)

|LUMO(H1)|>|LUMO(H2)| (5)

In the organic light-emitting element according to the present invention, exciton generation preferably concentrates on the first organic compound. In other words, it is preferred that the absolute value of the HOMO level of the first organic compound be the smallest and the absolute value of the LUMO level of the first organic compound be the largest. This is because having the above configuration enables recombination of electrons and holes to be more efficiently performed on the first organic compound. In addition, the rate of consumption of excitons can also be improved, and thus the effect of suppressing deactivation of excitons can also be produced.

Table 9 shows the configuration and element durability of organic light-emitting elements. Present Invention K is a configuration in which the absolute value of the HOMO level of the first organic compound is the smallest and the absolute value of the LUMO level of the first organic compound is the largest. Configuration L of the present invention is a configuration in which the absolute value of the HOMO level of the luminescent compound is the smallest and the absolute value of the LUMO level of the first organic compound is the largest.

TABLE 9

| | | | | | Ele- |
|---|---|---|---|---|---|
| | | | | | ment |
| | | | | Luminescent | dura- |
| | | First organic compound | Second organic compound | compound | bility |
| Pres- ent In- ven- tion K | Molec- ular struc- ture | 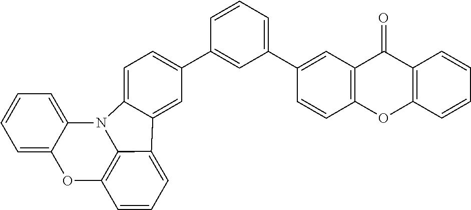 [SMILES: O=c1c2ccccc2oc2ccc(-c3cccc(-c4ccc5c(c4)c4cccc6c4n5-c4ccccc4O6)c3)cc12] | 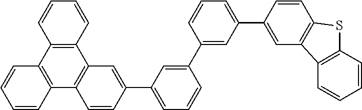 [SMILES: c1cc(-c2cccc(-c3ccc4c5ccccc5c5ccccc5c4c3)c2)cc(-c2ccc3sc4ccccc4c3c2)c1] | 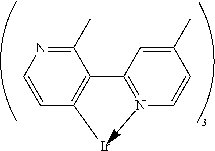 | 1.1 |
| | LUMO | −3.26 | −2.92 | −2.99 | |
| | HOMO | −5.75 | −6.38 | −5.98 | |
| Pres- ent In- ven- tion L | Molec- ular struc- ture | 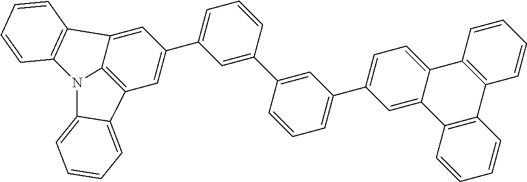 [SMILES: c1cc(-c2cccc(-c3cc4c5ccccc5n5c6ccccc6c(c3)c45)c2)cc(-c2ccc3c4ccccc4c4ccccc4c3c2)c1] | 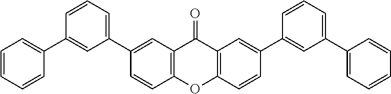 [SMILES: O=c1c2cc(-c3cccc(-c4ccccc4)c3)ccc2oc2ccc(-c3cccc(-c4ccccc4)c3)cc12] | 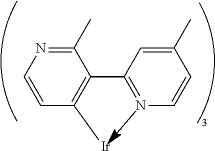 | 1.0 |
| | LUMO | −2.97 | −3.33 | −2.99 | |
| | HOMO | −6.10 | −6.43 | −5.98 | |

Table 9 shows that the element durability of Present Invention K is higher than the element durability of Present Invention L. This is because Present Invention K is a configuration in which the absolute value of the HOMO level of the first organic compound is the smallest and the absolute value of the LUMO level of the first organic compound is the largest, so that exciton generation is generated concentratedly on the first organic compound.

### (2) First Organic Compound

In the organic light-emitting element according to the present invention, all freely rotatable single bonds in the first organic compound are carbon-carbon bonds. Preferably, all the freely rotatable single bonds are constituted by bonds between sp2 carbons.

As described in (1-2), in the light-emitting layer of the organic light-emitting element according to the present invention, T1's of the first organic compound and the second organic compound are higher than T1 of the luminescent compound. Organic compounds have a large band gap because their lowest excited singlet energy (S1) is higher than their T1. In other words, the difference between the HOMO level and the LUMO level of the first organic compound and the second organic compound is large. Therefore, electrons or holes are likely to be trapped on the luminescent compound. This results in concentration of exciton generation on the luminescent compound, thus leading to deterioration of the luminescent compound. Thus, the first organic compound preferably has hole transportability. The use of an organic compound that exhibits hole transportability as the first organic compound can suppress concentration of exciton generation on the luminescent compound. In this specification, hole transportability means having the ability to move holes. More preferably, the mobility of holes is higher than that of electrons. Specifically, the first organic compound preferably has a skeleton represented by general formula (1-1) or (1-2).

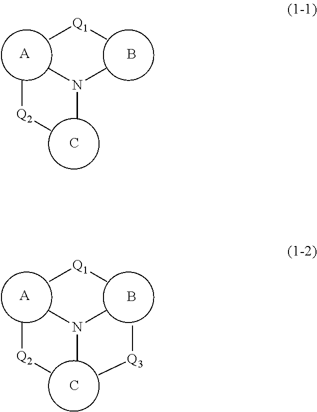

In general formulas (1-1) and (1-2), cyclic units A to C are each independently selected from a substituted or unsubstituted aryl group and a substituted or unsubstituted heteroaryl group. Q₁ to Q₃ are each independently selected from a direct bond, C(R_{A})(R_{B}), N(R_{C}), an oxygen atom, a sulfur atom, a selenium atom, and a tellurium atom. R_{A} to R_{C} are each independently selected from a hydrogen atom, a deuterium atom, a halogen atom, a substituted or unsubstituted alkyl group, a substituted or unsubstituted alkoxy group, a substituted or unsubstituted aryl group, and a substituted or unsubstituted heteroaryl group. R_{C} forms a ring together with adjacent one of the cyclic units A to C.

Specific skeletons represented by general formulas (1-1) and (1-2) are shown below, but these are not meant to be limiting.

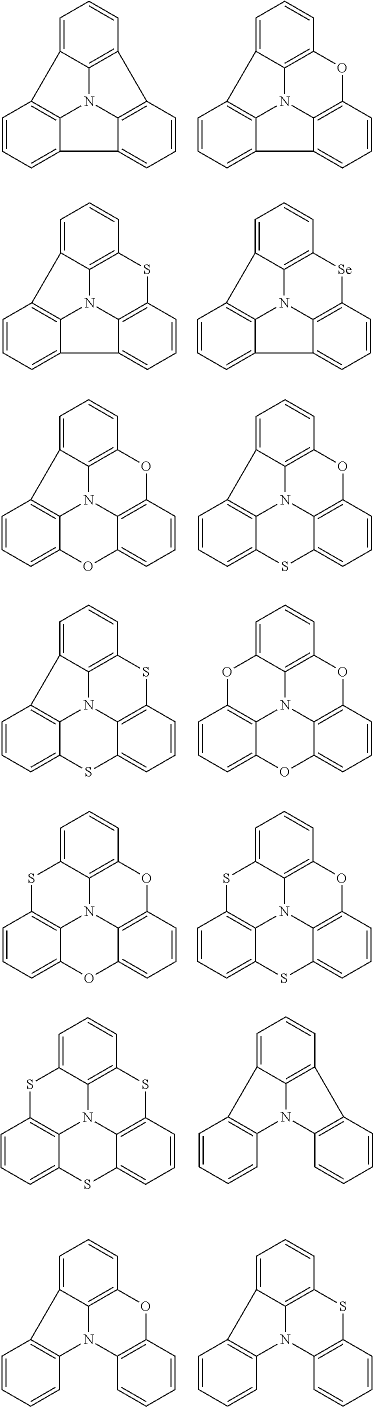

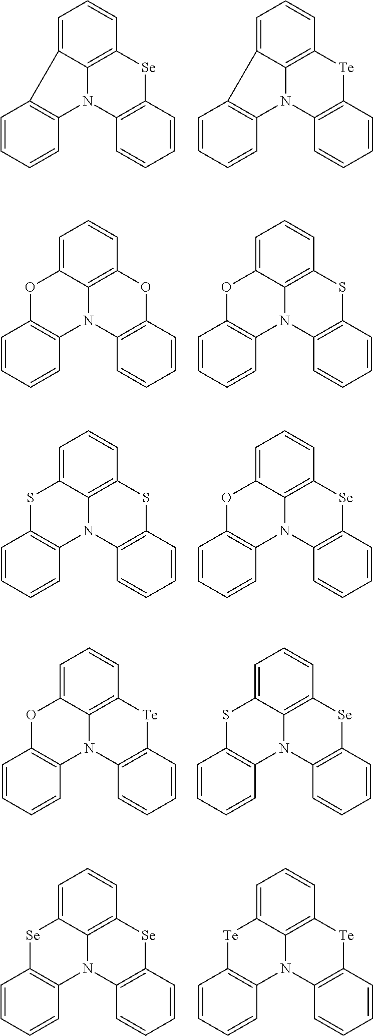

General formulas (1-1) and (1-2) may have an aryl group or a heteroaryl group through a direct bond or a phenyl group. The number of such phenyl groups may be one or more. The phenyl group may be bonded at the meta position or the para position, and is preferably bonded at the meta position. The aryl group or the heteroaryl group bonded through the phenyl group may further have a substituent, and the substituent may be an alkyl group having 1 to 4 carbon atoms or an aryl group having 6 to 12 carbon atoms. Specifically, the substituent may be a methyl group, a tert-butyl group, a phenyl group, or a biphenyl group.

Specific examples of the first organic compound are shown below. However, the present invention is not limited thereto.

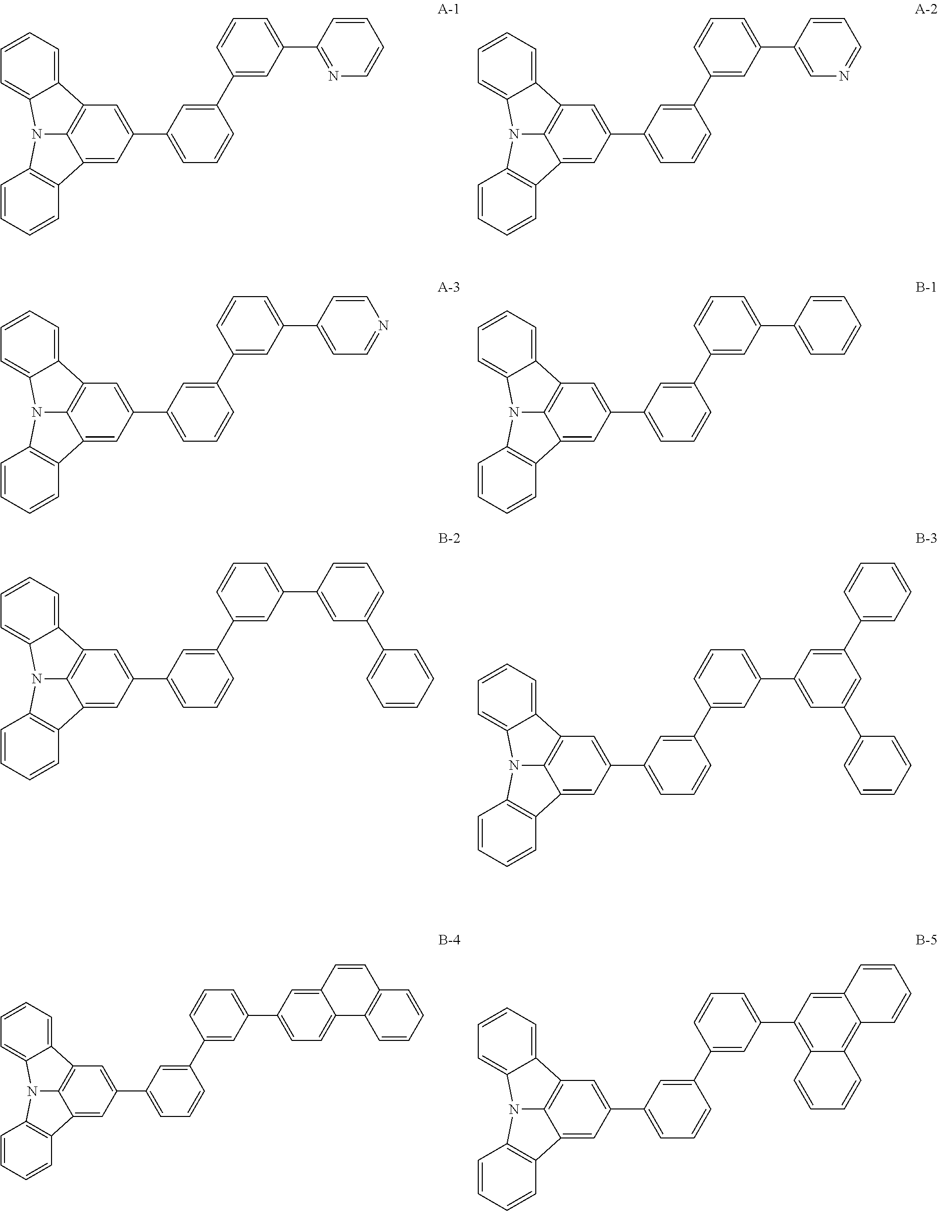

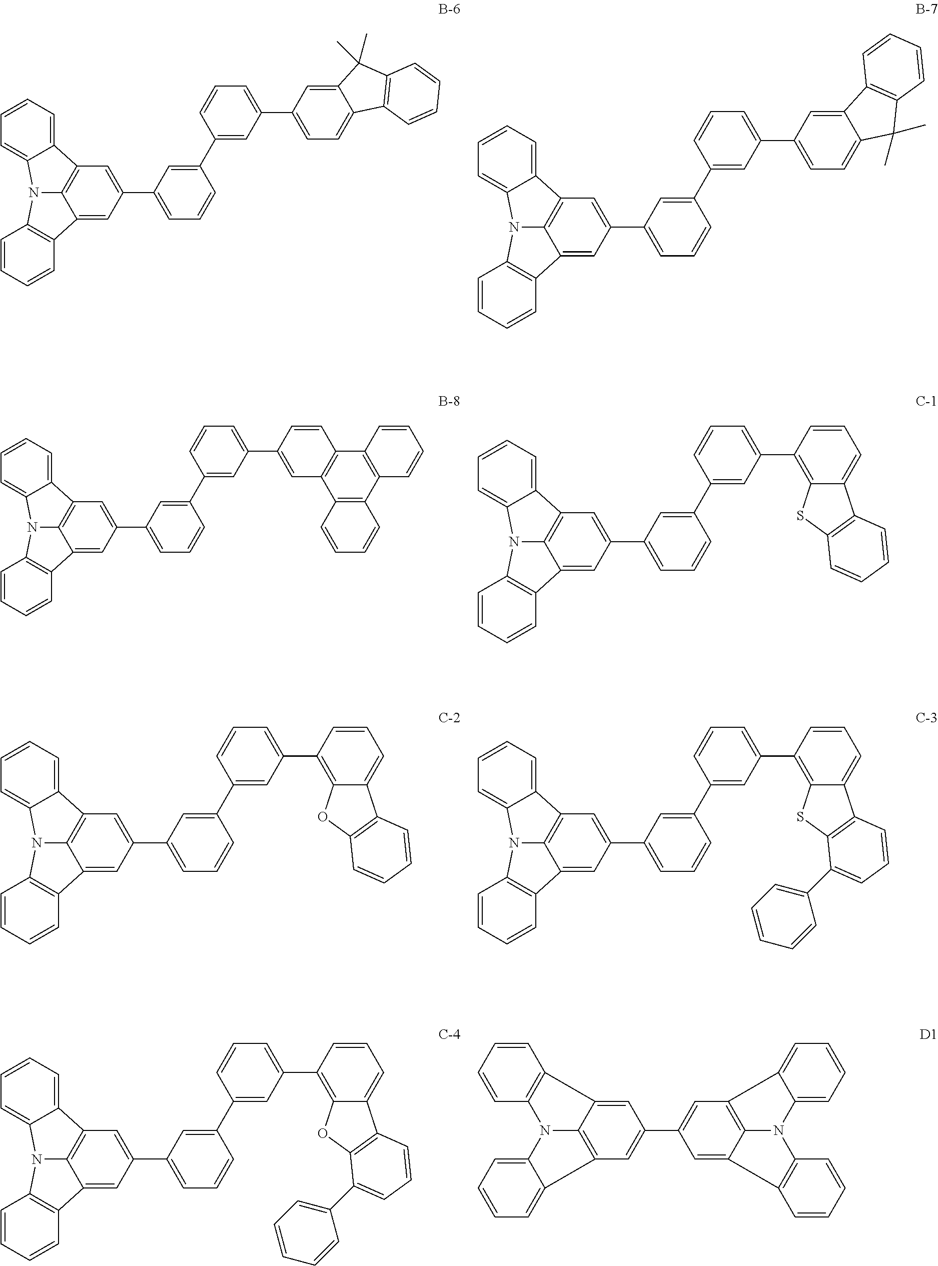

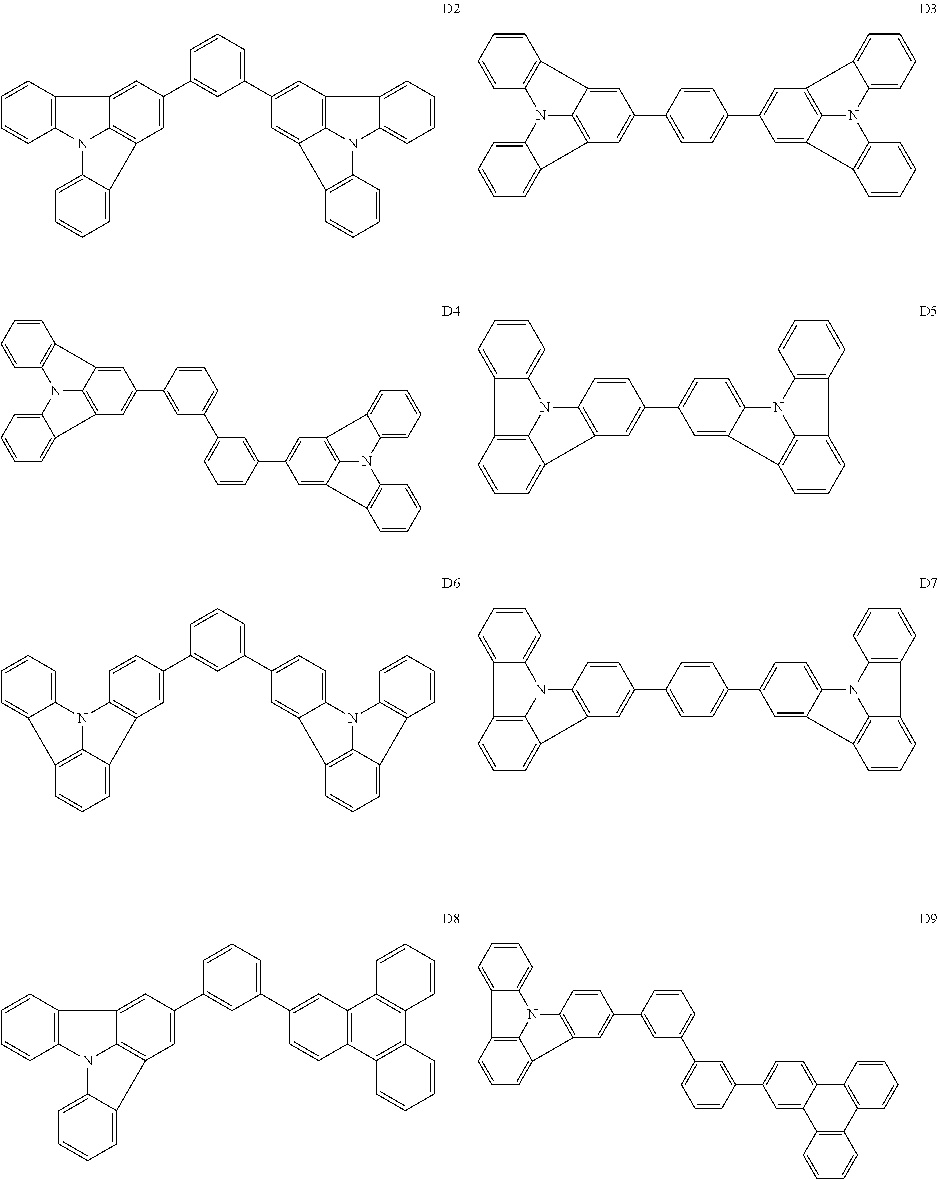

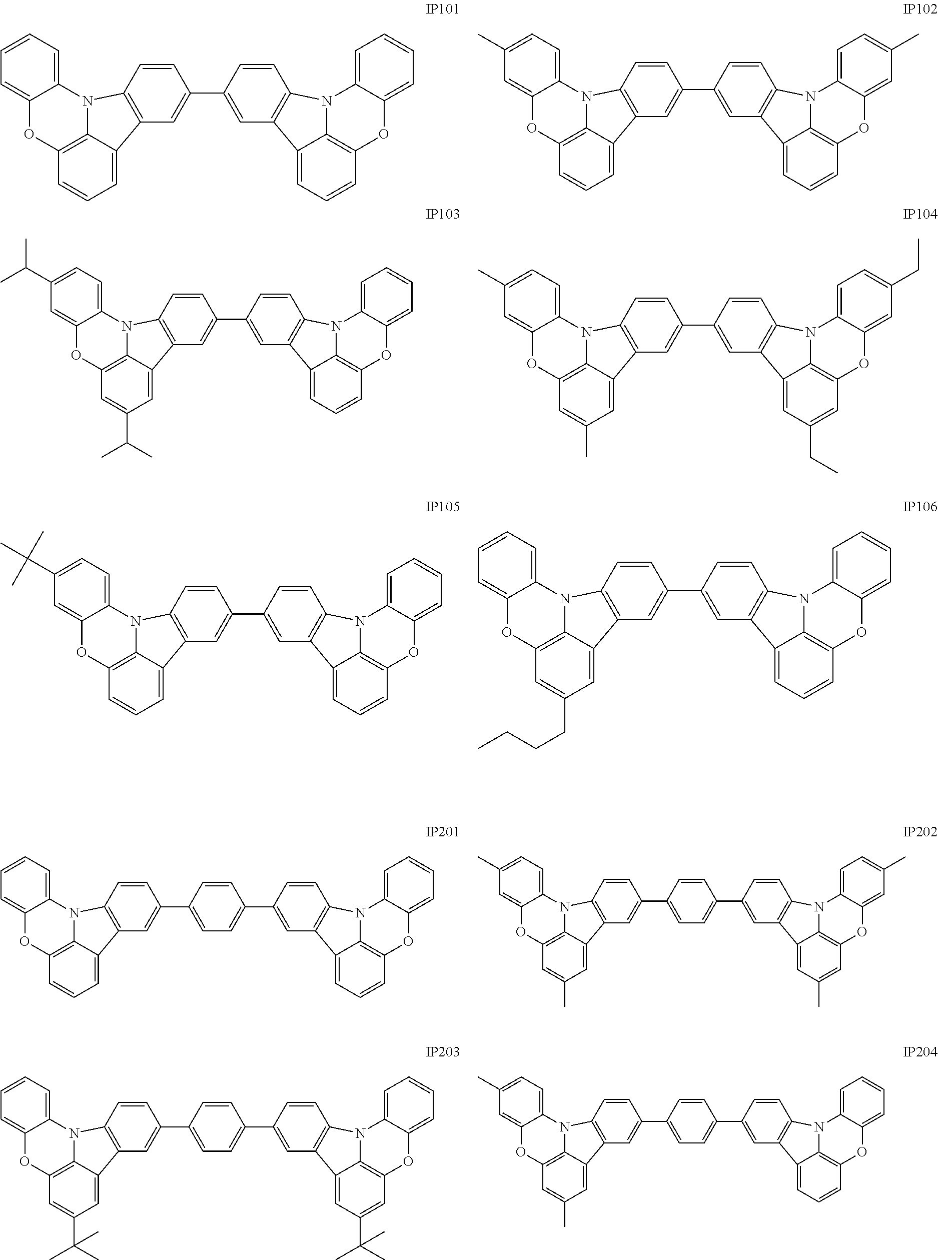

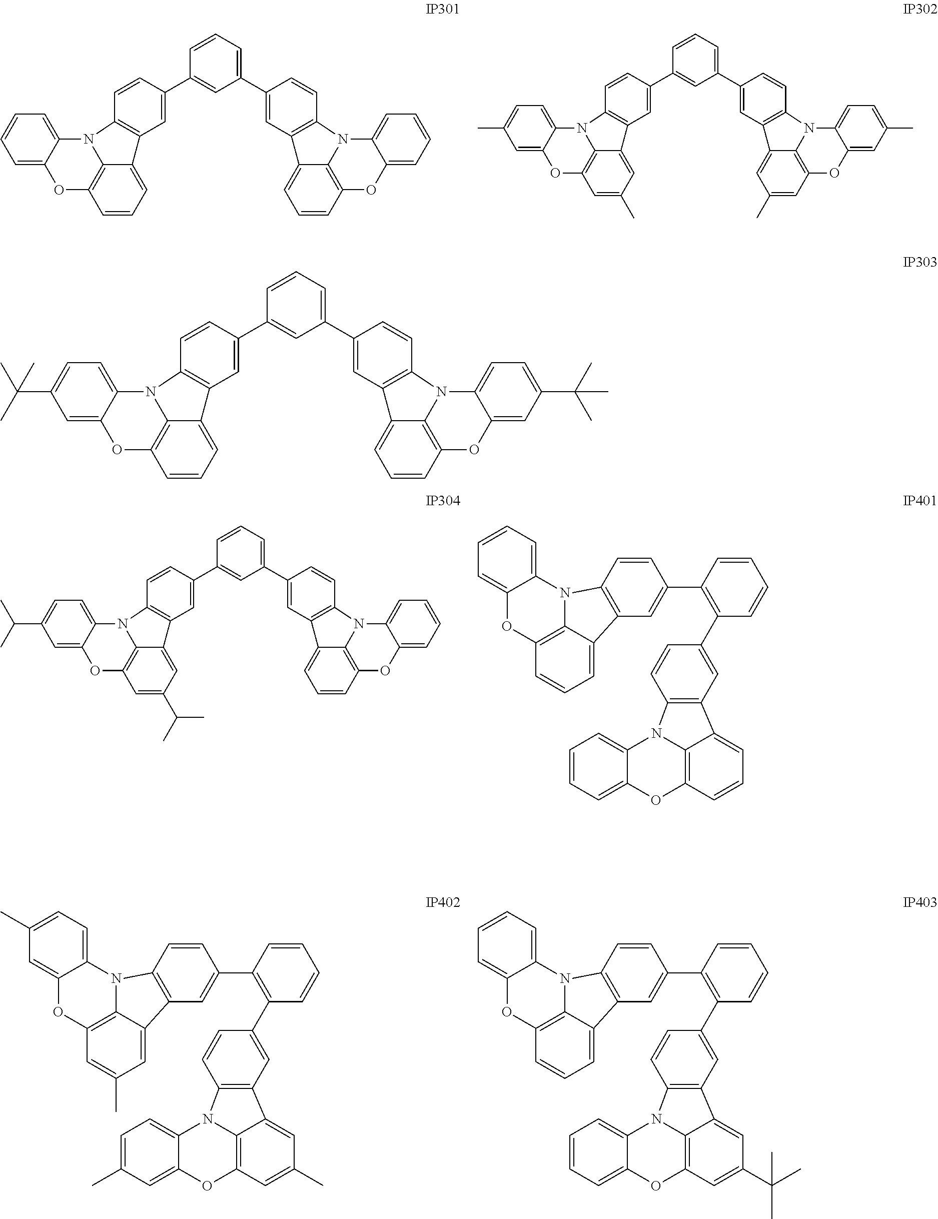

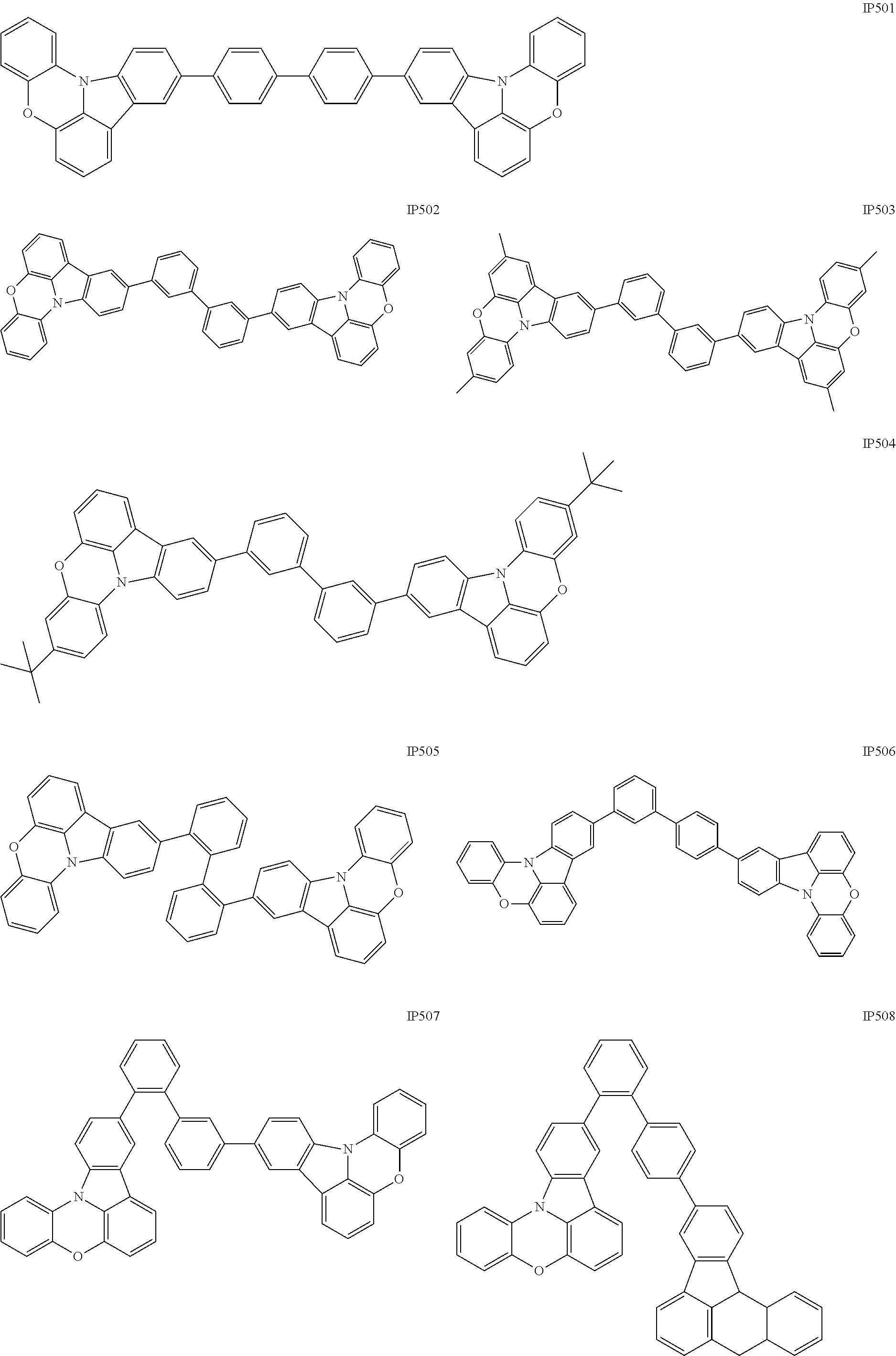

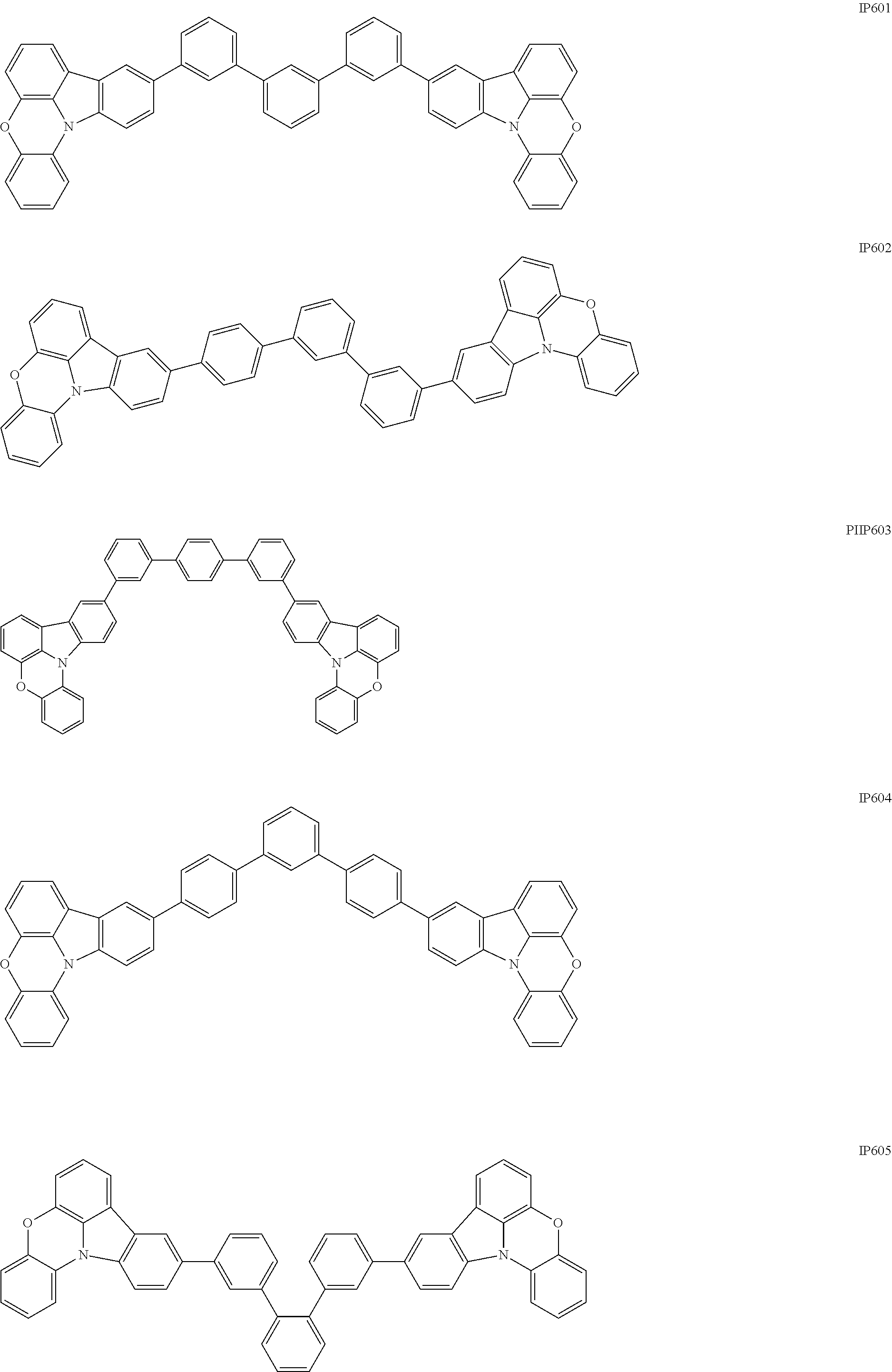

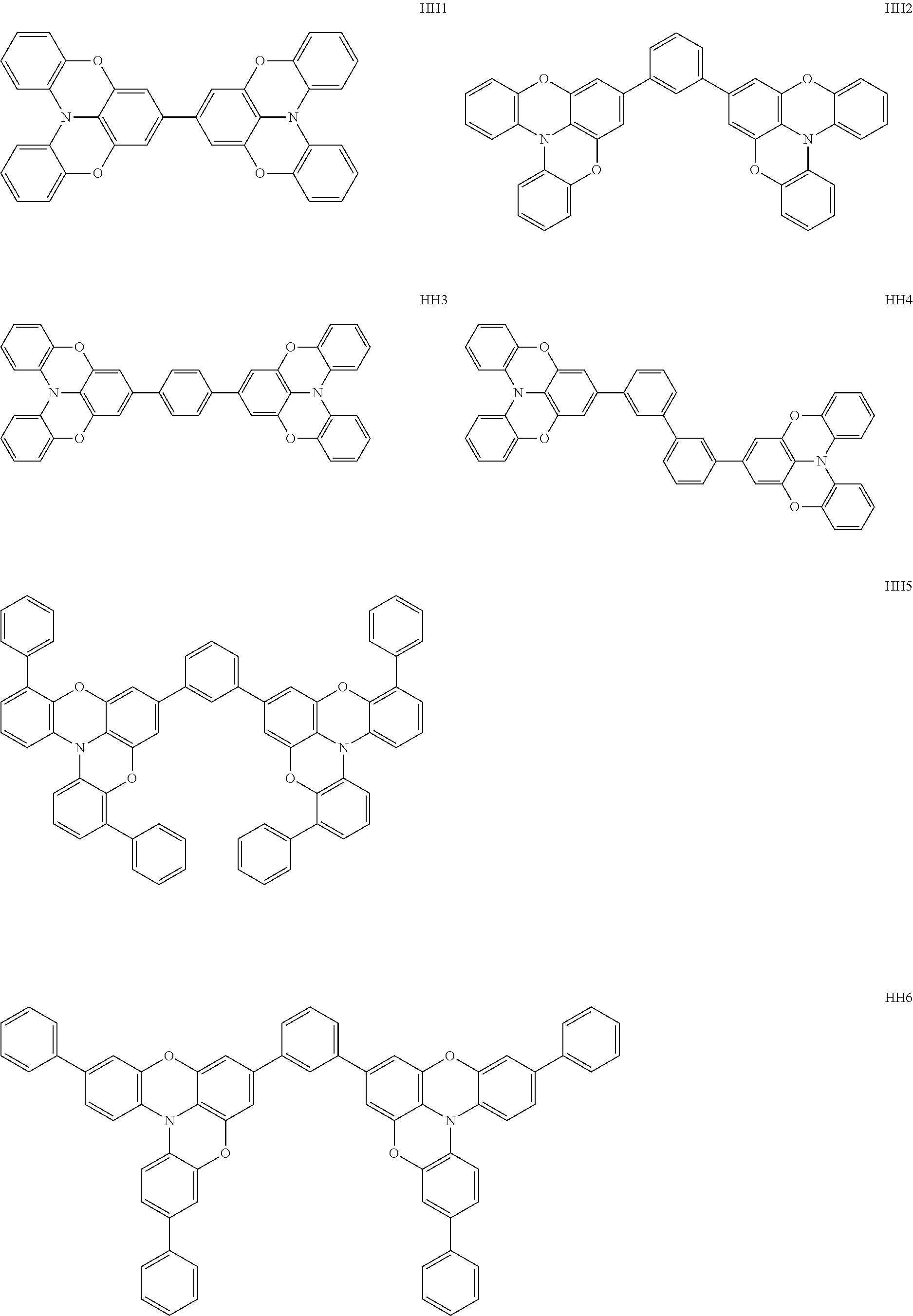

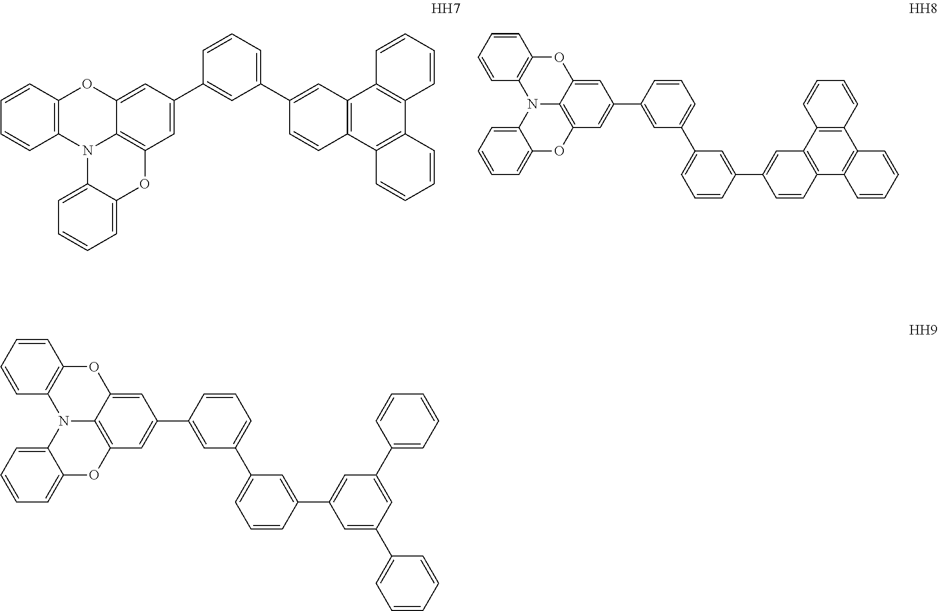 [SMILES: c1cc(-c2cc3c4c(c2)Oc2ccccc2N4c2ccccc2O3)cc(-c2ccc3c4ccccc4c4ccccc4c3c2)c1 ; c1cc(-c2cccc(-c3ccc4c5ccccc5c5ccccc5c4c3)c2)cc(-c2cc3c4c(c2)Oc2ccccc2N4c2ccccc2O3)c1 ; c1ccc(-c2cc(-c3ccccc3)cc(-c3cccc(-c4cccc(-c5cc6c7c(c5)Oc5ccccc5N7c5ccccc5O6)c4)c3)c2)cc1]

### (3) Second Organic Compound

In the organic light-emitting element according to the present invention, all freely rotatable single bonds in the second organic compound are carbon-carbon bonds. Preferably, all the freely rotatable single bonds are constituted by bonds between sp2 carbons. To further suppress exciton generation on the luminescent compound, it is preferable to use an organic compound having electron transportability as the second organic compound. This is because having this configuration can further suppress exciton generation on the luminescent compound. In this specification, electron transportability means having the ability to move electrons. More preferably, the mobility of electrons is higher than that of holes. Specifically, the second organic compound preferably has a skeleton represented by any of general formulas (2-1) to (2-7).

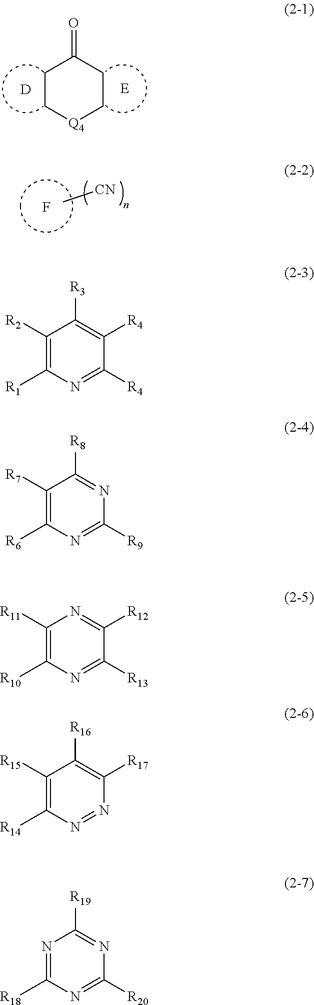

In general formulas (2-1) and (2-2), cyclic units D to F are each independently selected from a substituted or unsubstituted aryl group and a substituted or unsubstituted heteroaryl group. Q₄ is selected from a direct bond, C(R_{D})(R_{E}), an oxygen atom, a sulfur atom, a selenium atom, and a tellurium atom. R_{D} and R_{E} are each independently selected from a hydrogen atom, a deuterium atom, a halogen atom, a substituted or unsubstituted alkyl group, a substituted or unsubstituted alkoxy group, a substituted or unsubstituted aryl group, and a substituted or unsubstituted heteroaryl group. n is an integer of 1 to 5.

In general formulas (2-3) to (2-7), R₁ to R₂₀ are each independently selected from a hydrogen atom, a deuterium atom, a halogen atom, a substituted or unsubstituted alkyl group, and a substituted or unsubstituted aryl group. Among R₁ to R₂₀, substituents adjacent to each other may be bonded together to form a fused ring.

Specific skeletons represented by general formulas (2-1) to (2-7) are shown below, but these are not meant to be limiting.

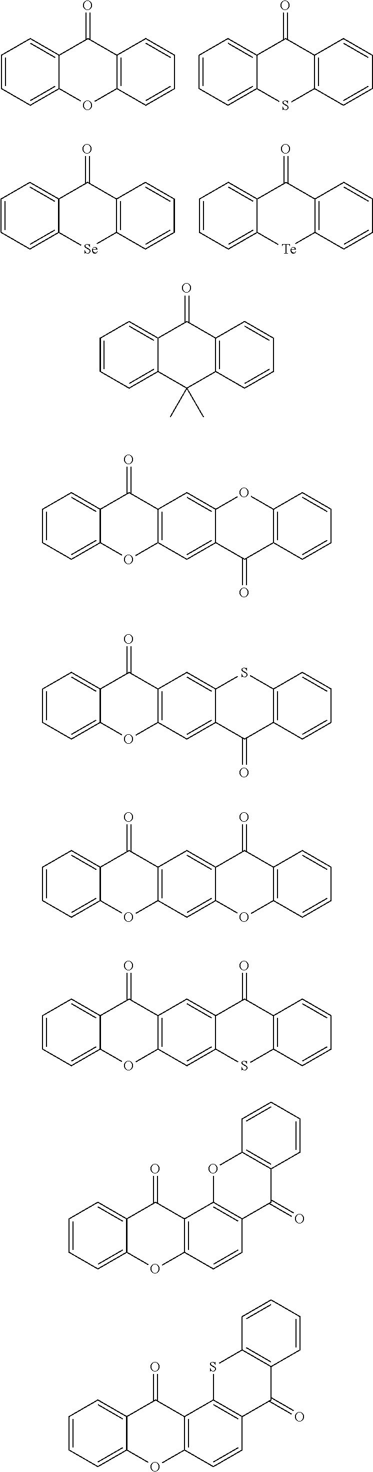

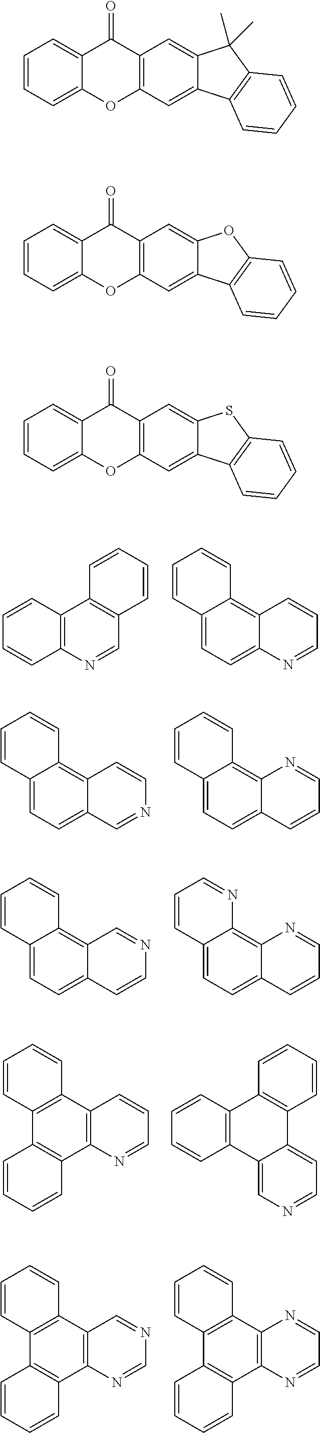

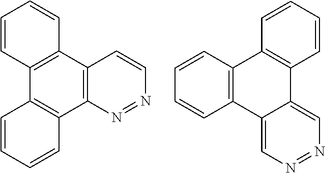

General formulas (2-1) to (2-7) may have an aryl group or a heteroaryl group through a phenyl group or a pyridyl group. The number of such phenyl groups or pyridyl groups may be one or more. The phenyl group or the pyridyl group may be bonded at the meta position or the para position, and is preferably bonded at the meta position. The aryl group or the heteroaryl group bonded through the phenyl group or the pyridyl group may further have a substituent, and the substituent may be an aryl group having 6 to 12 carbon atoms. Specifically, the substituent may be a phenyl group or a biphenyl group.

Specific examples of the second organic compound are shown below. However, the present invention is not limited thereto.

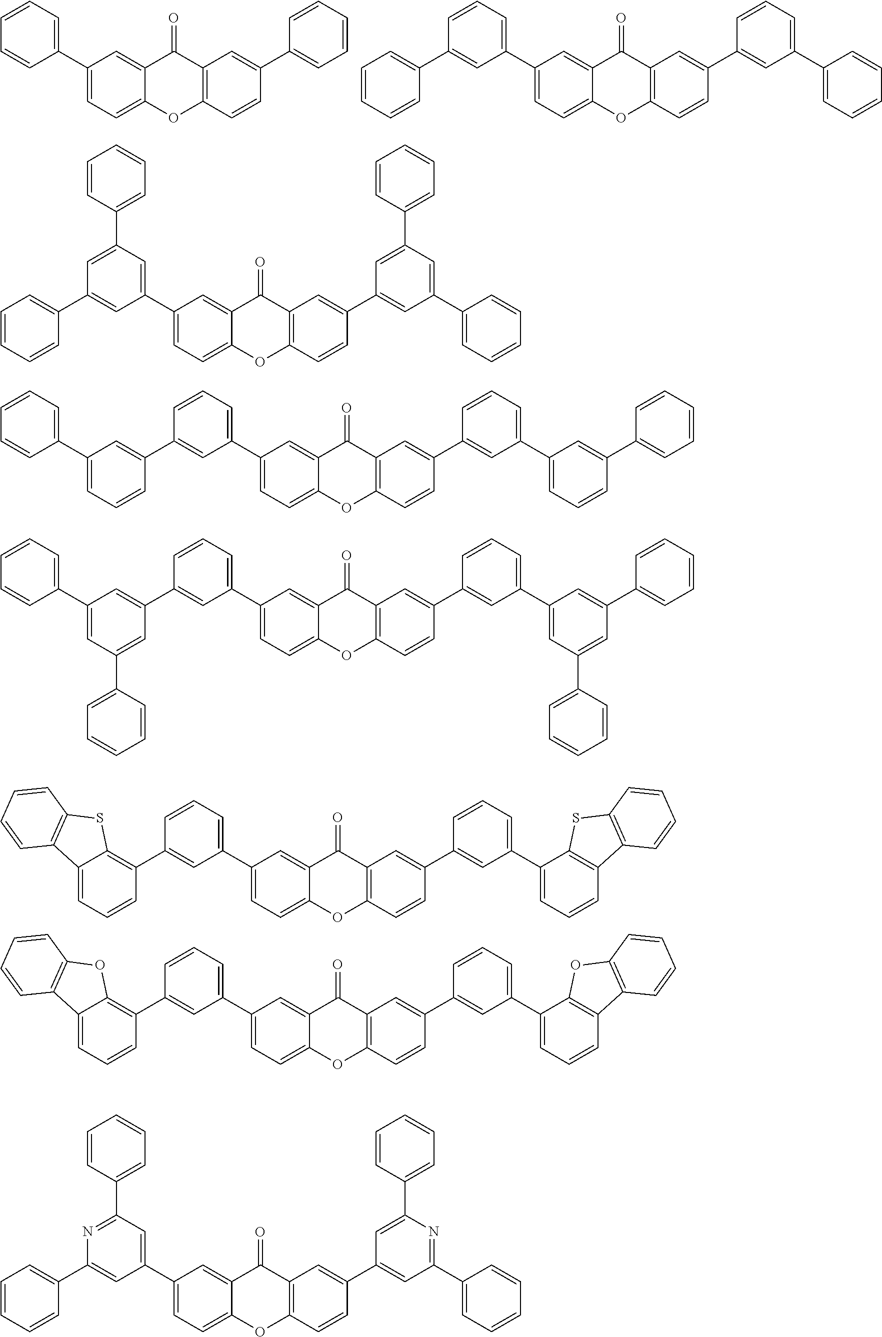

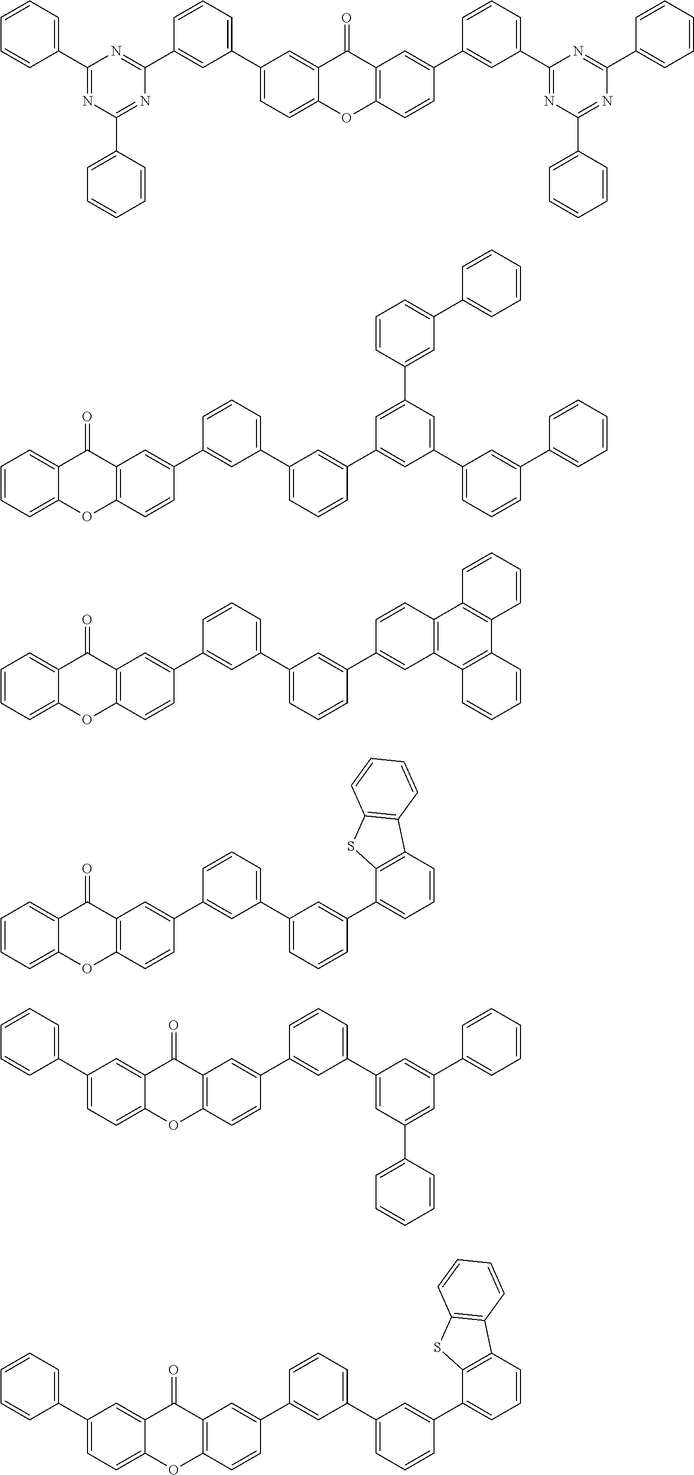

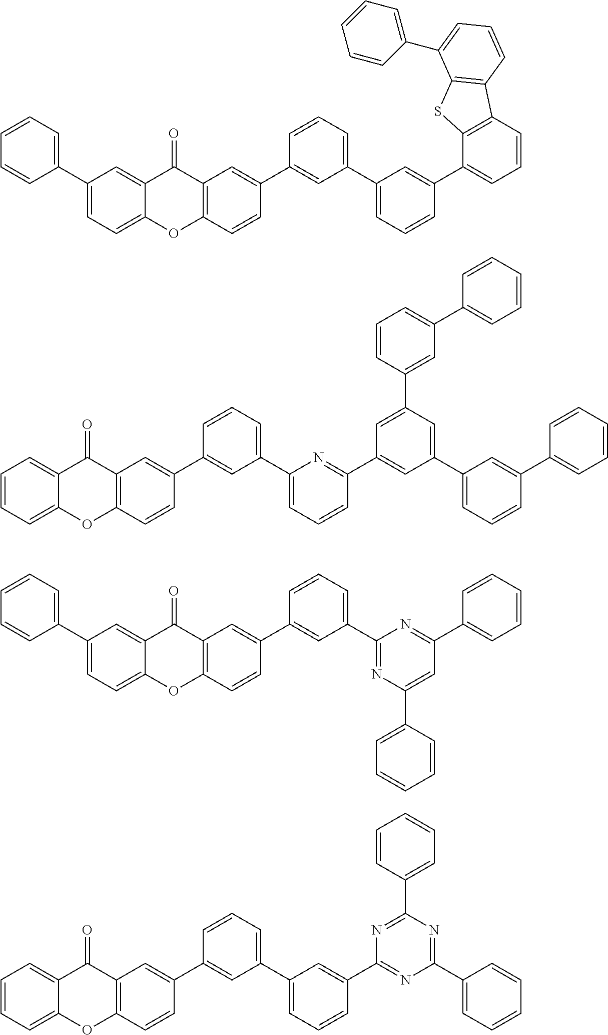

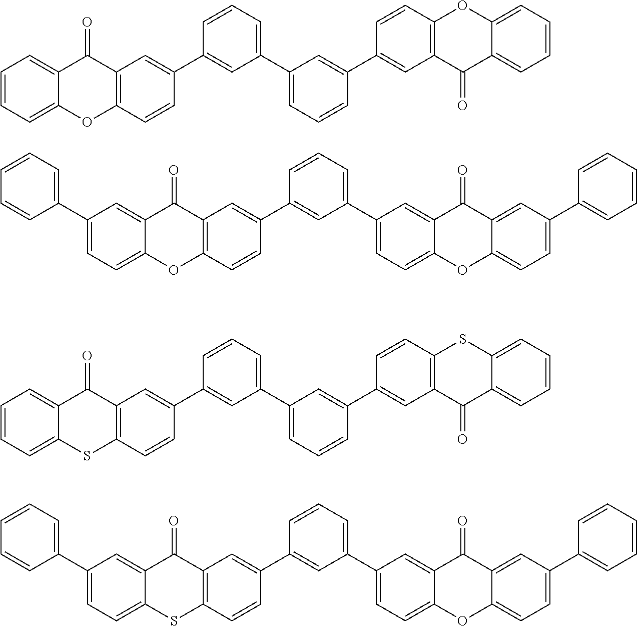

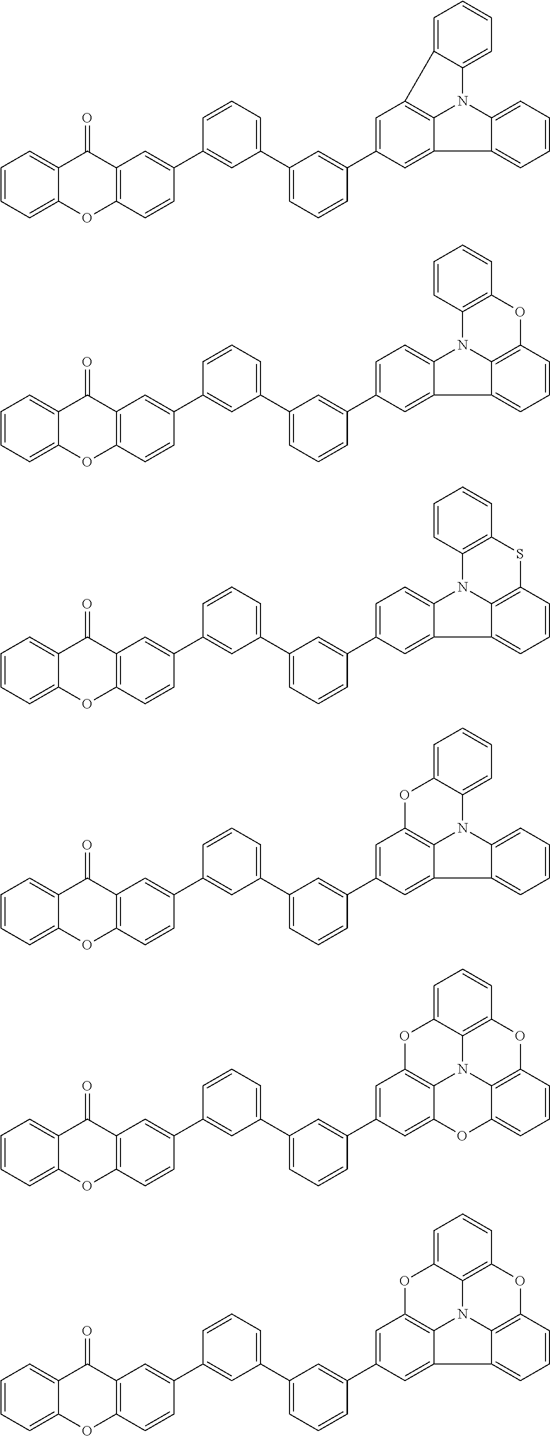

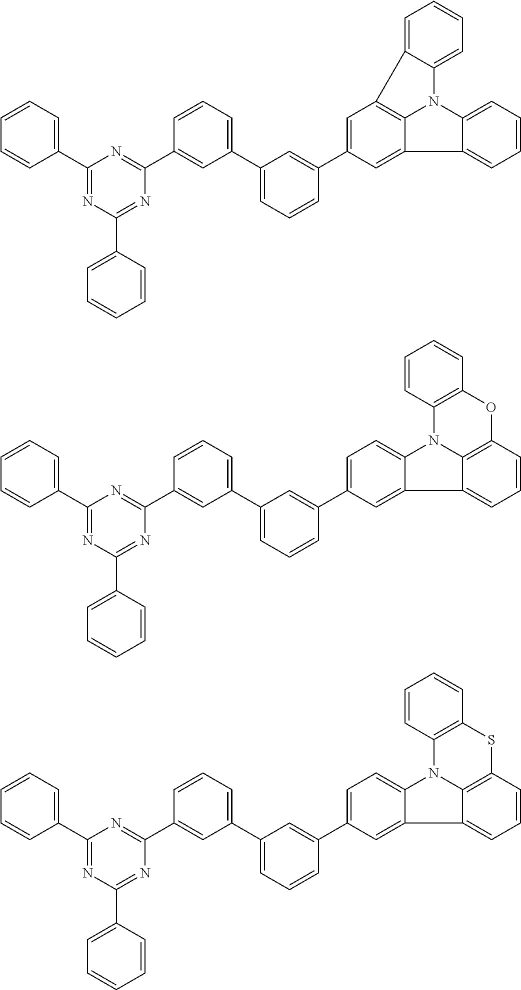 [SMILES: c1ccc(-c2nc(-c3ccccc3)nc(-c3cccc(-c4cccc(-c5cc6c7ccccc7n7c8ccccc8c(c5)c67)c4)c3)n2)cc1 ; c1ccc(-c2nc(-c3ccccc3)nc(-c3cccc(-c4cccc(-c5ccc6c(c5)c5cccc7c5n6-c5ccccc5O7)c4)c3)n2)cc1 ; c1ccc(-c2nc(-c3ccccc3)nc(-c3cccc(-c4cccc(-c5ccc6c(c5)c5cccc7c5n6-c5ccccc5S7)c4)c3)n2)cc1]

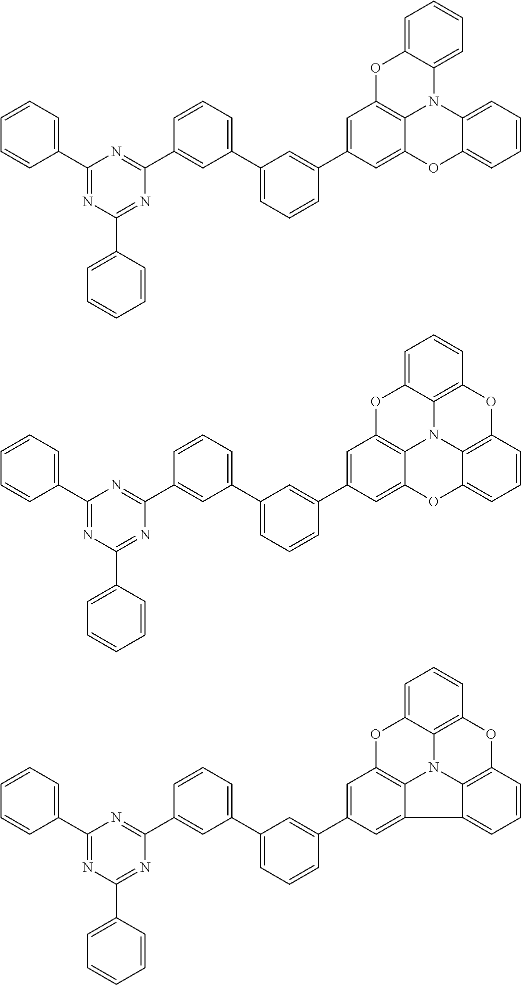 [SMILES: c1ccc(-c2nc(-c3ccccc3)nc(-c3cccc(-c4cccc(-c5cc6c7c(c5)Oc5ccccc5N7c5ccccc5O6)c4)c3)n2)cc1 ; c1ccc(-c2nc(-c3ccccc3)nc(-c3cccc(-c4cccc(-c5cc6c7c(c5)Oc5cccc8c5N7c5c(cccc5O6)O8)c4)c3)n2)cc1 ; c1ccc(-c2nc(-c3ccccc3)nc(-c3cccc(-c4cccc(-c5cc6c7c(c5)c5cccc8c5n7-c5c(cccc5O6)O8)c4)c3)n2)cc1]

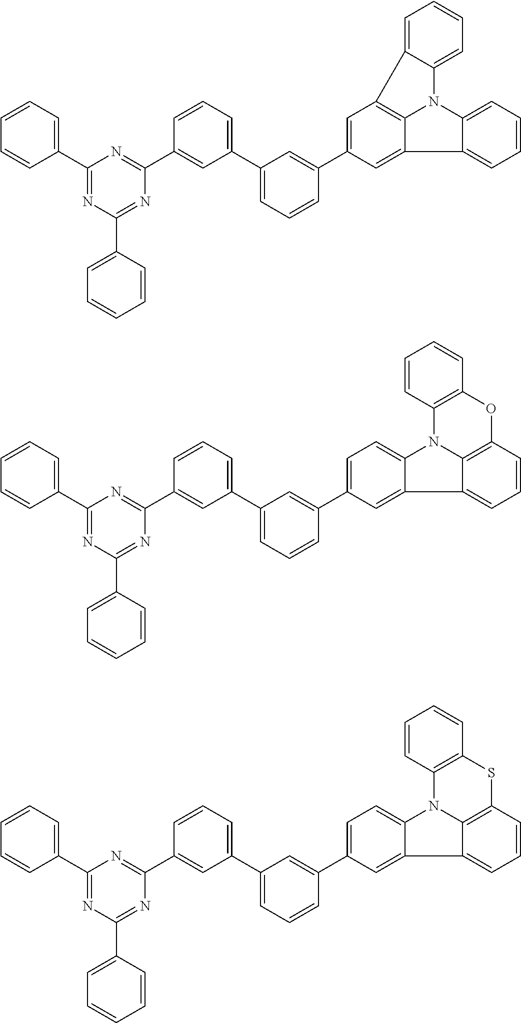 [SMILES: c1ccc(-c2nc(-c3ccccc3)nc(-c3cccc(-c4cccc(-c5cc6c7ccccc7n7c8ccccc8c(c5)c67)c4)c3)n2)cc1 ; c1ccc(-c2nc(-c3ccccc3)nc(-c3cccc(-c4cccc(-c5ccc6c(c5)c5cccc7c5n6-c5ccccc5O7)c4)c3)n2)cc1 ; c1ccc(-c2nc(-c3ccccc3)nc(-c3cccc(-c4cccc(-c5ccc6c(c5)c5cccc7c5n6-c5ccccc5S7)c4)c3)n2)cc1]

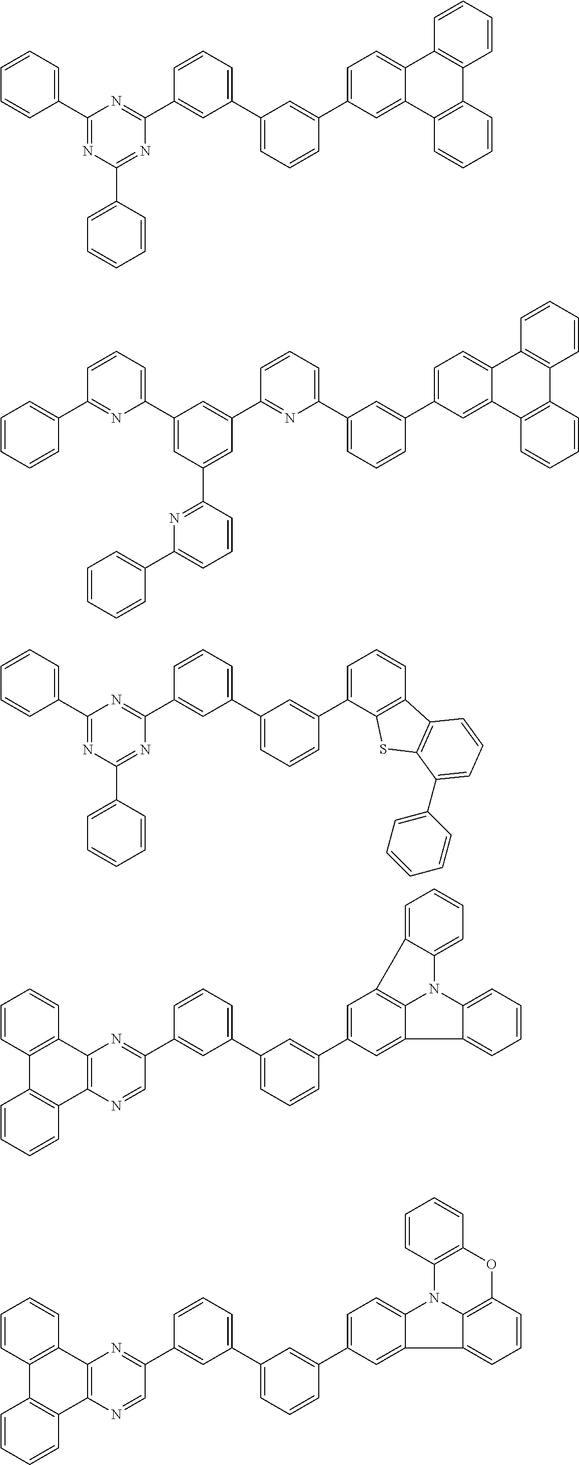

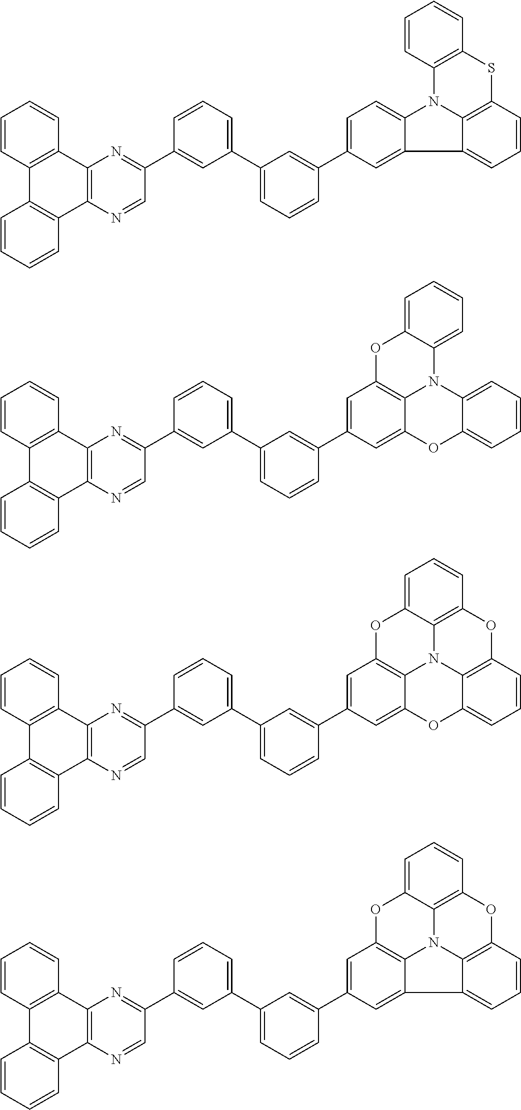 [SMILES: c1cc(-c2cccc(-c3cnc4c5ccccc5c5ccccc5c4n3)c2)cc(-c2ccc3c(c2)c2cccc4c2n3-c2ccccc2S4)c1 ; c1cc(-c2cccc(-c3cnc4c5ccccc5c5ccccc5c4n3)c2)cc(-c2cc3c4c(c2)Oc2ccccc2N4c2ccccc2O3)c1 ; c1cc(-c2cccc(-c3cnc4c5ccccc5c5ccccc5c4n3)c2)cc(-c2cc3c4c(c2)Oc2cccc5c2N4c2c(cccc2O3)O5)c1 ; c1cc(-c2cccc(-c3cnc4c5ccccc5c5ccccc5c4n3)c2)cc(-c2cc3c4c(c2)c2cccc5c2n4-c2c(cccc2O3)O5)c1]

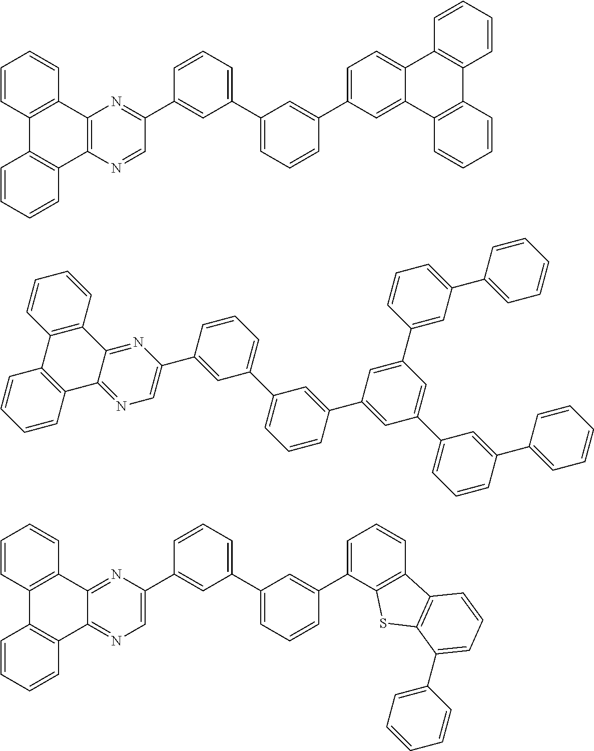 [SMILES: c1cc(-c2cccc(-c3cnc4c5ccccc5c5ccccc5c4n3)c2)cc(-c2ccc3c4ccccc4c4ccccc4c3c2)c1 ; c1ccc(-c2cccc(-c3cc(-c4cccc(-c5ccccc5)c4)cc(-c4cccc(-c5cccc(-c6cnc7c8ccccc8c8ccccc8c7n6)c5)c4)c3)c2)cc1 ; c1ccc(-c2cccc3c2sc2c(-c4cccc(-c5cccc(-c6cnc7c8ccccc8c8ccccc8c7n6)c5)c4)cccc23)cc1]

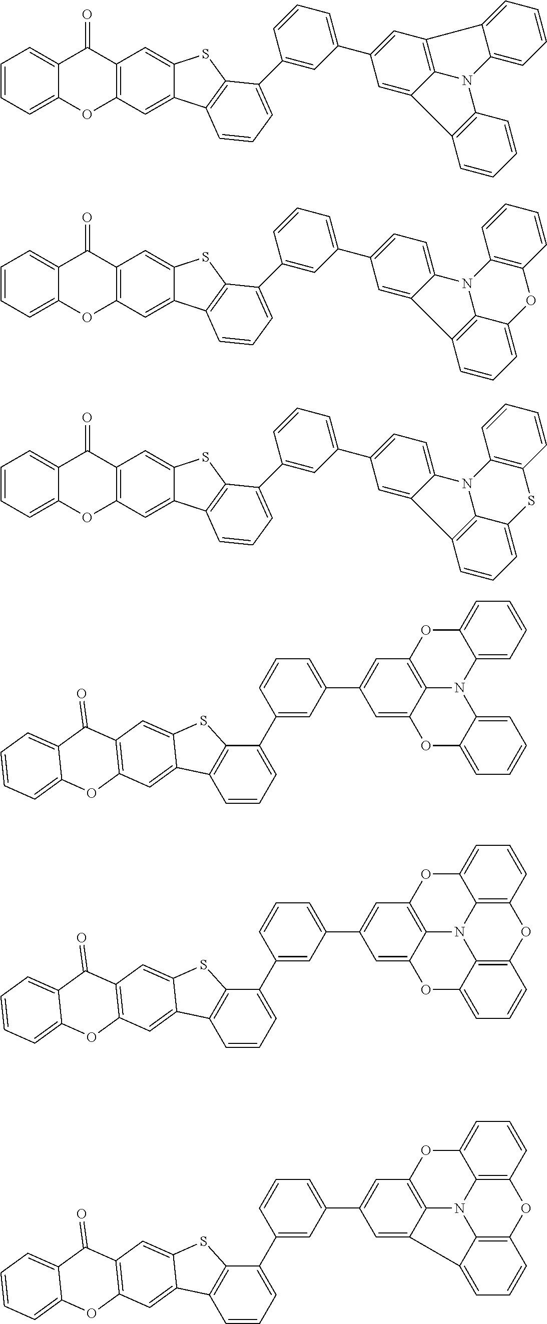

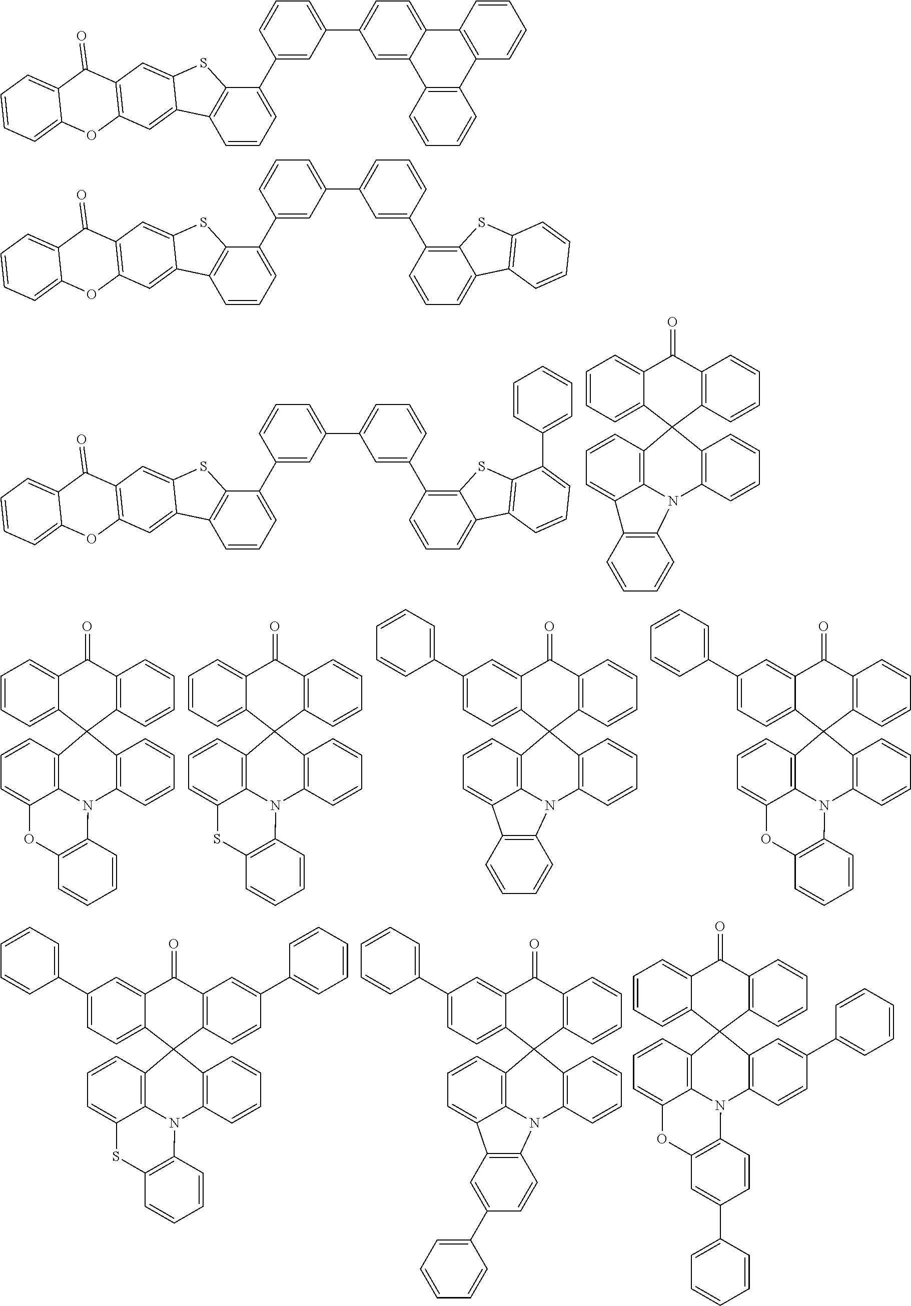

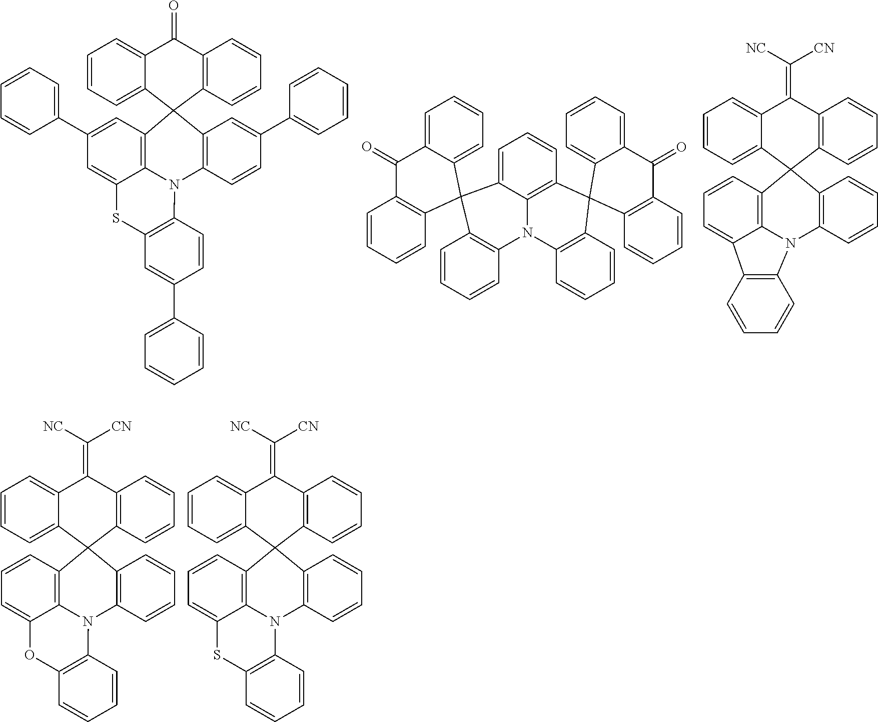

### (4) Luminescent Compound

The luminescent compound may be any compound that mainly emits phosphorescence, and is preferably an organometallic complex represented by general formula (3).

M(L)m(L′)n(L″)p (3)

In general formula (3), M represents a metal atom. Specifically, M is an iridium atom or a platinum atom, preferably an iridium atom. L, L′, and L″ represent bidentate ligands different from each other. m is selected from integers of 1 to 3, and n and p are selected from integers of 0 to 2, provided that m+n+p=3. When m is 2 or greater, L's may be the same or different. When n is 2, L″s may be the same or different. When p is 2, L″'s may be the same or different.

M (L) m is represented by general formula (4-1).

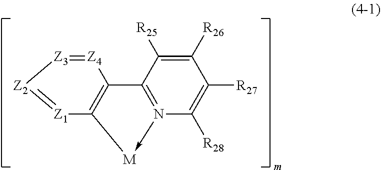

In general formula (4-1), Z₁ to Z₄ are each independently selected from C(R₂₁) and a nitrogen atom. R₂₁ to R₂₈ are each independently selected from a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heteroaryl group, a substituted or unsubstituted amino group, a substituted or unsubstituted aryloxy group, a substituted or unsubstituted heteroaryloxy group, and a cyano group. At least one of R₂₁ to R₂₈ is selected from a substituted or unsubstituted aryl group and a substituted or unsubstituted heteroaryl group. When Z₁ to Z₄ are represented by C(R₂₁), R₂₁'s may be the same as or different from each other.

Adjacent two of R₂₁ to R₂₈ may be bonded to each other to form a ring.

M (L′) n is represented by general formula (4-2).

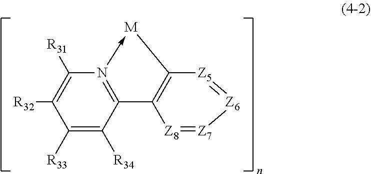

In formula (4-2), Z₅ to Z₈ are each independently selected from C(R₃₅) and a nitrogen atom. R₃₁ to R₃₅ are each independently selected from a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heteroaryl group, a substituted or unsubstituted amino group, a substituted or unsubstituted aryloxy group, a substituted or unsubstituted heteroaryloxy group, and a cyano group. When Z₅ to Z₈ are represented by C(R₃₅), R₃₅'s may be the same as or different from each other.

Adjacent two of R₃₁ to R₃₅ may be bonded to each other to form a ring.

M (L″) p is represented by general formula (4-3).

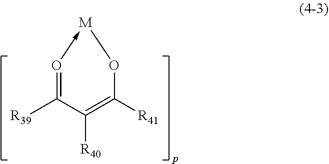

In formula (4-3), R₃₉ to R₄₁ are each independently selected from a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heteroaryl group, a substituted or unsubstituted amino group, a substituted or unsubstituted aryloxy group, a substituted or unsubstituted heteroaryloxy group, and a cyano group.

Non-limiting specific examples of the partial structure M (L) m of an organometallic complex that is the luminescent compound are shown below. In the following specific examples, coordinate bonds are indicated by straight lines, dotted lines, or arrows.

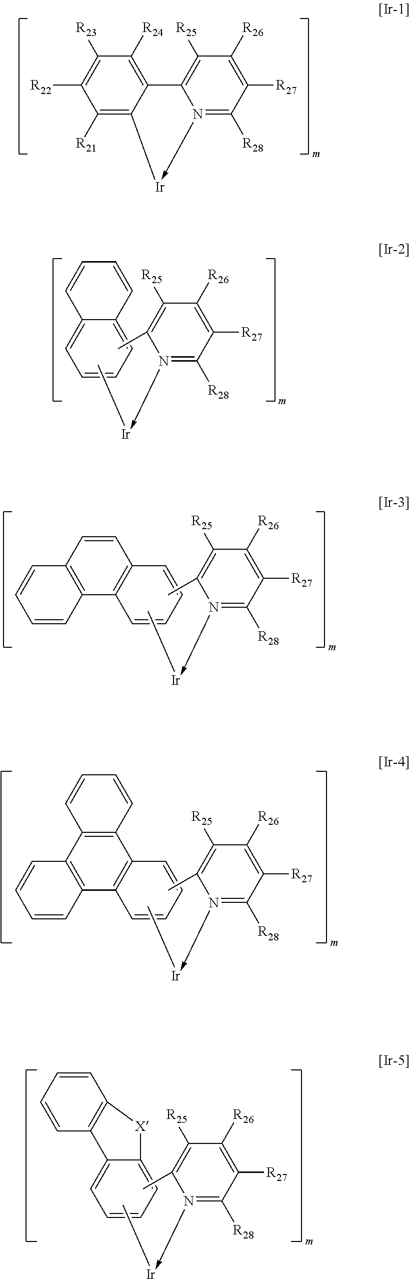

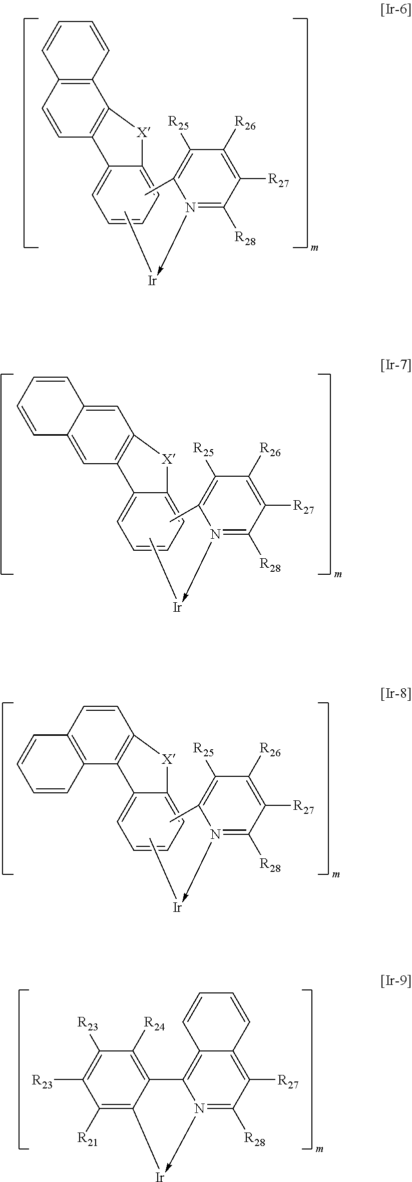

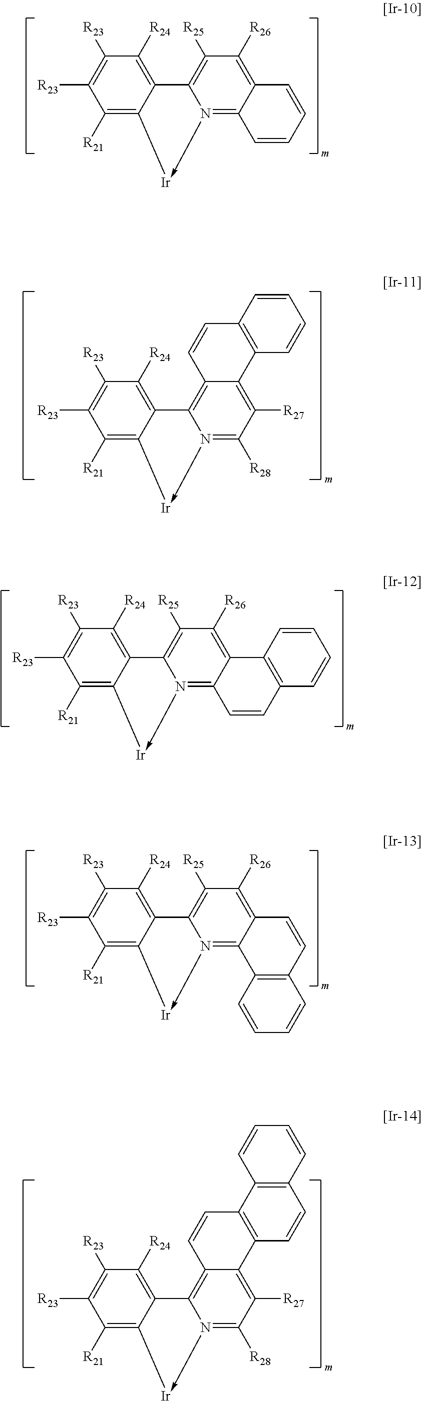

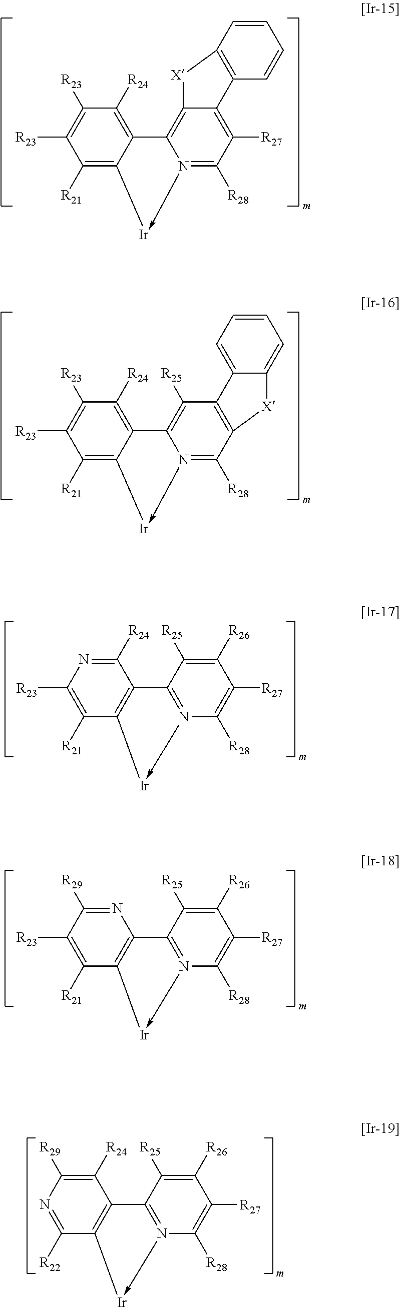

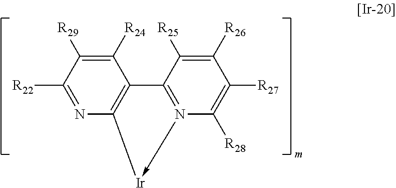

In general formulas [Ir-5] to [Ir-8], [Ir-15], and [Ir-16], X′ is selected from an oxygen atom, a sulfur atom, a substituted or unsubstituted carbon atom, and a substituted or unsubstituted nitrogen atom.

In general formulas [Ir-1] to [Ir-20], adjacent two of R₂₁ to R₂₉ may be bonded to each other to form a ring.

In the luminescent compound according to the present invention, the partial structure M (L) m preferably has a fused ring consisting of three or more rings. This is because the presence of a fused ring consisting of three or more rings improves the planarity of a molecule to facilitate energy transfer from the first organic compound or the second organic compound to the phosphorescent material, leading to improvements in light-emission efficiency and element durability. Examples of the fused ring consisting of three or more rings include those in general formulas [Ir-3] to [Ir-8] and [Ir-11] to [Ir-16]. Specific examples include a phenanthrene ring, a triphenylene ring, a benzofluorene ring, a dibenzofuran ring, a dibenzothiophene ring, a benzonaphthofuran ring, a benzonaphthothiophene ring, a benzoisoquinoline ring, and a naphthoisoquinoline ring.

Specific examples of the luminescent compound are shown below. However, the present invention is not limited thereto.

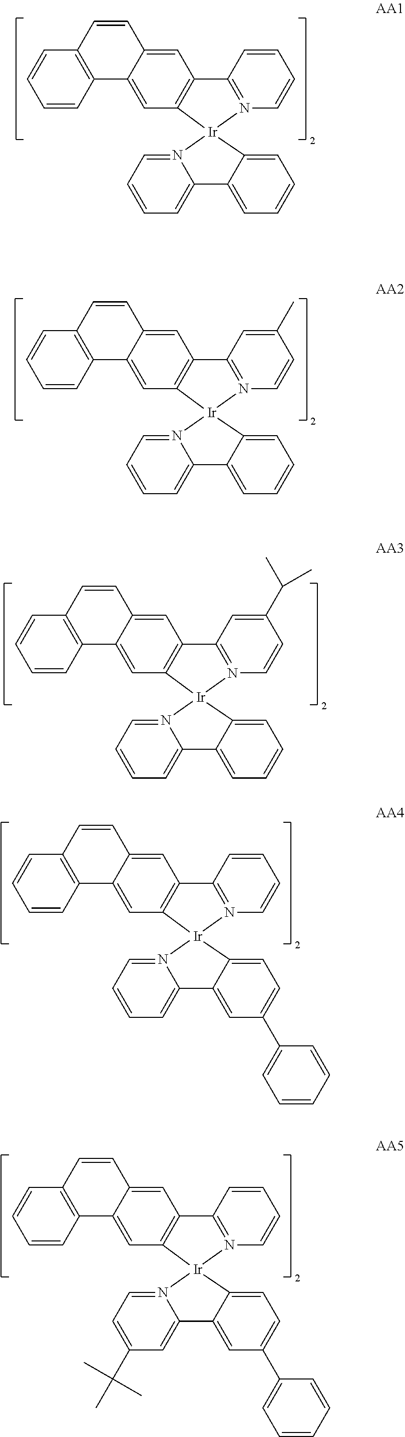

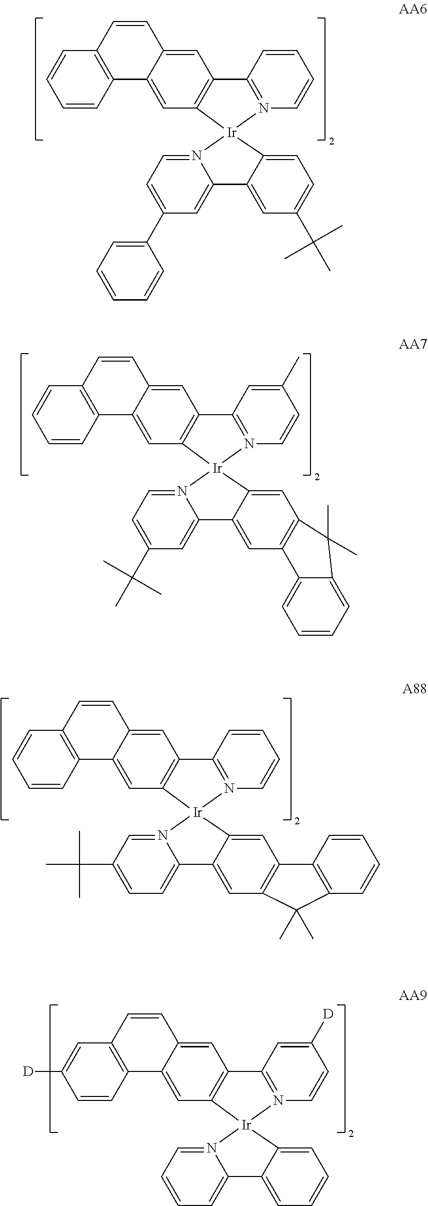

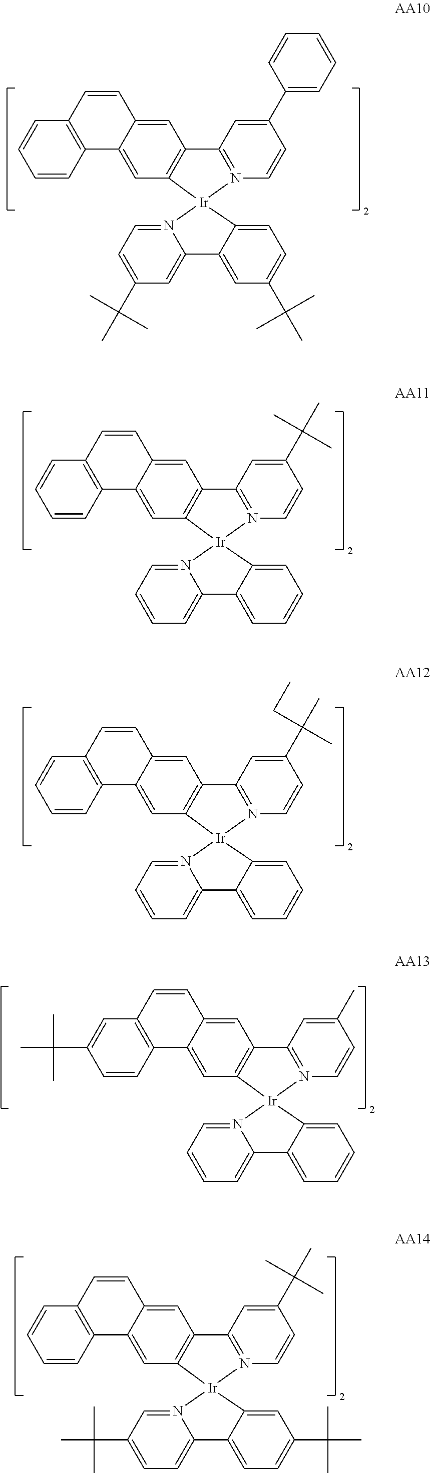

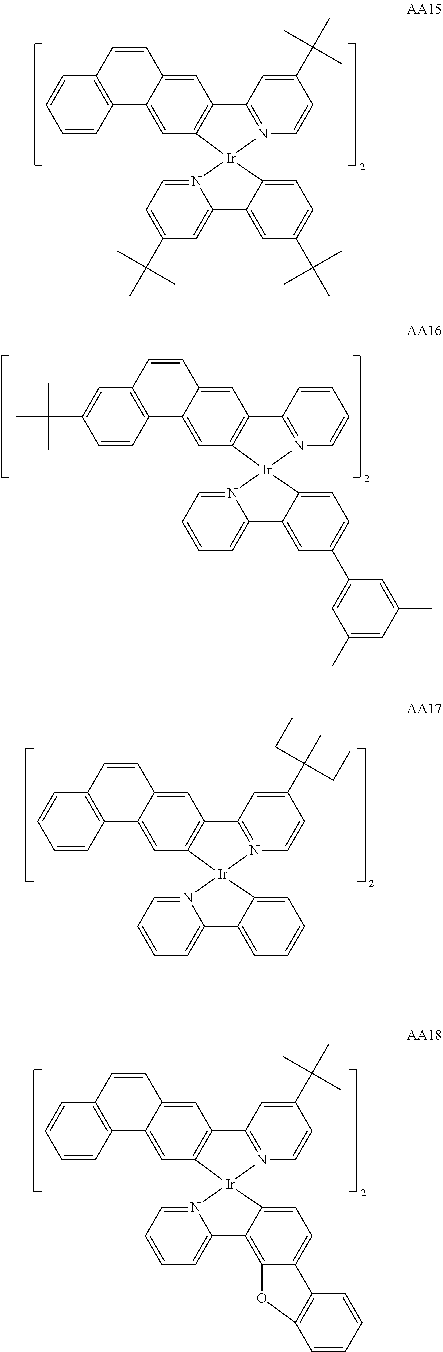

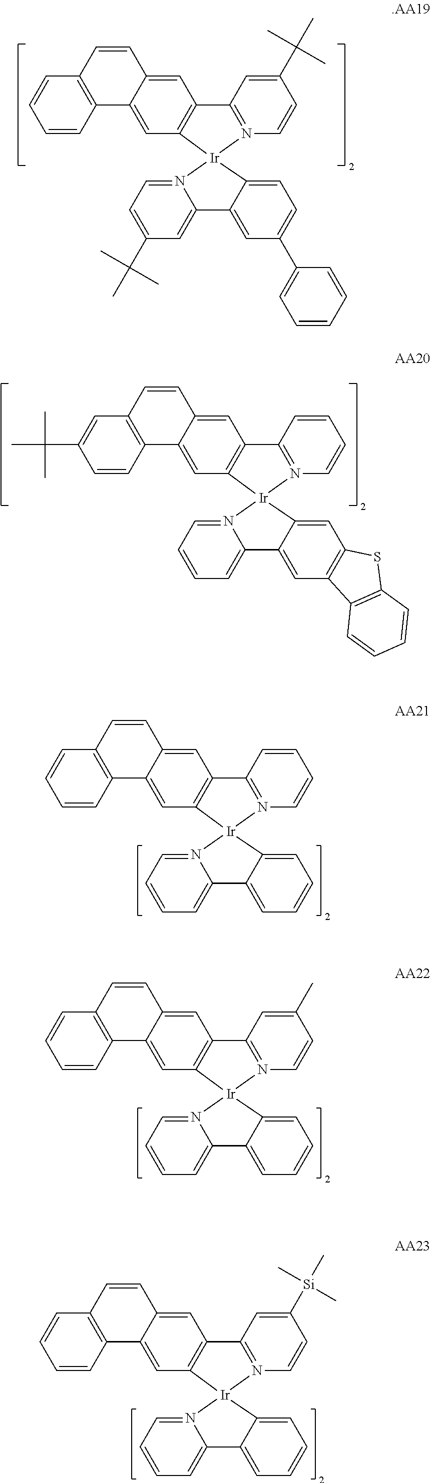

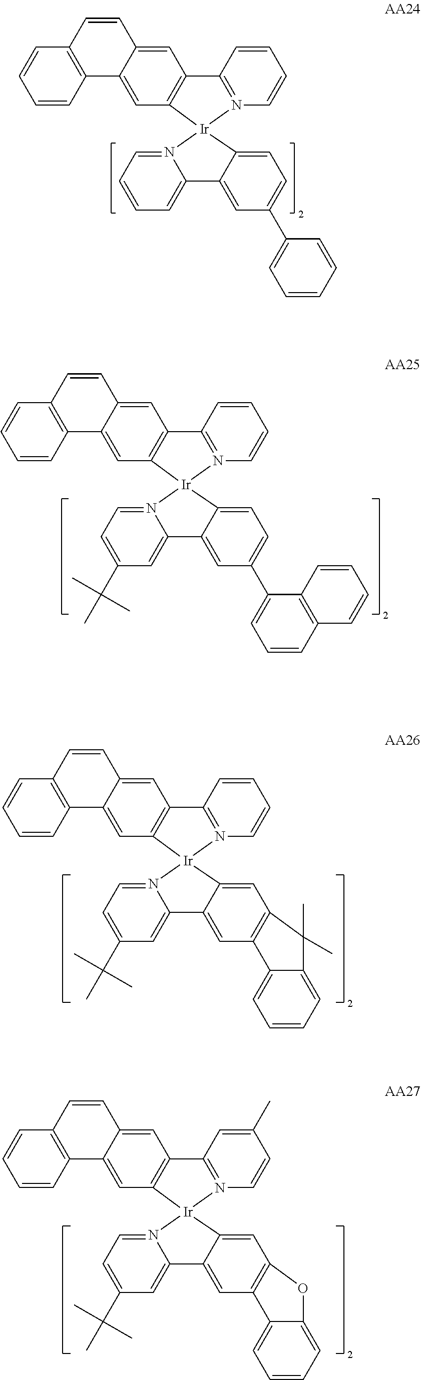

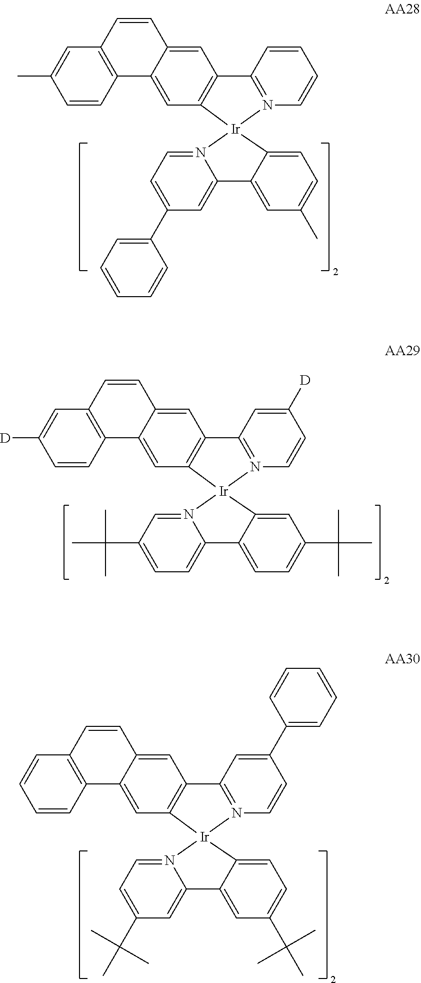

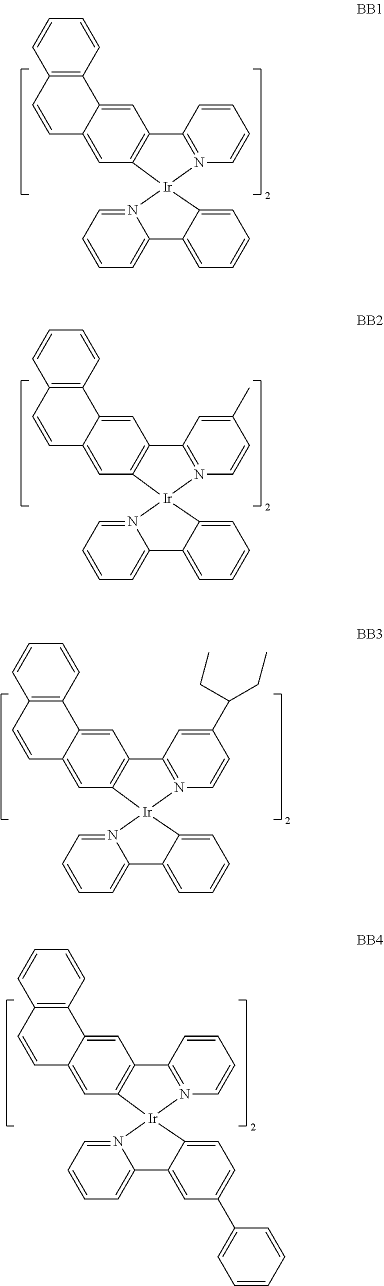

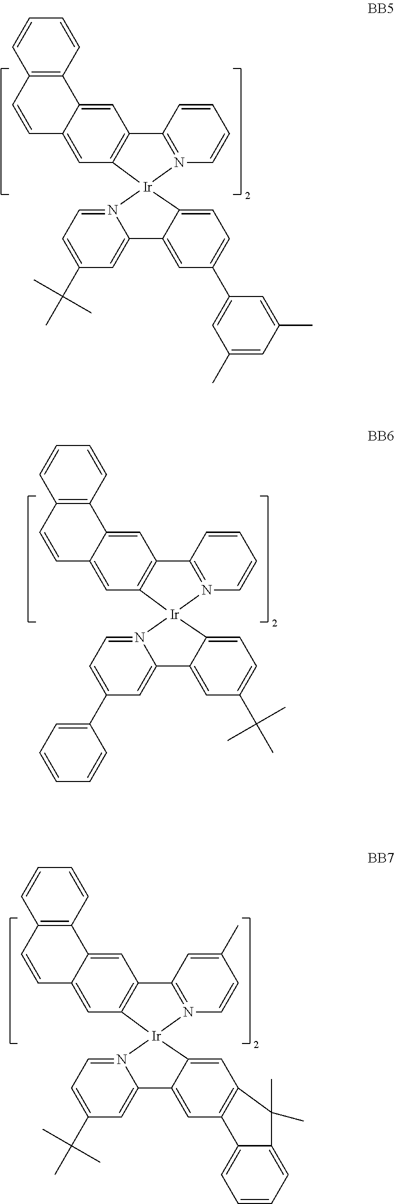

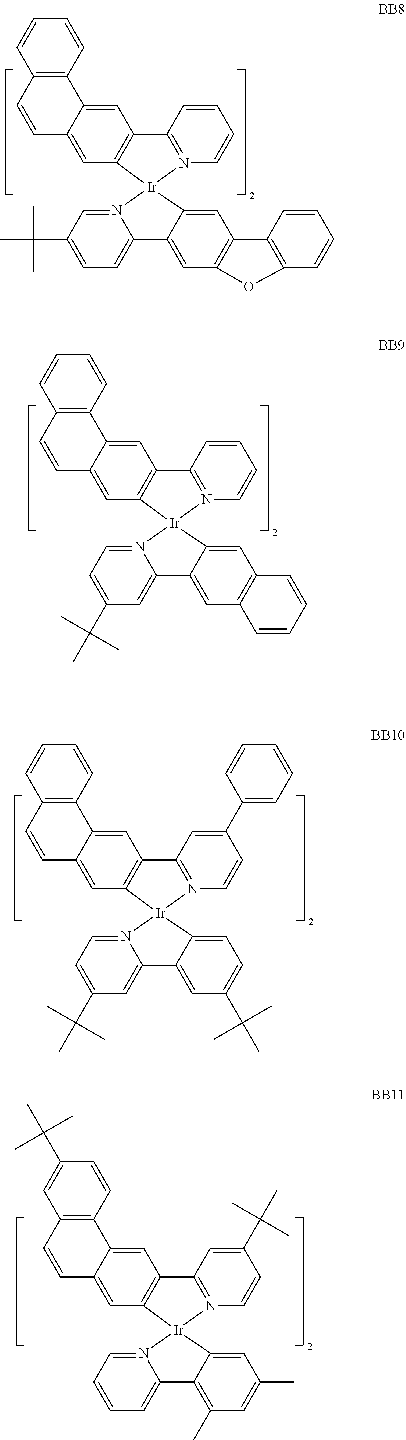

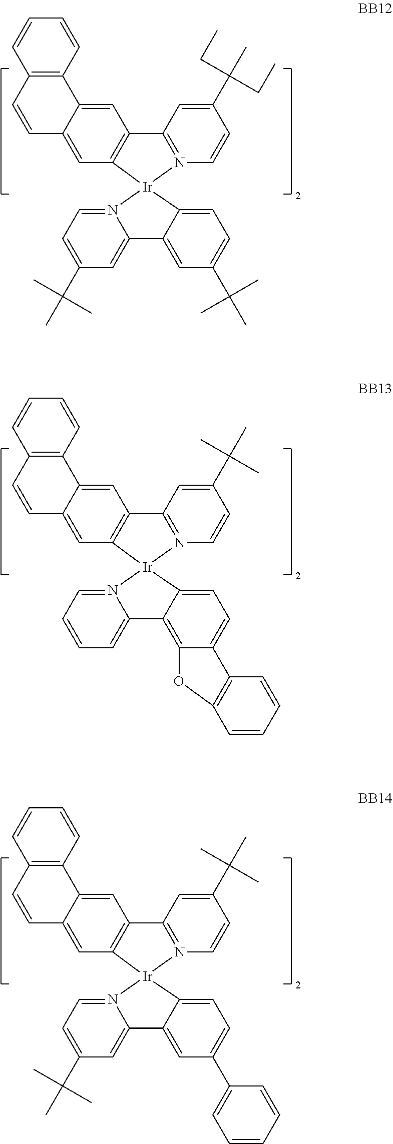

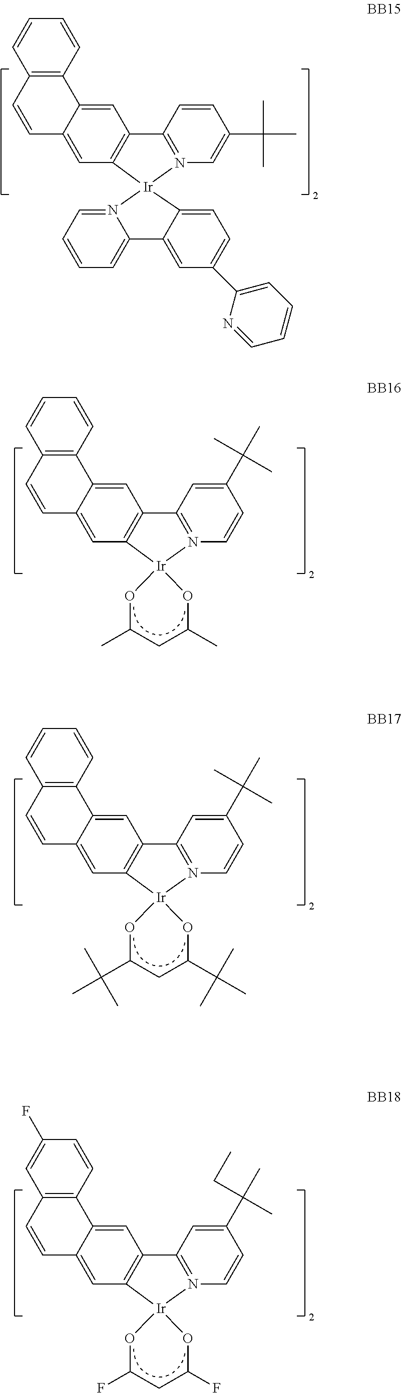

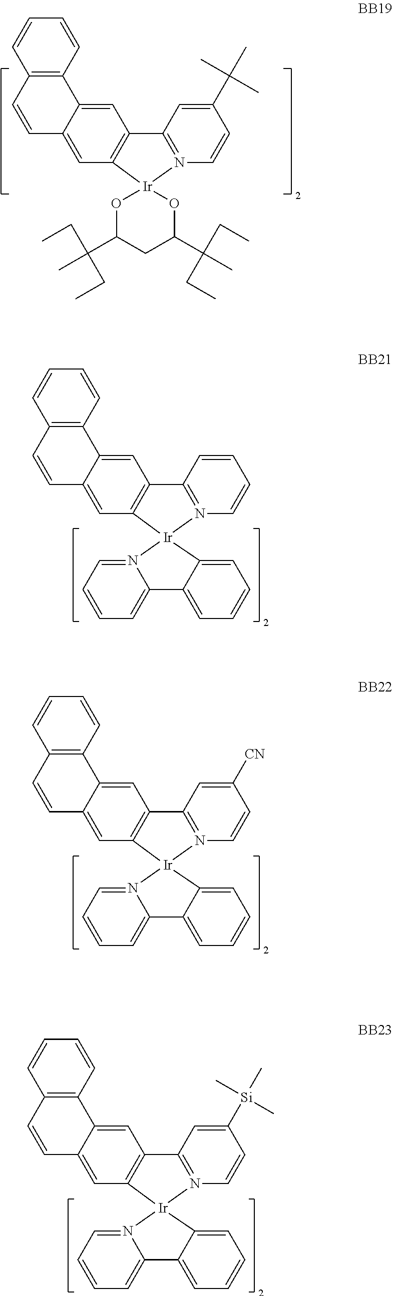

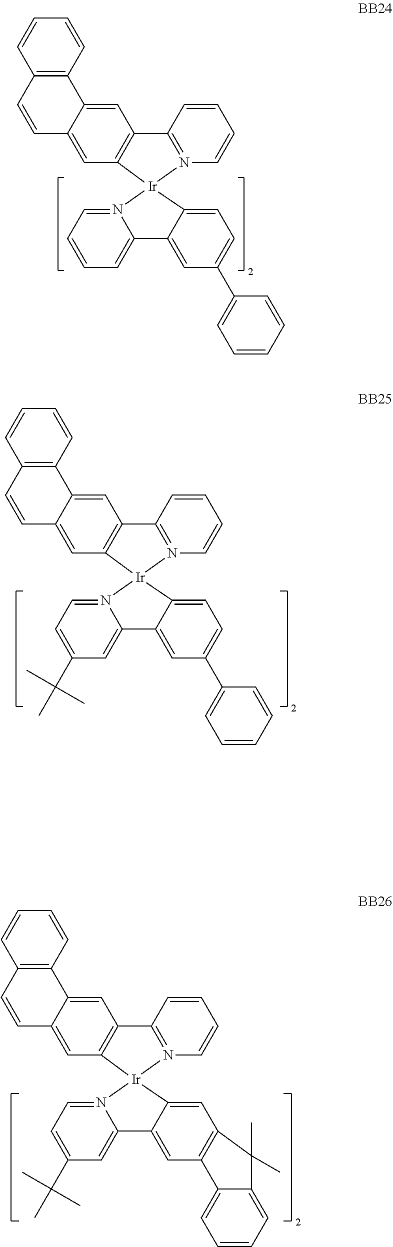

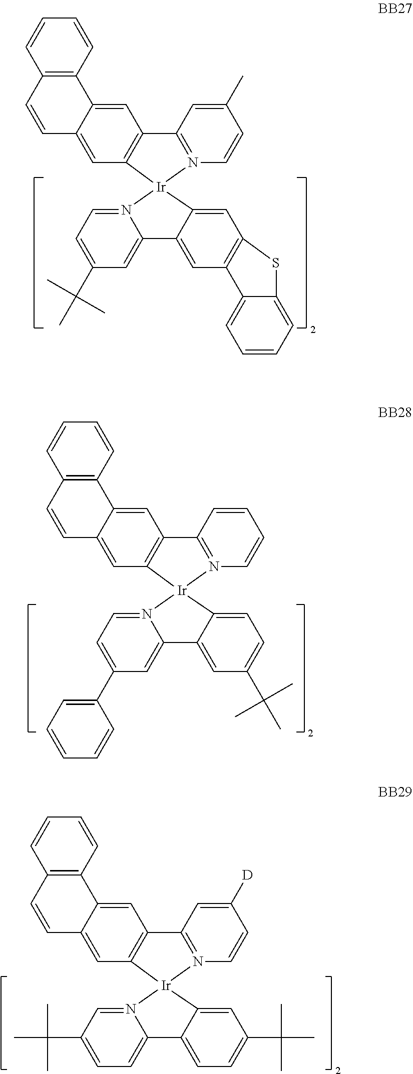

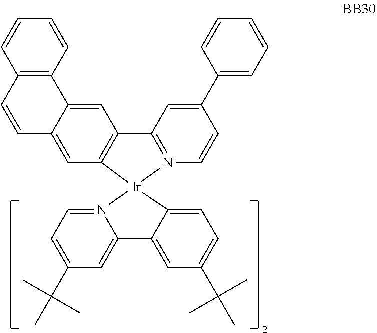

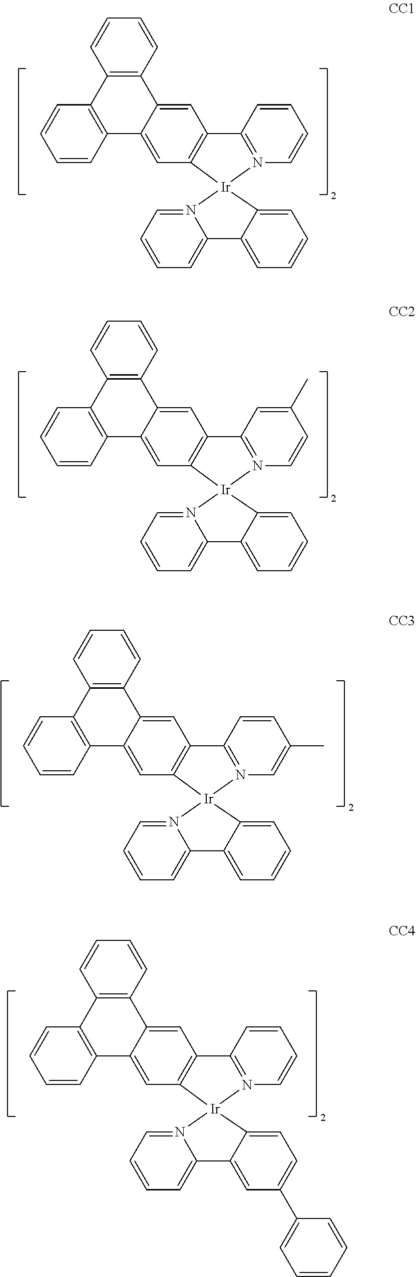

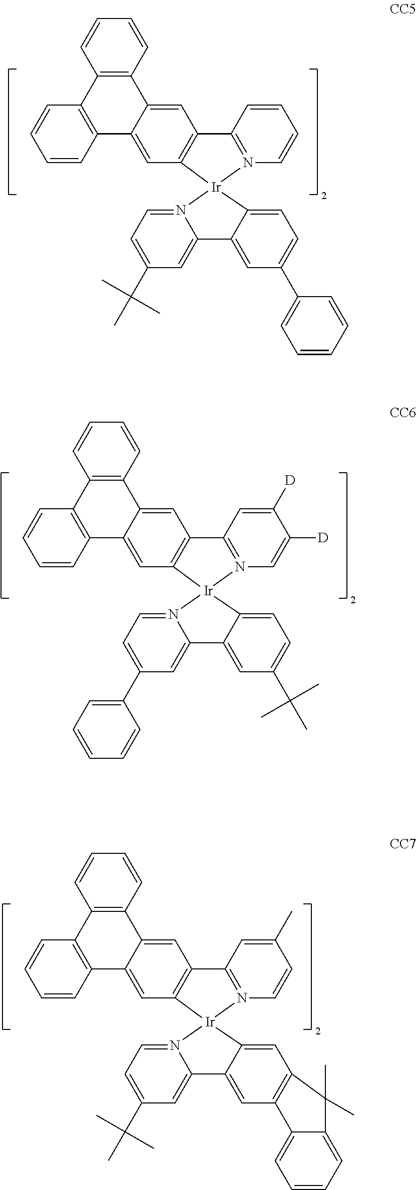

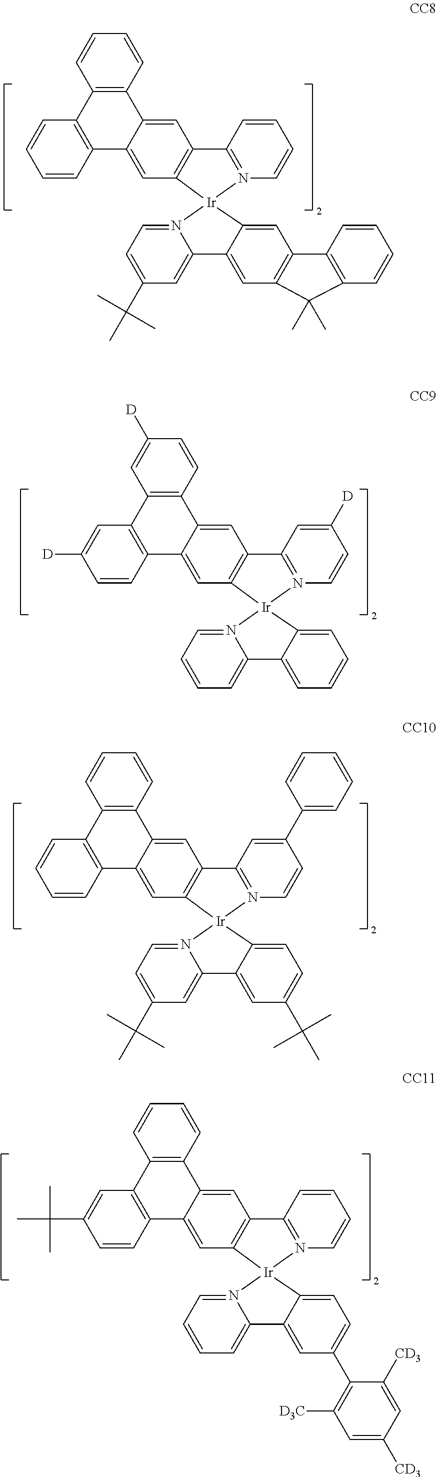

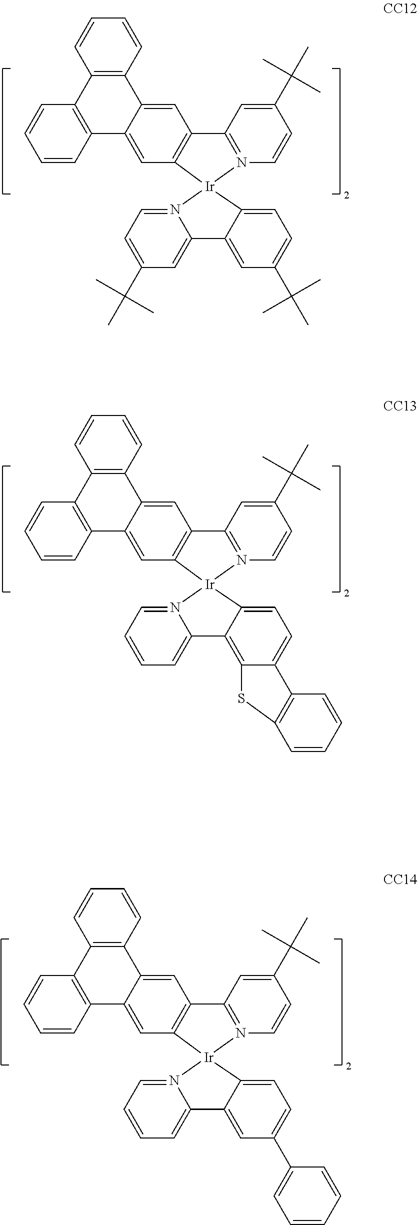

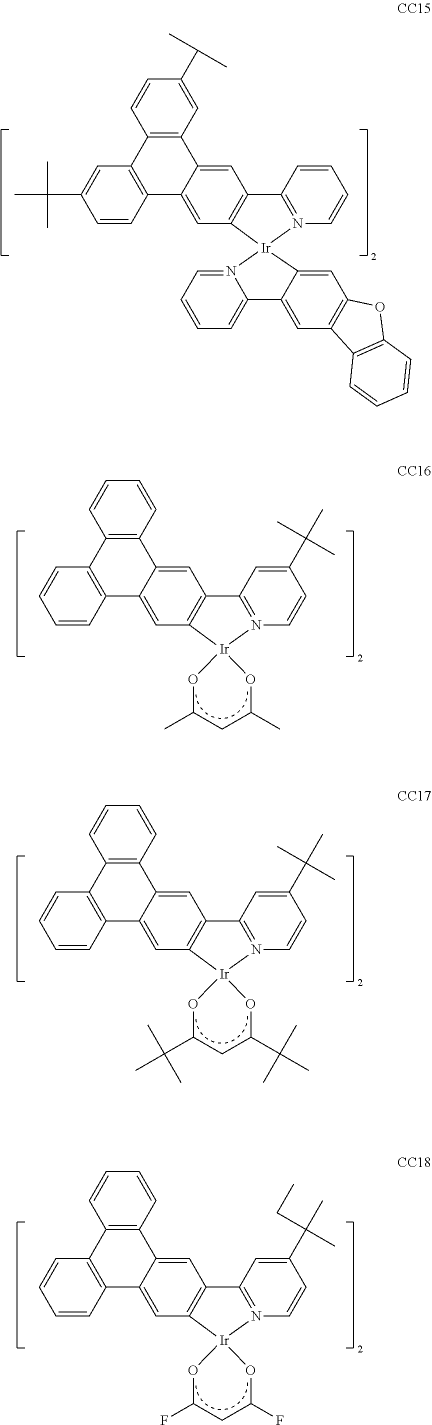

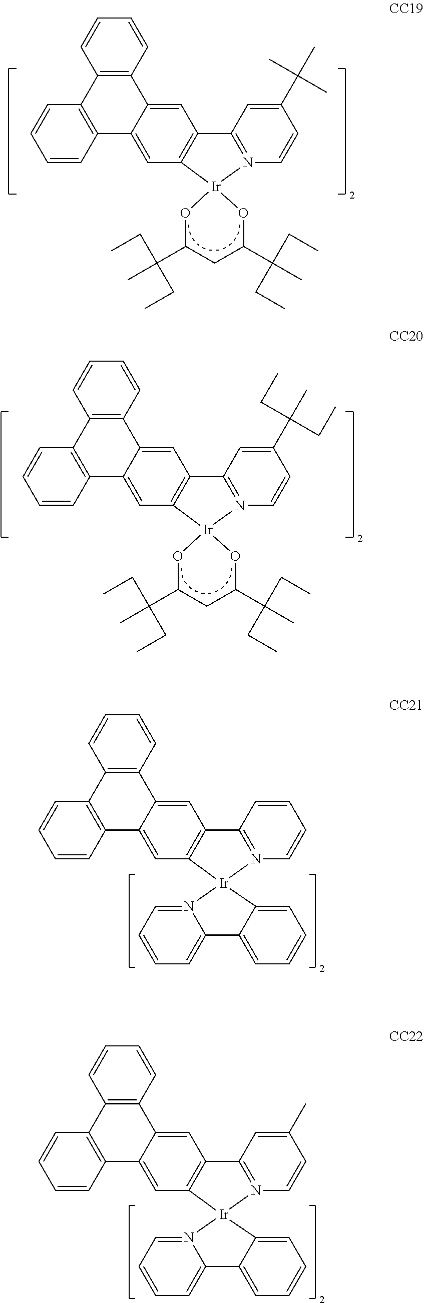

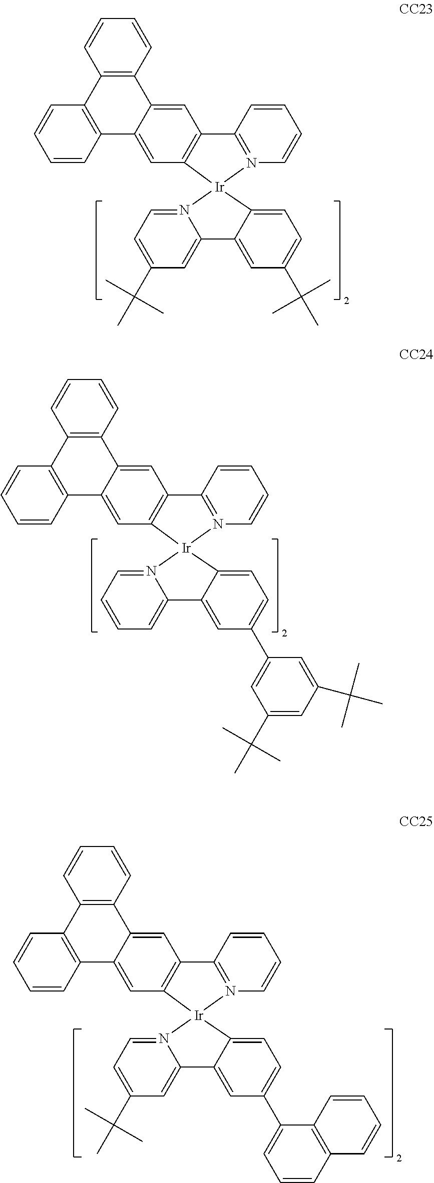

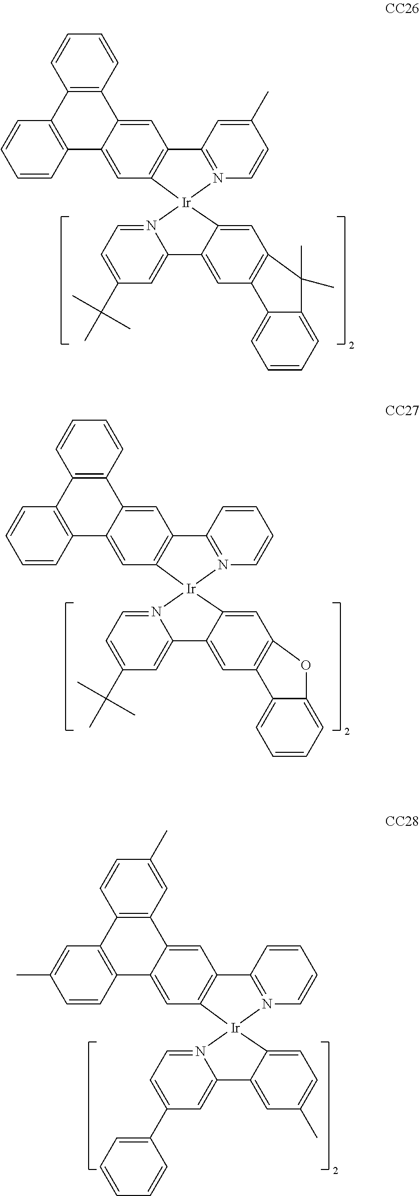

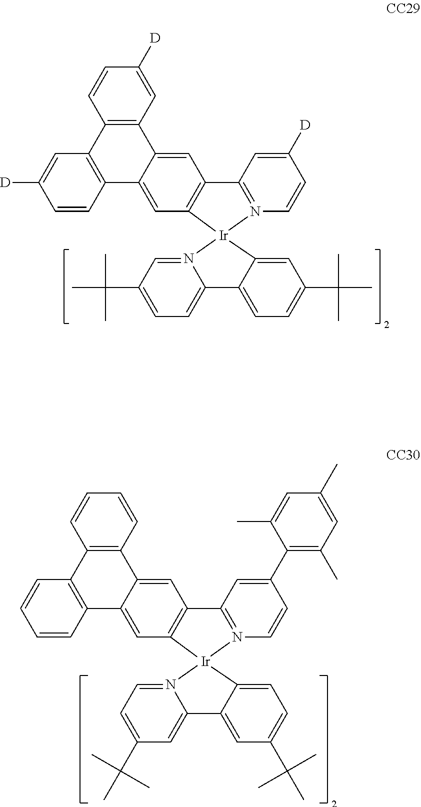

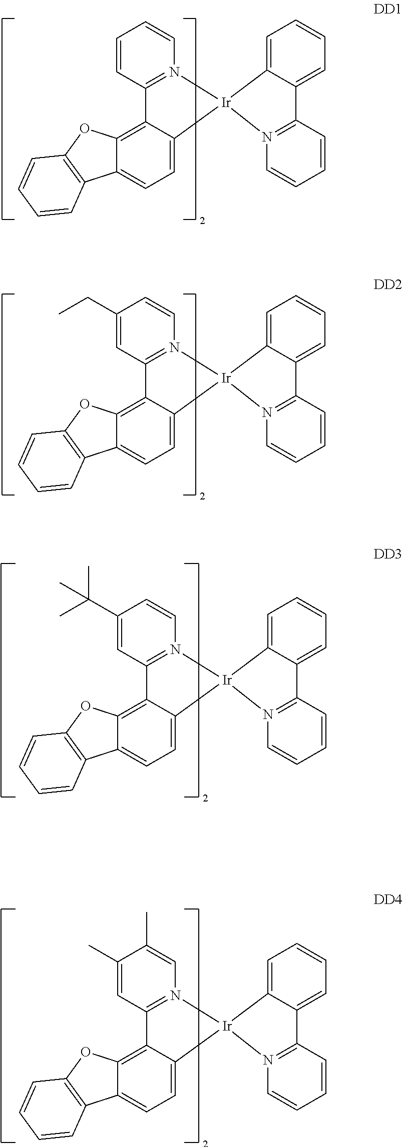

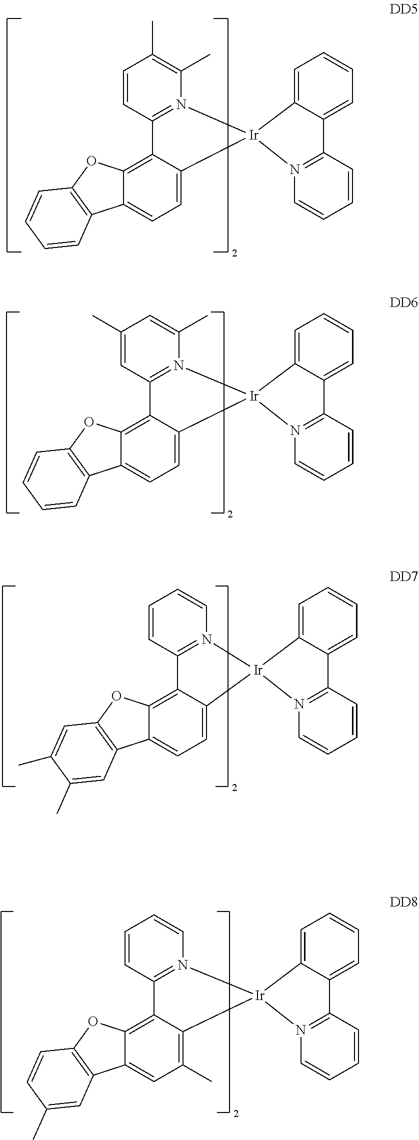

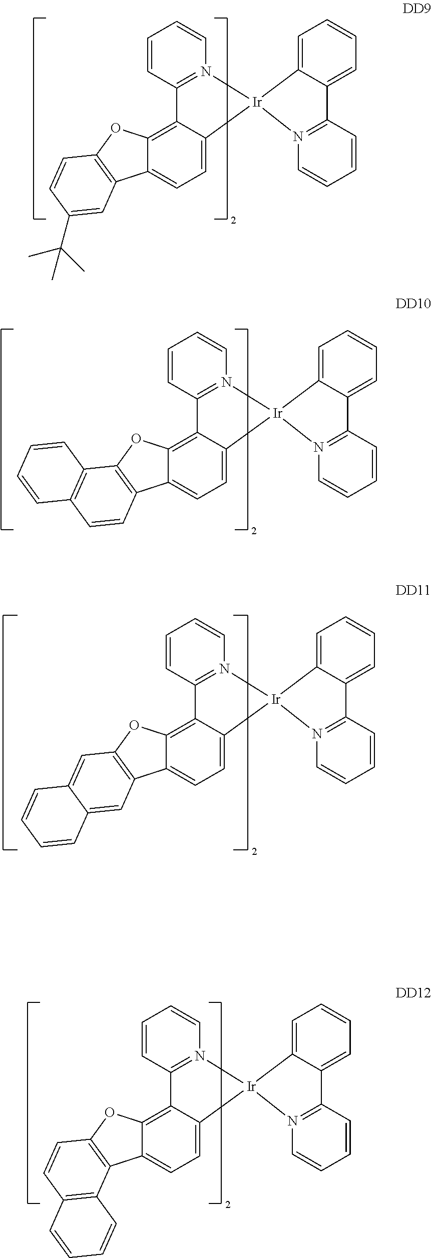

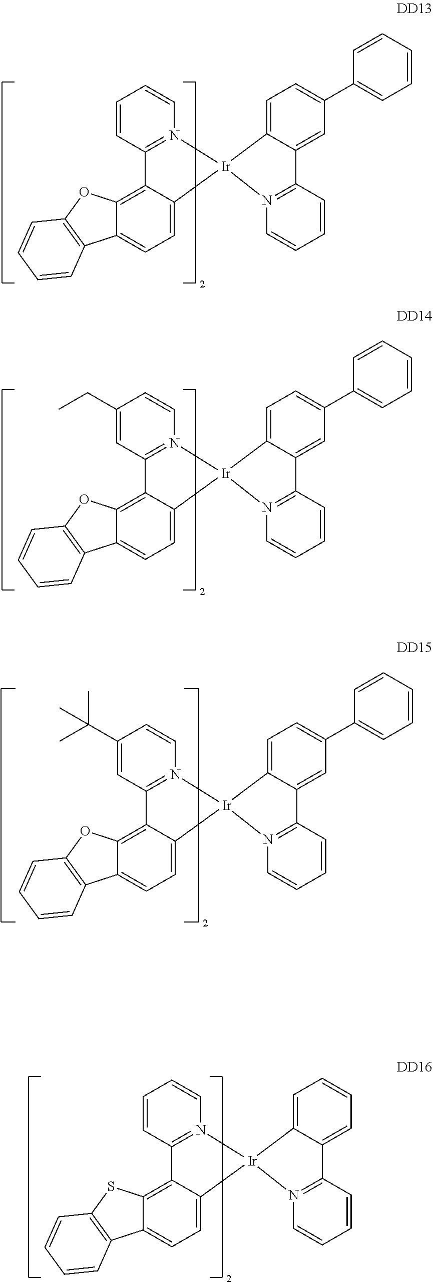

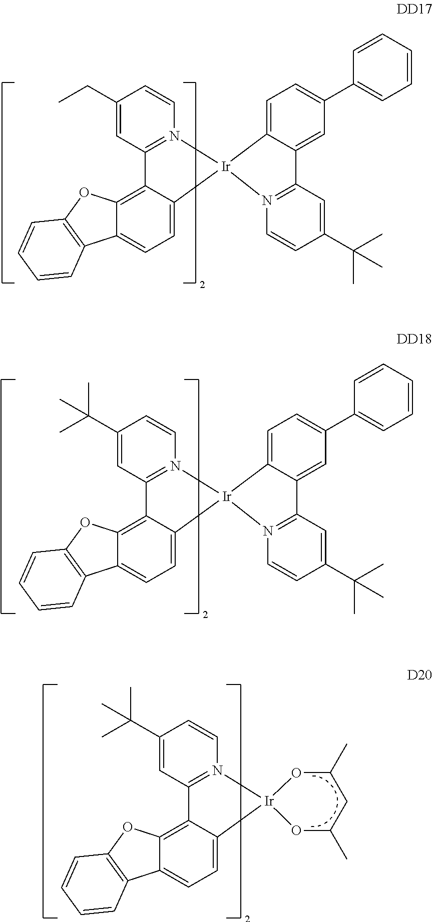

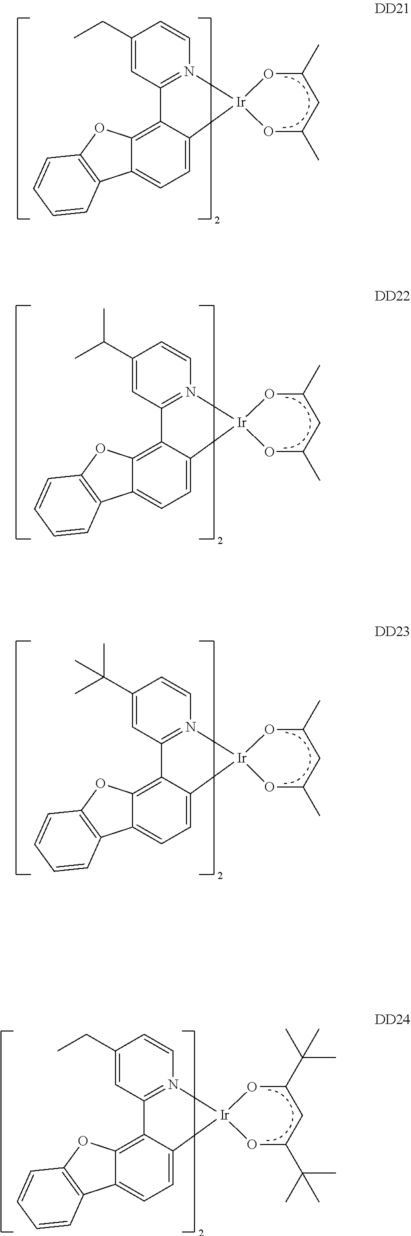

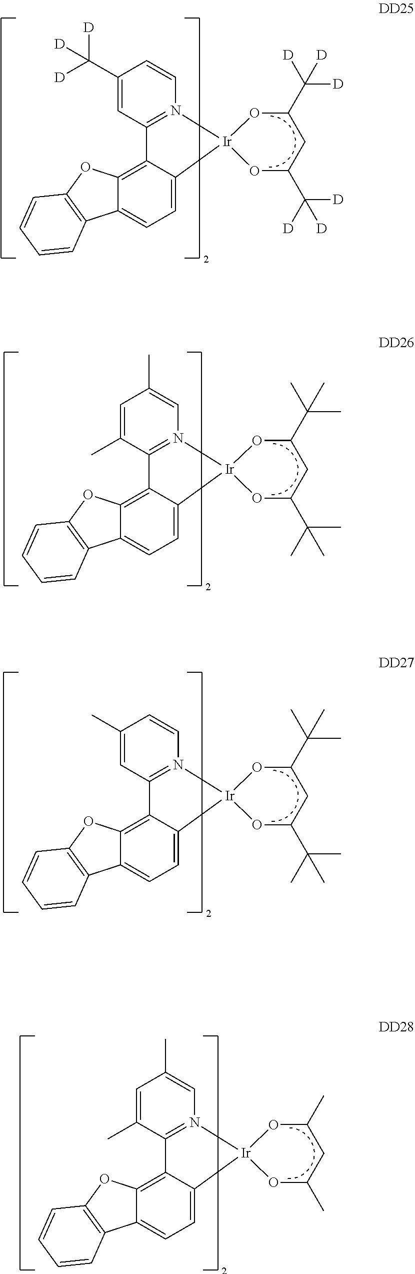

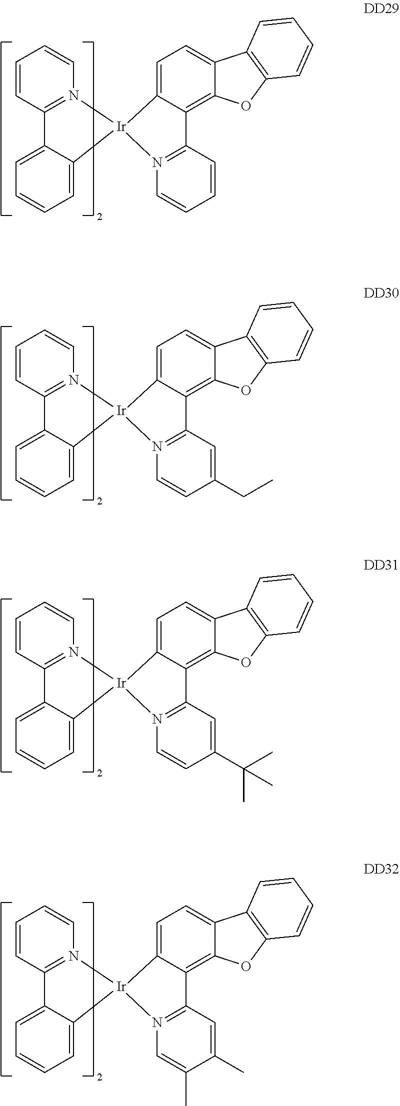

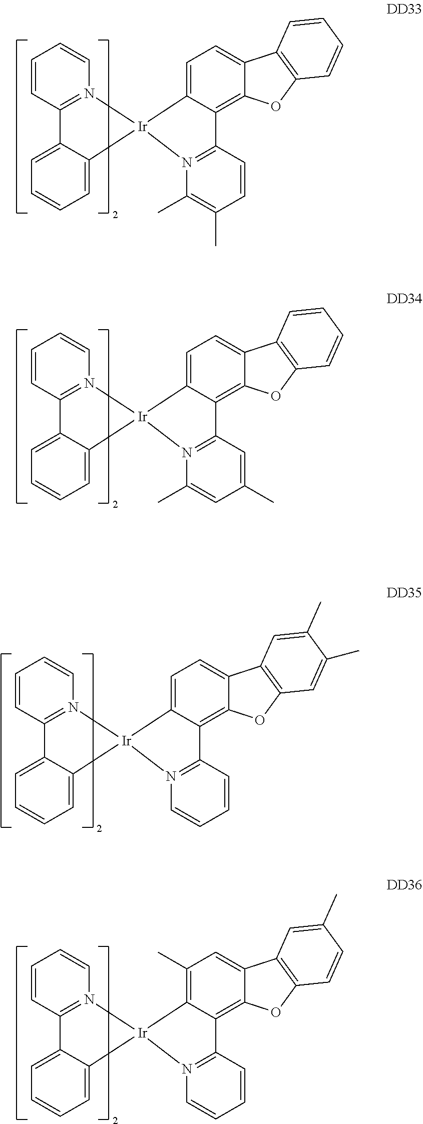

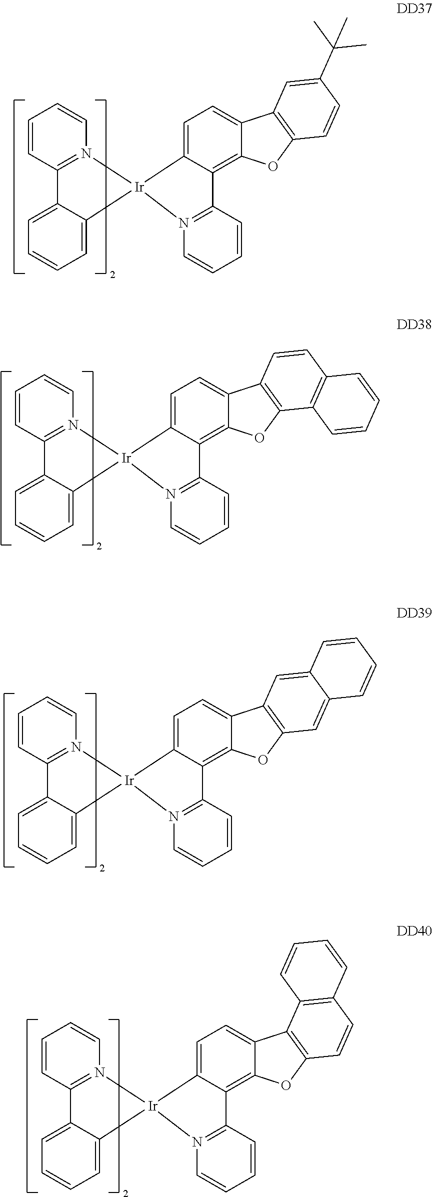

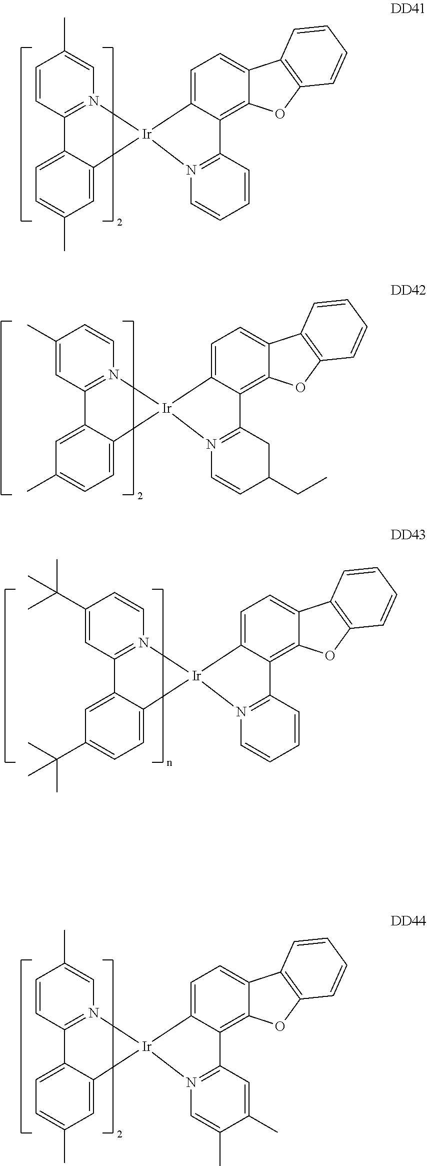

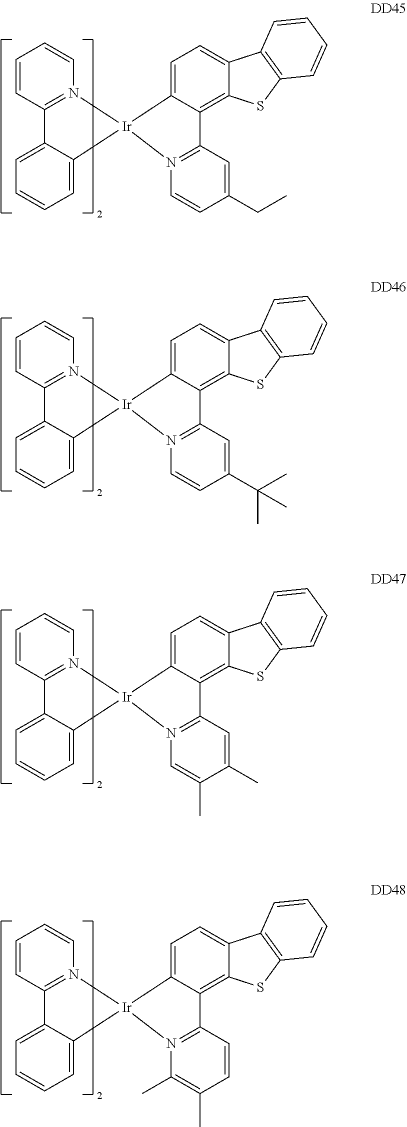

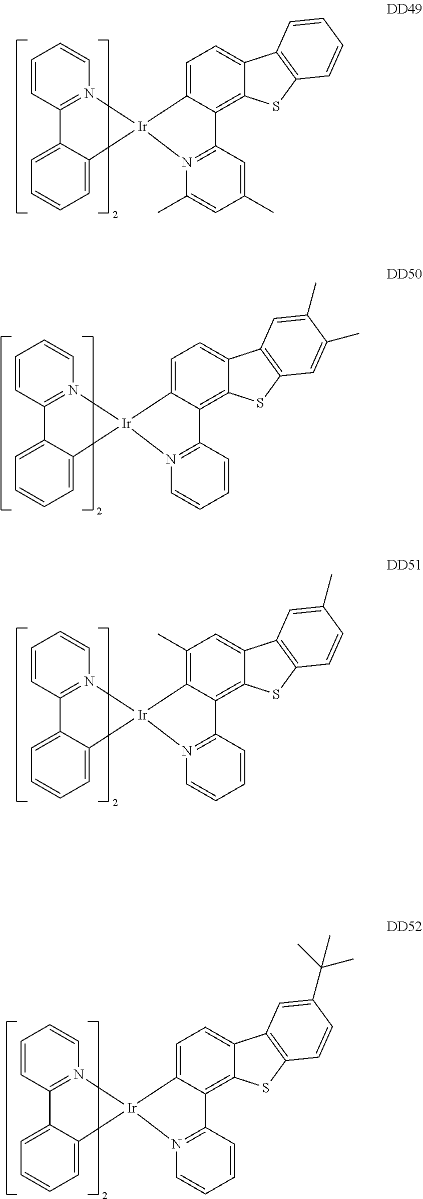

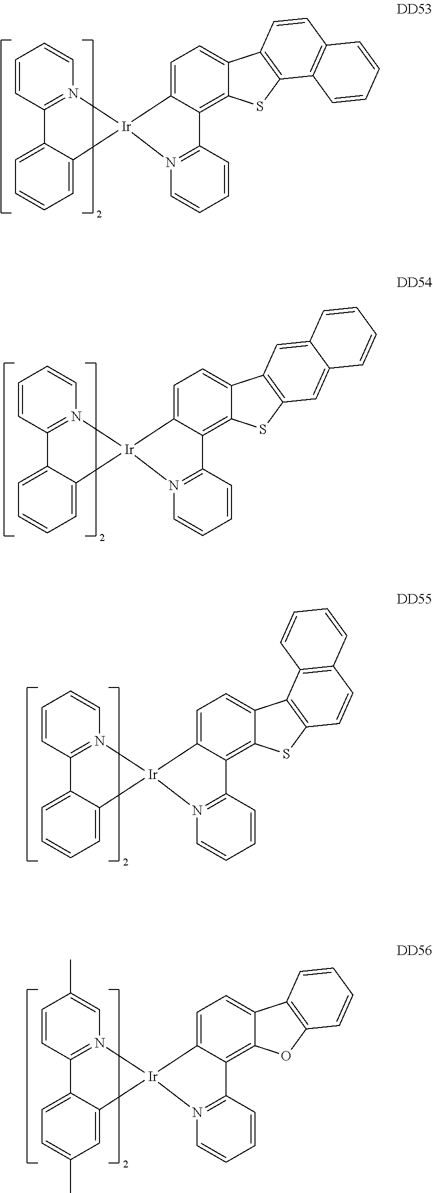

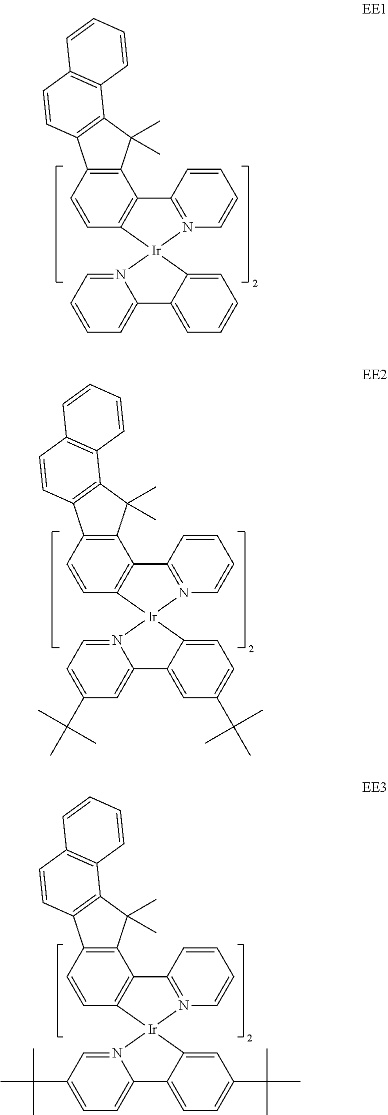

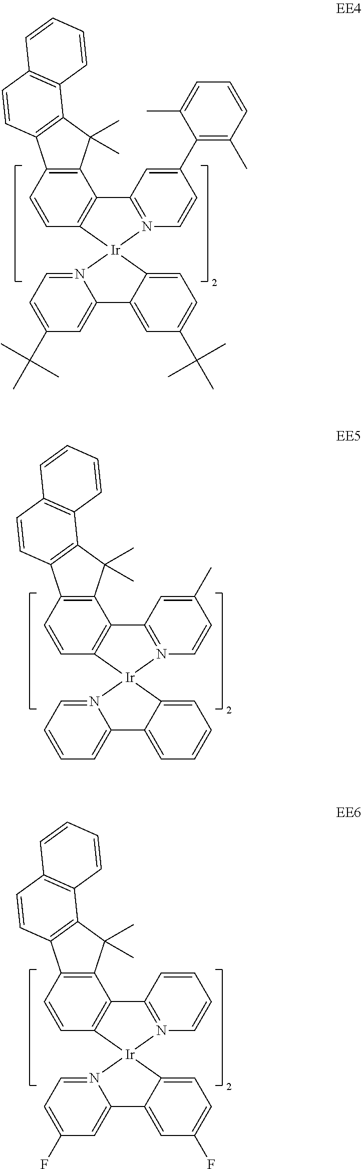

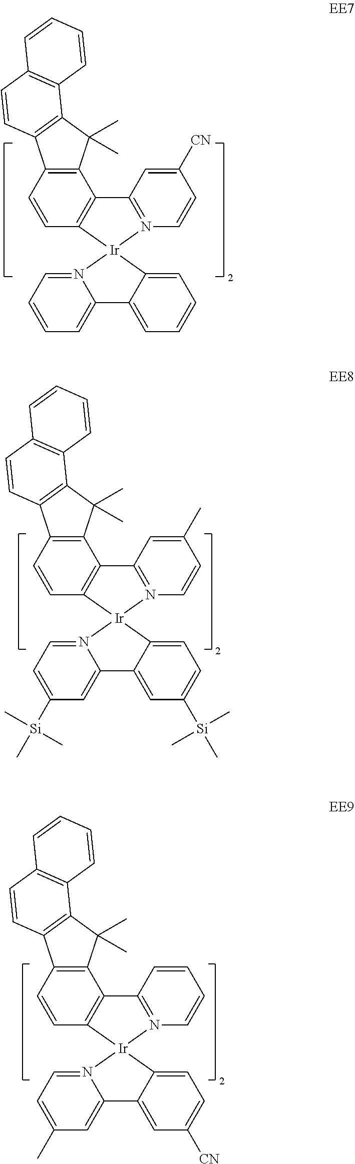

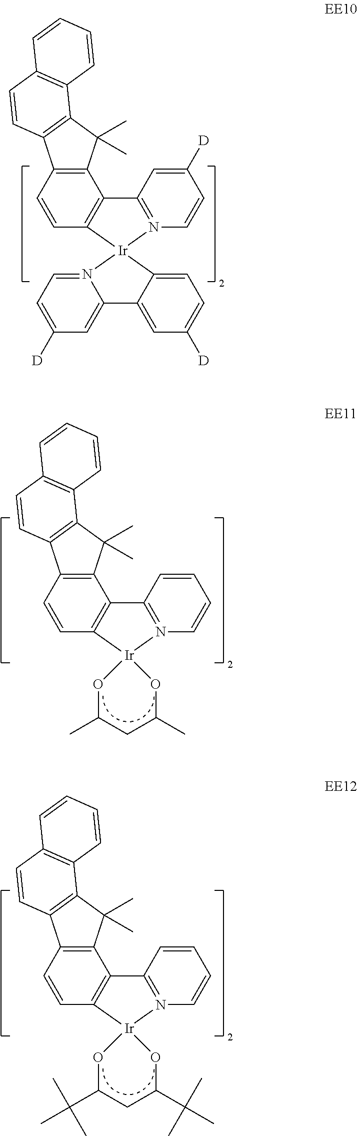

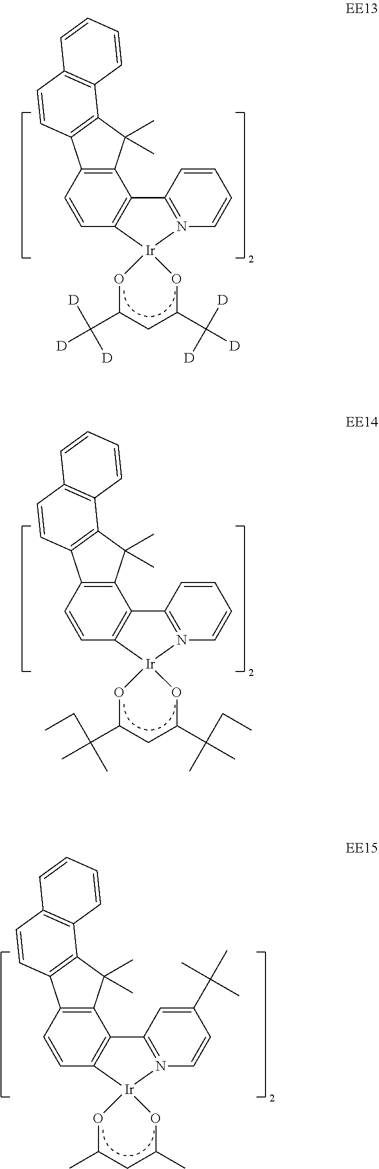

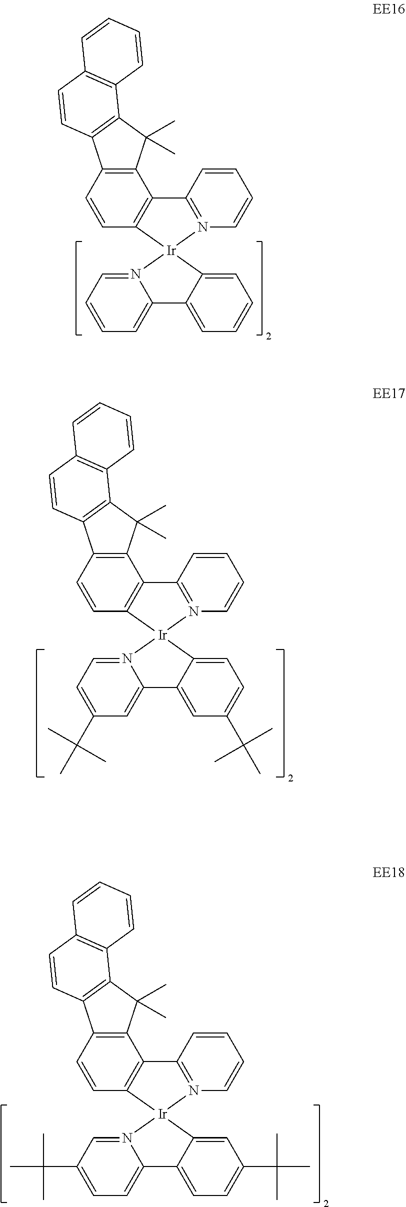

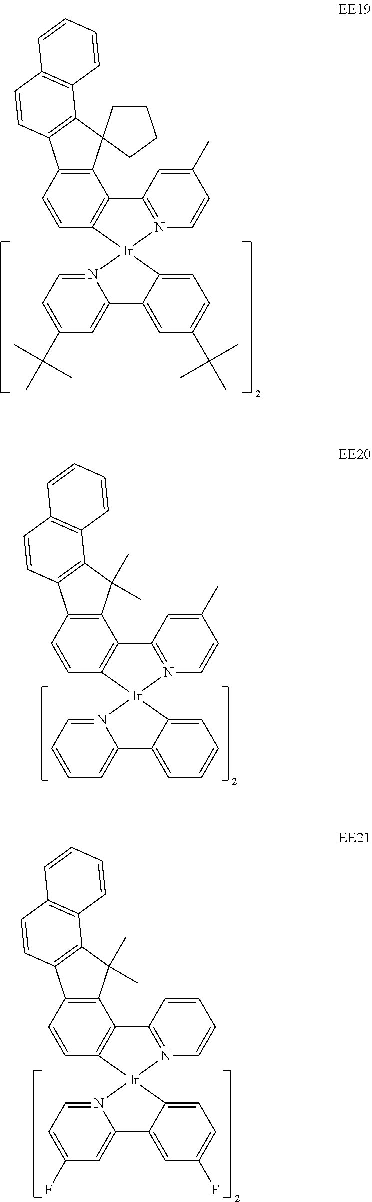

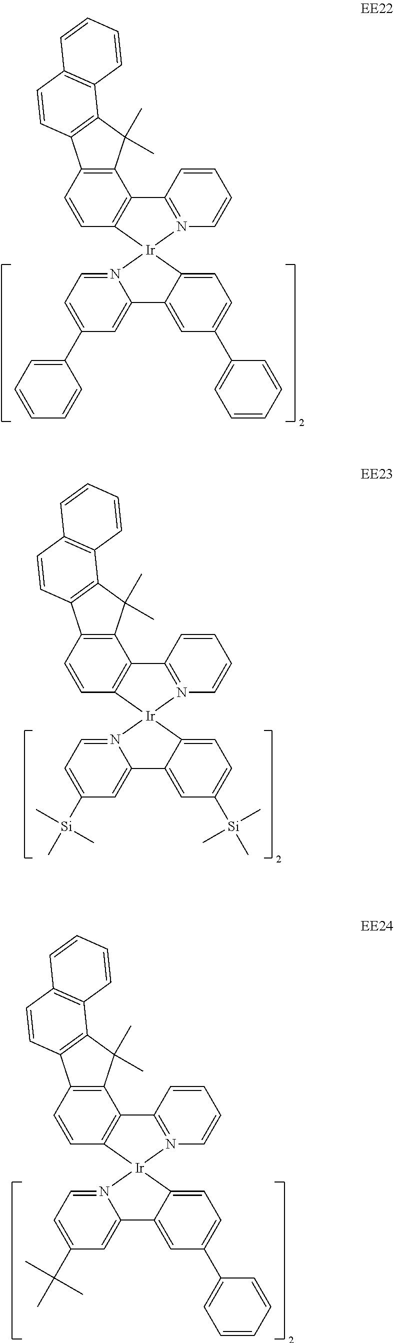

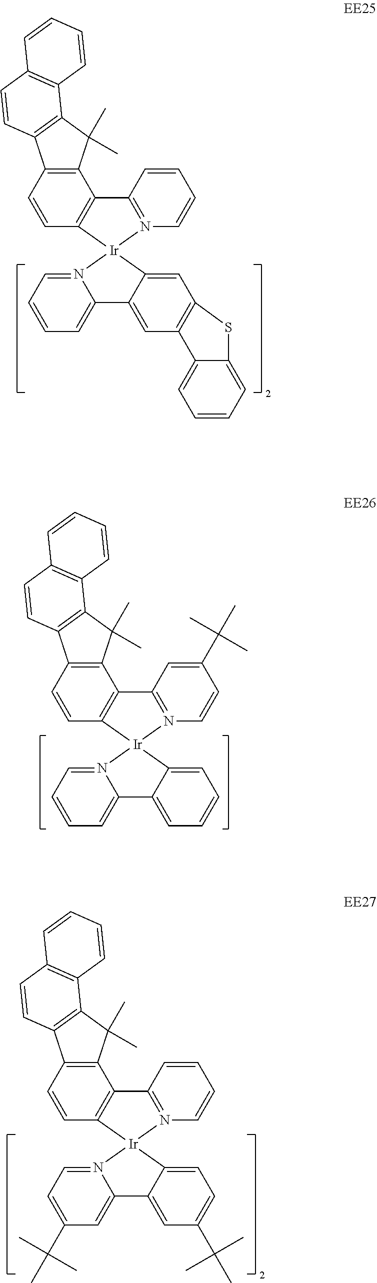

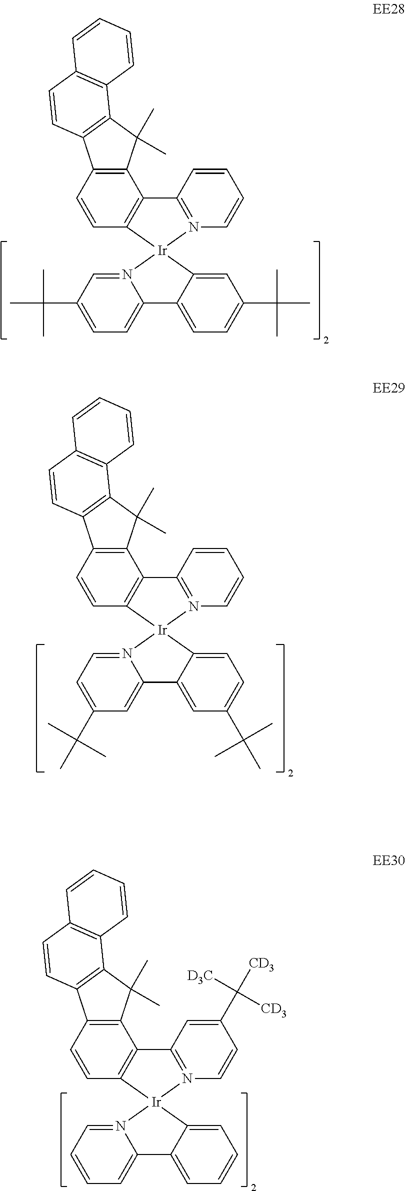

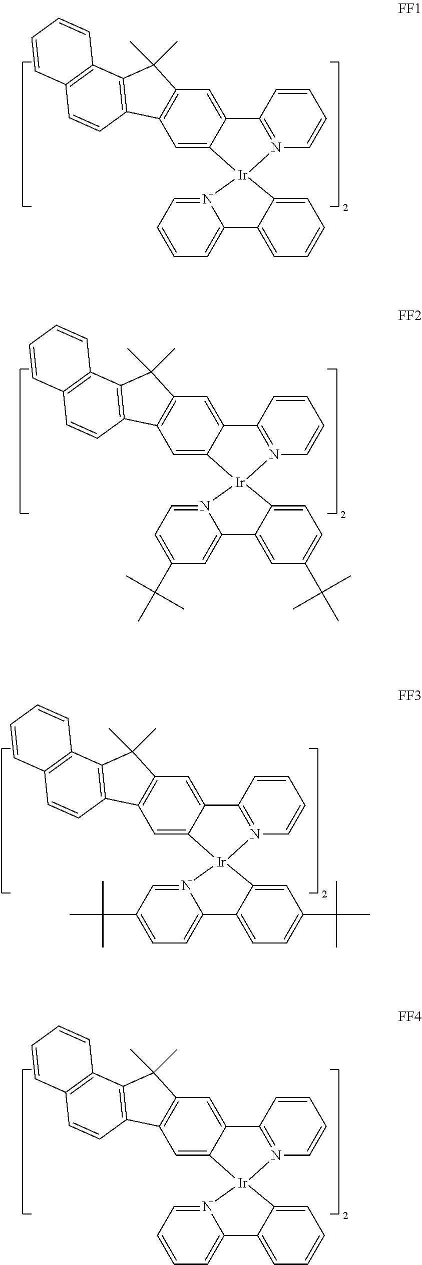

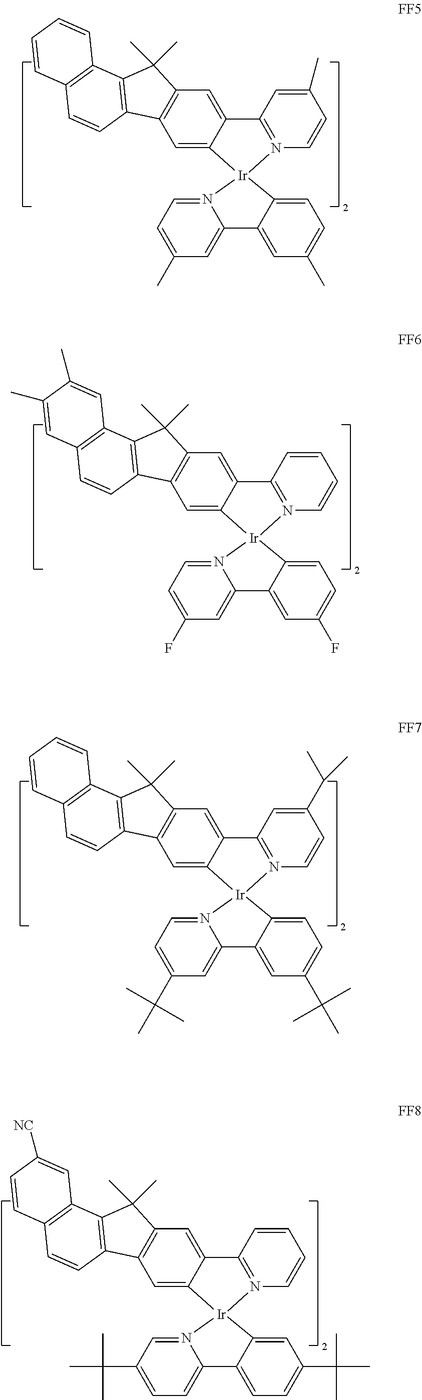

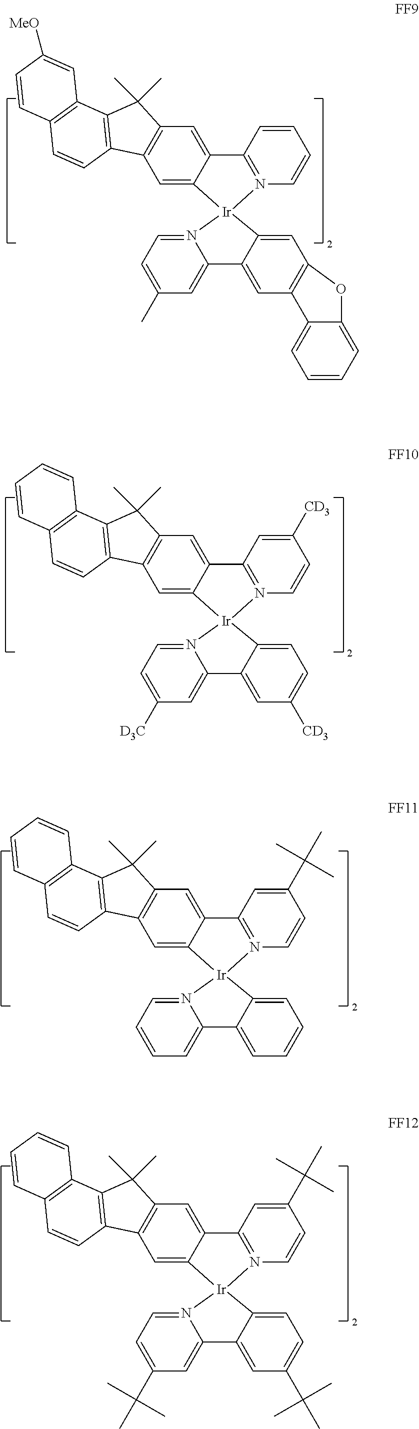

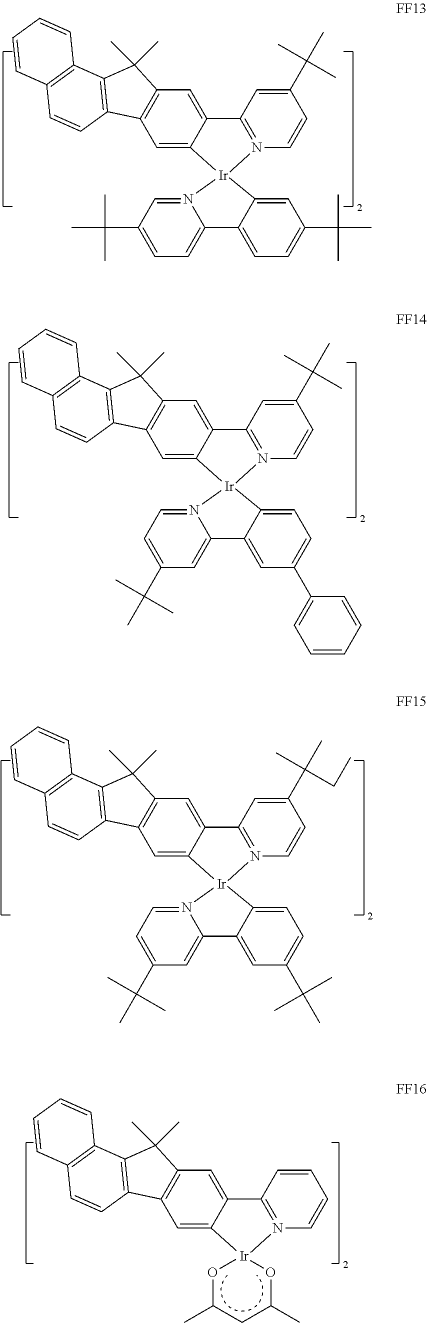

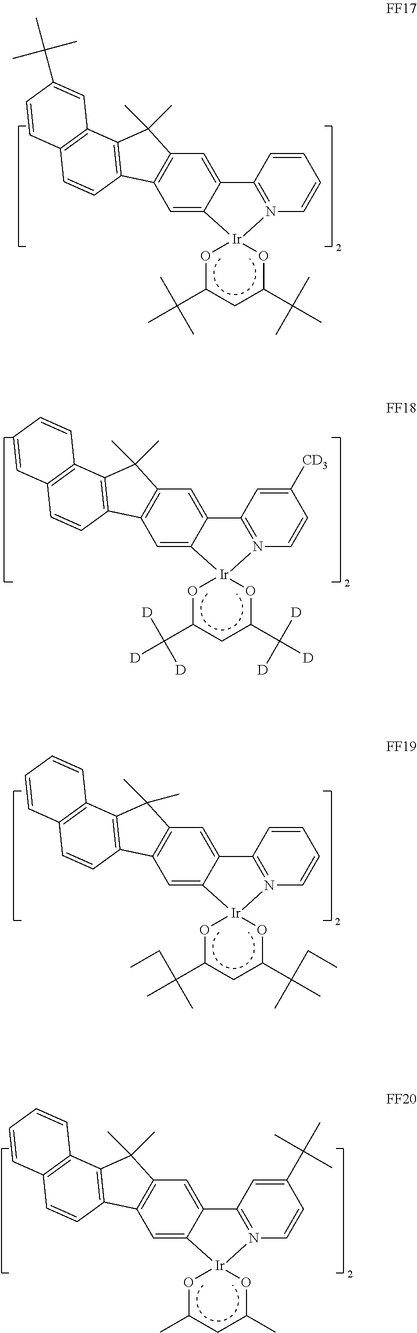

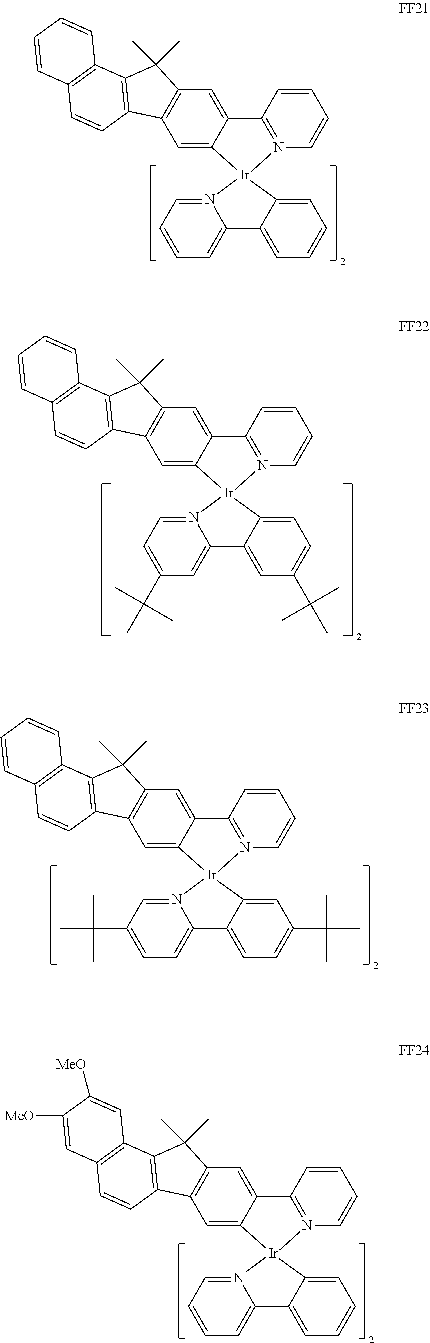

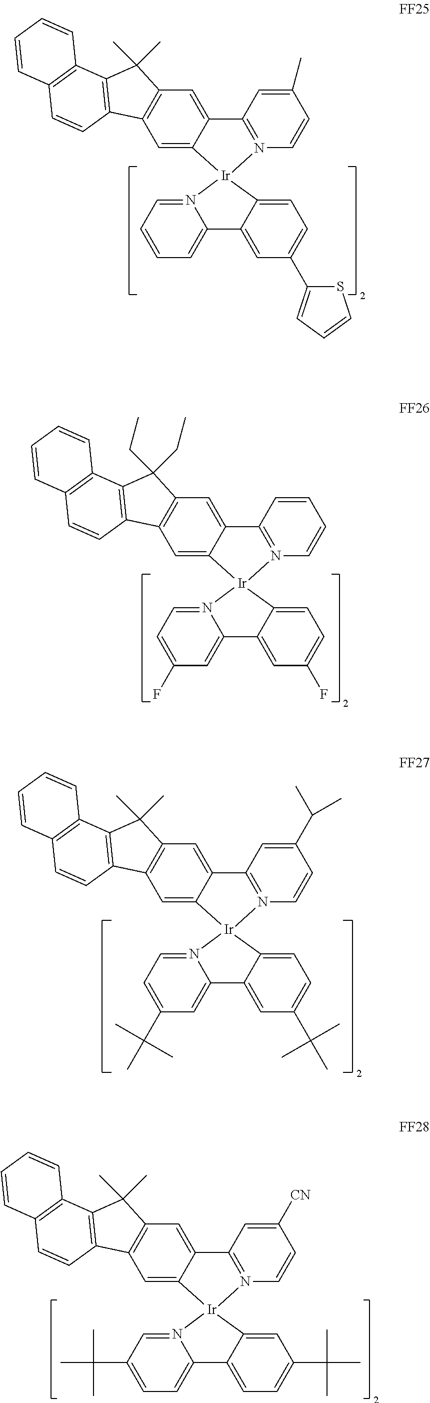

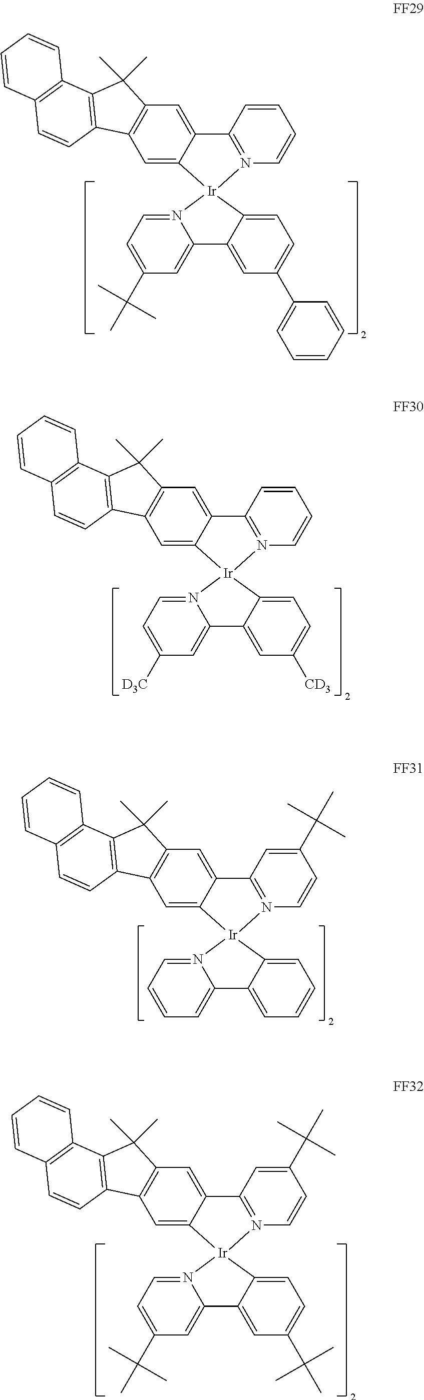

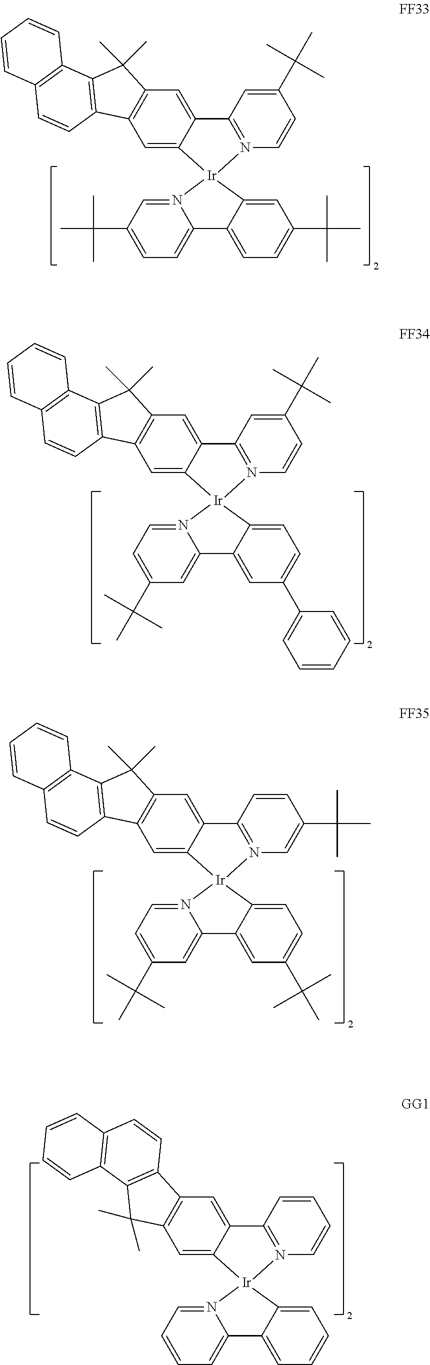

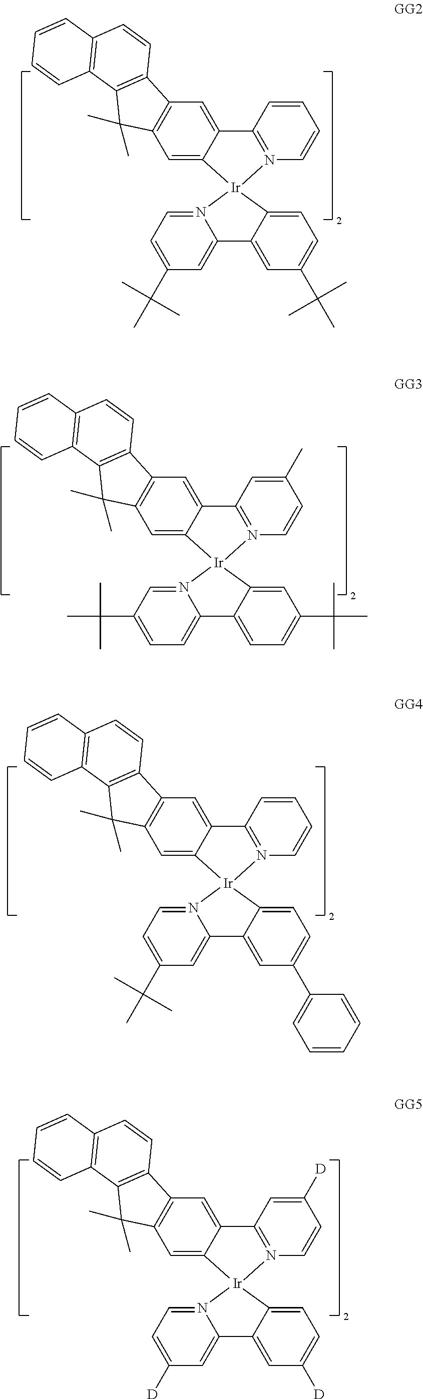

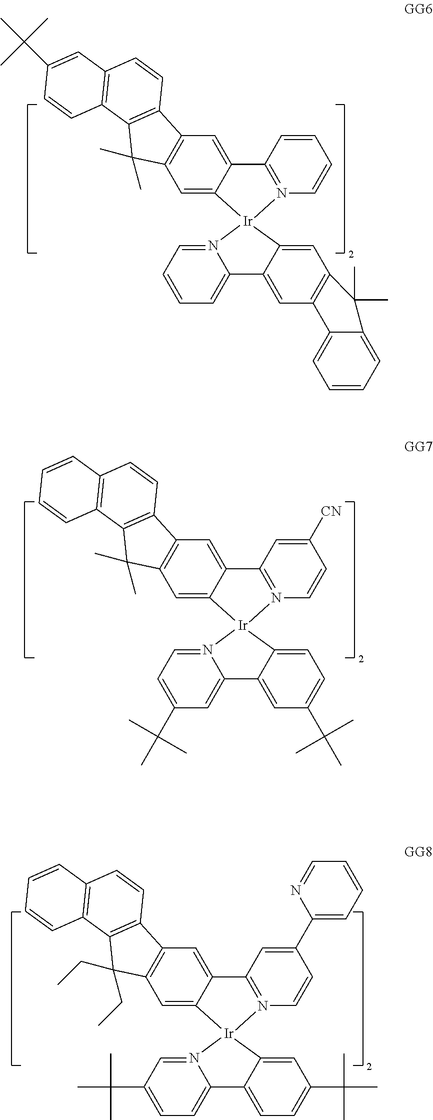

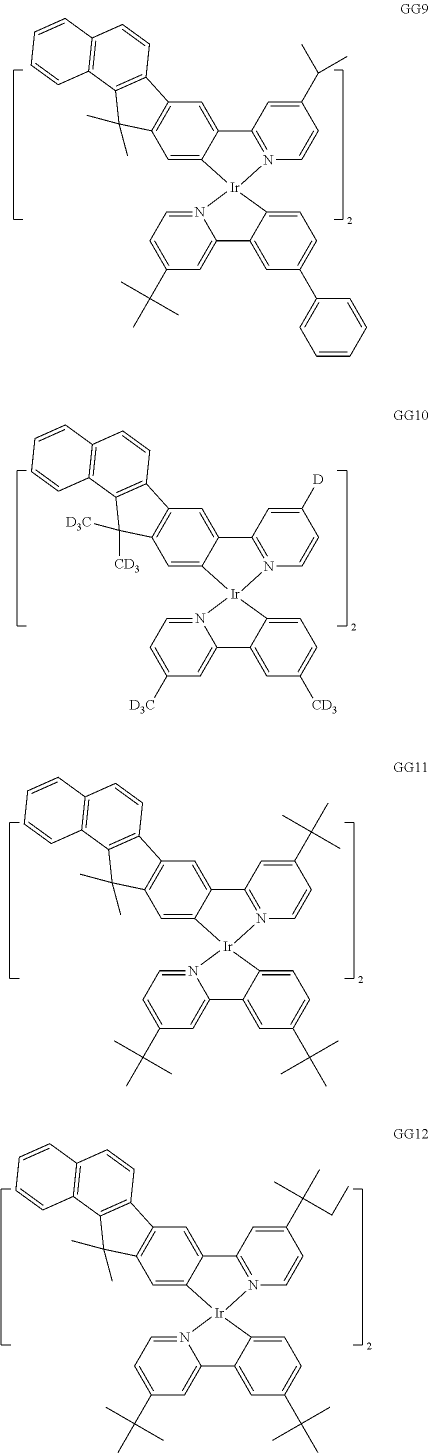

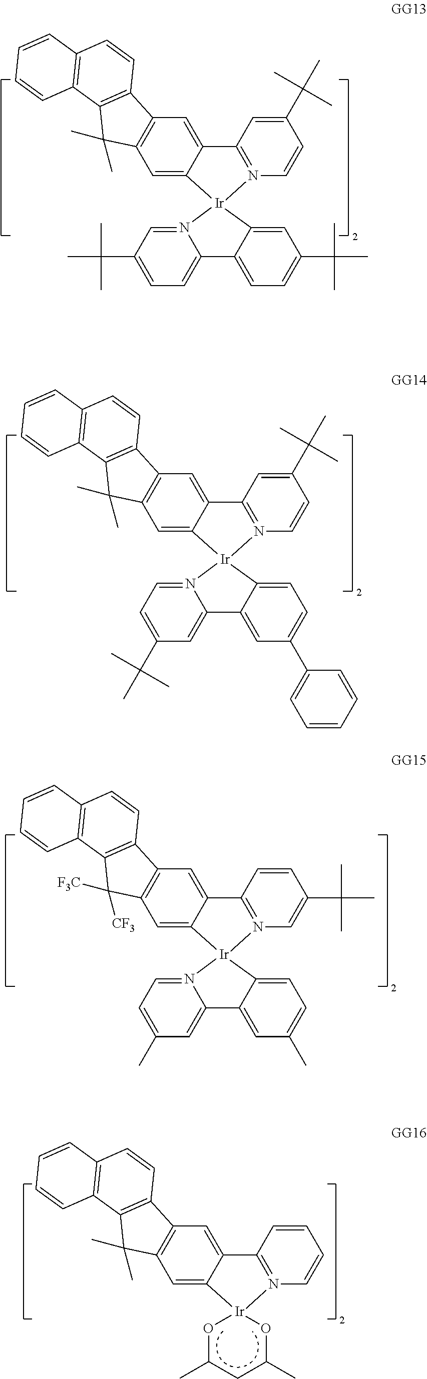

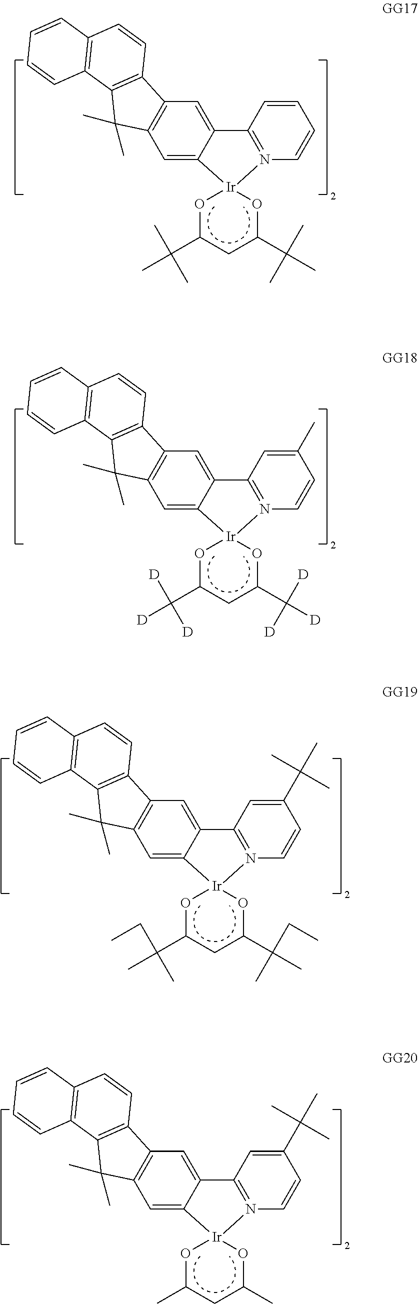

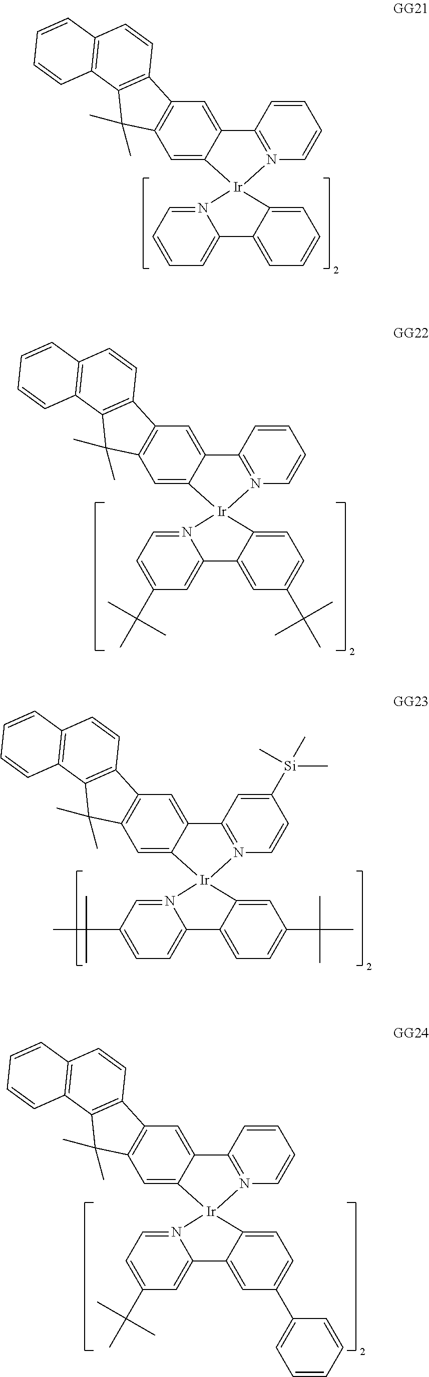

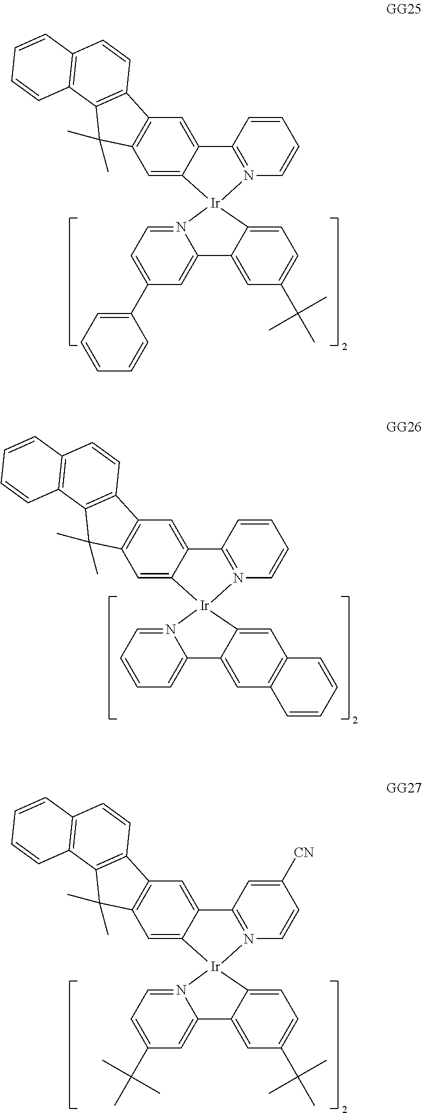

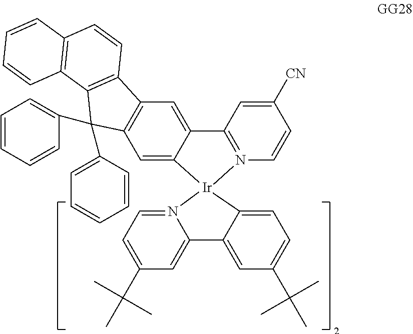

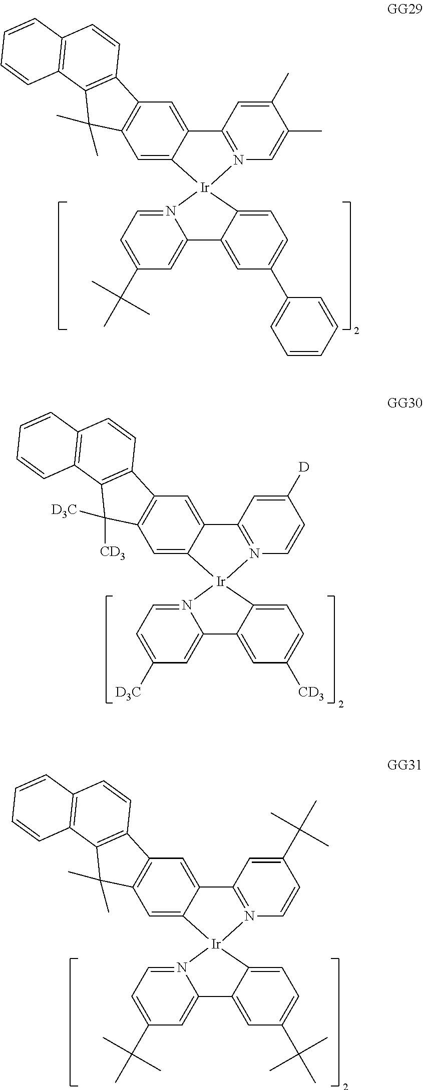

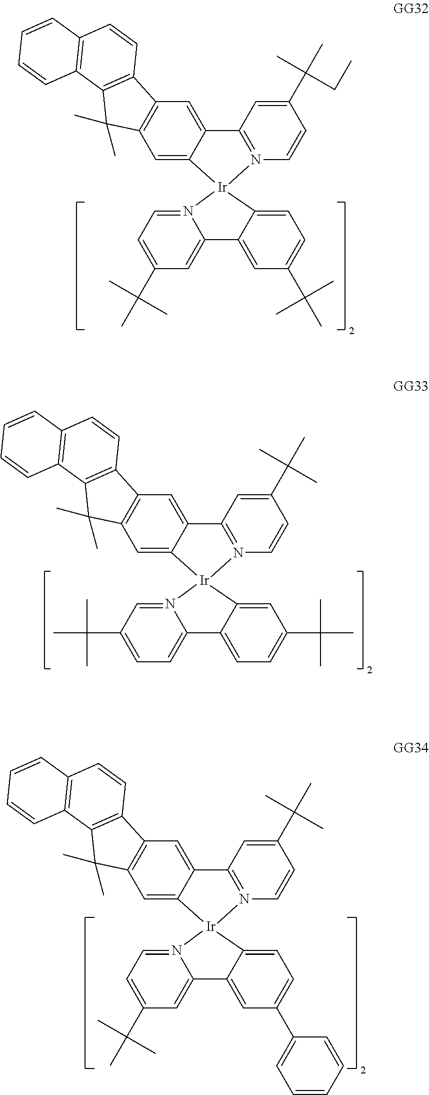

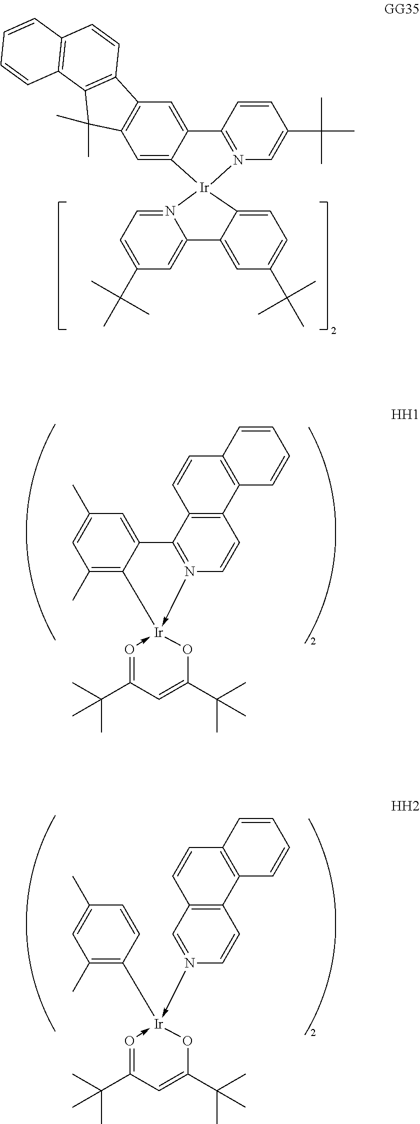

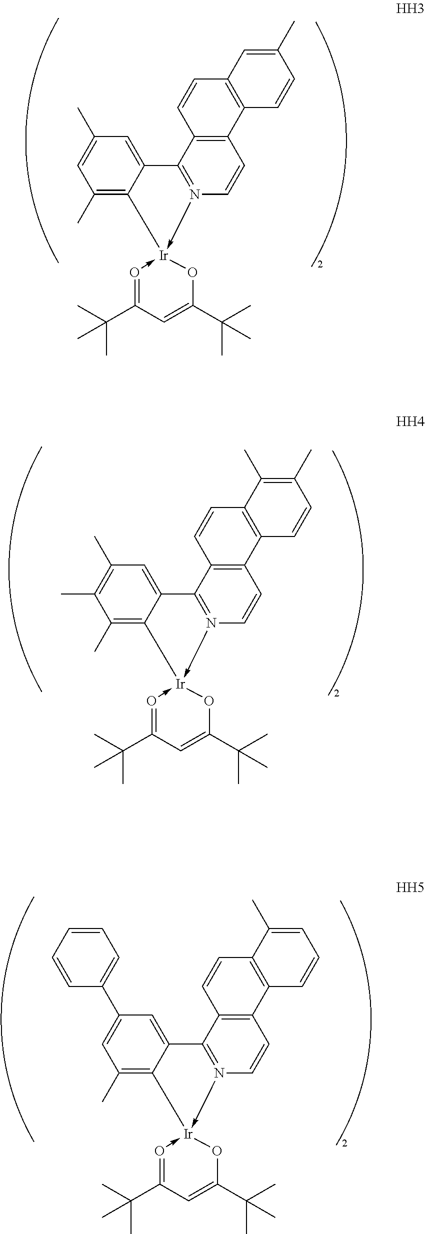

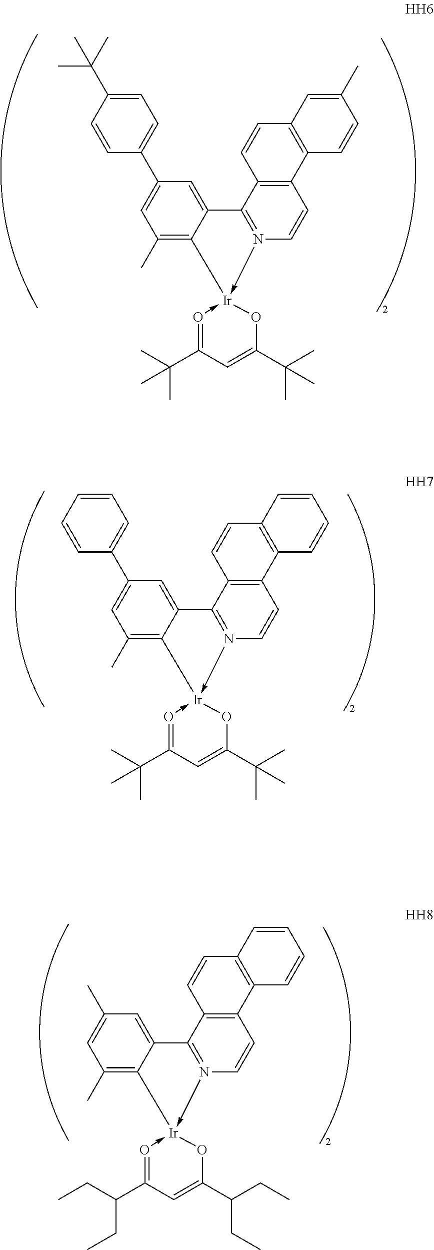

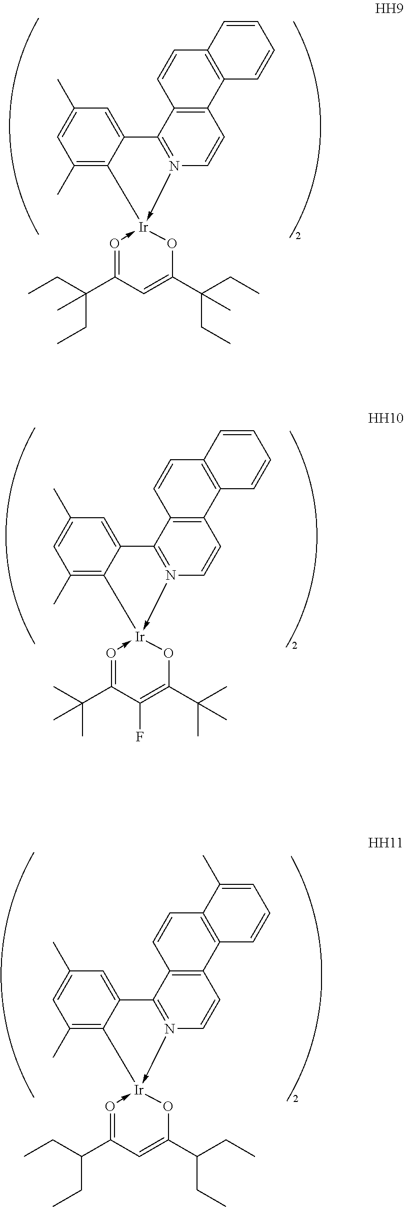

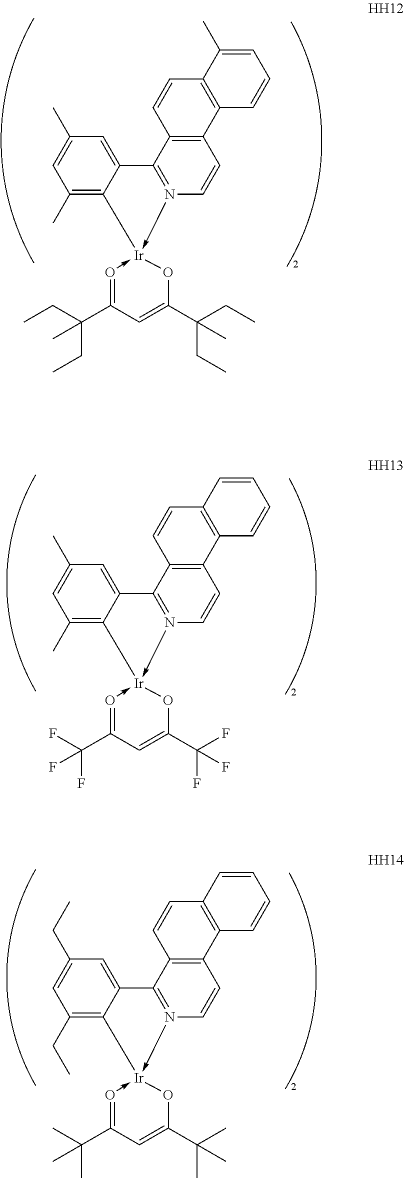

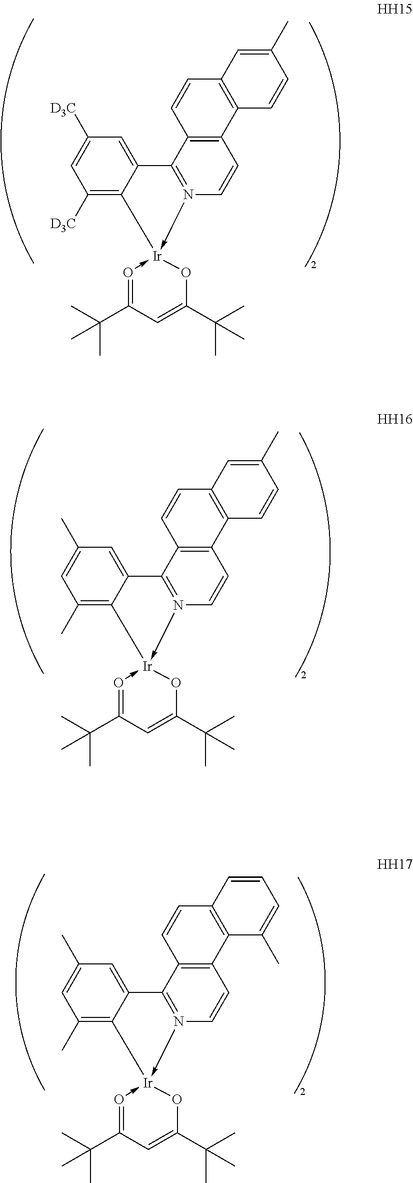

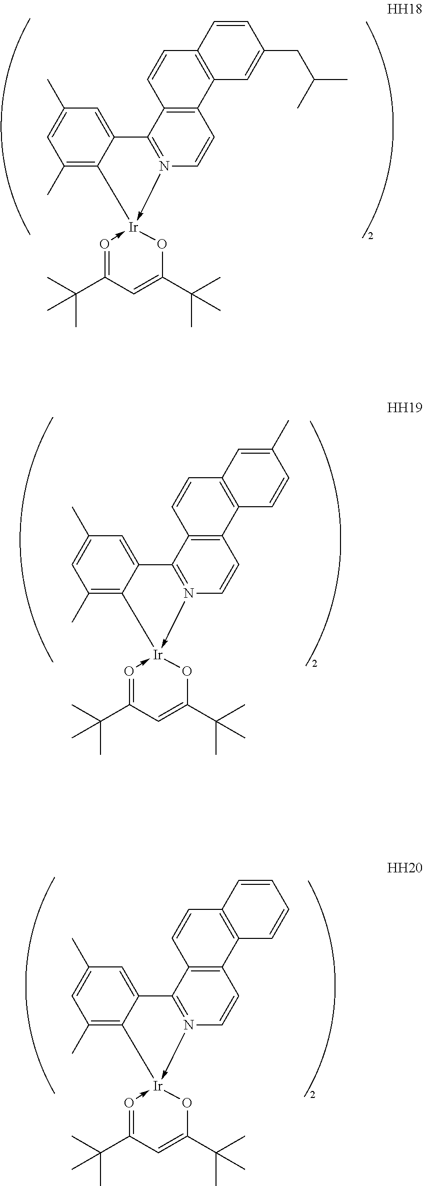

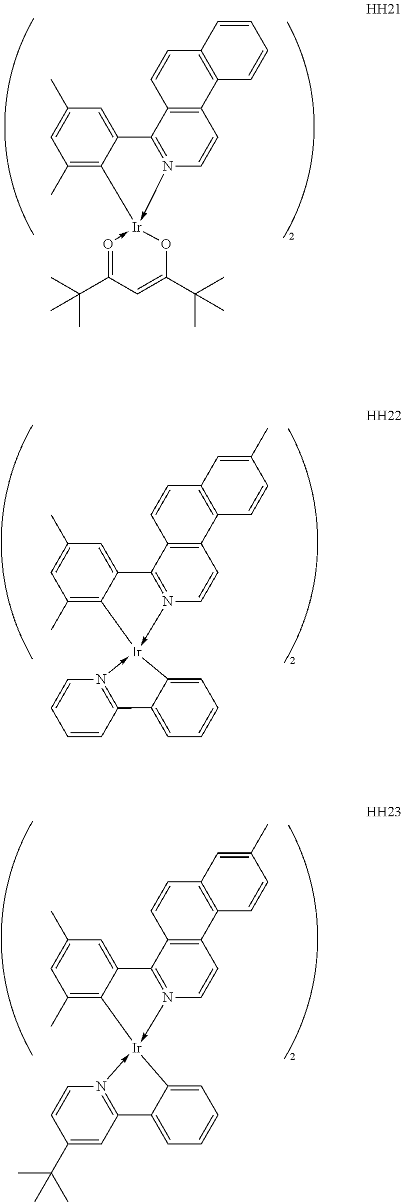

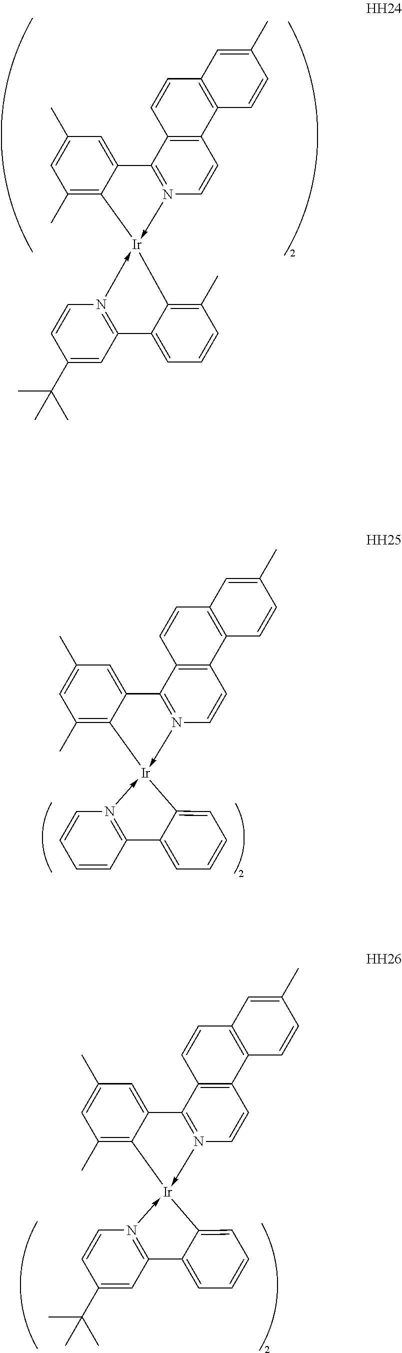

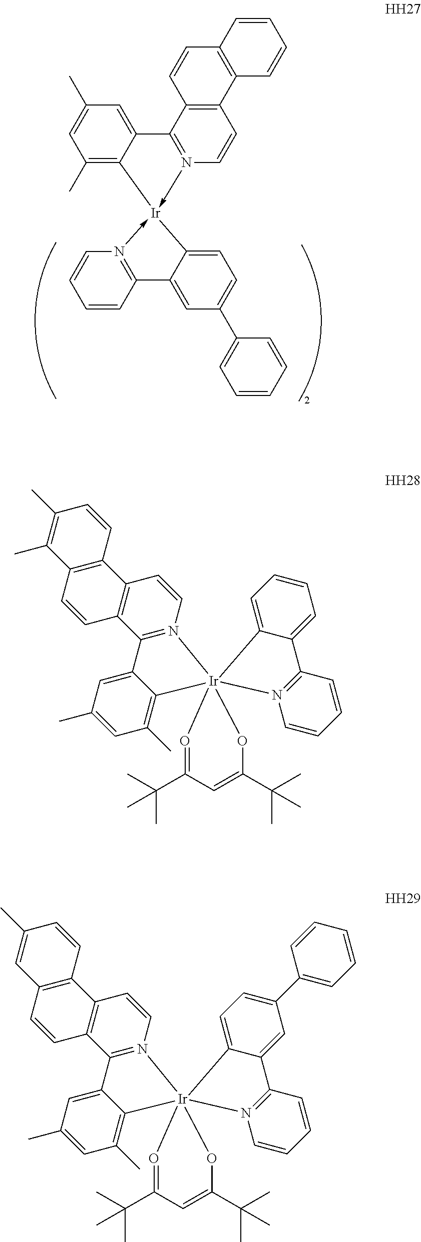

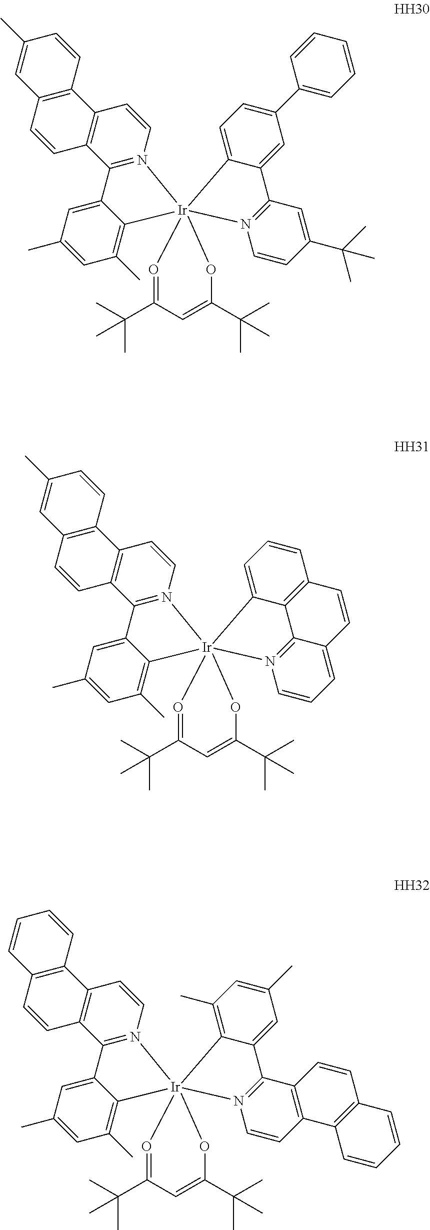

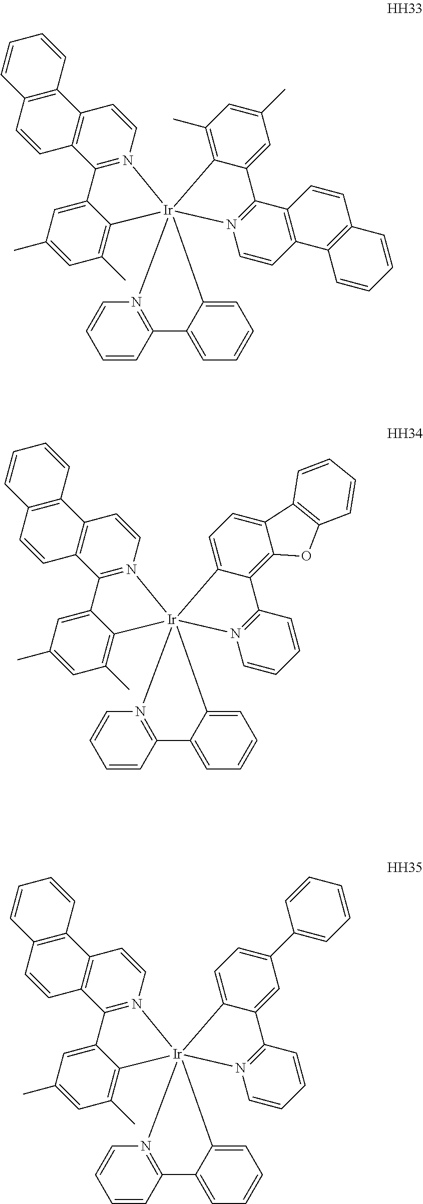

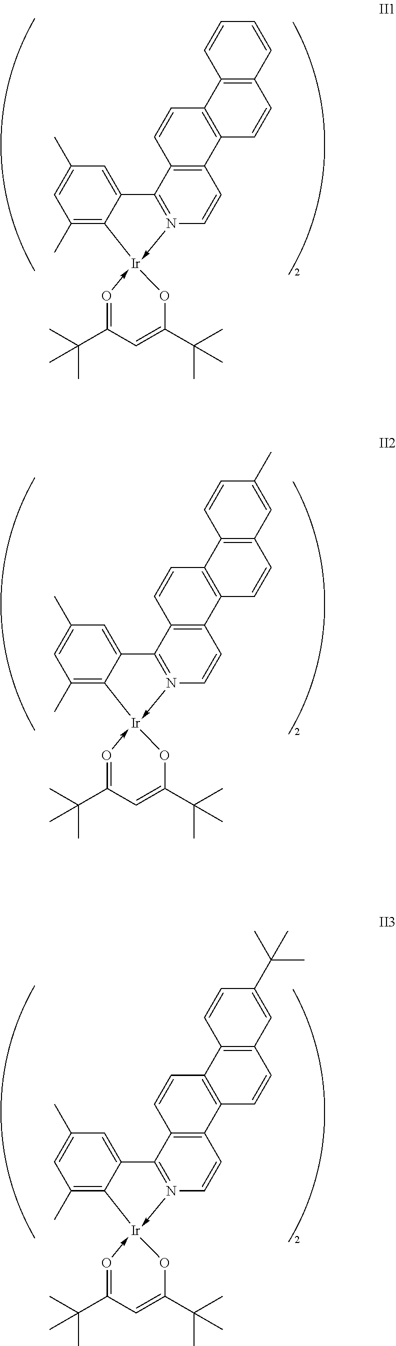

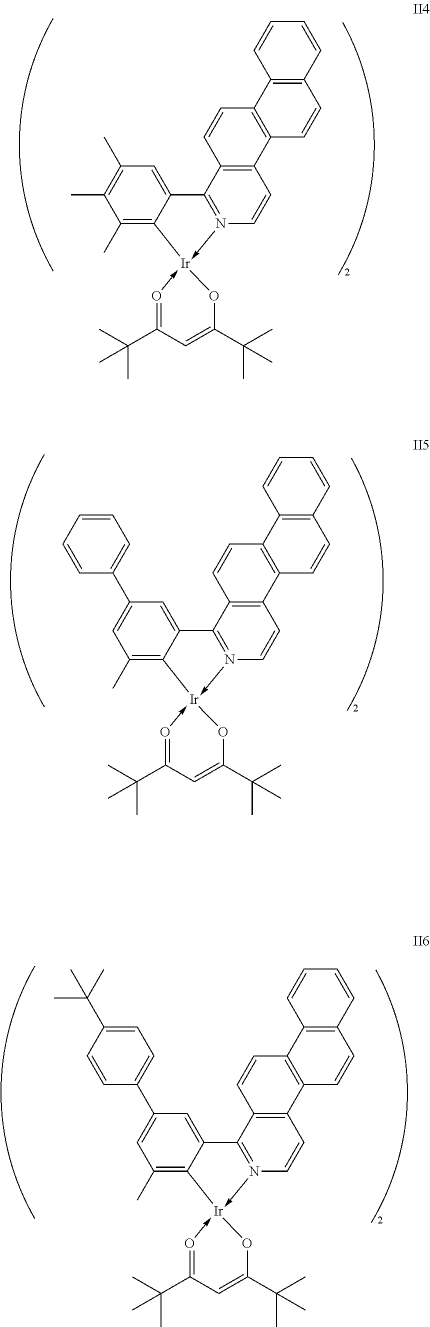

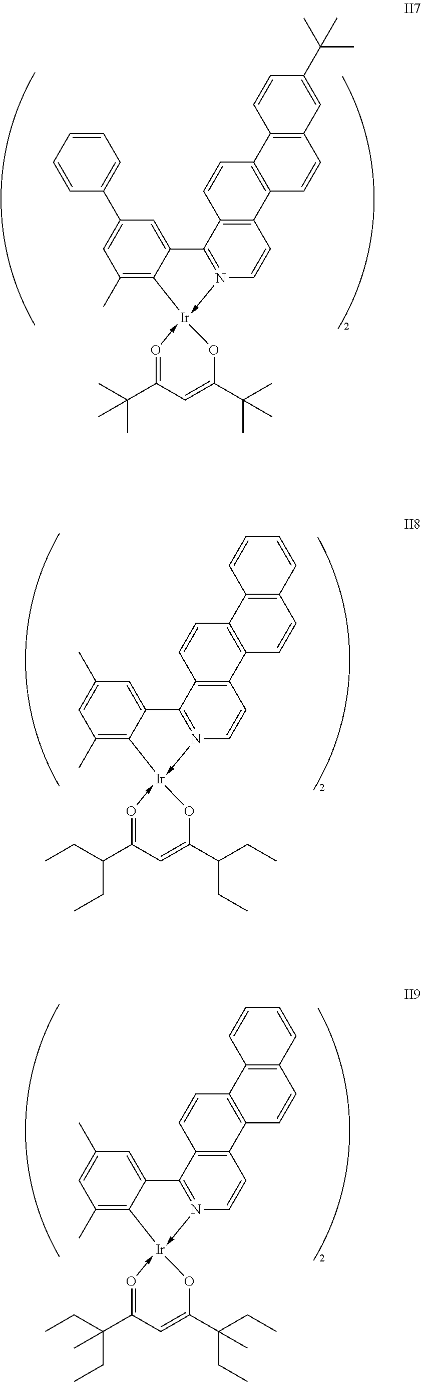

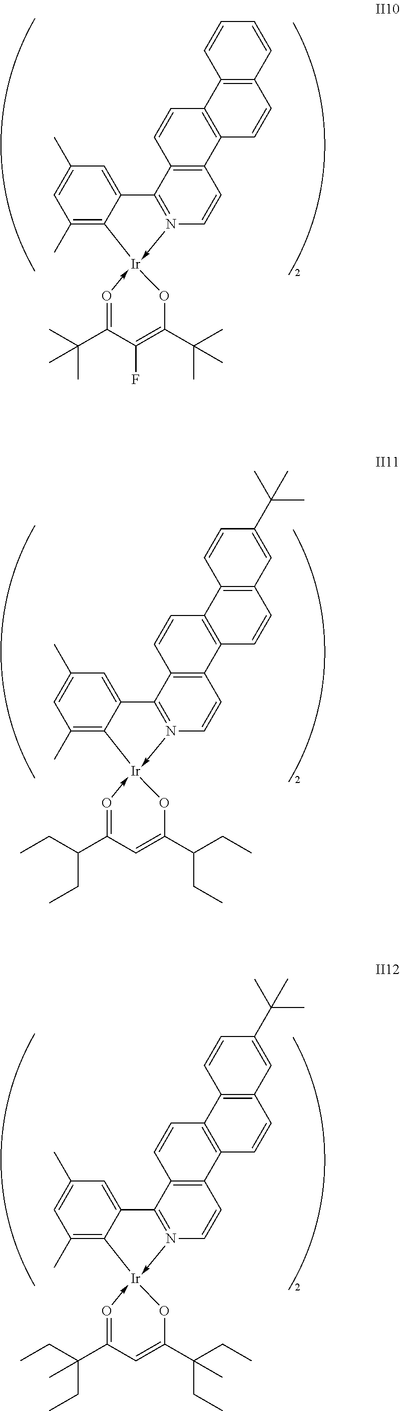

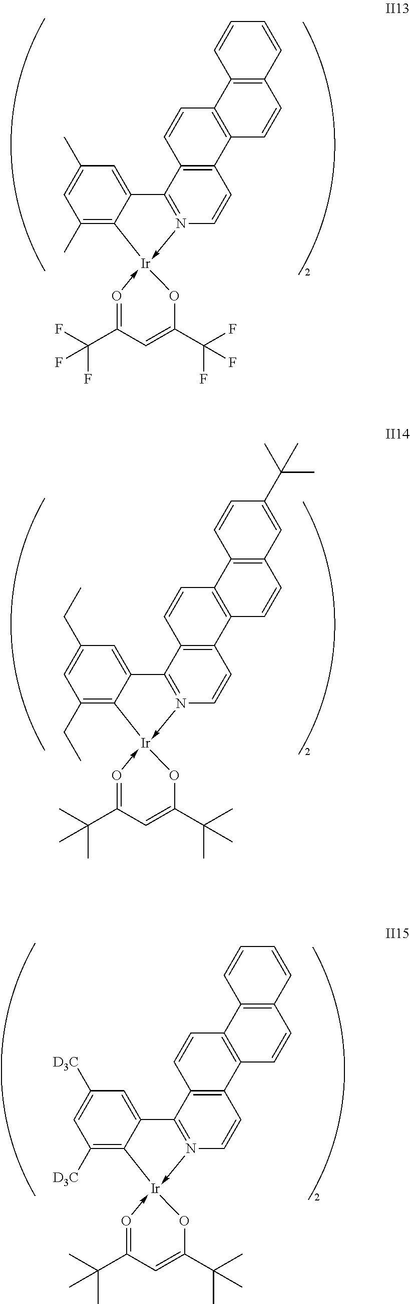

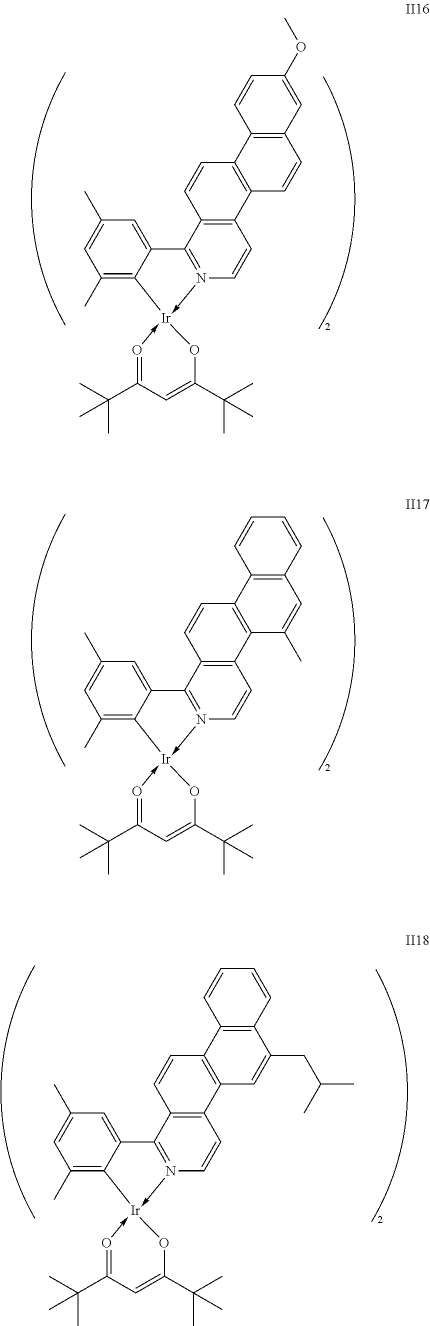

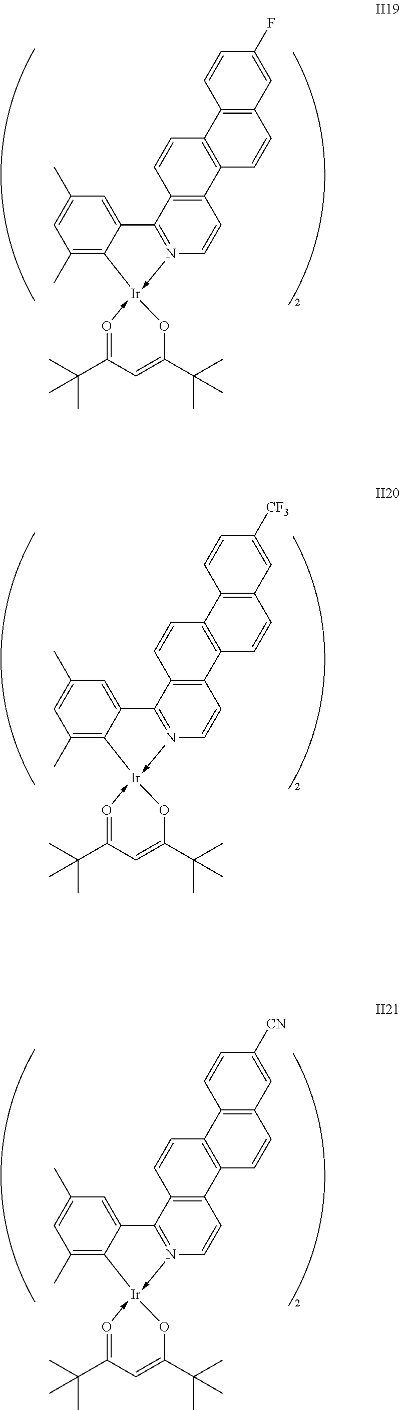

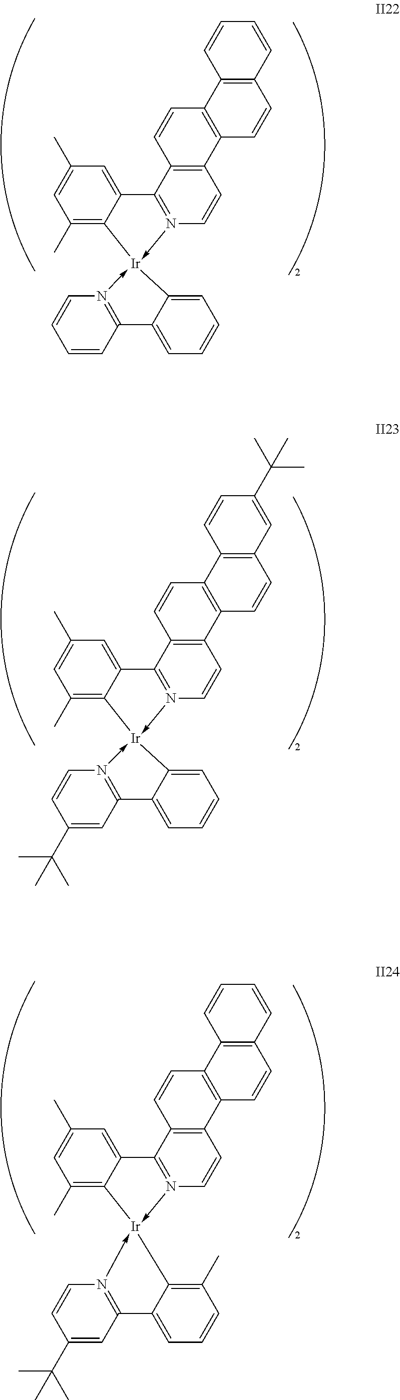

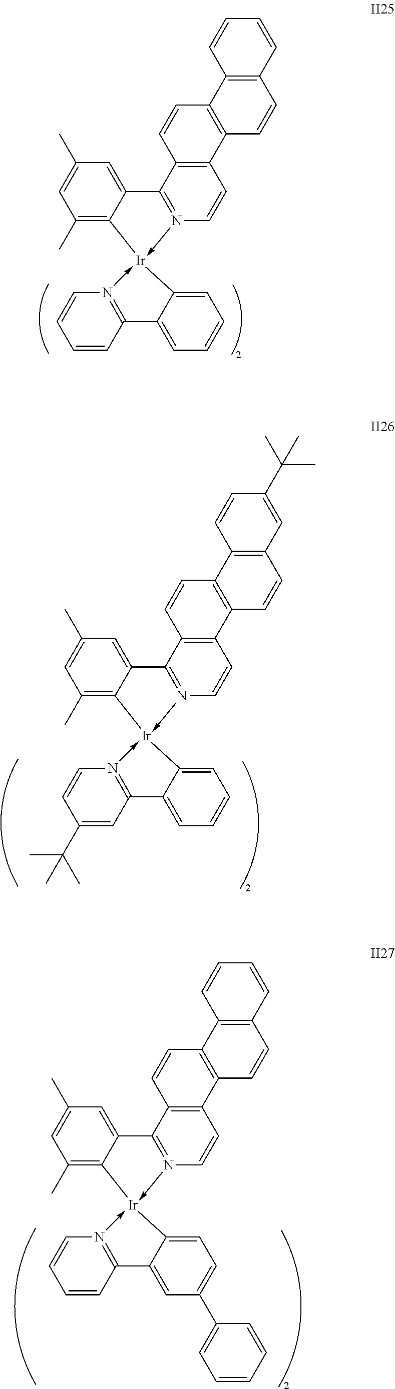

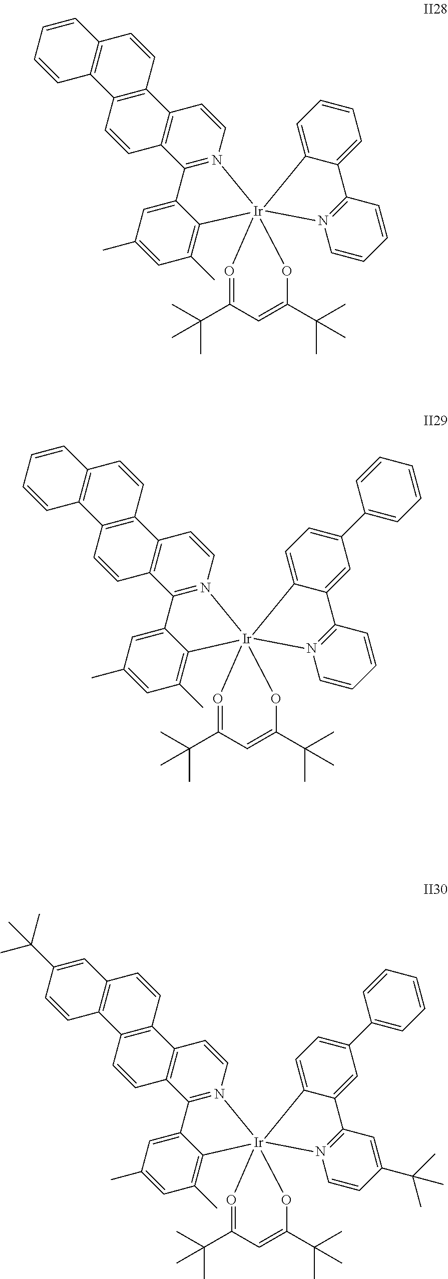

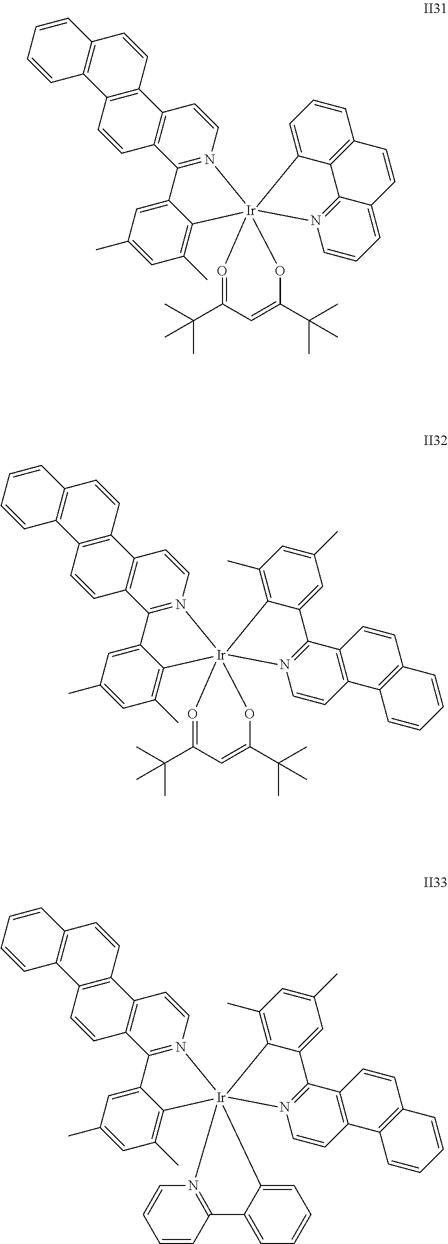

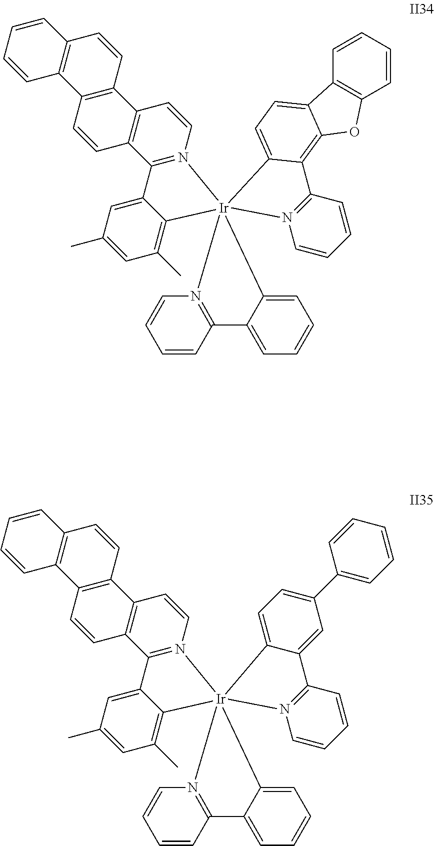

Exemplary compounds belonging to groups AA and BB are metal complexes whose partial structure M (L) m is represented by general formula [Ir-3], and are compounds having a phenanthrene ring in the ligand. These compounds are compounds having particularly high stability.

Exemplary compounds belonging to group CC are metal complexes whose partial structure M (L) m is represented by general formula [Ir-4], and are compounds having a triphenylene ring in the ligand. These compounds are compounds having particularly high stability.

Exemplary compounds belonging to group DD are metal complexes whose partial structure M (L) m is represented by any of general formulas [Ir-5] to [Ir-8], and are compounds having a dibenzofuran ring, a dibenzothiophene ring, a benzonaphthofuran ring, or a benzonaphthothiophene ring in the ligand. These compounds include an oxygen atom or a sulfur atom, and abundant unshared electron pairs of these atoms can enhance charge transportability. Thus, these are compounds that particularly help adjust the carrier balance.

Exemplary compounds belonging to groups EE to GG are metal complexes whose partial structure M (L) m is represented by any of general formulas [Ir-6] to [Ir-8], and are compounds having a benzofluorene ring in the ligand. These compounds have, at the 9-position of the fluorene ring, a substituent in a direction perpendicular to the in-plane direction of the fluorene ring, and thus can particularly inhibit overlapping of fused rings. Thus, these are compounds having particularly high sublimability.

Exemplary compounds belonging to group HH are metal complexes whose partial structure M (L) m is represented by any of general formulas [Ir-11] to [Ir-13], and are compounds having a benzoisoquinoline ring in the ligand. These compounds include a nitrogen atom in the fused ring, and unshared electron pairs and high electronegativity of this atom can enhance charge transportability. Thus, these are compounds that particularly help adjust the carrier balance.

Exemplary compounds belonging to group II are metal complexes whose partial structure M (L) m is represented by general formula [Ir-14], and are compounds having a naphthoisoquinoline ring in the ligand. These compounds include a nitrogen atom in the fused ring, and unshared electron pairs and high electronegativity of this atom can enhance charge transportability. Thus, these are compounds that particularly help adjust the carrier balance.

### Organic Light-Emitting Element

The organic light-emitting element according to this embodiment includes a first electrode and a second electrode, and an organic compound layer disposed between the first electrode and the second electrode. The organic compound layer includes at least a light-emitting layer. The organic compound layer may be a single layer or a stack of a plurality of layers. When the organic compound layer is a stack of a plurality of layers, at least one of the layers is a light-emitting layer. The organic compound layer may include, in addition to the light-emitting layer, a hole injection layer, a hole transport layer, an electron blocking layer, a hole/exciton blocking layer, an electron transport layer, an electron injection layer, and the like. These layers contain at least one organic compound, and T1 of the organic compound is preferably different from T1 of the first organic compound and T1 of the second organic compound and higher than T1 of the first organic compound and T1 of the second organic compound. The light-emitting layer may be a single layer or a stack of a plurality of layers.

In the organic light-emitting element according to this embodiment, at least one of the organic compound layers contains the organic compounds according to this embodiment.

The first organic compound or the second organic compound is also referred to as a host or a host material, and is a compound accounting for the largest mass proportion among the compounds constituting the light-emitting layer. The luminescent compound is also referred to as a guest, a guest material, or a light-emitting material, and is a compound that accounts for a smaller mass proportion than the host among the compounds constituting the light-emitting layer and that is responsible for main light emission.

The host of the light-emitting layer according to this embodiment includes at least two types of hosts. The concentrations of these hosts are each preferably 10 mass % or more and 90 mass % or less, more preferably 20 mass % or more and 80 mass % or less, still more preferably 30 mass or more and 70 mass % or less, relative to the total mass of the light-emitting layer.

The concentration of the guest relative to the host is 0.01 mass % or more and 50 mass % or less, preferably 0.1 mass % or more and 20 mass % or less, based on the total amount of the constituent materials of the light-emitting layer. From the viewpoint of suppressing concentration quenching, the concentration of the guest is particularly preferably 10 mass % or less.

The guest may be contained uniformly or with a concentration gradient throughout the layer in which the host serves as a matrix. Alternatively, the guest may be locally contained in a specific region in the layer so that the light-emitting layer has a region containing the host alone without the guest.

The light-emitting layer in the present invention may be single-layered or multi-layered, and may also contain a light-emitting material having a different emission color to mix colors. The term “multi-layered” refers to a state in which the light-emitting layer and another light-emitting layer are stacked on top of each other. In this case, the emission color of the organic light-emitting element is not particularly limited. More specifically, the emission color may be white or an intermediate color. In the case of white, for example, when the emission color of the light-emitting layer is blue, the other light-emitting layer emits light of a color different from blue, that is, green or red. Furthermore, a third light-emitting layer that emits blue light and a charge generation layer may be disposed between the light-emitting layer or light-emitting layer stack in the present invention and the first or second electrode. The charge generation layer activates the function as a tandem element; electrons generated from the charge generation layer and holes injected from the first electrode undergo charge recombination to generate excitons, and holes generated from the charge generation layer and electrons injected from the second electrode undergo charge recombination to form excitons. As a result of this, the internal quantum efficiency is doubled. In this case, the organic light-emitting element according to the present invention can be applied on one side of a tandem element as a layer that emits light of yellow as a complementary color for blue light emission. Therefore, by using a light-emitting layer stack composed of the light-emitting layers in the present invention and forming a tandem element configuration together with a blue light-emitting layer, a white light-emitting element can be provided. The third light-emitting layer contains at least a third organic compound and a fourth organic compound. The third organic compound is a host material, and the fourth organic compound is a blue light-emitting material.

The layer formation is performed by vapor deposition or coating.

Specific examples of the element configuration of the organic light-emitting element according to this embodiment include multilayer element configurations in which electrode layers and organic compound layers shown in (1) to (6) below are sequentially stacked on a substrate. In every element configuration, the organic compound layers include a light-emitting layer containing a light-emitting material without exception.

(1) Anode/light-emitting layer/cathode

(2) Anode/hole transport layer/light-emitting layer/electron transport layer/cathode

(3) Anode/hole transport layer/light-emitting layer/electron transport layer/electron injection layer/cathode

(4) Anode/hole injection layer/hole transport layer/light-emitting layer/electron transport layer/cathode

(5) Anode/hole injection layer/hole transport layer/light-emitting layer/electron transport layer/electron injection layer/cathode

(6) Anode/hole transport layer/electron blocking layer/light-emitting layer/hole blocking layer/electron transport layer/cathode

It should be noted that these exemplary element configurations are merely basic element configurations and are not meant to be limiting. For example, various layer configurations such as a configuration in which an insulating layer, an adhesive layer, or an interference layer is disposed at the interface between an electrode and an organic compound layer, a configuration in which the electron transport layer or the hole transport layer is composed of two layers having different ionization potentials, and a configuration in which the light-emitting layer is composed of two layers formed of different light-emitting materials may be employed.

Of the element configurations shown in (1) to (6) above, the configuration (6) is preferred because it is a configuration including both an electron blocking layer and a hole blocking layer. That is, (6) which includes an electron blocking layer and a hole blocking layer enables reliable trapping of both carriers, that is, holes and electrons, in the light-emitting layer, and thus provides an organic light-emitting element that undergoes no carrier leakage and has high light-emission efficiency.

Here, the organic light-emitting element according to the present invention is characterized in that all freely rotatable single bonds in the first organic compound and the second organic compound constituting the light-emitting layer are carbon-carbon bonds, preferably bonds between sp2 carbons. This means being formed of a host material having high planarity. Therefore, the organic light-emitting element is superior in hole transport ability and electron transport ability to standard organic light-emitting elements. Hence, the electron blocking layer and the hole blocking layer play important roles. For example, the hole blocking layer needs to be stable to holes, and thus the hole blocking layer compound is preferably an organic compound with low reactivity, further preferably an organic compound composed only of hydrocarbons. For example, the electron blocking layer also needs to be stable to electrons, and thus the electron blocking layer compound is preferably an organic compound with low reactivity, further preferably an organic compound in which all freely rotatable single bonds are carbon-carbon bonds, preferably bonds between sp2 carbons.

The mode (element configuration) of extraction of light output from the light-emitting layer may be what is called a bottom-emission mode in which light is extracted from the substrate-side electrode or what is called a top-emission mode in which light is extracted from the side opposite the substrate. Alternatively, a double-side extraction mode in which light is extracted from the substrate side and the side opposite the substrate may also be employed.

### Other Compounds

The organic compound according to this embodiment can be used as a constituent material of an organic compound layer other than the light-emitting layer constituting the organic light-emitting element according to this embodiment. Specifically, the organic compound may be used as a constituent material of, for example, the electron transport layer, the electron injection layer, the hole transport layer, the hole injection layer, or the hole blocking layer. In this case, the emission color of the organic light-emitting element is not particularly limited. More specifically, the emission color may be white or an intermediate color.

In the organic light-emitting element according to this embodiment, known low-molecular-weight and high-molecular-weight hole injection compounds or hole transport compounds, compounds serving as hosts, luminescent compounds, electron injection compounds or electron transport compounds, and the like may be used in combination as required. Examples of these compounds will be described below.

As hole injection and transport materials, materials that facilitate injection of holes from the anode and that have so high hole mobility that enables injected holes to be transported to the light-emitting layer are preferred. To suppress deterioration of film quality, such as crystallization, in the organic light-emitting element, materials having high glass-transition temperatures are preferred. Examples of low-molecular-weight and high-molecular-weight materials capable of injecting and transporting holes include triarylamine derivatives, arylcarbazole derivatives, phenylenediamine derivatives, stilbene derivatives, phthalocyanine derivatives, porphyrin derivatives, poly(vinylcarbazole), poly(thiophene), and other conductive polymers. Furthermore, these hole injection and transport materials are also suitable for use in the electron blocking layer. Non-limiting specific examples of compounds usable as hole injection and transport materials are shown below.

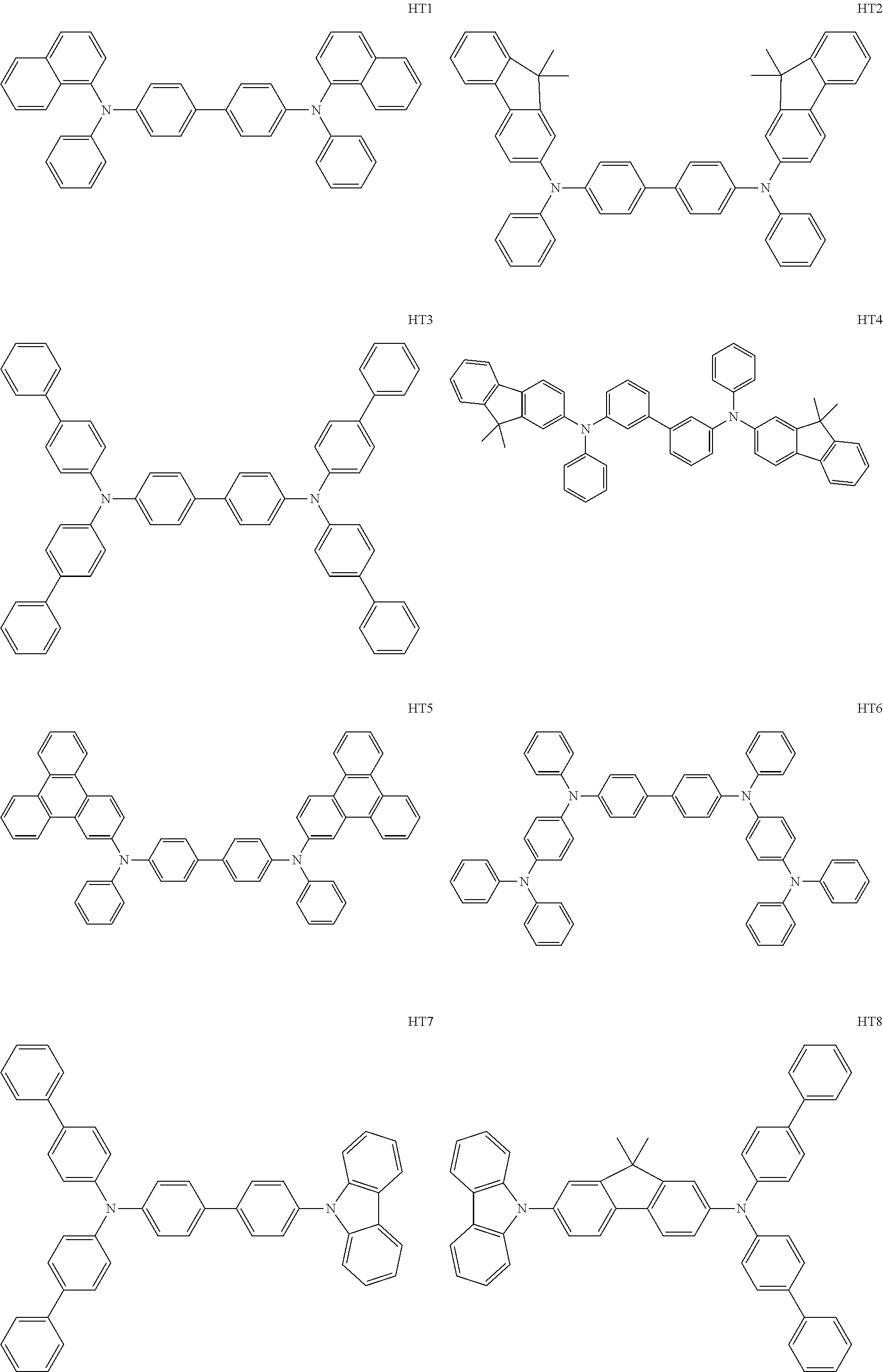

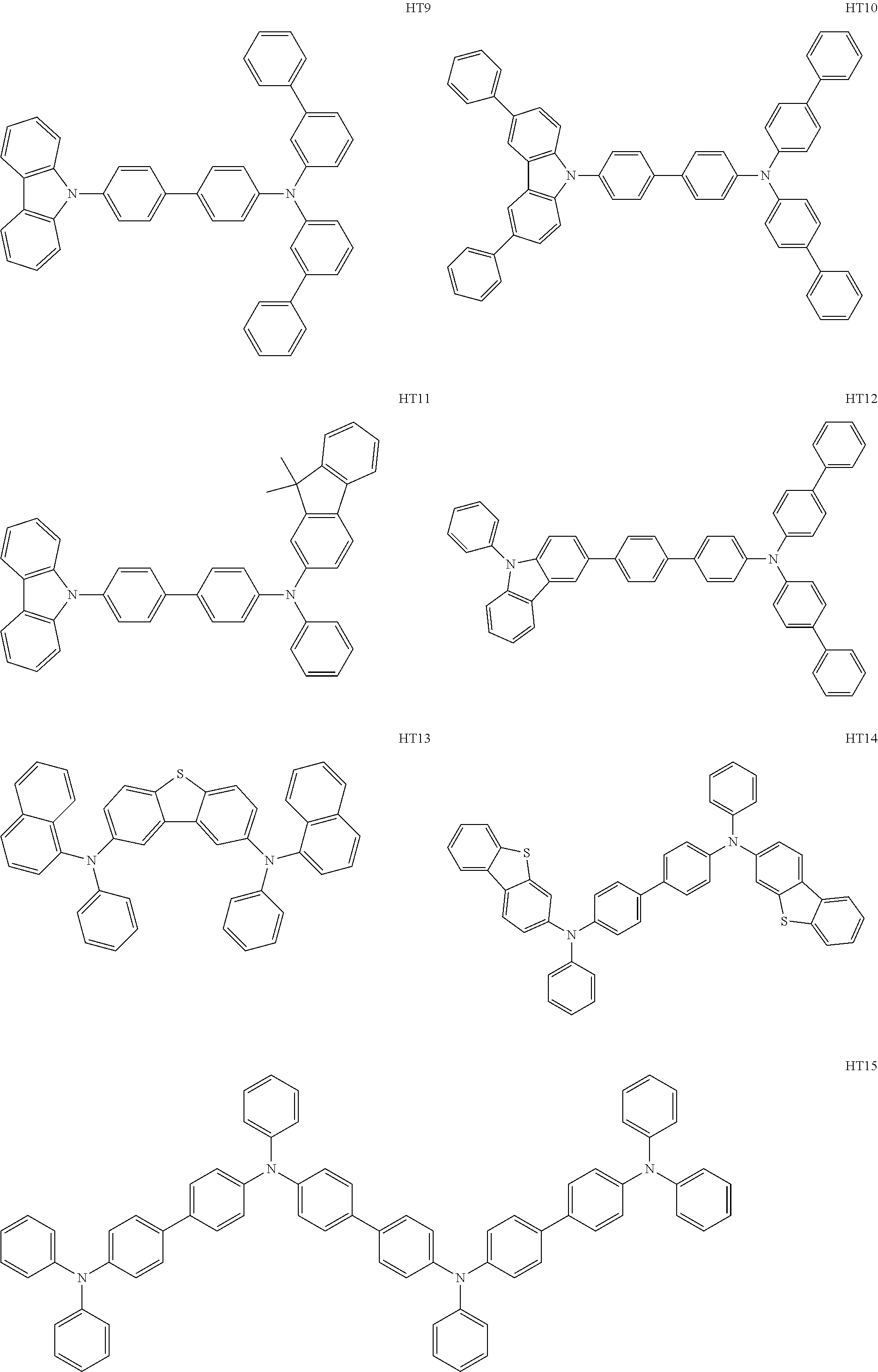

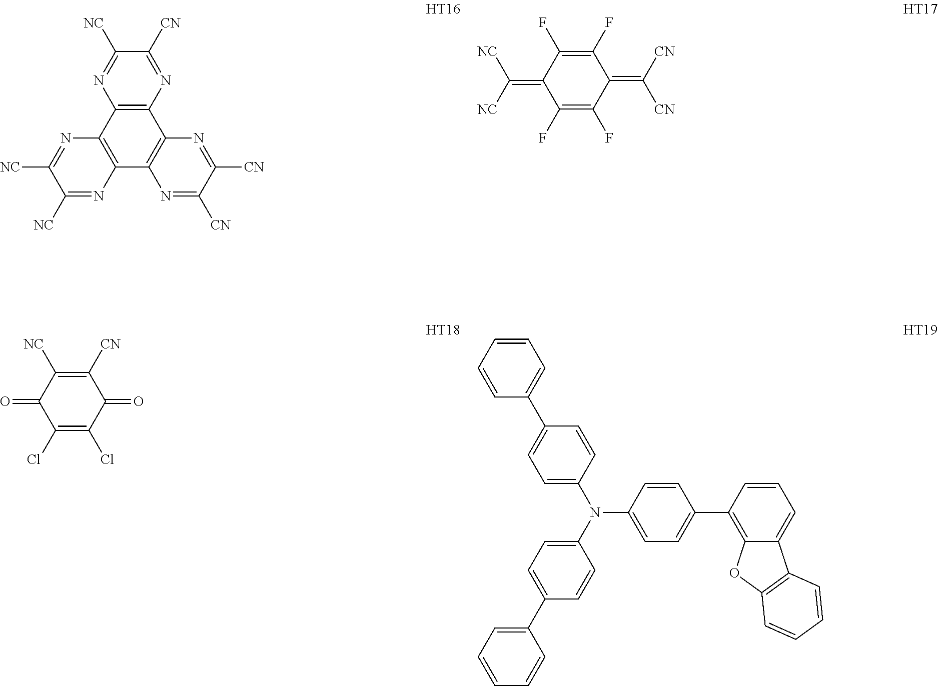 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F ; N#CC1=C(C#N)C(=O)C(Cl)=C(Cl)C1=O ; c1ccc(-c2ccc(N(c3ccc(-c4ccccc4)cc3)c3ccc(-c4cccc5c4oc4ccccc45)cc3)cc2)cc1]

Examples of light-emitting materials mainly involved in the light-emitting function include, in addition to the organometallic complex involved with the light-emitting layer compound in the present invention, fused-ring compounds (e.g., fluorene derivatives, naphthalene derivatives, pyrene derivatives, perylene derivatives, tetracene derivatives, anthracene derivatives, and rubrene), quinacridone derivatives, coumarin derivatives, stilbene derivatives, organic aluminum complexes such as tris(8-quinolinolato)aluminum, iridium complexes, platinum complexes, rhenium complexes, copper complexes, europium complexes, ruthenium complexes, and polymer derivatives such as poly(phenylenevinylene) derivatives, poly(fluorene) derivatives, and poly(phenylene) derivatives. Non-limiting specific examples of compounds usable as light-emitting materials are shown below.

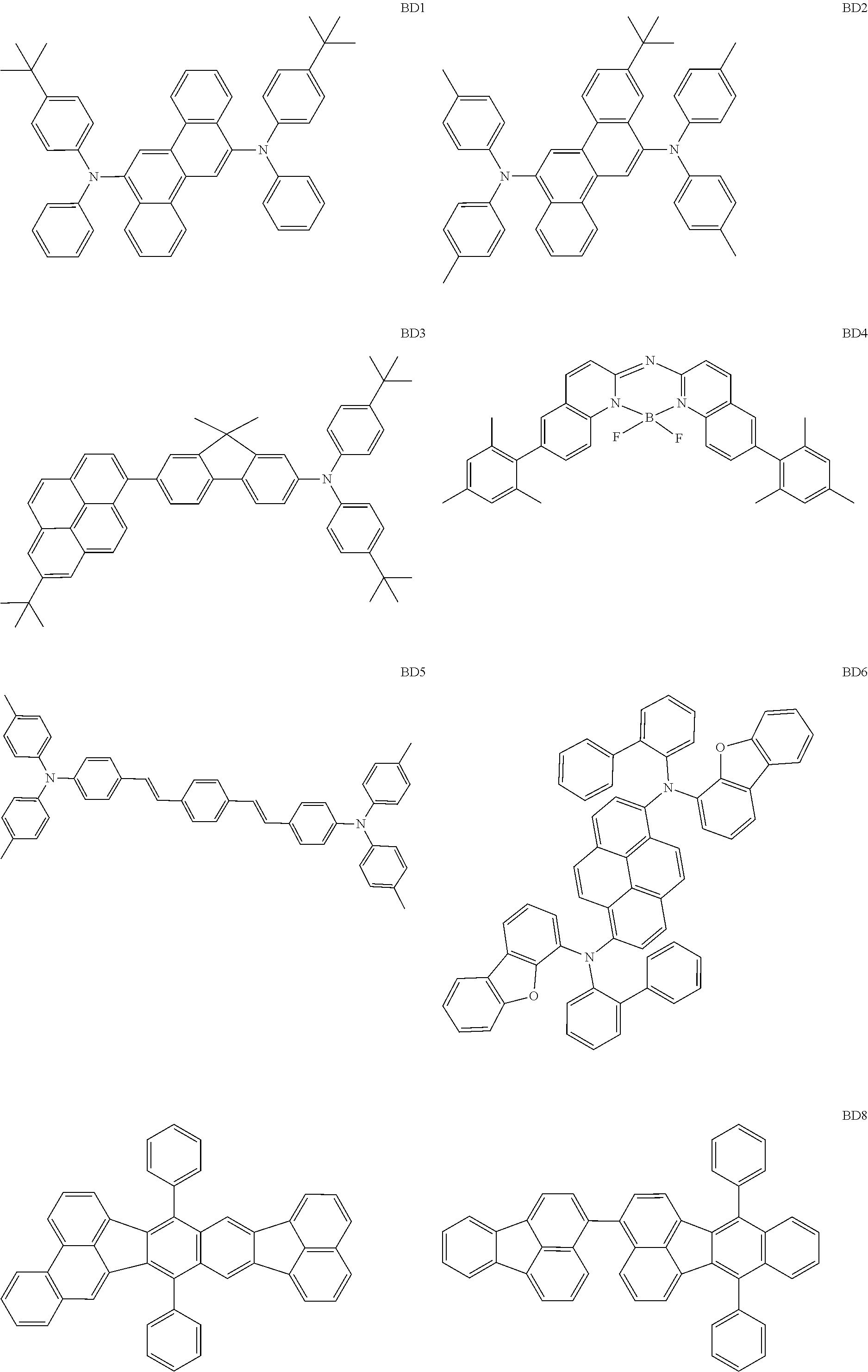

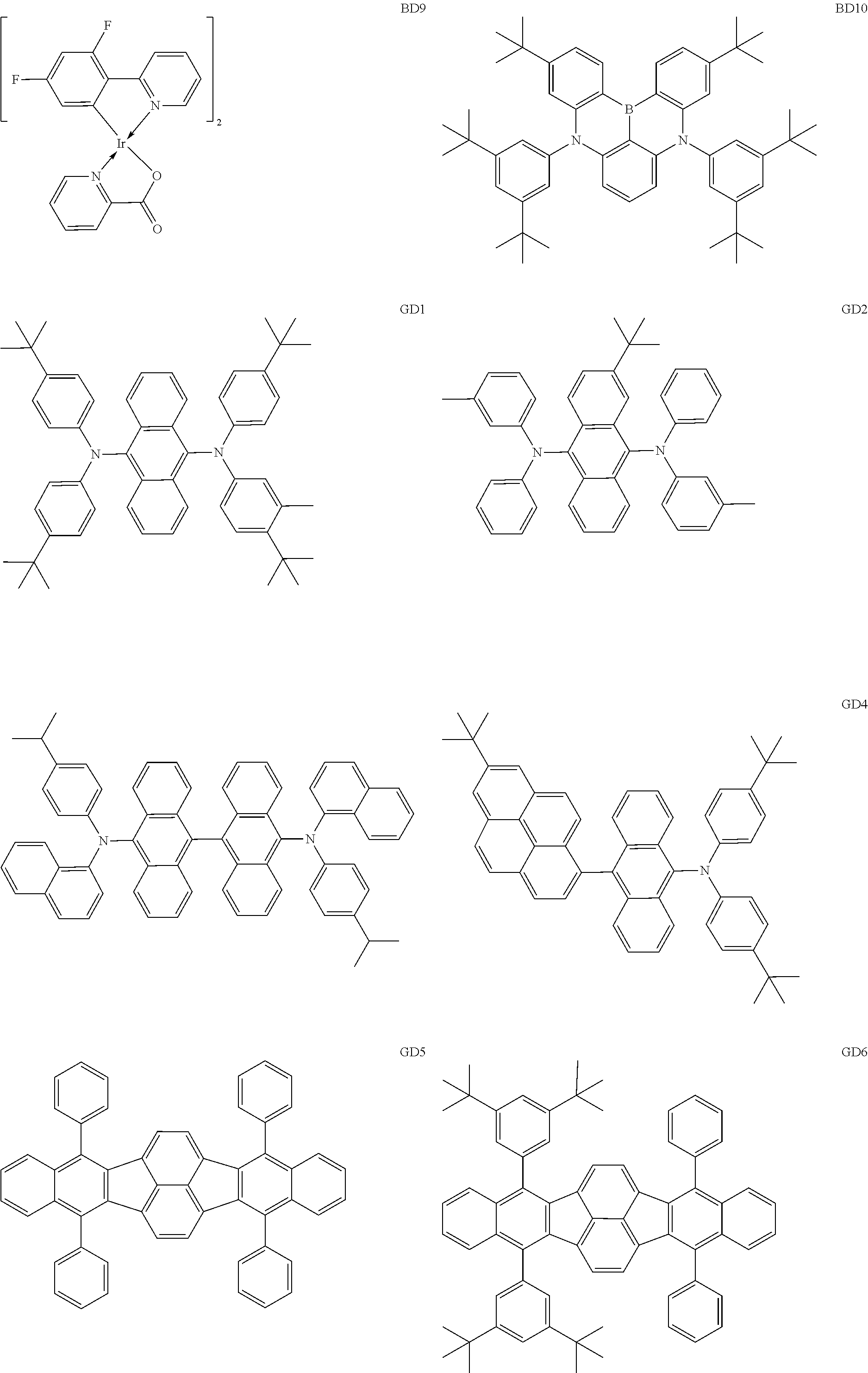

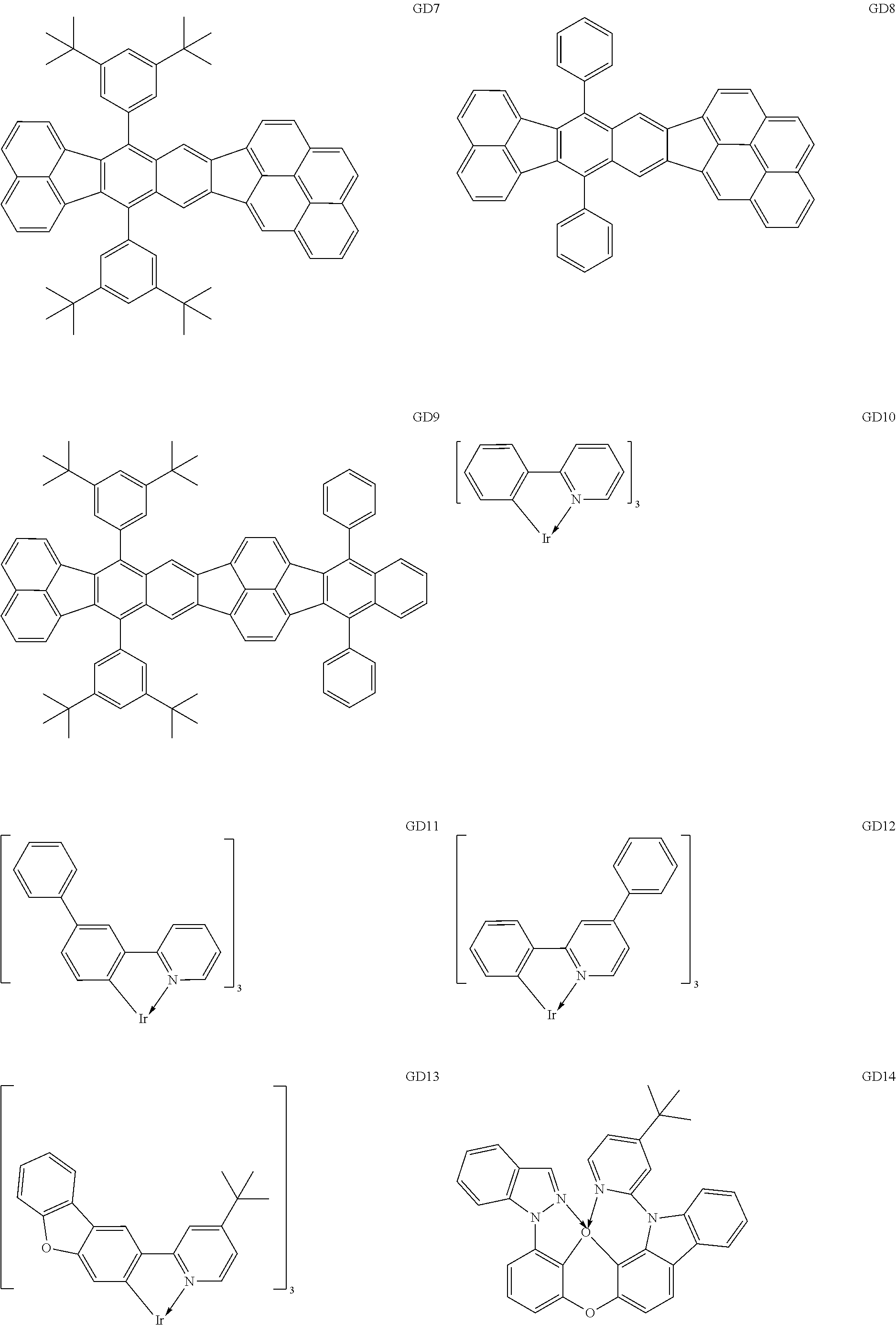

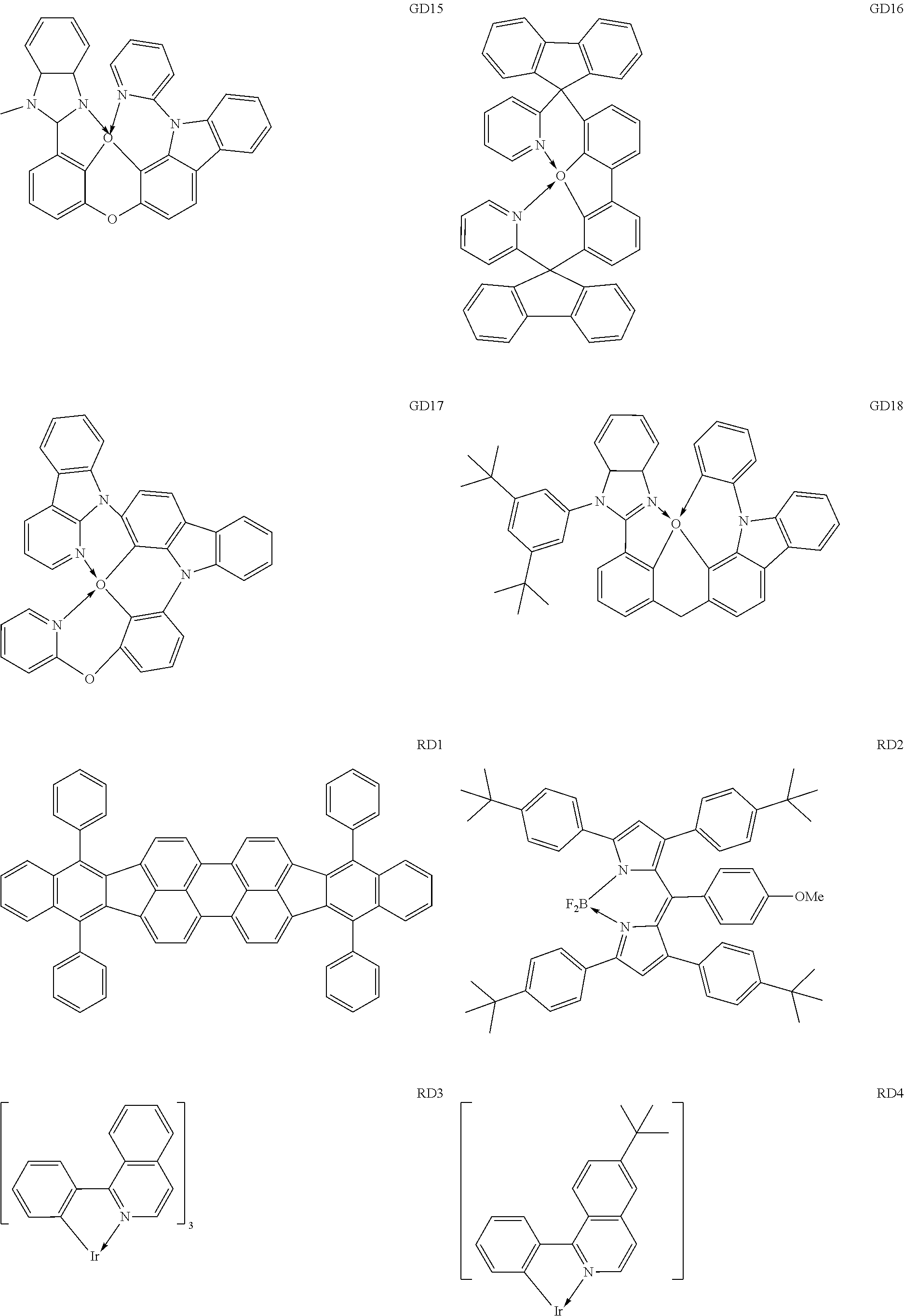

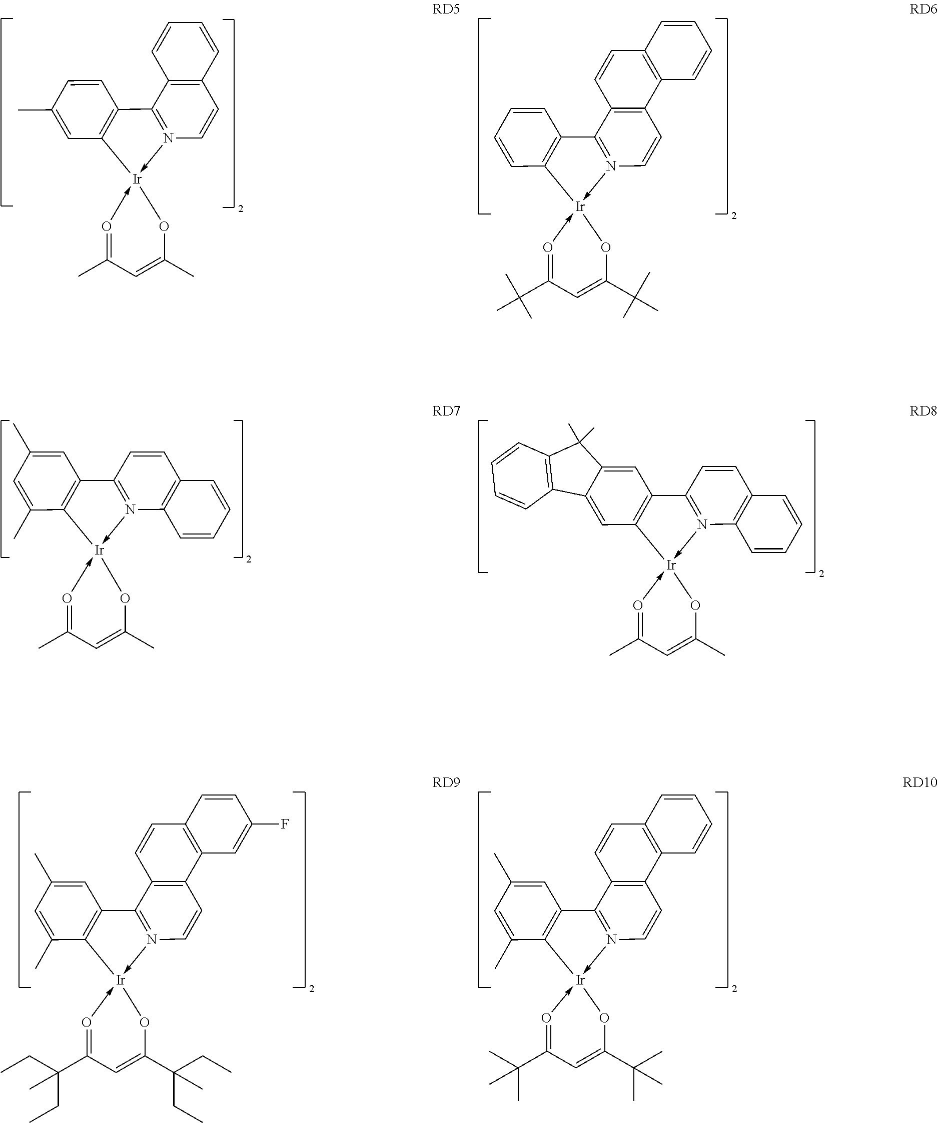

As a light-emitting layer host or a light-emission assist material contained in the light-emitting layer, a compound other than the organic compounds according to this embodiment may be contained as a third component. Examples of the third component include aromatic hydrocarbon compounds and derivatives thereof, carbazole derivatives, azine derivatives, xanthone derivatives, dibenzofuran derivatives, dibenzothiophene derivatives, organic aluminum complexes such as tris(8-quinolinolato)aluminum, and organic beryllium complexes.

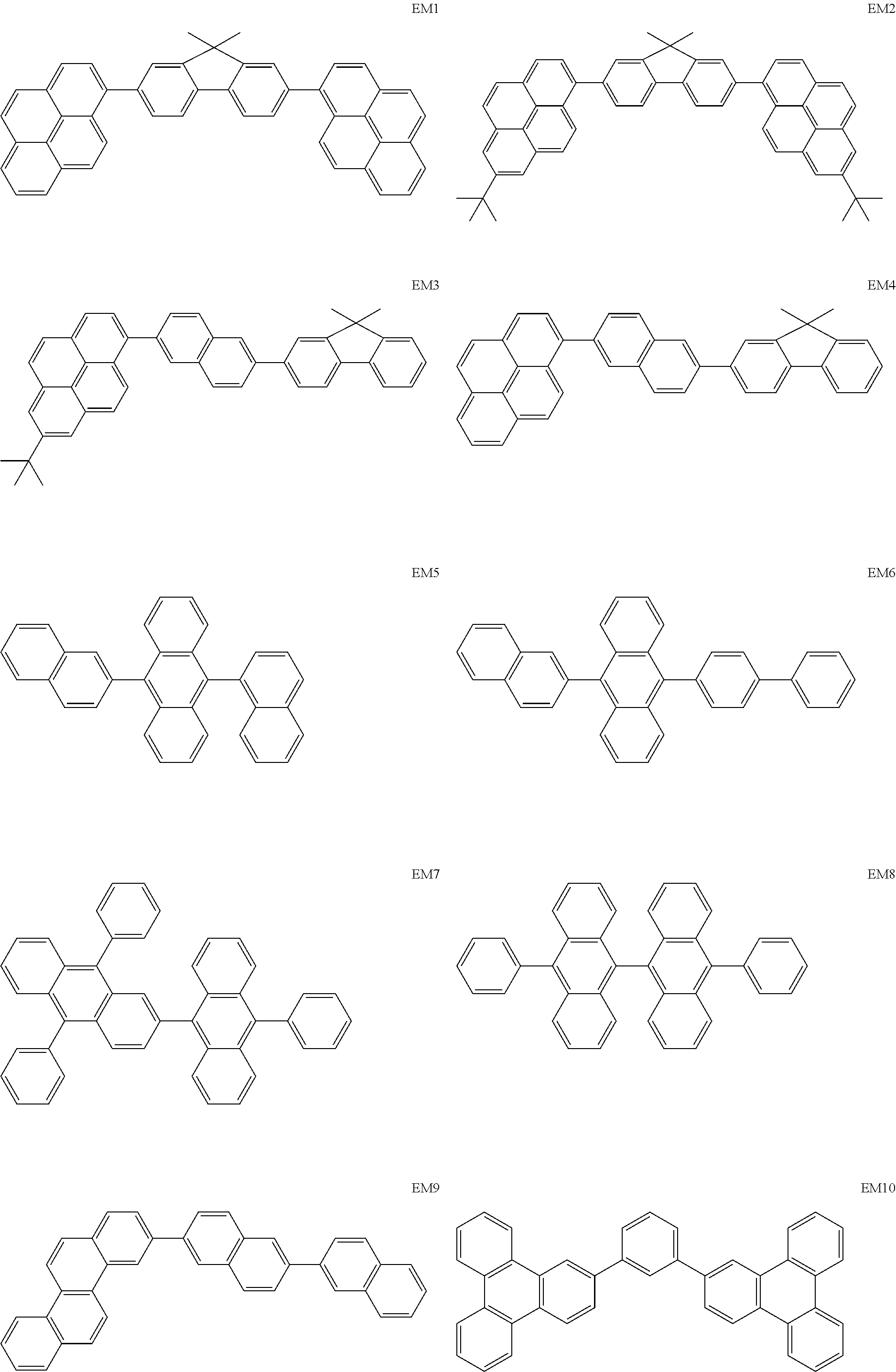

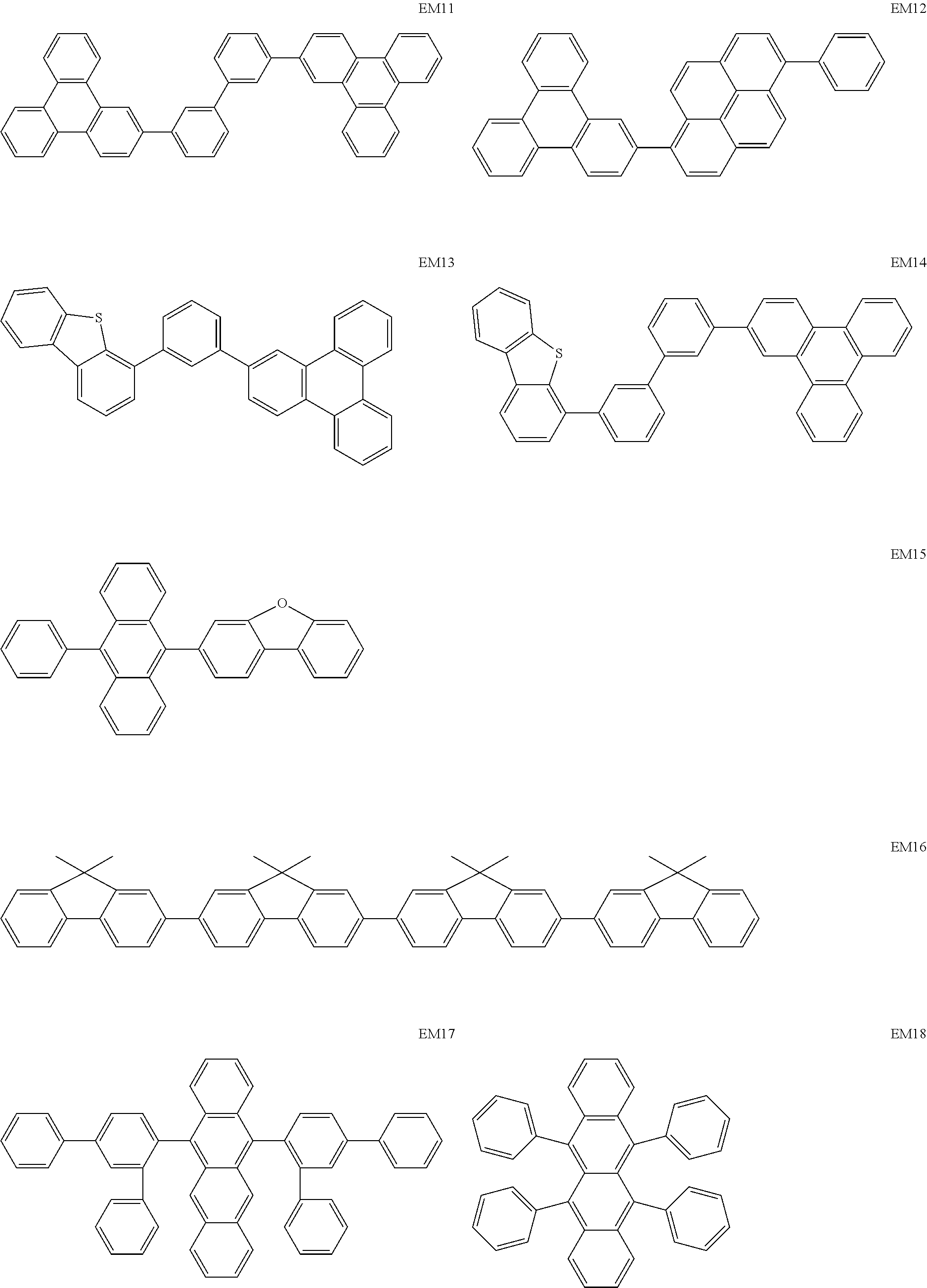

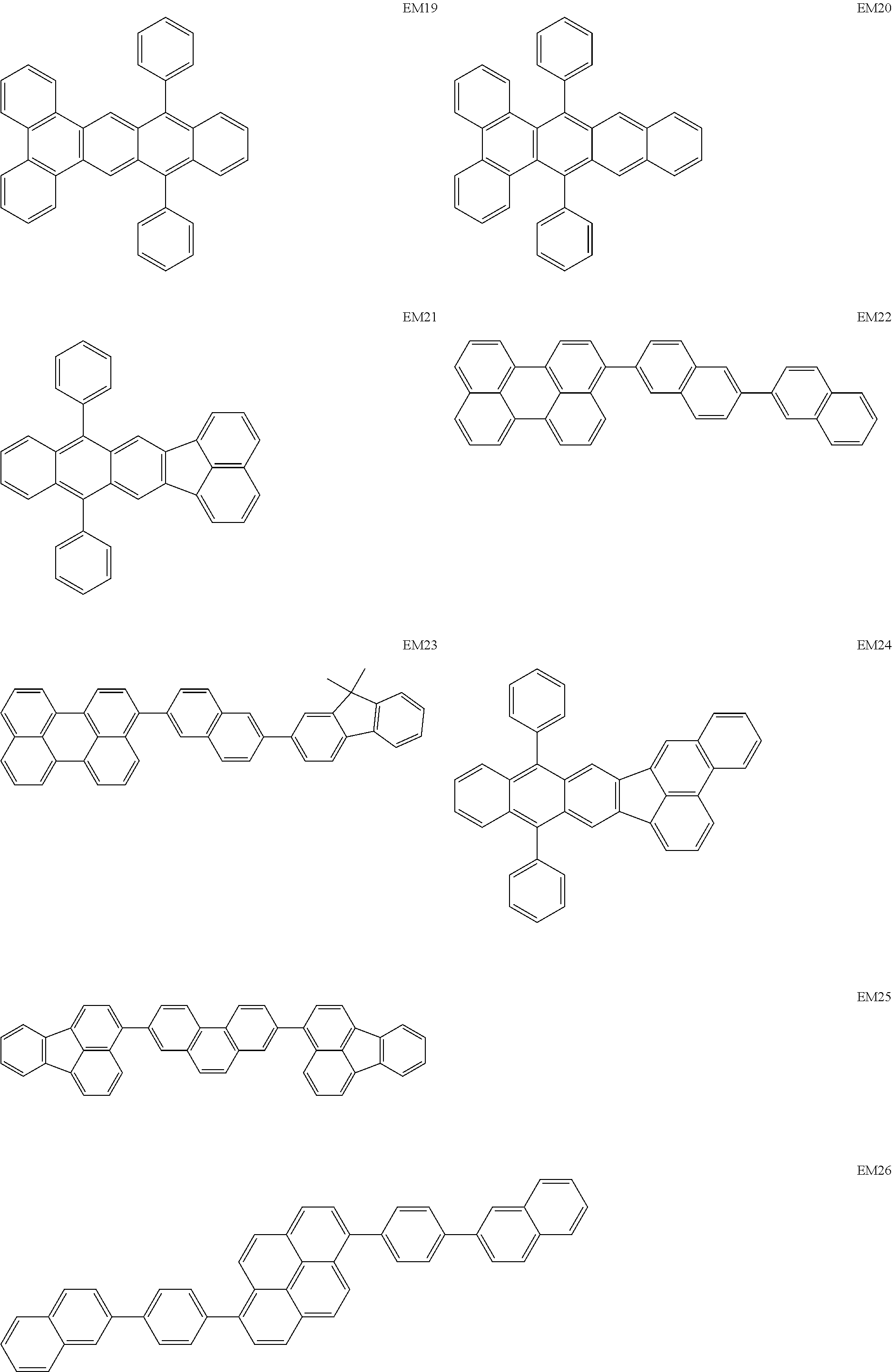

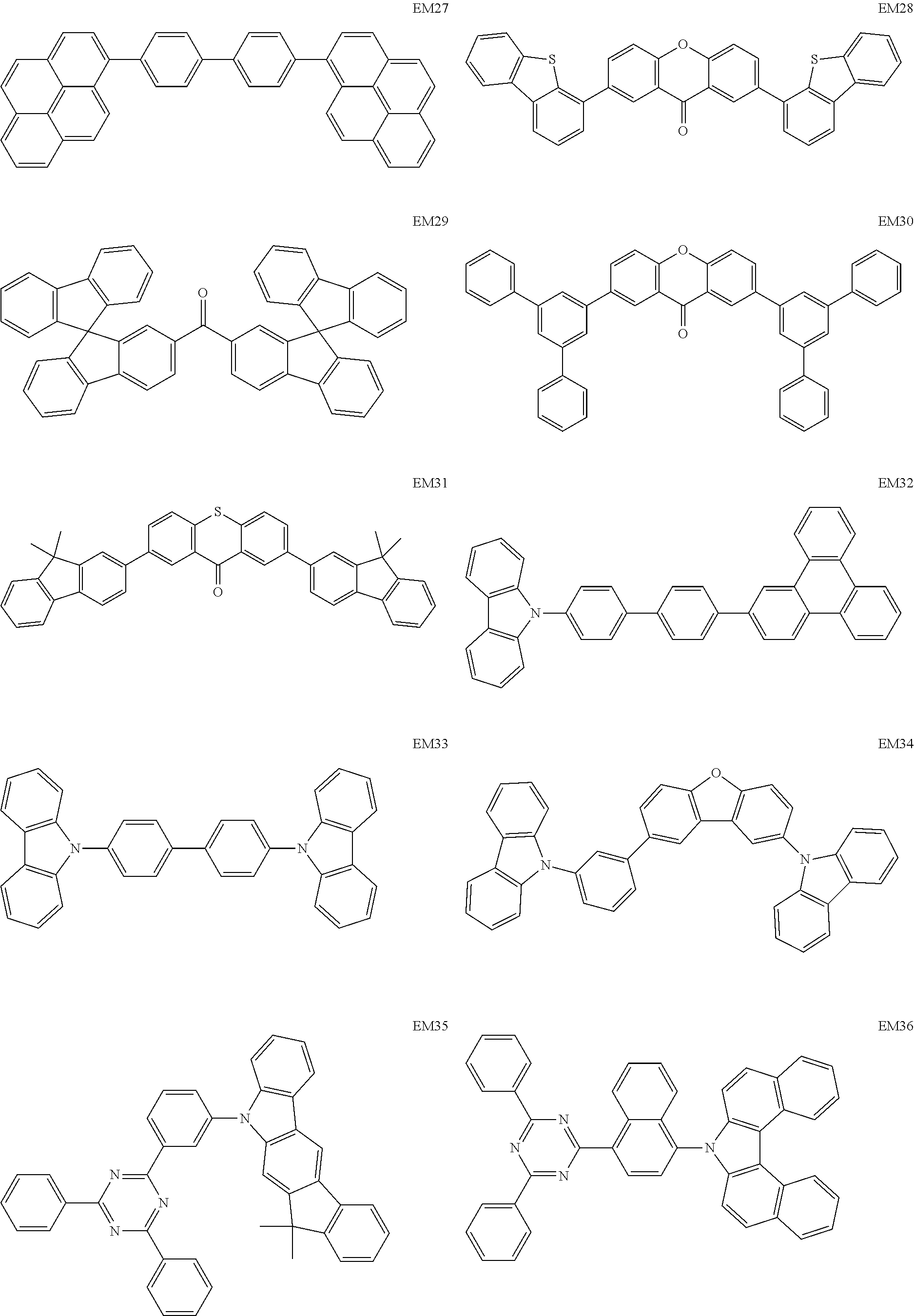

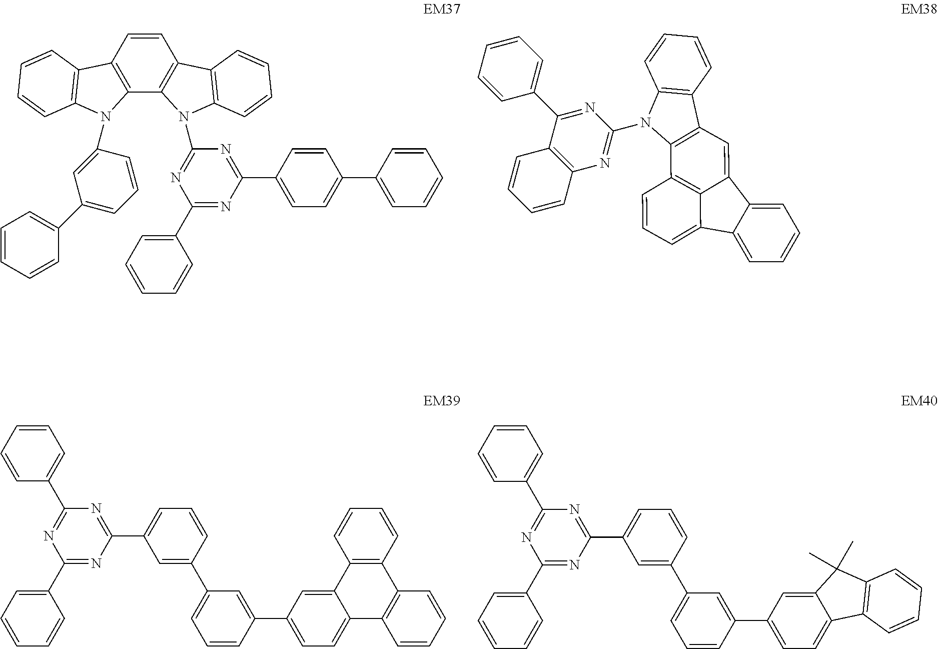

Any electron transport material capable of transporting electrons injected from the cathode to the light-emitting layer can be freely selected in consideration of, for example, the balance with the hole mobility of a hole transport material. Examples of materials capable of transporting electrons include oxadiazole derivatives, oxazole derivatives, pyrazine derivatives, triazole derivatives, triazine derivatives, quinoline derivatives, quinoxaline derivatives, phenanthroline derivatives, organic aluminum complexes, and fused-ring compounds (e.g., fluorene derivatives, naphthalene derivatives, chrysene derivatives, and anthracene derivatives). These electron transport materials are also suitable for use for the hole blocking layer. Non-limiting specific examples of compounds usable as electron transport materials are shown below.

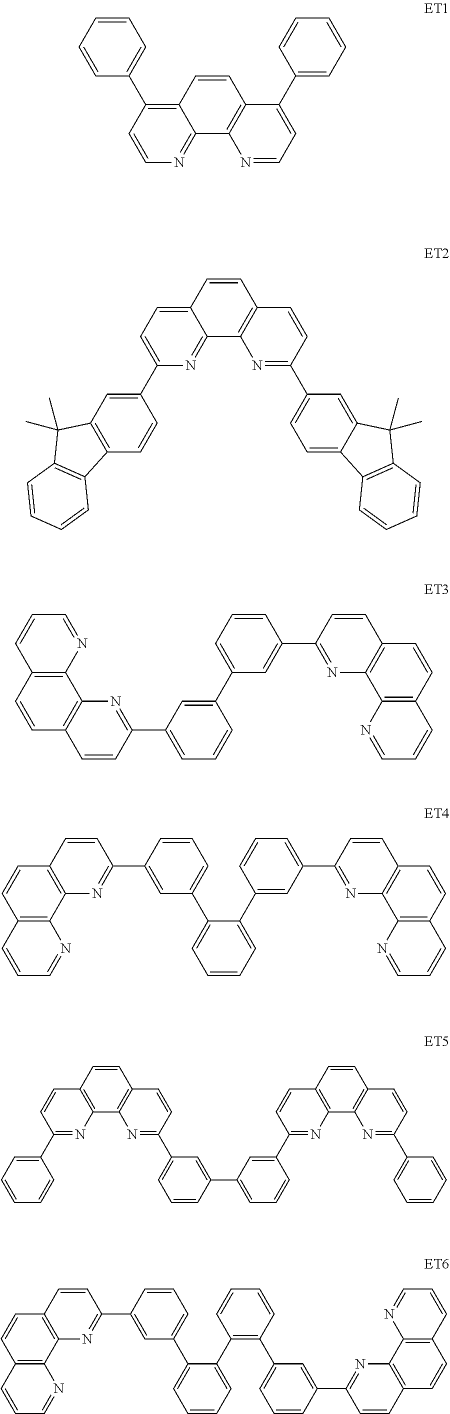

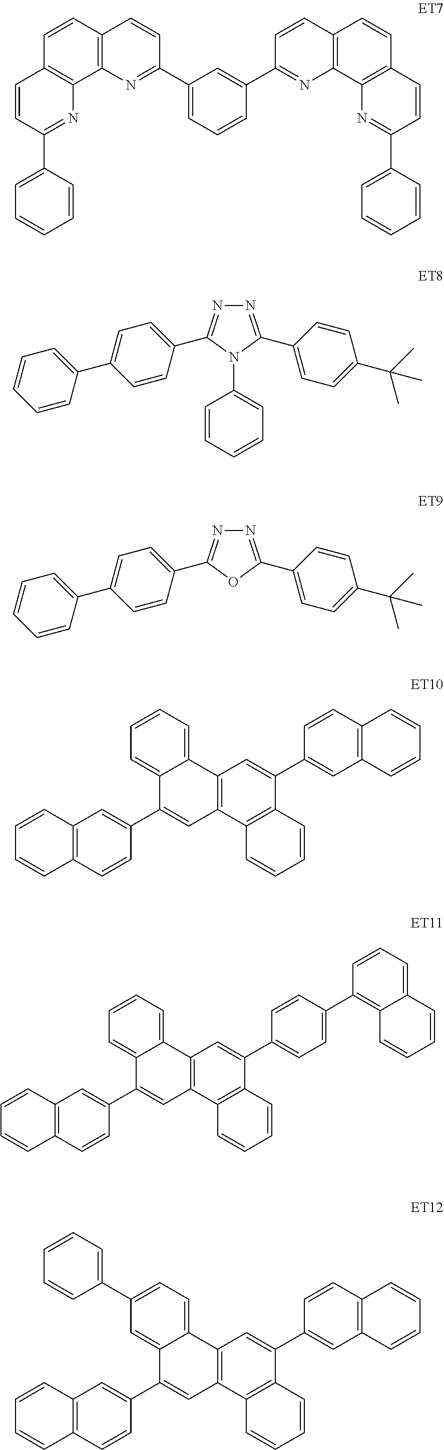

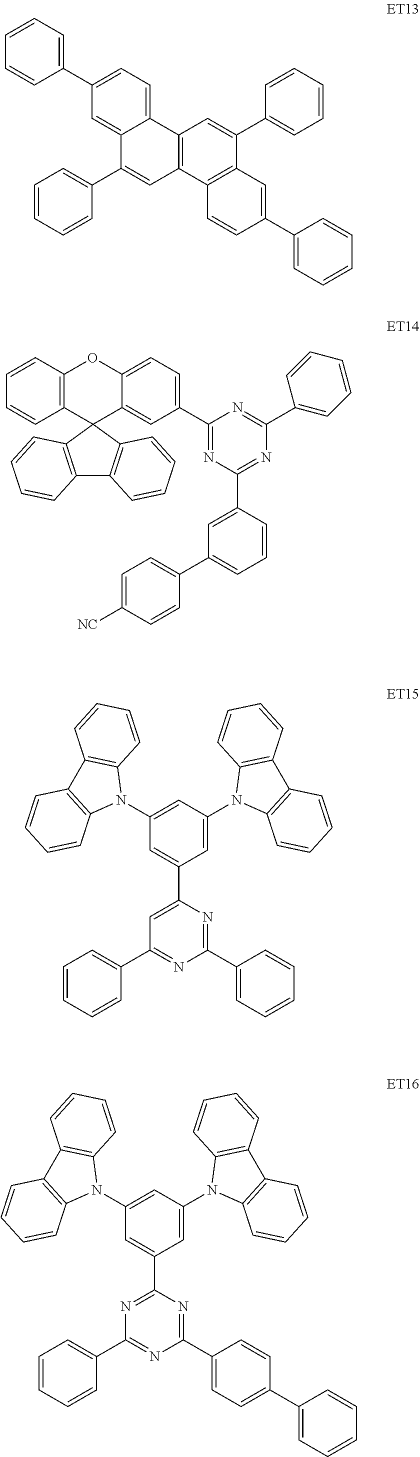

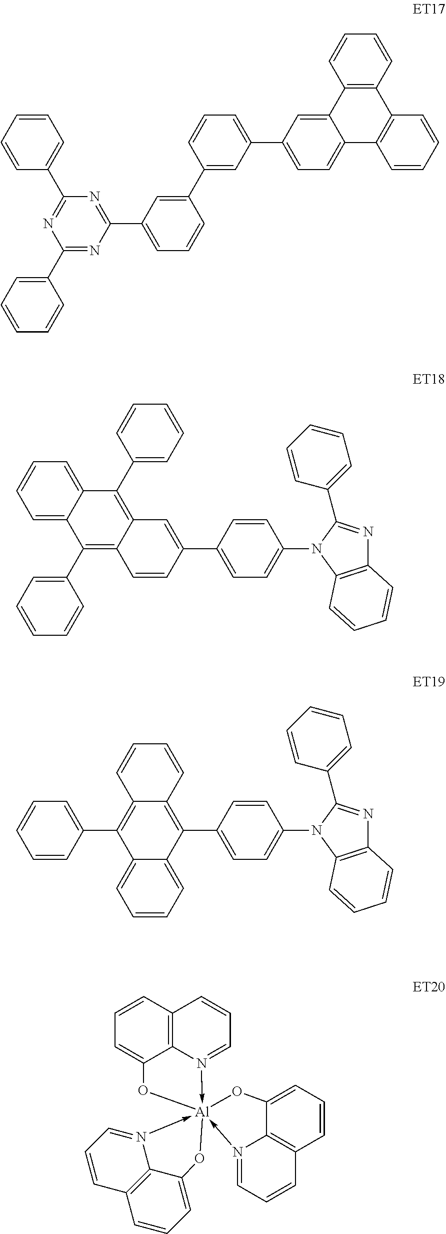

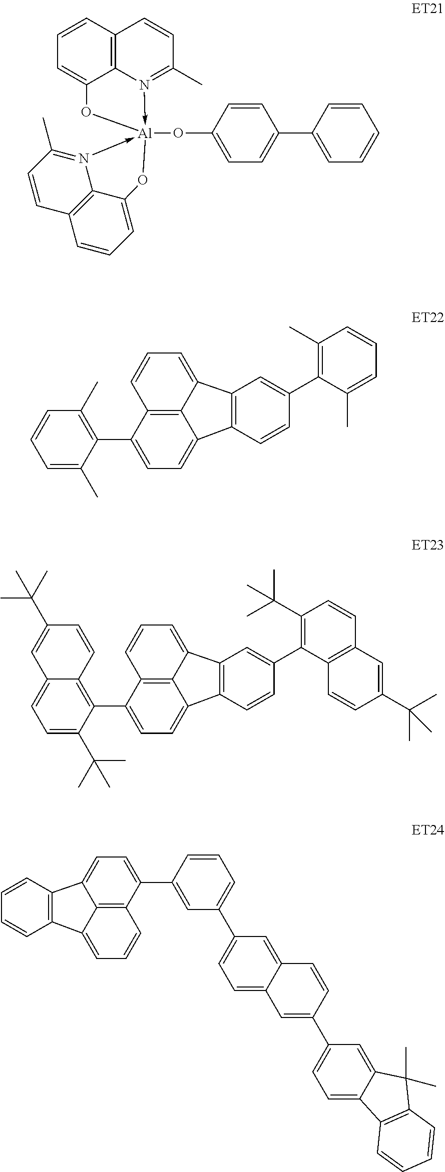

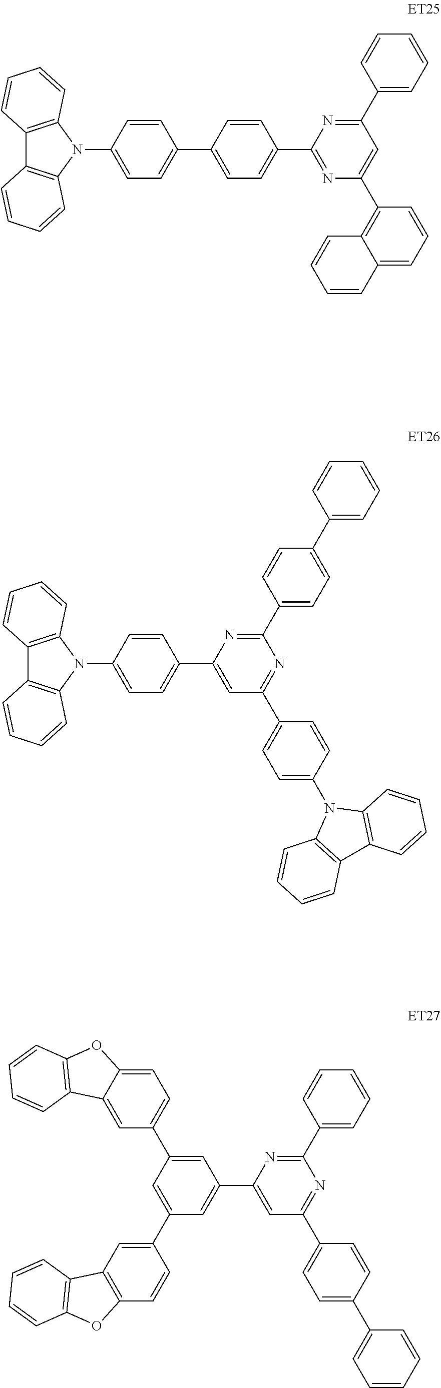 [SMILES: c1ccc(-c2cc(-c3cccc4ccccc34)nc(-c3ccc(-c4ccc(-n5c6ccccc6c6ccccc65)cc4)cc3)n2)cc1 ; c1ccc(-c2ccc(-c3nc(-c4ccc(-n5c6ccccc6c6ccccc65)cc4)cc(-c4ccc(-n5c6ccccc6c6ccccc65)cc4)n3)cc2)cc1 ; c1ccc(-c2ccc(-c3cc(-c4cc(-c5ccc6oc7ccccc7c6c5)cc(-c5ccc6oc7ccccc7c6c5)c4)nc(-c4ccccc4)n3)cc2)cc1]

Any electron injection material capable of readily injecting electrons from the cathode can be freely selected in consideration of, for example, the balance with hole injectability. An n-type dopant and a reducing dopant are also contained as an organic compound. Examples include alkali metal-containing compounds such as lithium fluoride, lithium complexes such as lithium quinolinol, benzimidazolidene derivatives, imidazolidene derivatives, fulvalene derivatives, and acridine derivatives. These can also be used in combination with the electron transport materials above.

### Configuration of Organic Light-Emitting Element

The organic light-emitting element is provided by forming an insulating layer, a first electrode, an organic compound layer, and a second electrode on a substrate. On the second electrode, a protective layer, a color filter, a microlens, etc. may be disposed. When the color filter is disposed, a planarization layer may be disposed between the color filter and the protective layer. The planarization layer may be formed of, for example, an acrylic resin. This also applies to the case where the planarization layer is disposed between the color filter and the microlens.

### Substrate

Examples of the substrate include quartz, glass, silicon wafers, resins, and metals. The substrate may have switching elements, such as transistors, and wiring lines disposed thereon, and may have an insulating layer disposed thereon. The insulating layer may be made of any material as long as a contact hole can be formed therein so as to allow formation of a wiring line connecting to the first electrode and insulation from unconnected wiring lines can be provided. For example, resins such as polyimide, silicon oxide, silicon nitride, and the like can be used.

### Electrode

The electrodes may be a pair of electrodes. The pair of electrodes may be an anode and a cathode. When an electric field is applied in a direction in which the organic light-emitting element emits light, one of the electrodes at a higher potential is the anode, and the other is the cathode. Stated another way, one of the electrodes that supplies holes to the light-emitting layer is the anode, and the other electrode that supplies electrons to the light-emitting layer is the cathode.

The constituent material of the anode preferably has as high a work function as possible. For example, elemental metals such as gold, platinum, silver, copper, nickel, palladium, cobalt, selenium, vanadium, and tungsten, mixtures containing these metals, alloys obtained by combining these metals, and metal oxides such as tin oxide, zinc oxide, indium oxide, indium tin oxide (ITO), and indium zinc oxide can be used. Conductive polymers such as polyaniline, polypyrrole, and polythiophene can also be used.

These electrode materials may be used alone or in combination of two or more. The anode may be composed of a single layer or a plurality of layers.

When the anode is used as a reflection electrode, for example, chromium, aluminum, silver, titanium, tungsten, molybdenum, an alloy thereof, or a stack thereof can be used. These materials can also be used to function as a reflective film that does not have a role of an electrode. When the anode is used as a transparent electrode, it may be, for example, but not necessarily, a transparent conductive layer made of an oxide such as indium tin oxide (ITO) or indium zinc oxide. The electrode can be formed by photolithography.

The constituent material of the cathode preferably has a low work function. Examples of such materials include alkali metals such as lithium; alkaline earth metals such as calcium; elemental metals such as aluminum, titanium, manganese, silver, lead, and chromium; and mixtures thereof. Alloys obtained by combining these elemental metals can also be used. For example, magnesium-silver, aluminum-lithium, aluminum-magnesium, silver-copper, and zinc-silver alloys can be used. Metal oxides such as indium tin oxide (ITO) can also be used. These electrode materials may be used alone or in combination of two or more. The cathode may be composed of a single layer or a plurality of layers. In particular, silver is preferably used, and a silver alloy is more preferred to reduce aggregation of silver. As long as aggregation of silver can be reduced, the content ratio in the alloy is not limited. For example, the ratio of silver to other metals may be, for example, 1:1 or 3:1.

The cathode is not particularly limited; a conductive layer formed of an oxide such as ITO may be used to provide a top-emission element, or a reflection electrode formed of aluminum (Al) or the like may be used to provide a bottom-emission element. The method of forming the cathode is not particularly limited, and the use of DC sputtering or AC sputtering is more preferred because good film coverage can be achieved and the resistance tends to decrease.

### Organic Compound Layer

The organic compound layer may be formed of a single layer or a plurality of layers. When the organic compound layer includes a plurality of layers, the layers may be referred to as a hole injection layer, a hole transport layer, an electron blocking layer, a light-emitting layer, a hole blocking layer, an electron transport layer, and an electron injection layer depending on their functions. The organic compound layer is composed mainly of an organic compound and may contain an inorganic atom and an inorganic compound. For example, the organic compound layer may contain copper, lithium, magnesium, aluminum, iridium, platinum, molybdenum, zinc, or the like. The organic compound layer may be disposed between the first electrode and the second electrode and may be disposed in contact with the first electrode and the second electrode.

The organic compound layers (e.g., a hole injection layer, a hole transport layer, an electron blocking layer, a light-emitting layer, a hole blocking layer, an electron transport layer, and an electron injection layer) constituting the organic light-emitting element according to an embodiment of the present invention are formed by the following methods.

The organic compound layers constituting the organic light-emitting element according to an embodiment of the present invention can be formed using a dry process such as vacuum deposition, ionized deposition, sputtering, or plasma. Instead of the dry process, a wet process involving dissolving a material in an appropriate solvent and forming a layer by a known coating method (e.g., spin coating, dipping, a casting method, an LB method, or an ink jet method) can also be used.

When the layers are formed by, for example, vacuum deposition or solution coating, the layers are unlikely to undergo crystallization or the like and are highly stable over time. When a coating method is used for film formation, an appropriate binder resin can be used in combination to form a film.

Examples of the binder resin include polyvinylcarbazole resins, polycarbonate resins, polyester resins, ABS resins, acrylic resins, polyimide resins, phenol resins, epoxy resins, silicone resins, and urea resins, but are not limited thereto.

These binder resins may be used alone as a homopolymer or copolymer or may be used as a mixture of two or more. In addition, known additives such as plasticizers, antioxidants, and UV absorbers may be used in combination as required.

### Protective Layer

A protective layer may be disposed on the second electrode. For example, a glass member provided with a moisture absorbent can be bonded onto the second electrode to reduce the entry of, for example, water into the organic compound layer, thereby reducing the occurrence of display failure. In another embodiment, a passivation film made of silicon nitride or the like may be disposed on the second electrode to reduce the entry of, for example, water into the organic compound layer. For example, the protective layer may be formed in a manner that after the formation of the second electrode, the resultant is conveyed to another chamber without breaking the vacuum, and a silicon nitride film having a thickness of 2 μm is formed by CVD. After the film formation by CVD, atomic layer deposition (ALD) may be performed to form a protective layer. The material of the film formed by ALD is not limited and may be, for example, silicon nitride, silicon oxide, or aluminum oxide. On the film formed by ALD, silicon nitride may further be formed by CVD. The film formed by ALD may have a smaller thickness than the film formed by CVD. Specifically, the thickness may be 50% or less, or even 10% or less.

### Color Filter

A color filter may be disposed on the protective layer. For example, a color filter may be formed on another substrate so as to correspond to the size of the organic light-emitting element and bonded to the substrate having the organic light-emitting element disposed thereon. Alternatively, a color filter may be patterned on the above-described protective layer by photolithography. The color filter may be made of a polymer.

### Planarization Layer

A planarization layer may be disposed between the color filter and the protective layer. The planarization layer is disposed for the purpose of reducing unevenness of the underlying layer. The planarization layer may be referred to as a material resin layer without limiting the purpose. The planarization layer may be formed of an organic compound. The organic compound may have a low molecular weight or a high molecular weight, and preferably has a high molecular weight.

The planarization layer may be disposed on opposite surfaces of the color filter, and the constituent materials thereof may be the same or different. Specific examples include polyvinylcarbazole resins, polycarbonate resins, polyester resins, ABS resins, acrylic resins, polyimide resins, phenol resins, epoxy resins, silicone resins, and urea resins.

### Microlens

The organic light-emitting element or an organic light-emitting apparatus may include, on its light-emitting side, an optical member such as a microlens. The microlens can be formed of, for example, an acrylic resin or an epoxy resin. The microlens may be used to increase the amount of light extracted from the organic light-emitting element or the organic light-emitting apparatus and to control the direction of the extracted light. The microlens may have a hemispherical shape. In the case of a hemispherical shape, among tangents to the hemisphere, there is a tangent parallel to the insulating layer, and the point of contact between this tangent and the hemisphere is the vertex of the microlens. The vertex of the microlens can be determined in the same manner in any sectional view. That is, among tangents to the semicircle of the microlens in a sectional view, there is a tangent parallel to the insulating layer, and the point of contact between this tangent and the semicircle is the vertex of the microlens.

The midpoint of the microlens can also be defined. In a section of the microlens, a line segment from one end point to the other end point of the arc is imagined, and the midpoint of the line segment can be referred to as the midpoint of the microlens. The section used to determine the vertex and the midpoint may be a section perpendicular to the insulating layer.

### Opposite Substrate

An opposite substrate may be disposed on the planarization layer. The opposite substrate is disposed at a position opposite to the above-described substrate and thus is referred to as the opposite substrate. The constituent material of the opposite substrate may be the same as that of the above-described substrate. When the above-described substrate is a first substrate, the opposite substrate may be a second substrate.

### Pixel Circuit

The organic light-emitting apparatus including the organic light-emitting element may include a pixel circuit connected to the organic light-emitting element. The pixel circuit may be an active matrix-type circuit which independently controls the light emission of a first light-emitting element and a second light-emitting element. The active matrix-type circuit may be voltage programmed or current programmed. A drive circuit includes the pixel circuit for each pixel. The pixel circuit may include a light-emitting element, a transistor that controls the emission luminance of the light-emitting element, a transistor that controls the timing of light emission, a capacitor that holds the gate voltage of the transistor that controls the emission luminance, and a transistor for providing a connection to GND not through the light-emitting element.

The light-emitting apparatus has a display region and a peripheral region disposed around the display region. The display region includes the pixel circuit, and the peripheral region includes a display control circuit. The mobility of the transistor constituting the pixel circuit may be lower than the mobility of a transistor constituting the display control circuit. The gradient of the current-voltage characteristics of the transistor constituting the pixel circuit may be smaller than the gradient of the current-voltage characteristics of the transistor constituting the display control circuit. The gradient of the current-voltage characteristics can be determined on the basis of, what is called, Vg-Ig characteristics. The transistor constituting the pixel circuit is a transistor connected to a light-emitting element such as the first light-emitting element.

### Pixel

The organic light-emitting apparatus including the organic light-emitting element may include a plurality of pixels. Each pixel includes subpixels that emit light of colors different from each other. The subpixels may respectively have, for example, R, G, and B emission colors.

In the pixel, a region also referred to as a pixel aperture emits light. This region is the same as the first region. The size of the pixel aperture may be 15 μm or less and 5 μm or more. More specifically, the size may be, for example, 11 μm, 9.5 μm, 7.4 μm, or 6.4 μm. The distance between the subpixels may be 10 μm or less, specifically 8 μm, 7.4 μm, or 6.4 μm.

The pixels may be in a known arrangement when viewed in plan. For example, the arrangement may be the stripe arrangement, the delta arrangement, the PenTile arrangement, or the Bayer arrangement. The shape of the subpixel in plan view may be any known shape. Examples include quadrangles, such as rectangles and rhombuses, and hexagons. It is appreciated that shapes that are not exactly rectangles but are similar to rectangles are also regarded as rectangles. The shape of the subpixel and the pixel array can be used in combination.

### Applications of Organic Light-Emitting Element

The organic light-emitting element according to this embodiment can be used as a constituent member of a display apparatus or a lighting apparatus. Other applications include an exposure light source in an electrophotographic image-forming apparatus, a backlight in a liquid crystal display, and a light-emitting apparatus including a white light source with a color filter.

The display apparatus may be an image information processor that includes an image input unit to which image information from an area CCD, a linear CCD, a memory card, or the like is input, includes an information-processing unit configured to process the input information, and displays the input image on a display unit. The display apparatus may include a plurality of pixels such that at least one of the plurality of pixels includes the organic light-emitting element according to this embodiment and a transistor connected to the organic light-emitting element.

The display unit of an image pickup apparatus or an ink-jet printer may have a touch panel function. The touch panel function may be activated by any system, such as an infrared system, an electrostatic capacitive system, a resistive film system, or an electromagnetic induction system. The display apparatus may also be used as a display unit of a multifunctional printer.

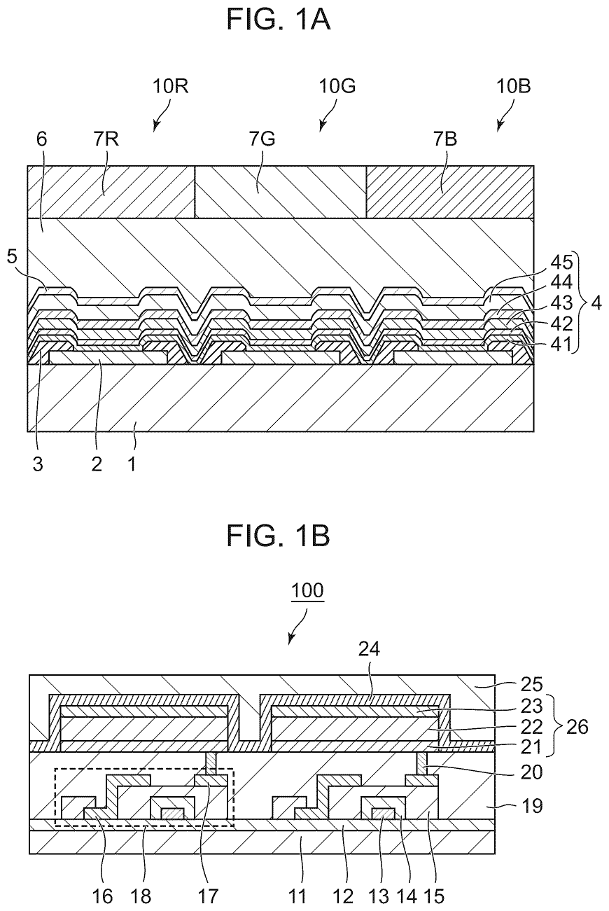

Next, the display apparatus according to this embodiment will be described with reference to the drawings. FIG. 1A and FIG. 1B are schematic sectional views each showing an example of a display apparatus including an organic light-emitting element and a transistor connected to the organic light-emitting element. The transistor is an example of an active element. The transistor may be a thin film transistor (TFT).

FIG. 1A is an example of a pixel that is a component of the display apparatus according to this embodiment. The pixel includes subpixels 10. The subpixels are divided into 10R, 10G, and 10B according to their light emission. The emission color may be distinguished on the basis of the wavelength of light emitted from a light-emitting layer, or light emitted from the subpixels may undergo selective transmission or color conversion through a color filter or the like. Each of the subpixels 10 includes, on an interlayer insulating layer 1, a reflective electrode that is a first electrode 2, an insulating layer 3 that covers the edge of the first electrode 2, an organic compound layer 4 that covers the first electrode 2 and the insulating layer 3, a transparent electrode that is a second electrode 5, a protective layer 6, and a color filter 7.

The interlayer insulating layer 1 may include a transistor and a capacitor element below or inside the interlayer insulating layer 1. The transistor and the first electrode 2 may be electrically connected to each other through a contact hole (not illustrated) or the like.

The insulating layer 3 is also referred to as a bank or a pixel-separating film. The insulating layer 3 is disposed so as to cover the edge of the first electrode 2 and surround the first electrode 2. A portion in which the insulating layer 3 is not disposed is in contact with the organic compound layer 4 and serves as a light-emitting region.

The organic compound layer 4 includes a hole injection layer 41, a hole transport layer 42, a first light-emitting layer 43, a second light-emitting layer 44, and an electron transport layer 45.

The second electrode 5 may be a transparent electrode, a reflective electrode, or a semitransparent electrode.

The protective layer 6 reduces permeation of water into the organic compound layer 4. Although the protective layer 6 is illustrated as a single layer, it may be constituted by a plurality of layers. The layers may be constituted by an inorganic compound layer and an organic compound layer.

The color filter 7 is divided into 7R, 7G, and 7B according to their color. The color filter 7 may be formed on a planarization film (not illustrated). A resin protective layer (not illustrated) may be disposed on the color filter 7. The color filter 7 may be formed on the protective layer 6. The color filter may be bonded after being formed on an opposite substrate such as a glass substrate.

A display apparatus 100 in FIG. 1B includes an organic light-emitting element 26 and a TFT 18, which is an example of a transistor. The display apparatus 100 includes a substrate 11 made of glass, silicon, or the like and an insulating layer 12 disposed thereon. An active element such as the TFT 18 is disposed on the insulating layer 12, and a gate electrode 13, a gate insulating film 14, and a semiconductor layer 15 of the active element are disposed. The TFT 18 further includes a drain electrode 16 and a source electrode 17. An insulating film 19 is disposed over the TFT 18. An anode 21 constituting the organic light-emitting element 26 and the source electrode 17 are connected to each other through a contact hole 20 extending through the insulating film 19.

The electrodes (the anode 21 and a cathode 23) included in the organic light-emitting element 26 and the electrodes (the source electrode 17 and the drain electrode 16) included in the TFT 18 need not necessarily be electrically connected to each other in the manner illustrated in FIG. 1B. It is only required that either the anode 21 or the cathode 23 be electrically connected to either the source electrode 17 or the drain electrode 16 of the TFT 18. TFT stands for a thin film transistor.

Although the organic compound layer 22 is illustrated as a single layer in the display apparatus 100 in FIG. 1B, the organic compound layer 22 may be constituted by a plurality of layers. A first protective layer 24 and a second protective layer 25 for reducing deterioration of the organic light-emitting element 26 are disposed over the cathode 23.

Although a transistor is used as a switching element in the display apparatus 100 in FIG. 1B, another switching element may be used instead.

The transistor used in the display apparatus 100 in FIG. 1B may be not only a transistor obtained using a single-crystal silicon wafer but also a thin film transistor including a substrate and an active layer on an insulating surface of the substrate. The active layer may be made of, for example, single-crystal silicon, non-single-crystal silicon such as amorphous silicon or microcrystalline silicon, or a non-single-crystal oxide semiconductor such as indium zinc oxide or indium gallium zinc oxide. The thin film transistor is also referred to as a TFT element.

The transistor included in the display apparatus 100 in FIG. 1B may be formed in a substrate such as a Si substrate. The phrase “formed in a substrate” means producing a transistor by processing a substrate itself, such as a Si substrate. That is, having a transistor in a substrate can also mean that the substrate and the transistor are integrally formed.

The emission luminance of the organic light-emitting element according to this embodiment is controlled by a TFT, which is an example of a switching element, and disposing a plurality of the organic light-emitting elements in a screen enables a display of an image with different emission luminances. The switching element according to this embodiment need not necessarily be a TFT and may be a transistor formed of low-temperature polysilicon or an active matrix driver formed on a substrate such as a Si substrate. The phrase “on a substrate” may also be referred to as “in a substrate”. Whether a transistor is provided in the substrate or a TFT is used is chosen depending on the size of the display unit. For example, when the display unit has a size of about 0.5 inches, the organic light-emitting element is preferably disposed on a Si substrate.

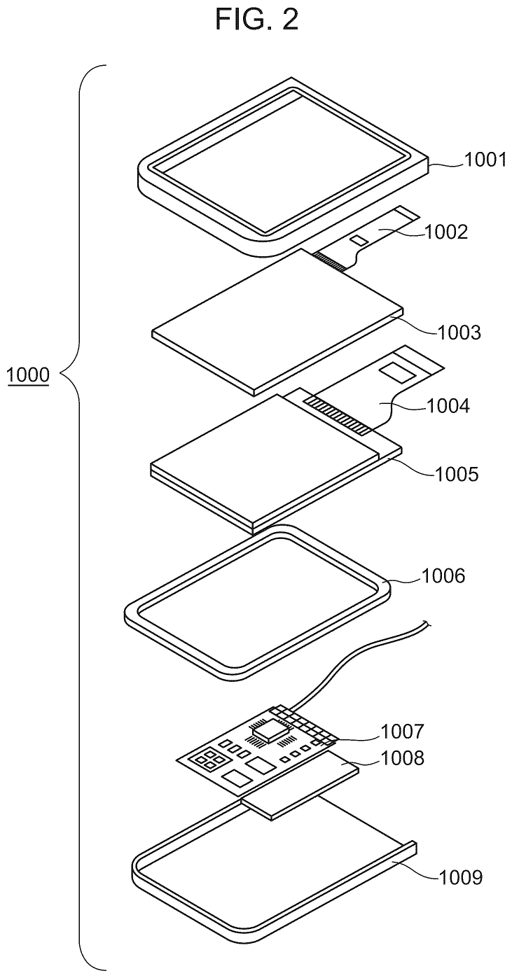

FIG. 2 is a schematic view showing an example of the display apparatus according to this embodiment. A display apparatus 1000 may include an upper cover 1001, a lower cover 1009, and a touch panel 1003, a display panel 1005, a frame 1006, a circuit board 1007, and a battery 1008 disposed between the covers. Flexible print circuits (FPCs) 1002 and 1004 are connected to the touch panel 1003 and the display panel 1005, respectively. A transistor is printed on the circuit board 1007. The battery 1008 may be omitted if the display apparatus is not a mobile device. If the display apparatus is a mobile device, the battery 1008 may be disposed in another position.

The display apparatus according to this embodiment may include red, green, and blue color filters. The red, green, and blue color filters may be disposed in the delta arrangement.

The display apparatus according to this embodiment may be used as a display unit of a mobile terminal. In this case, the display apparatus may have both a display function and an operating function. Examples of the mobile terminal include cellular phones such as smart phones, tablets, and head mount displays.

The display apparatus according to this embodiment may be used as a display unit of an image pickup apparatus that includes an optical unit including a plurality of lenses and an image pickup element configured to receive light that has passed through the optical unit. The image pickup apparatus may include a display unit configured to display information acquired by the image pickup element. The display unit may be exposed to the outside of the image pickup apparatus or disposed in a viewfinder. The image pickup apparatus may be a digital camera or a digital camcorder.

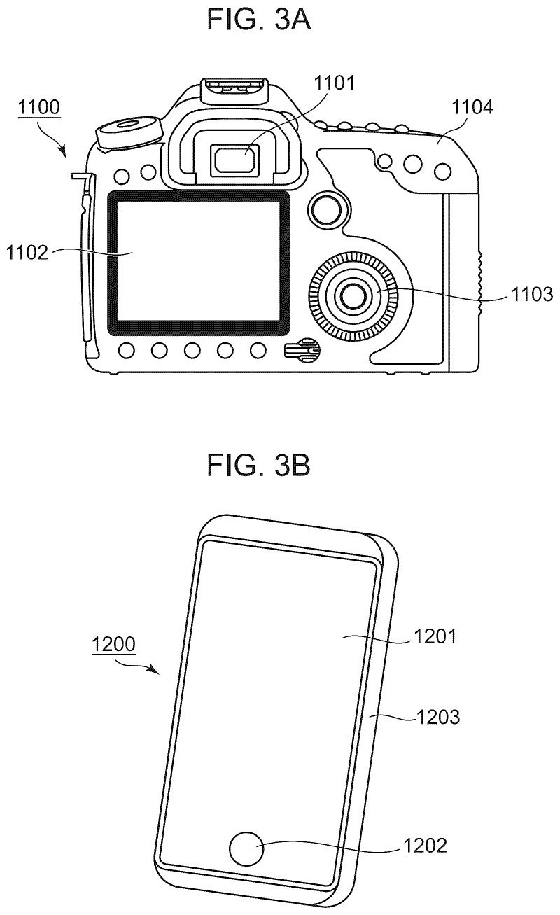

FIG. 3A is a schematic view showing an example of an image pickup apparatus according to this embodiment. An image pickup apparatus 1100 may include a viewfinder 1101, a rear display 1102, an operation unit 1103, and a housing 1104. The viewfinder 1101 may include the display apparatus according to this embodiment. In this case, the display apparatus may display not only an image to be captured but also environmental information, image capture instructions, etc. The environmental information may be, for example, the intensity of external light, the direction of external light, the moving speed of a subject, and the possibility that the subject is hidden by an object.

Since the timing appropriate for capturing an image is only a moment, the information is desirably displayed as quickly as possible. Thus, the display apparatus including the organic light-emitting element according to this embodiment is preferably used. This is because the organic light-emitting element has a high response speed. The display apparatus including the organic light-emitting element is more suitable for use in such an apparatus that requires speedy display than liquid crystal display apparatuses.

The image pickup apparatus 1100 includes an optical unit (not illustrated). The optical unit includes a plurality of lenses and focuses an image on the image pickup element accommodated in the housing 1104. By adjusting the relative positions of the plurality of lenses, the focal point can be adjusted. This operation can also be performed automatically. The image pickup apparatus may be referred to as a photoelectric conversion apparatus. Instead of sequential imaging, the photoelectric conversion apparatus may involve, as an imaging method, detection of a difference from the previous image, extraction from continuously recorded images, or the like.

FIG. 3B is a schematic view showing an example of an electronic apparatus according to this embodiment. An electronic apparatus 1200 includes a display unit 1201, an operation unit 1202, and a housing 1203. The housing 1203 may include a circuit, a printed board including the circuit, a battery, and a communication unit. The operation unit 1202 may be a button or a touch-sensitive response unit. The operation unit 1202 may be a biometric recognition unit that, for example, releases a lock upon recognition of fingerprints. An electronic apparatus including a communication unit can also be referred to as a communication apparatus. The electronic apparatus 1200 may further has a camera function by including lenses and an image pickup element. An image captured by the camera function is displayed on the display unit 1201. Examples of the electronic apparatus 1200 include smartphones and notebook computers.

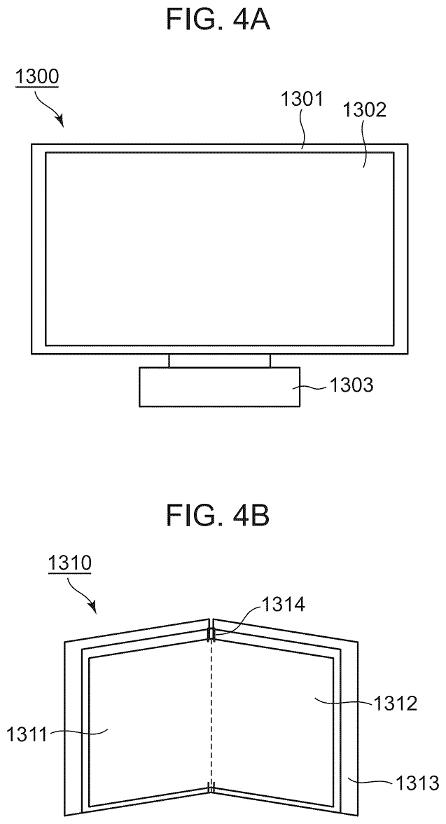

FIG. 4A and FIG. 4B show schematic views showing examples of the display apparatus according to this embodiment. FIG. 4A is a display apparatus such as a television monitor or a PC monitor. A display apparatus 1300 includes a frame 1301 and a display unit 1302. The light-emitting element according to this embodiment may be used in the display unit 1302. The display apparatus 1300 includes a base 1303 that supports the frame 1301 and the display unit 1302. The base 1303 need not necessarily be in the form illustrated in FIG. 4A. The lower side of the frame 1301 may serve as a base. The frame 1301 and the display unit 1302 may be curved. The radius of curvature may be 5000 mm or more and 6000 mm or less.

FIG. 4B is a schematic view showing another example of the display apparatus according to this embodiment. A display apparatus 1310 in FIG. 4B is configured to be folded and what is called a foldable display apparatus. The display apparatus 1310 includes a first display unit 1311, a second display unit 1312, a housing 1313, and a bending point 1314. The first display unit 1311 and the second display unit 1312 may include the light-emitting element according to this embodiment. The first display unit 1311 and the second display unit 1312 may be a seamless, monolithic display apparatus. The first display unit 1311 and the second display unit 1312 can be divided by the bending point. The first display unit 1311 and the second display unit 1312 may display different images, or the first and second display units may together display a single image.

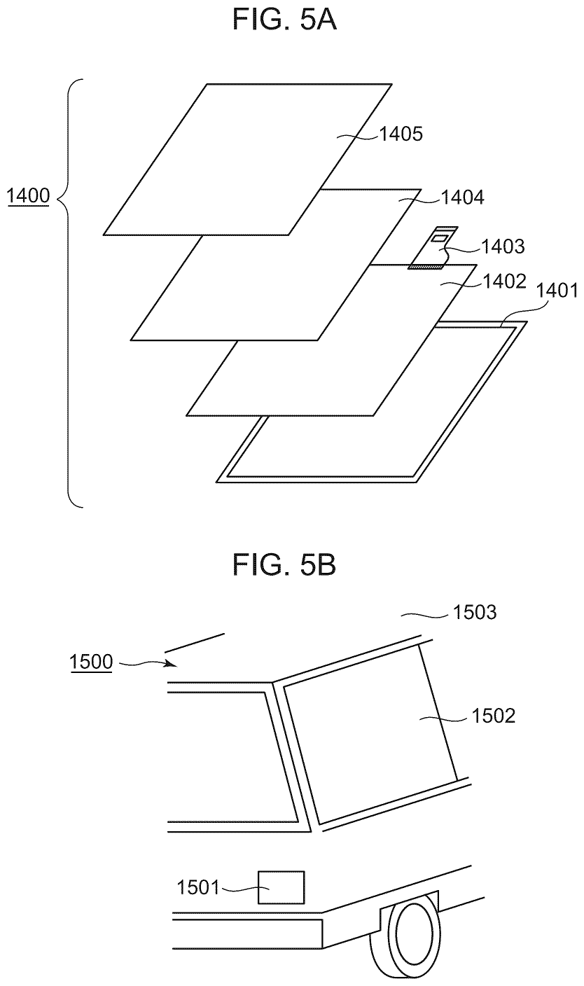

FIG. 5A is a schematic view showing an example of a lighting apparatus according to this embodiment. A lighting apparatus 1400 may include a housing 1401, a light source 1402, a circuit board 1403, an optical filter 1404 configured to transmit light emitted from the light source 1402, and a light diffusion unit 1405. The light source 1402 may include the organic light-emitting element according to this embodiment. The optical filter 1404 may be a filter for improving the color rendering properties of the light source. The light diffusion unit 1405 effectively diffuses light from the light source and enables the light to reach a wide region for, for example, lighting up. The optical filter 1404 and the light diffusion unit 1405 may be disposed on the light-emitting side of the lighting apparatus. If necessary, a cover may be disposed at an outermost portion.

The lighting apparatus is, for example, an indoor lighting apparatus. The lighting apparatus may emit light of white, daylight white, or any other color from blue to red. The lighting apparatus may include a modulation circuit configured to modulate the light. The lighting apparatus may include the organic light-emitting element according to this embodiment and a power supply circuit connected thereto. The power supply circuit is a circuit configured to convert AC voltage to DC voltage. White is a color with a color temperature of 4200 K, and daylight white is a color with a color temperature of 5000 K. The lighting apparatus may include a color filter.

The lighting apparatus according to this embodiment may also include a heat dissipation unit. The heat dissipation unit dissipates heat in the apparatus to the outside and is formed of, for example, a metal with high specific heat or liquid silicon.

FIG. 5B is a schematic view of an automobile that is an example of a moving object according to this embodiment. The automobile includes a tail lamp that is an example of a lighting fixture. An automobile 1500 includes a tail lamp 1501, and the tail lamp may be configured to be turned on in response to, for example, brake operation.

The tail lamp 1501 may include the organic light-emitting element according to this embodiment. The tail lamp 1501 may include a protective member that protects the organic light-emitting element. The protective member may be made of any material that has a certain degree of high strength and is transparent, but is preferably made of a polycarbonate or the like. The polycarbonate may be mixed with a furandicarboxylic acid derivative, an acrylonitrile derivative, or the like.

The automobile 1500 may include a car body 1503 and a window 1502 attached thereto. The window 1502 may be a transparent display unless it is a window for checking the front and rear of the automobile. The transparent display may include the organic light-emitting element according to this embodiment. In this case, components of the organic light-emitting element, such as electrodes, are constituted by transparent members.

The moving object according to this embodiment may be, for example, a ship, an aircraft, or a drone. The moving object may include a body and a lighting fixture disposed on the body. The lighting fixture may emit light for allowing the position of the body to be recognized. The lighting fixture includes the organic light-emitting element according to this embodiment.

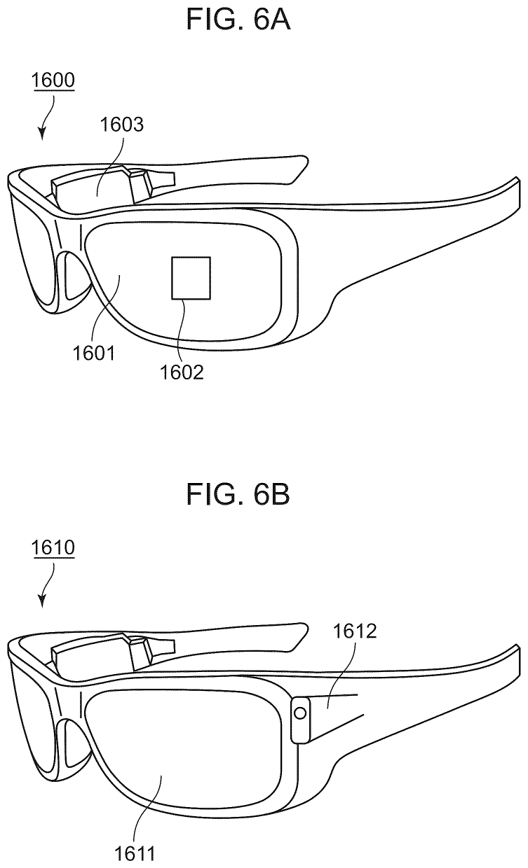

Application examples of the display apparatuses according to the above-described embodiments will be described with reference to FIG. 6A and FIG. 6B. The display apparatuses can be applied to systems that can be worn as wearable devices such as smart glasses, HMDs, and smart contact lenses. An image pickup and display apparatus used in such an application example includes an image pickup apparatus that can photoelectrically convert visible light and a display apparatus that can emit visible light.

FIG. 6A is a schematic view showing an example of a wearable device according to an embodiment of the present invention. Eyeglasses 1600 (smart glasses) according to one application example will be described with reference to FIG. 6A. An image pickup apparatus 1602, such as a CMOS sensor or a SPAD, is disposed on the front side of a lens 1601 of the eyeglasses 1600. The display apparatus according to any one of the above-described embodiments is provided on the rear side of the lens 1601.

The eyeglasses 1600 further include a controller 1603. The controller 1603 functions as a power source for supplying electricity to the image pickup apparatus 1602 and the display apparatus. The controller 1603 controls the operation of the image pickup apparatus 1602 and the display apparatus. The lens 1601 is provided with an optical system for focusing light on the image pickup apparatus 1602.

FIG. 6B is a schematic view showing another example of a wearable device according to an embodiment of the present invention. Eyeglasses 1610 (smart glasses) according to one application example will be described with reference to FIG. 6B. The eyeglasses 1610 include a controller 1612, and the controller 1612 is equipped with an image pickup apparatus corresponding to the image pickup apparatus 1602 in FIG. 6A and a display apparatus. A lens 1611 is provided with the image pickup apparatus in the controller 1612 and an optical system for projecting light emitted from the display apparatus, and an image is projected onto the lens 1611. The controller 1612 functions as a power source for supplying electricity to the image pickup apparatus and the display apparatus and also controls the operation of the image pickup apparatus and the display apparatus.

The controller 1612 may include a gaze detection unit configured to detect the gaze of a wearer. The gaze may be detected using infrared radiation. An infrared light emission unit emits infrared light to an eyeball of a user gazing at a displayed image. The reflection of the emitted infrared light from the eyeball is detected by an image pickup unit including a light-receiving element, whereby a captured image of the eyeball is obtained. Due to the presence of a reduction unit configured to reduce light from the infrared light emission unit to the display unit in plan view, degradation of image quality is reduced. The gaze of the user toward the displayed image is detected from the captured image of the eyeball obtained by infrared imaging. Any known method can be used for the gaze detection using the captured image of the eyeball. For example, a gaze detection method based on a Purkinje image formed by the reflection of irradiation light on a cornea can be used. More specifically, a gaze detection process based on a pupil-corneal reflection method is performed. Using the pupil-corneal reflection method, a gaze vector representing the direction (rotation angle) of the eyeball is calculated on the basis of a pupil image and a Purkinje image included in the captured image of the eyeball, whereby the gaze of the user is detected.

A display apparatus according to an embodiment of the present invention may include an image pickup apparatus including a light-receiving element and may control a displayed image on the display apparatus on the basis of the gaze information of the user from the image pickup apparatus. Specifically, the display apparatus determines, on the basis of the gaze information, a first viewing region at which the user gazes and a second viewing region other than the first viewing region. The first viewing region and the second viewing region may be determined by the controller of the display apparatus, or may be determined by an external controller and sent therefrom. In a display region of the display apparatus, the display resolution of the first viewing region may be controlled to be higher than the display resolution in the second viewing region. That is, the resolution in the second viewing region may be set to be lower than that in the first viewing region.

The display region includes a first display region and a second display region different from the first display region, and a region of high priority is determined from the first display region and the second display region on the basis of the gaze information. The first display region and the second display region may be determined by the controller of the display apparatus, or may be determined by an external controller and sent therefrom. The resolution in the region of high priority may be controlled to be higher than the resolution in the area other than the region of high priority. That is, the resolution in an area of relatively low priority may be set to be lower.

AI may be used to determine the first viewing region or the region of high priority. AI may be a model configured to use, as teaching data, an image of an eyeball and the actual gaze direction of the eyeball in the image and estimate, from the image of the eyeball, the angle of gaze and the distance to an object gazed. The AI program may be included in the display apparatus, the image pickup apparatus, or an external apparatus. In the case of an external apparatus, transmission to the display apparatus via communications is carried out.

When display control is performed on the basis of visual recognition, smart glasses further including an image pickup apparatus configured to capture an external image are suitable for use. Smart glasses can display captured external information in real time.

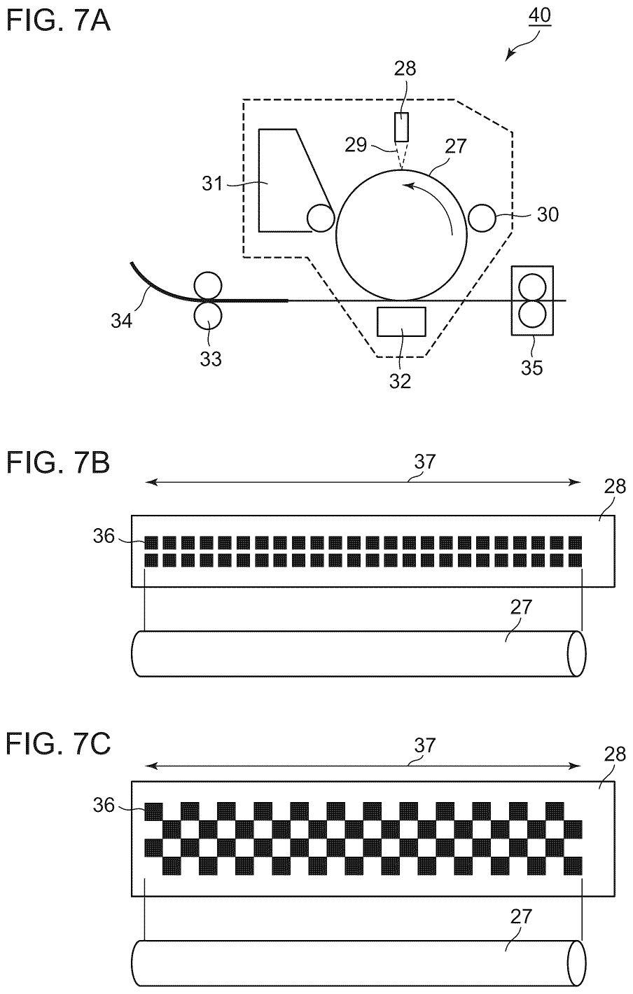

FIG. 7A is a schematic view showing an example of an image-forming apparatus according to an embodiment of the present invention. An image-forming apparatus 40 is an electrophotographic image-forming apparatus and includes a photoreceptor 27, an exposure light source 28, a charging unit 30, a developing unit 31, a transfer unit 32, a conveyer roller 33, and a fixing unit 35. The exposure light source 28 emits light 29, and an electrostatic latent image is formed on the surface of the photoreceptor 27. The exposure light source 28 includes the organic light-emitting element according to this embodiment. The developing unit 31 contains a toner and the like. The charging unit 30 charges the photoreceptor 27. The transfer unit 32 transfers a developed image onto a recording medium 34. The conveyer roller 33 conveys the recording medium 34. The recording medium 34 is paper, for example. The fixing unit 35 fixes an image formed on the recording medium 34.

FIG. 7B and FIG. 7C each illustrate the exposure light source 28 and each schematically illustrate how a plurality of light-emitting portions 36 are arranged on a long substrate. An arrow 37 indicates a row direction which is a direction parallel to the axis of the photoreceptor and in which organic light-emitting elements are aligned. The row direction is the same as the direction of the rotation axis of the photoreceptor 27. This direction can also be referred to as the major-axis direction of the photoreceptor 27. In FIG. 7B, the light-emitting portions 36 are arranged along the major-axis direction of the photoreceptor 27. In FIG. 7C, unlike FIG. 7B, the light-emitting portions 36 are alternately arranged in the row direction in a first row and a second row. The first row and the second row are located at different positions in the column direction. In the first row, the plurality of light-emitting portions 36 are arranged at intervals. In the second row, the light-emitting portions 36 are arranged at positions corresponding to the spaces between the light-emitting portions 36 in the first row. That is, the plurality of light-emitting portions 36 are arranged at intervals also in the column direction. The arrangement in FIG. 7C can be referred to as, for example, a lattice arrangement, a staggered arrangement, or a checkered pattern.

As described above, the use of an apparatus including the organic light-emitting element according to this embodiment enables a stable display with good image quality over a long period of time.

### EXAMPLES

The present invention will now be described with reference to Examples. It should be noted that the present invention is not limited thereto.

First organic compounds, second organic compounds, and luminescent compounds used for light-emitting layers in EXAMPLES are shown below. The compounds used in EXAMPLES were synthesized with reference to Japanese Patent Laid-Open No. 2012-72099, PCT Japanese Translation Patent Publication No. 2013-518068, Japanese Patent Laid-Open No. 2012-191031, U.S. Patent Application Publication No. 2010/0051928, International Publication No. 2010/050778, International Publication No. 2012/077582, International Publication No. 2011/136156, German Patent Application Publication No. 10 2010 005 697.

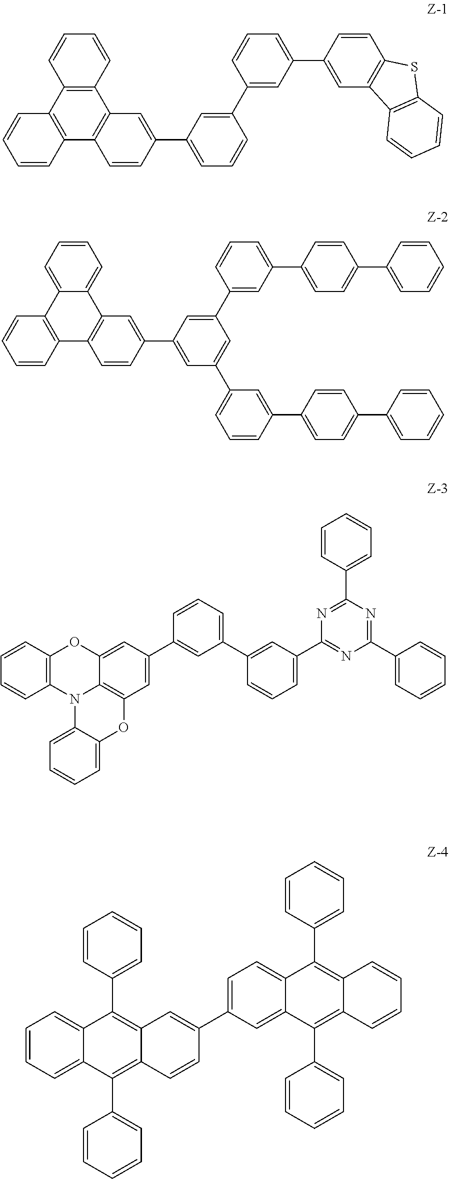

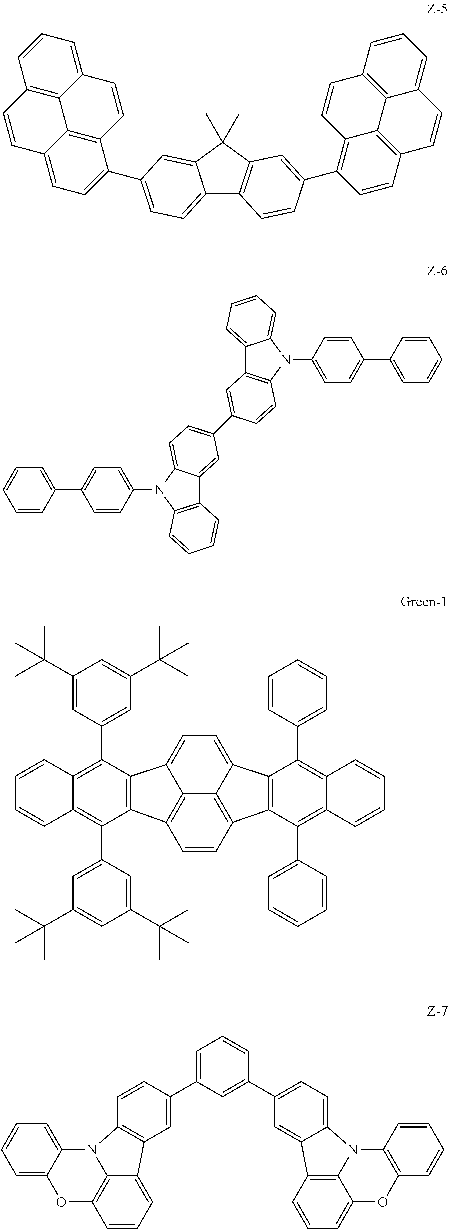

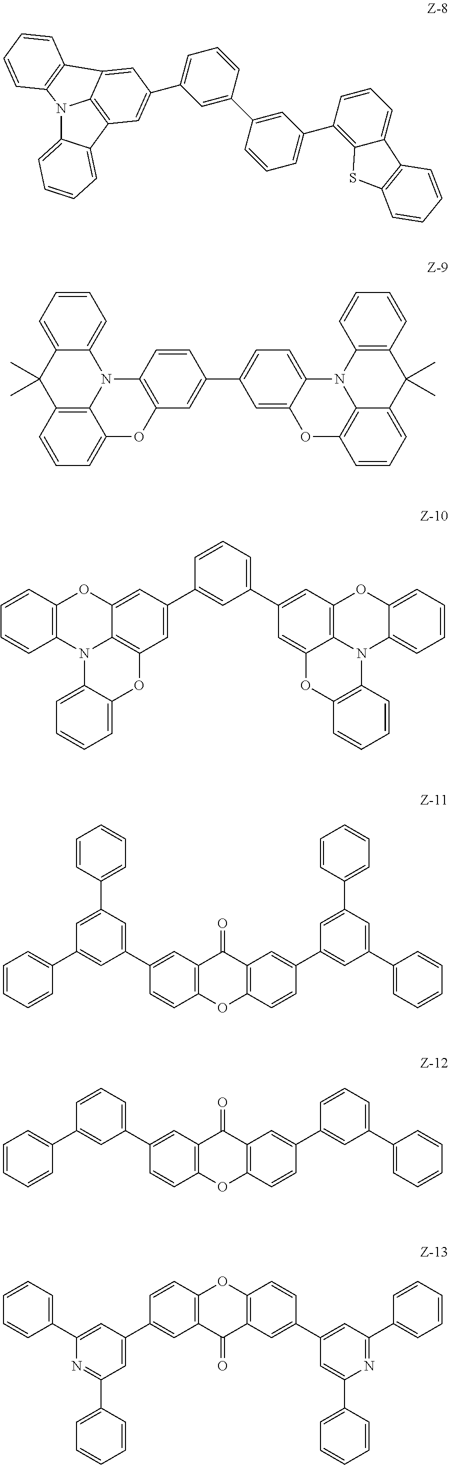

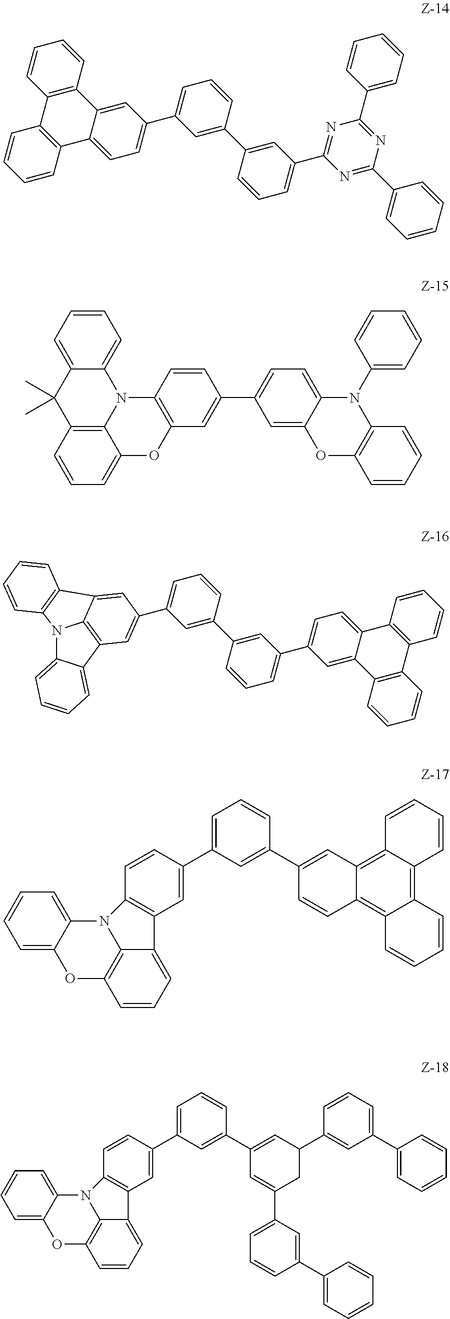 [SMILES: c1ccc(-c2nc(-c3ccccc3)nc(-c3cccc(-c4cccc(-c5ccc6c7ccccc7c7ccccc7c6c5)c4)c3)n2)cc1 ; CC1(C)c2ccccc2N2c3ccc(-c4ccc5c(c4)Oc4ccccc4N5c4ccccc4)cc3Oc3cccc1c32 ; c1cc(-c2cccc(-c3cc4c5ccccc5n5c6ccccc6c(c3)c45)c2)cc(-c2ccc3c4ccccc4c4ccccc4c3c2)c1 ; c1cc(-c2ccc3c4ccccc4c4ccccc4c3c2)cc(-c2ccc3c(c2)c2cccc4c2n3-c2ccccc2O4)c1 ; C1=C(c2cccc(-c3ccc4c(c3)c3cccc5c3n4-c3ccccc3O5)c2)C=C(c2cccc(-c3ccccc3)c2)CC1c1cccc(-c2ccccc2)c1]

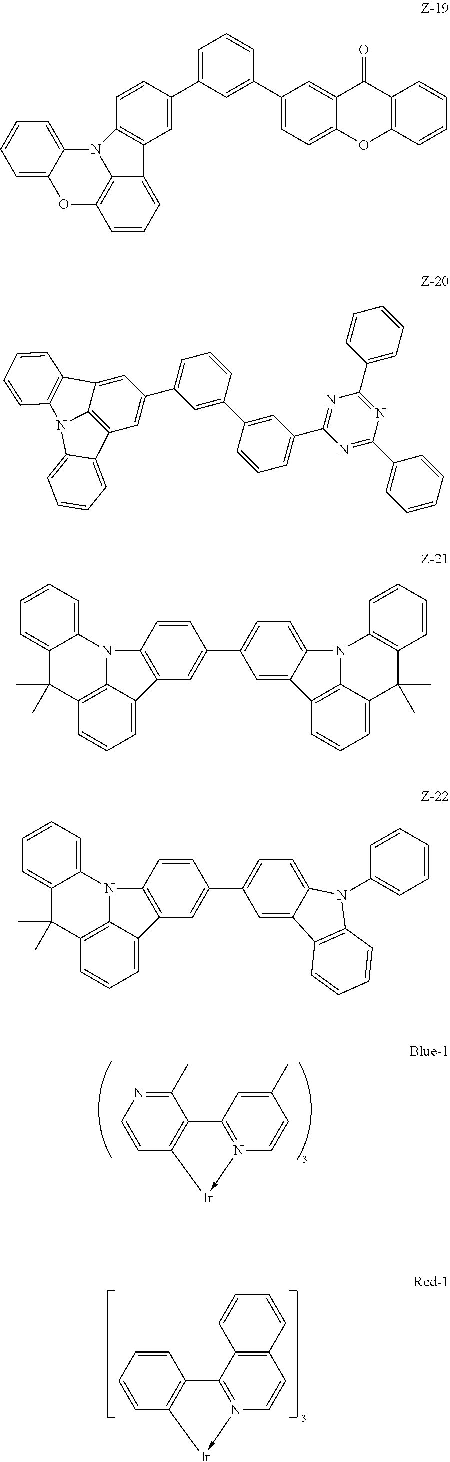

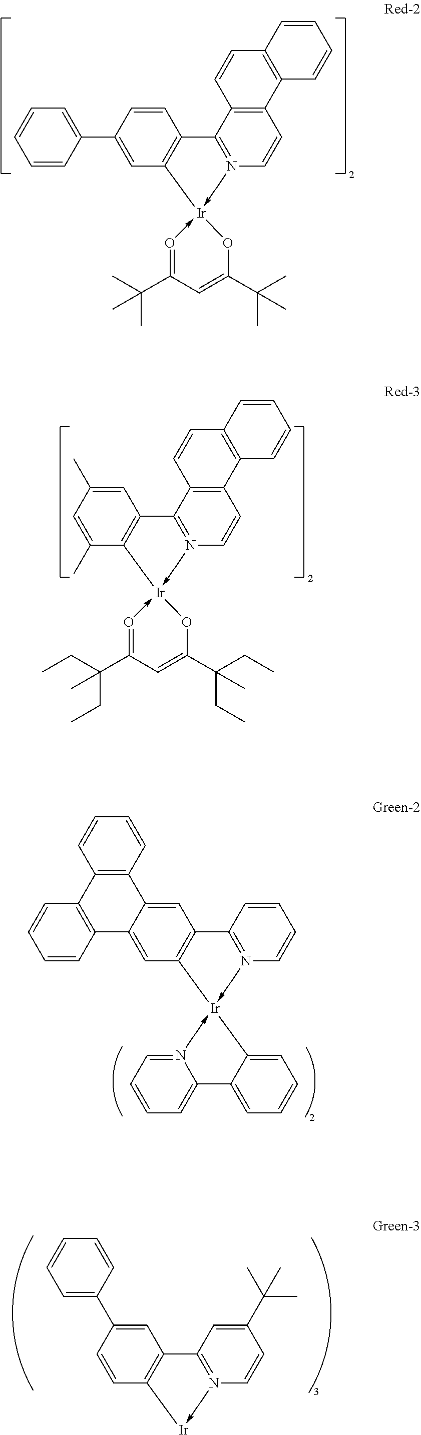

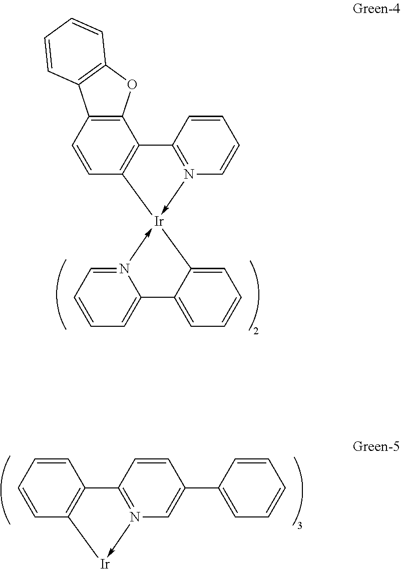

Table 10 shows the HOMO level and the LUMO level of the above compounds. The HOMO level is a value of an ionization potential determined as follows: for each compound, a 50-nm-thick film is prepared by vacuum deposition, and the film is subjected to a measurement using an AC-3 manufactured by RIKEN KEIKI Co., Ltd. The LUMO level is a value determined as follows: the absorption spectrum of a film prepared in the same manner is measured, and an optical absorption edge is determined as a band gap, which is then subtracted from the ionization potential.

TABLE 10

| Compound | HOMO | LUMO |
|---|---|---|
| Z-1 | −6.38 | −2.92 |
| Z-2 | −6.40 | −2.94 |
| Z-3 | −5.66 | −3.11 |
| Z-4 | −5.91 | −3.14 |
| Z-5 | −6.02 | −3.10 |
| Z-6 | −5.73 | −2.47 |
| Z-7 | −5.76 | −2.72 |
| Z-8 | −6.11 | −2.96 |
| Z-9 | −5.66 | −2.72 |
| Z-10 | −5.63 | −2.74 |
| Z-11 | −6.55 | −3.42 |
| Z-12 | −6.43 | −3.30 |
| Z-13 | −6.70 | −3.65 |
| Z-14 | −6.38 | −3.13 |
| Z-15 | −5.64 | −2.71 |
| Z-16 | −6.10 | −2.97 |
| Z-17 | −5.94 | −2.96 |
| Z-18 | −5.95 | −2.70 |
| Z-19 | −5.75 | −3.26 |
| Z-20 | −6.12 | −3.14 |
| Z-21 | −5.83 | −2.37 |
| Z-22 | −5.82 | −2.36 |
| Blue-1 | −5.98 | −2.99 |
| Red-1 | −5.53 | −3.31 |
| Red-2 | −5.46 | −3.23 |
| Red-3 | −5.52 | −3.25 |
| Green-1 | −5.87 | −3.47 |
| Green-2 | −5.68 | −3.04 |
| Green-3 | −5.08 | −2.35 |
| Green-4 | −5.62 | −2.95 |
| Green-5 | −5.62 | −3.04 |

### Example 1

In this Example, an organic light-emitting element having a top-emission structure was produced in which an anode, a hole injection layer, a hole transport layer, an electron blocking layer, a light-emitting layer, a hole blocking layer, an electron transport layer, an electron injection layer, and a cathode were sequentially formed on a substrate.

A Ti film with a thickness of 40 nm was formed on a glass substrate by sputtering and patterned by photolithography to form an anode. The anode was formed so as to have an electrode area of 3 mm². The resultant was then washed.

Subsequently, the above-produced substrate with the electrode was attached to a vacuum deposition apparatus (manufactured by ULVAC, Inc.). After deposition materials were prepared for deposition, the apparatus was evacuated to 1.33×10⁻⁴ Pa (1×10⁻⁶ Torr). Thereafter, the inside of a chamber was subjected to UV/ozone cleaning. Subsequently, layers were formed so as to have a layer structure as shown in Table 11.

TABLE 11

| | | | | Thickness |
|---|---|---|---|---|
| | Material | | | (nm) |
| Cathode | Al | | | 100 |
| Electron | LiF | | | 1 |
| injection | | | | |
| layer | | | | |
| (EIL) | | | | |
| Electron | ET2 | | | 15 |
| transport | | | | |
| layer | | | | |
| (ETL) | | | | |
| Hole | ET12 | | | 15 |
| blocking | | | | |
| layer | | | | |
| (HBL) | | | | |
| Light- | First | Second | Luminescent | 30 |
| emitting | organic | organic | compound | |
| layer | compound | compound | Green-3 | |
| | Z-7 | Z-12 | 10% | |
| | 45% | 45% | | |
| Electron | HT12 | | | 15 |
| blocking | | | | |
| layer | | | | |
| (EBL) | | | | |
| Hole | HT3 | | | 30 |
| transport | | | | |
| layer | | | | |
| (HTL) | | | | |
| Hole | HT16 | | | 5 |
| injection | | | | |
| layer | | | | |
| (HIL) | | | | |

Thereafter, the substrate was transferred into a glove box and sealed in a nitrogen atmosphere with a glass cap including a drying agent, thereby obtaining an organic light-emitting element.

The obtained organic light-emitting element was connected to a voltage application apparatus and evaluated for its characteristics. Current-voltage characteristics were measured with a microammeter 4140B manufactured by Hewlett-Packard Company, and chromaticity was evaluated using an “SR-3” manufactured by TOPCON CORPORATION. Emission luminance was measured with a BM7 manufactured by TOPCON CORPORATION. The external quantum efficiency (E.Q.E.) during display at 1000 cd/m² was 18%, indicating that the organic light-emitting element was a good organic green light-emitting element.

Furthermore, a continuous operation test was performed at an initial luminance of 2000 cd/m², and the decrease in luminance after 100 hours was determined. The results are shown in Tables 12-1 to 12-3.

### Examples 2 to 23 and Comparative Examples 1 to 11

Organic light-emitting elements were produced in the same manner as in Example 1 except that the configuration of the light-emitting layer of Example 1 was changed as shown in Tables 12-1 to 12-3, and evaluated for their characteristics. The results are shown in Tables 12-1 to 12-3.

For E.Q.E., when the ratio of E.Q.E. during display at 1000 cd/m² relative to that in Example 1 was 0.1 or less, it was graded as C, when the ratio of E.Q.E. was 0.1 or more and 0.9 or less, it was graded as B, and the ratio of E.Q.E. was 1.0 or more, it was graded as A. The luminance degradation ratio is a value relative to that in Comparative Example 10 taken as 1.0.

TABLE 12-1

| | | | | EML | | | | | | | |
|---|---|---|---|---|---|---|---|---|---|---|---|
| | | | | First | Second | | | | | | Luminance |
| | | | | organic | organic | Luminescent | | | Emission | EQE | degradation |
| | HIL | HTL | EBL | compound | compound | compound | HBL | ETL | color | ratio | ratio |
| Example 1 | HT 16 | HT3 | HT 12 | Z-7 | Z-12 | Green-3 | ET12 | ET2 | green | A | 2.2 |
| | | | | 45% | 45% | 10% | | | | | |
| Comparative | HT 16 | HT3 | HT 12 | Z-5 | Z-4 | Green-1 | ET12 | ET2 | green | B | |
| Example 1 | | | | 49% | 49% | 2% | | | | | |
| Comparative | HT 16 | HT3 | HT 12 | Z-5 | Z-4 | Green-3 | ET12 | ET2 | — | C | |
| Example 2 | | | | 45% | 45% | 10% | | | | | |
| Example 2 | HT 16 | HT3 | HT 12 | Z-7 | Z-12 | Green-2 | ET12 | ET2 | green | A | 1.9 |
| | | | | 45% | 45% | 10% | | | | | |
| Comparative | HT 16 | HT3 | HT 12 | Z-7 | | Green-2 | ET12 | ET2 | green | A | 0.6 |
| Example 3 | | | | 90% | | 10% | | | | | |
| Comparative | HT 16 | HT3 | HT 12 | Z-8 | | Green-2 | ET12 | ET2 | green | A | 1.0 |
| Example 4 | | | | 90% | | 10% | | | | | |
| Comparative | HT 16 | HT3 | HT 12 | Z-1 | | Green-2 | ET12 | ET2 | green | A | 0.9 |
| Example 5 | | | | 90% | | 10% | | | | | |
| Example 3 | HT 16 | HT3 | HT 12 | Z-21 | Z-12 | Green-3 | ET12 | ET2 | green | A | 1.8 |
| | | | | 45% | 45% | 10% | | | | | |
| Comparative | HT 16 | HT3 | HT 12 | Z-22 | Z-12 | Green-3 | ET12 | ET2 | green | A | 1.2 |
| Example 6 | | | | 45% | 45% | 10% | | | | | |
| Example 4 | HT 16 | HT3 | HT 12 | Z-10 | Z-12 | Green-2 | ET12 | ET2 | green | A | 2.3 |
| | | | | 45% | 45% | 10% | | | | | |
| Example 5 | HT 16 | HT3 | HT 12 | Z-9 | Z-12 | Green-2 | ET12 | ET2 | green | A | 1.8 |
| | | | | 45% | 45% | 10% | | | | | |

TABLE 12-2

| | | | | EML | | | | | | | |
|---|---|---|---|---|---|---|---|---|---|---|---|
| | | | | First | Second | | | | | | Luminance |
| | | | | organic | organic | Luminescent | | | Emission | EQE | degradation |
| | HIL | HTL | EBL | compound | compound | compound | HBL | ETL | color | ratio | ratio |
| Example 5 | HT 16 | HT3 | HT 12 | Z-9 | Z-12 | Green-2 | ET12 | ET2 | green | A | 1.8 |
| | | | | 45% | 45% | 10% | | | | | |
| Example 6 | HT 16 | HT3 | HT 12 | Z-21 | Z-12 | Green-2 | ET12 | ET2 | green | A | 1.6 |
| | | | | 45% | 45% | 10% | | | | | |
| Comparative | HT 16 | HT3 | HT 12 | Z-15 | Z-12 | Green-2 | ET12 | ET2 | green | A | 1.2 |
| Example 7 | | | | 45% | 45% | 10% | | | | | |
| Comparative | HT 16 | HT3 | HT 12 | Z-22 | Z-12 | Green-2 | ET12 | ET2 | green | A | 1.2 |
| Example 8 | | | | 45% | 45% | 10% | | | | | |
| Comparative | HT16 | HT3 | HT 12 | Z-6 | Z-12 | Green-2 | ET12 | ET2 | green | A | 1.2 |
| Example 9 | | | | 45% | 45% | 10% | | | | | |
| Example 7 | HT 16 | HT3 | HT 12 | Z-16 | Z-12 | Green-4 | ET12 | ET2 | green | A | 2.1 |
| | | | | 45% | 45% | 10% | | | | | |
| Example 8 | HT16 | HT3 | HT 12 | Z-7 | Z-12 | Green-4 | ET12 | ET2 | green | A | 1.6 |
| | | | | 45% | 45% | 10% | | | | | |
| Comparative | HT 16 | HT3 | HT 12 | Z-6 | Z-12 | Green-4 | ET12 | ET2 | green | A | 1.0 |
| Example 10 | | | | 45% | 45% | 10% | | | | | |
| Comparative | HT16 | HT3 | HT12 | Z-22 | Z-12 | Green-4 | ET12 | ET2 | green | A | 1.0 |
| Example 11 | | | | 45% | 45% | 10% | | | | | |
| Example 9 | HT16 | HT3 | HT12 | Z-3 | Z-1 | Green-2 | ET12 | ET2 | green | A | 2.0 |
| | | | | 45% | 45% | 10% | | | | | |
| Example 10 | HT16 | HT3 | HT 12 | Z-10 | Z-20 | Green-2 | ET12 | ET2 | green | A | 2.3 |
| | | | | 45% | 45% | 10% | | | | | |
| Example 11 | HT 16 | HT3 | HT 12 | Z-10 | Z-20 | Green-2 | ET12 | ET2 | green | A | 2.4 |
| | | | | 65% | 25% | 10% | | | | | |
| Example 12 | HT16 | HT3 | HT12 | Z-10 | Z-12 | Green-2 | ET8 | ET2 | green | A | 1.9 |
| | | | | 45% | 45% | 10% | | | | | |
| Example 13 | HT 16 | HT3 | Z-10 | Z-10 | Z-12 | Green-2 | ET12 | ET2 | green | A | 2.4 |
| | | | | 45% | 45% | 10% | | | | | |

TABLE 12-3

| | | | | EML | | | | | | | |
|---|---|---|---|---|---|---|---|---|---|---|---|
| | | | | First | Second | | | | | | Luminance |
| | | | | organic | organic | Luminescent | | | Emission | EQE | degradation |
| | HIL | HTL | EBL | compound | compound | compound | HBL | ETL | color | ratio | ratio |
| Example | HT 16 | HT3 | HT12 | Z-16 | Z-12 | Green-4 | ET12 | ET2 | green | A | 2.2 |
| 14 | | | | 65% | 25% | 10% | | | | | |
| Example | HT 16 | HT3 | HT12 | Z-8 | Z-12 | Green-4 | ET12 | ET2 | green | A | 2.1 |
| 15 | | | | 45% | 45% | 10% | | | | | |
| Example | HT 16 | HT3 | HT12 | Z-16 | Z-11 | Green-4 | ET12 | ET2 | green | A | 2.1 |
| 16 | | | | 45% | 45% | 10% | | | | | |
| Example | HT 16 | HT3 | HT12 | Z-16 | Z-20 | Green-4 | ET12 | ET2 | green | A | 2.2 |
| 17 | | | | 45% | 45% | 10% | | | | | |
| Example | HT 16 | HT3 | HT12 | Z-16 | Z-12 | Green-4 | Z-12 | ET2 | green | A | 2.0 |
| 18 | | | | 45% | 45% | 10% | | | | | |
| Example | HT16 | HT3 | Z-10 | Z-16 | Z-20 | Green-4 | ET12 | ET2 | green | A | 2.3 |
| 19 | | | | 45% | 45% | 10% | | | | | |
| Example | HT 16 | HT3 | HT12 | Z-3 | Z-14 | Green-2 | ET12 | ET2 | green | A | 2.2 |
| 20 | | | | 45% | 45% | 10% | | | | | |
| Example | HT 16 | HT3 | HT12 | Z-3 | Z-1 | Green-2 | ET27 | ET2 | green | A | 2.1 |
| 21 | | | | 55% | 35% | 10% | | | | | |
| Example | HT16 | HT3 | HT12 | Z-3 | Z-1 | Green-2 | ET27 | ET2 | green | A | 1.6 |
| 22 | | | | 45% | 45% | 10% | | | | | |
| Example | HT16 | HT3 | Z-10 | Z-3 | Z-1 | Green-2 | ET12 | ET2 | green | A | 2.1 |
| 23 | | | | 45% | 45% | 10% | | | | | |

Comparison of Example 1 with Comparative Example 1 shows that E.Q.E. of Example 1 is higher. This is because in the present invention, the luminescent compound is used, and T1's of the first organic compound and the second organic compound are higher than that of the luminescent compound. As shown in Comparative Example 2, even if the luminescent compound is used relative to the first organic compound and the second organic compound of Comparative Example 2, the value of E.Q.E. is low because T1's of the first organic compound and the second organic compound are higher than T1 of the luminescent compound.

Comparison of Example 2 with Comparative Examples 3 to 5 shows that Example 2 is superior in the luminance degradation ratio. Comparative Examples 3 to 5 have a two-component configuration composed of a first organic compound and a luminescent compound, whereas Example 2 has a three-component configuration composed of a first organic compound, a second organic compound, and a luminescent compound. The first organic compound has a skeleton that exhibits hole transportability, and the second organic compound has a skeleton that exhibits electron transportability. As a result of this, exciton generation on the luminescent compound is suppressed, and thus the organic light-emitting element of Example 2 is excellent in the luminance degradation ratio.

Comparison of Example 3 with Comparative Example 6 shows that Example 3 is superior in the luminance degradation ratio. This is due to the molecular structure of the first organic compound. In Z-21 of Example 3, all freely rotatable single bonds are carbon-carbon bonds, whereas in Z-22 of Comparative Example 6, a carbon-nitrogen bond is included as a freely rotatable single bond. As described above, the carbon-nitrogen bond has a lower binding energy than the carbon-carbon bond and thus is poor in binding stability. Thus, the organic light-emitting element of Example 3 is excellent in the luminance degradation ratio.

Comparison of Example 1 with Example 3 shows that the luminance degradation ratio in Example 1 is even more excellent. This is due to the molecular structure of the first organic compound. In Z-7 of Example 1, all freely rotatable single bonds are bonds between sp2 carbons. As described above, the binding energy of a bond between sp2 carbons is higher than the binding energy of a carbon-carbon bond, and thus even higher binding stability is provided. Thus, the organic light-emitting element of Example 1 is more excellent in the luminance degradation ratio.

Comparison of Example 2 with Examples 4 to 6 shows that the luminance degradation ratios in Examples 4 and 5 are more excellent than those in Examples 2 and 6. Examples 4 and 5 are configured so as to have the configurations of Examples 2 and 6 and, in addition, further satisfy the relation of formula (3). In other words, Example 2 and Example 4 to 6 are embodiments of the organic light-emitting element having the configuration (1-5). Thus, in the organic light-emitting elements of Examples 4 and 5, as compared with the organic light-emitting elements of Examples 2 and 6, hole trapping on the luminescent compound can be further suppressed, and thus concentration of exciton generation on the luminescent compound can be further suppressed. Thus, the organic light-emitting elements of Examples 4 and 5 are more excellent in the luminance degradation ratio.

Comparison of Example 7 with Example 8 shows that Example 8 is more superior in the luminance degradation ratio. Example 7 is configured so as to have the configuration of Example 8 and, in addition, further satisfy the relation of formula (4). In other words, Example 7 is an embodiment of the organic light-emitting element having the configuration (1-6), and Example 8 is an embodiment of the organic light-emitting element having the configuration (1-5). When the configuration of formula (4) is satisfied, the absolute value of the LUMO level of the luminescent compound is the smallest, and thus electron trapping on the luminescent compound can be further suppressed. Thus, concentration of exciton generation on the luminescent compound can be further suppressed. Thus, the organic light-emitting element of Example 7 is more excellent in the luminance degradation ratio.

Comparison of Example 2 with Example 9 shows that Example 9 is more superior in the luminance degradation ratio. The organic light-emitting element of Example 9 has a configuration satisfying formula (1) and formulas (3) to (5). In other words, Example 9 is an embodiment of the organic light-emitting element having the configuration (1-7), that is, an organic light-emitting element in which the absolute value of the HOMO level of the first organic compound is the smallest and the absolute value of the LUMO level is the largest. Due to the above configuration, electron and hole trapping on the luminescent compound can be further suppressed. In addition, the speed of exciton generation in the first organic compound is increased, so that exciton concentration on the luminescent compound can be suppressed, and thus the organic light-emitting element of Example 9 is more excellent in the luminance degradation ratio.

Example 20 is an organic light-emitting element that satisfies formulas (1) to (4). In other words, Example 20 is an embodiment of the organic light-emitting element having the configuration (1-5) and the configuration (1-6). When formulas (1) to (4) are satisfied, electrons or holes are unlikely to be trapped on the luminescent compound, so that exciton generation on the luminescent compound can be suppressed, and thus the organic light-emitting element of Example 20 is excellent in the luminance degradation ratio.

### Examples 24 and 25

Organic light-emitting elements were produced in the same manner as in Example 1 except that the configuration of the light-emitting layer of Example 1 was changed as shown in Table 13, and evaluated for their characteristics. The results are shown in Table 13. The luminance degradation ratio is a ratio relative to that in Example 25 taken as 1.0.

TABLE 13

| | | | | EML | | | | | | |
|---|---|---|---|---|---|---|---|---|---|---|
| | | | | First | Second | | | | | Luminance |
| | | | | organic | organic | Luminescent | | | Emission | degradation |
| | HIL | HTL | EBL | compound | compound | compound | HBL | ETL | color | ratio |
| Example | HT16 | HT3 | HT12 | Z-19 | Z-1 | Blue-1 | ET12 | ET2 | blue | 1.1 |
| 24 | | | | 45% | 45% | 10% | | | | |
| Example | HT16 | HT3 | HT12 | Z-16 | Z-12 | Blue-1 | ET12 | ET2 | blue | 1.0 |
| 25 | | | | 45% | 45% | 10% | | | | |

The organic light-emitting elements of Examples 24 and 25 have in common the configurations (1-1) to (1-5) and thus have excellent luminance degradation ratios. In particular, the organic light-emitting element of Example 24 has the configurations (1-1) to (1-5) and (1-7). Due to these configurations, the absolute value of the HOMO level of the first organic compound is the smallest, and the absolute value of the LUMO level is the largest, so that exciton concentration on the luminescent compound can be suppressed. Therefore, the organic light-emitting element of Example 24 has a more excellent luminance degradation ratio than the organic light-emitting element of Example 25.

### Examples 26 to 28 and Comparative Examples 12 and 13

Organic light-emitting elements were produced in the same manner as in Example 1 except that the configuration of the light-emitting layer of Example 1 was changed as shown in the following table, and evaluated for their characteristics. The results are shown in Table 14. The luminance degradation ratio is a ratio relative to that in Comparative Example 13 taken as 1.0.

TABLE 14

| | | | | EML | | | | | | |
|---|---|---|---|---|---|---|---|---|---|---|
| | | | | First | Second | | | | | Luminance |
| | | | | organic | organic | Luminescent | | | Emission | degradation |
| | HIL | HTL | EBL | compound | compound | compound | HBL | ETL | color | ratio |
| Example 26 | HT16 | HT3 | HT 12 | Z-19 | Z-11 | Red-1 | ET12 | ET2 | red | 2.5 |
| | | | | 49% | 49% | 2% | | | | |
| Example 27 | HT16 | HT3 | HT 12 | Z-7 | Z-11 | Red-3 | ET12 | ET2 | red | 1.6 |
| | | | | 49% | 49% | 2% | | | | |
| Example 28 | HT16 | HT3 | HT 12 | Z-3 | Z-11 | Red-3 | ET12 | ET2 | red | 1.7 |
| | | | | 49% | 49% | 2% | | | | |
| Comparative | HT16 | HT3 | HT 12 | Z-15 | Z-11 | Red-3 | ET12 | ET2 | red | 0.9 |
| Example 12 | | | | 49% | 49% | 2% | | | | |
| Comparative | HT16 | HT3 | HT 12 | Z-6 | Z-11 | Red-3 | ET12 | ET2 | red | 1.0 |
| Example 13 | | | | 49% | 49% | 2% | | | | |

In the organic light-emitting elements of Comparative Examples 12 and 13, a carbon-nitrogen bond is included as a freely rotatable single bond in the first organic compound. As described above, the carbon-nitrogen bond has a low binding energy and thus is poor in binding stability. By contrast, in the organic light-emitting elements of Examples 26 to 28, freely rotatable single bonds in the first organic compound are carbon-carbon bonds. Thus, the organic light-emitting elements of Examples 26 to 28 have more excellent luminance degradation ratios than Comparative Examples 12 and 13.

### Example 29

In this Example, an organic light-emitting element having a top-emission structure was produced in which an anode, a hole injection layer, a hole transport layer, an electron blocking layer, a first light-emitting layer, a second light-emitting layer, a hole blocking layer, an electron transport layer, an electron injection layer, and a cathode were sequentially formed on a substrate.

A Ti film with a thickness of 40 nm was formed on a glass substrate by sputtering and patterned by photolithography to form an anode. The anode was formed so as to have an electrode area of 3 mm². The resultant was then washed.

Subsequently, the above-produced substrate with the electrode was attached to a vacuum deposition apparatus (manufactured by ULVAC, Inc.). After deposition materials were prepared for deposition, the apparatus was evacuated to 1.33×10⁻⁴ Pa (1×10⁻⁶ Torr). Thereafter, the inside of a chamber was subjected to UV/ozone cleaning. Subsequently, layers were formed so as to have a layer structure as shown in Table 15.

TABLE 15

| | | Thickness |
|---|---|---|
| | Material | (nm) |
| Cathode | Al | 100 |
| Electron | LiF | 1 |

injection
layer
(EIL)

| | | |
|---|---|---|
| Electron | ET2 | 15 |

transport
layer
(ETL)

| | | |
|---|---|---|
| Hole | ET12 | 15 |

| | | | | |
|---|---|---|---|---|
| blocking | | | | |
| layer | | | | |
| (HBL) | | | | |
| First | First | Second | Luminescent | 20 |
| light- | organic | organic | compound | |
| emitting | compound | compound | Green-2 | |
| layer | Z-10 | Z-12 | 12% | |
| | 44% | 44% | | |
| Second | First | Second | Luminescent | 4 |
| light- | organic | organic | compound | |
| emitting | compound | compound | Red-3 | |
| layer | Z-10 | Z-12 | 1% | |
| | 50% | 49% | | |

| | | |
|---|---|---|
| Electron | HT12 | 15 |

blocking
layer
(EBL)

| | | |
|---|---|---|
| Hole | HT3 | 30 |

transport
layer
(HTL)

| | | |
|---|---|---|
| Hole | HT16 | 5 |

injection
layer
(HIL)

Thereafter, the substrate was transferred into a glove box and sealed in a nitrogen atmosphere with a glass cap including a drying agent, thereby obtaining an organic light-emitting element.

The obtained organic light-emitting element was connected to a voltage application apparatus and evaluated for its characteristics. Current-voltage characteristics were measured with a microammeter 4140B manufactured by Hewlett-Packard Company, and chromaticity was evaluated using an “SR-3” manufactured by TOPCON CORPORATION. Emission luminance was measured with a BM7 manufactured by TOPCON CORPORATION. The organic light-emitting element was a good organic yellow light-emitting element during display at 1000 cd/m².

Furthermore, a continuous operation test was performed at an initial luminance of 2000 cd/m², and the decrease in luminance after 100 hours was determined. The results are shown in Table 16.

### Examples 30 to 32 and Comparative Example 14

Organic light-emitting elements were produced in the same manner as in Example 29 except that the configuration of the light-emitting layer of Example 29 was changed as shown in the following table, and evaluated for their characteristics. The results are shown in Table 16.

TABLE 16

| | EML | | | EML | | | | |
|---|---|---|---|---|---|---|---|---|
| | First | Second | | First | Second | | | Luminance |
| | organic | organic | Luminescent | organic | organic | Luminescent | Emission | degradation |
| | compound | compound | compound | compound | compound | compound | color | ratio |
| Example 29 | Z-10 | Z-12 | Red-3 | Z-10 | Z-12 | Green-2 | yellow | 1.9 |
| | 45% | 45% | 1% | 45% | 45% | 12% | | |
| Example 30 | Z-16 | Z-12 | Red-3 | Z-16 | Z-12 | Green-4 | yellow | 1.7 |
| | 45% | 45% | 1% | 45% | 45% | 12% | | |
| Example 31 | Z-3 | Z-1 | Red-3 | Z-3 | Z-1 | Green-2 | yellow | 1.8 |
| | 45% | 45% | 1% | 45% | 45% | 12% | | |
| Example 32 | Z-9 | Z-12 | Red-3 | Z-9 | Z-12 | Green-2 | yellow | 1.6 |
| | 45% | 45% | 1% | 45% | 45% | 12% | | |
| Comparative | Z-6 | Z-12 | Red-3 | Z-6 | Z-12 | Green-2 | yellow | 1.0 |
| Example 14 | 45% | 45% | 1% | 45% | 45% | 12% | | |

In the organic light-emitting element of Comparative Example 14, a carbon-nitrogen bond is included as a freely rotatable single bond in the first organic compound. As described above, the carbon-nitrogen bond has a low binding energy and thus is poor in binding stability. By contrast, in the organic light-emitting elements of Examples 29 to 32, freely rotatable single bonds in the first organic compound are carbon-carbon bonds. Thus, the organic light-emitting elements of Examples 29 to 32 have more excellent luminance degradation ratios than Comparative Example 14.

The above shows that when two kinds of organic compounds in which freely rotatable bonds consist of carbon-carbon bonds are used to adjust the HOMO-LUMO relationship, charge trapping on a luminescent compound can be suppressed. As a result, exciton concentration is suppressed, thus providing an organic light-emitting element having high light-emission efficiency and high element durability. Furthermore, by applying the organic light-emitting element according to the present invention to various light-emitting devices, display apparatuses and luminaires having good light-emitting characteristics and high element durability can be obtained.

The present invention may also have the following configurations.

### Configuration 1

An organic light-emitting element including:
a first electrode and a second electrode; and
an organic compound layer disposed between the first electrode and the second electrode,
in which the organic compound layer includes a light-emitting layer,
the light-emitting layer contains at least a first organic compound, a second organic compound, and a luminescent compound that emits phosphorescence,
lowest excited triplet energies of the first organic compound and the second organic compound are higher than a lowest excited triplet energy of the luminescent compound,
all freely rotatable single bonds in the first organic compound are carbon-carbon bonds, and
the organic light-emitting element satisfies a relation of formula (1):

|HOMO(H2)|>|HOMO(H1)| (1).

In formula (1), HOMO (H1) and HOMO (H2) represent a HOMO of the first organic compound and a HOMO of the second organic compound, respectively.

### Configuration 2

The organic light-emitting element according to Configuration 1, in which the organic light-emitting element further satisfies a relation of formula (2):

|LUMO(H2)|>|LUMO(D)| (2).

In formula (2), LUMO (H2) and LUMO (D) represent a LUMO of the second organic compound and a LUMO of the luminescent compound, respectively.

### Configuration 3

The organic light-emitting element according to Configuration 1 or 2, in which the organic light-emitting element further satisfies a relation of formula (3):

|LUMO(H1)|>|LUMO(D)| (3).

In formula (3), LUMO (H1) represents a LUMO of the first organic compound.

### Configuration 4

The organic light-emitting element according to any one of Configurations 1 to 3, in which the organic light-emitting element further satisfies a relation of formula (4):

|LUMO(H1)|>|LUMO(H2)| (4).

### Configuration 5

The organic light-emitting element according to any one of Configurations 1 to 4, in which the organic light-emitting element further satisfies a relation of formula (5):

|HOMO(D)|>|HOMO(H1)| (5).

In formula (5), HOMO (D) and HOMO (H1) represent a HOMO of the luminescent compound and a HOMO of the first organic compound, respectively.

### Configuration 6

The organic light-emitting element according to any one of Configurations 1 to 5, in which all the freely rotatable single bonds in the first organic compound are bonds between sp2 carbons.

### Configuration 7

The organic light-emitting element according to any one of Configurations 1 to 6, in which all freely rotatable single bonds in the second organic compound are carbon-carbon bonds.

### Configuration 8

The organic light-emitting element according to any one of Configurations 1 to 7, in which all freely rotatable single bonds in the second organic compound are bonds between sp2 carbons.

### Configuration 9

The organic light-emitting element according to any one of Configurations 1 to 8, in which the first organic compound has a skeleton represented by general formula (1-1) or (1-2).

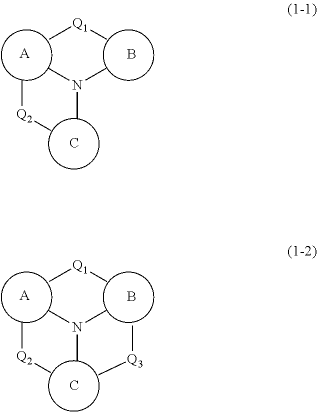

In general formulas (1-1) and (1-2), cyclic units A to C are each independently selected from a substituted or unsubstituted aryl group and a substituted or unsubstituted heteroaryl group. Q₁ to Q₃ are each independently selected from a direct bond, C(R_{A})(R_{B}), N(R_{C}), an oxygen atom, a sulfur atom, a selenium atom, and a tellurium atom. R_{A} to R_{C} are each independently selected from a hydrogen atom, a deuterium atom, a halogen atom, a substituted or unsubstituted alkyl group, a substituted or unsubstituted alkoxy group, a substituted or unsubstituted aryl group, and a substituted or unsubstituted heteroaryl group. R_{C} forms a ring together with adjacent one of the cyclic units A to C.

### Configuration 10

The organic light-emitting element according to any one of Configurations 1 to 9, in which the first organic compound has a skeleton represented by any of structural formulas below.

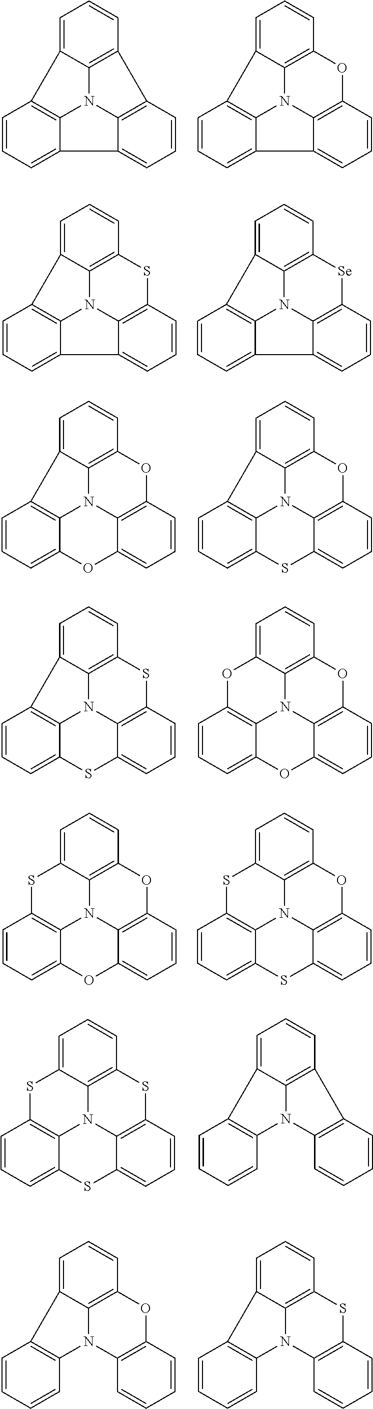

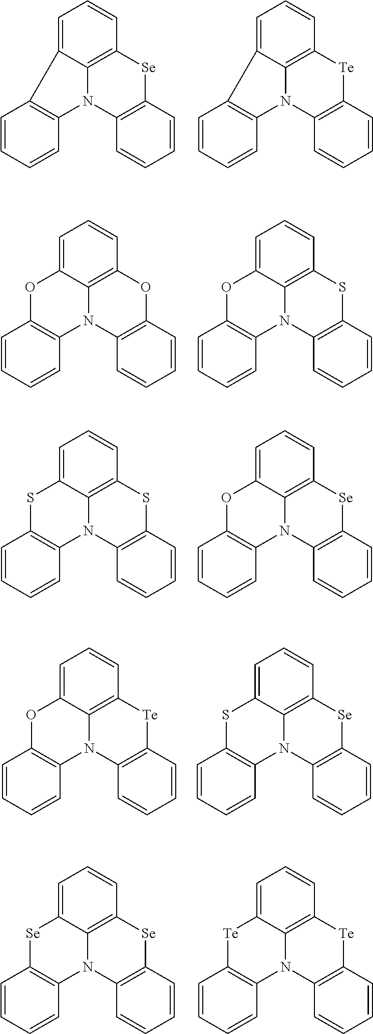

### Configuration 11

The organic light-emitting element according to any one of Configurations 1 to 10, in which the second organic compound has a skeleton represented by any of general formulas (2-1) to (2-7).

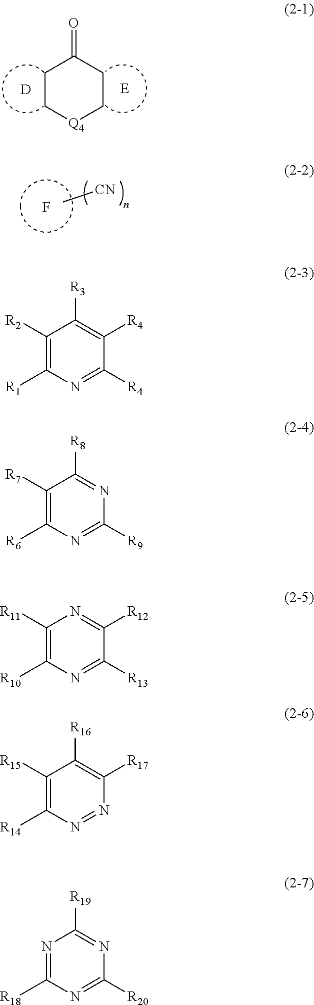

In general formulas (2-1) and (2-2), cyclic units D to F are each independently selected from a substituted or unsubstituted aryl group and a substituted or unsubstituted heteroaryl group. Q₄ is selected from a direct bond, C(R_{D})(R_{E}), an oxygen atom, a sulfur atom, a selenium atom, and a tellurium atom. R_{D} and R_{E} are each independently selected from a hydrogen atom, a deuterium atom, a halogen atom, a substituted or unsubstituted alkyl group, a substituted or unsubstituted alkoxy group, a substituted or unsubstituted aryl group, and a substituted or unsubstituted heteroaryl group. n is an integer of 1 to 5.

In general formulas (2-3) to (2-7), R₁ to R₂₀ are each independently selected from a hydrogen atom, a deuterium atom, a halogen atom, a substituted or unsubstituted alkyl group, and a substituted or unsubstituted aryl group. Among R₁ to R₂₀, substituents adjacent to each other may be bonded together to form a fused ring.

### Configuration 12

The organic light-emitting element according to any one of Configurations 1 to 11, in which the second organic compound has a skeleton represented by any of structural formulas below.

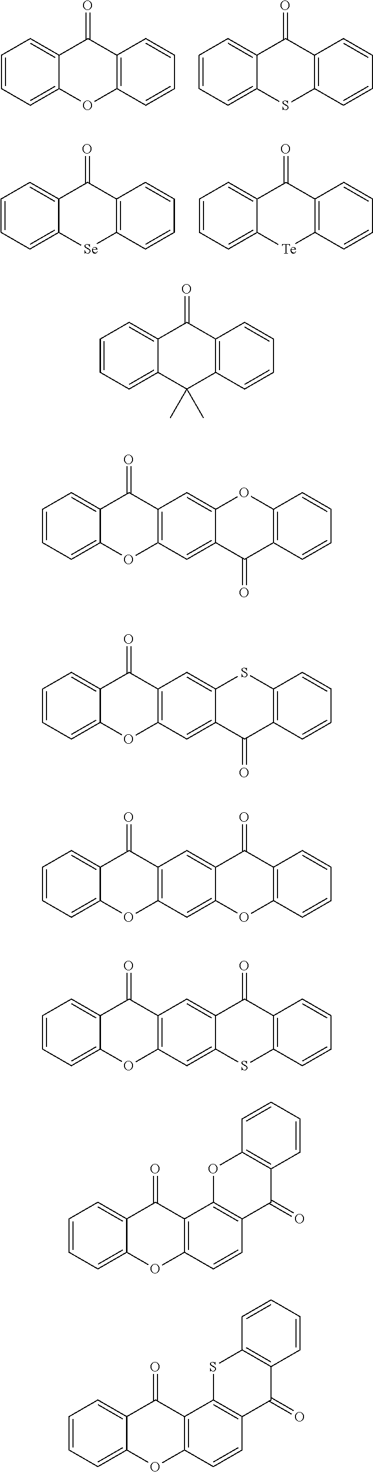

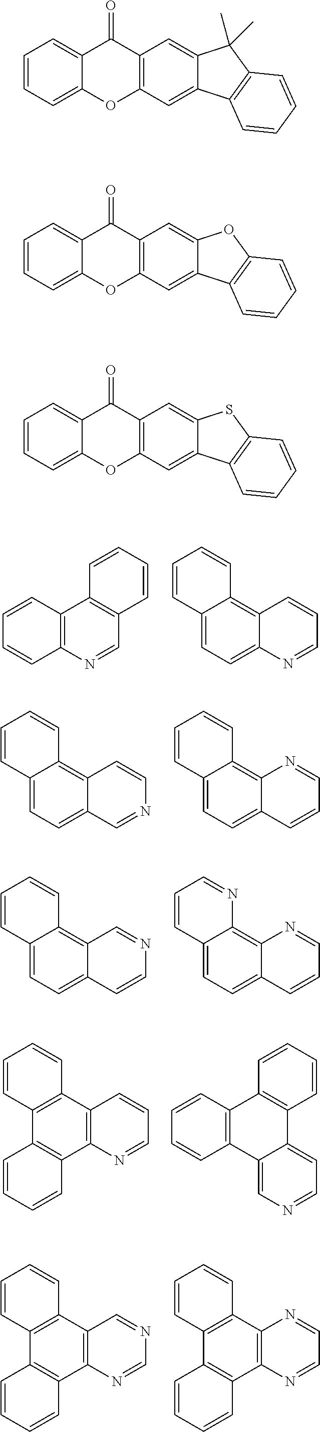

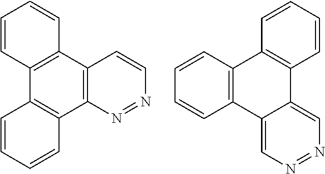

### Configuration 13

The organic light-emitting element according to any one of Configurations 1 to 12, in which the organic compound layer is constituted by a plurality of layers,
the plurality of layers are constituted by at least the light-emitting layer and a second layer different from the light-emitting layer,
the second layer contains at least one organic compound, and
a lowest excited triplet energy of the organic compound is higher than the lowest excited triplet energies of the first organic compound and the second organic compound.

### Configuration 14

The organic light-emitting element according to any one of Configurations 1 to 13, in which the light-emitting layer is a first light-emitting layer,
a second light-emitting layer different from the first light-emitting layer is further disposed between the first light-emitting layer and the first electrode or between the first light-emitting layer and the second electrode, and
the second light-emitting layer emits light with a color different from a color of light emitted from the first light-emitting layer.

### Configuration 15

A display apparatus including a plurality of pixels, wherein at least one of the plurality of pixels includes the organic light-emitting element according to any one of Configurations 1 to 14 and a transistor connected to the organic light-emitting element.

### Configuration 16

A photoelectric conversion apparatus including: an optical unit including a plurality of lenses; an image pickup element configured to receive light that has passed through the optical unit; and a display unit configured to display an image captured by the image pickup element,
wherein the display unit includes the organic light-emitting element according to any one of Configurations 1 to 14.

### Configuration 17

An electronic apparatus including: a display unit including the organic light-emitting element according to any one of Configurations 1 to 14; a housing provided with the display unit; and a communication unit provided in the housing and configured to communicate with an external device.

### Configuration 18

A lighting apparatus including: a light source including the organic light-emitting element according to any one of Configurations 1 to 14; and a light diffusion unit or an optical film configured to transmit light emitted from the light source.

### Configuration 19

A moving object including: a lighting fixture including the organic light-emitting element according to any one of Configurations 1 to 14; and a body provided with the lighting fixture.

### Configuration 20

An image-forming apparatus including: a photoreceptor; and an exposure light source configured to expose the photoreceptor,
wherein the exposure light source includes the organic light-emitting element according to any one of Configurations 1 to 14.

According to the present invention, an organic light-emitting element having high element durability can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. An organic light-emitting element comprising:
a first electrode and a second electrode; and
an organic compound layer disposed between the first electrode and the second electrode,
wherein the organic compound layer includes a light-emitting layer,
the light-emitting layer contains at least a first organic compound, a second organic compound, and a luminescent compound that emits phosphorescence,
lowest excited triplet energies of the first organic compound and the second organic compound are higher than a lowest excited triplet energy of the luminescent compound,
all freely rotatable single bonds in the first organic compound are carbon-carbon bonds, and
the organic light-emitting element satisfies a relation of formulas (1), (2), and (3):

|HOMO(H2)|>|HOMO(H1)| (1)

|LUMO(H2)|>|LUMO(D)| (2)

|LUMO(H1)|>|LUMO(D)| (3)
where in formulas (1) to (3), HOMO (H1), HOMO (H2), LUMO (H1), LUMO (H2), and LUMO (D) represent a HOMO of the first organic compound, a HOMO of the second organic compound, a LUMO of the first organic compound, a LUMO of the second organic compound, and a LUMO of the luminescent compound, respectively.

2. The organic light-emitting element according to claim 1, wherein the organic light-emitting element further satisfies a relation of formula (4):

|LUMO(H1)|>|LUMO(H2)| (4).

3. The organic light-emitting element according to claim 1, wherein the organic light-emitting element further satisfies a relation of formula (5):

|HOMO(D)|>|HOMO(H1)| (5)
where in formula (5), HOMO (D) and HOMO (H1) represent a HOMO of the luminescent compound and a HOMO of the first organic compound, respectively.

4. The organic light-emitting element according to claim 1, wherein all the freely rotatable single bonds in the first organic compound are bonds between sp2 carbons.

5. The organic light-emitting element according to claim 1, wherein all the freely rotatable single bonds in the second organic compound are carbon-carbon bonds.

6. The organic light-emitting element according to claim 5, wherein all the freely rotatable single bonds in the second organic compound are bonds between sp2 carbons.

7. The organic light-emitting element according to claim 1, wherein the first organic compound has a skeleton represented by formula (1-1) or (1-2): 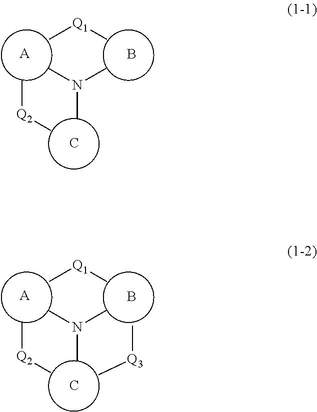
where in formulas (1-1) and (1-2), cyclic units A to C are each independently selected from a substituted or unsubstituted aryl group and a substituted or unsubstituted heteroaryl group; Q₁ to Q₃ are each independently selected from a direct bond, C(R_{A})(R_{B}), N(R_{C}), an oxygen atom, a sulfur atom, a selenium atom, and a tellurium atom; R_{A} to R_{C} are each independently selected from a hydrogen atom, a deuterium atom, a halogen atom, a substituted or unsubstituted alkyl group, a substituted or unsubstituted alkoxy group, a substituted or unsubstituted aryl group, and a substituted or unsubstituted heteroaryl group; and R_{C} forms a ring together with adjacent one of the cyclic units A to C.

8. The organic light-emitting element according to claim 7, wherein the first organic compound has a skeleton represented by any of structural formulas:

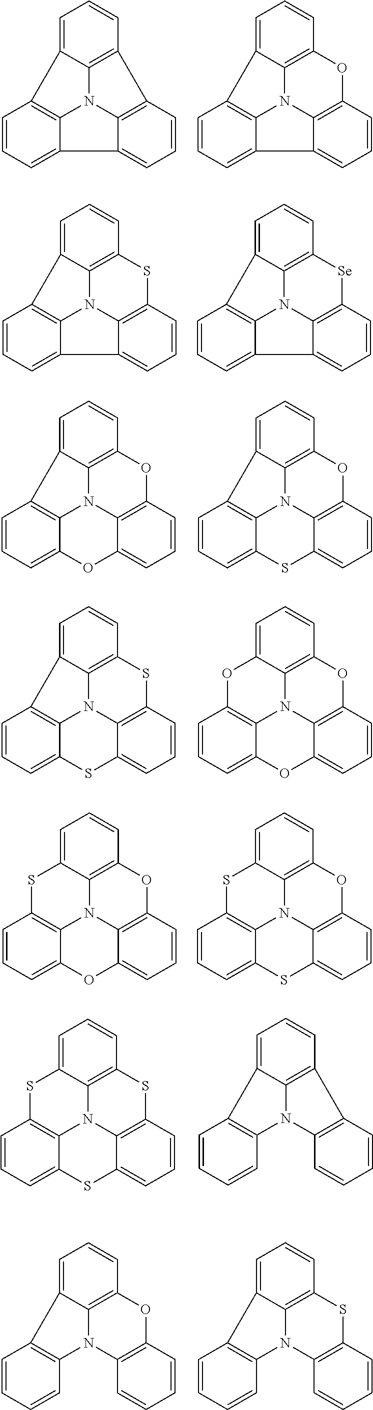

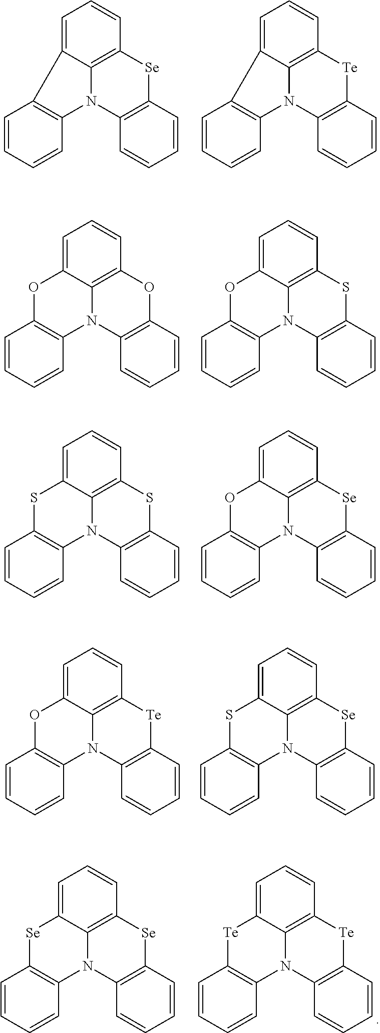

9. The organic light-emitting element according to claim 1, wherein the second organic compound has a skeleton represented by any of formulas (2-1) to (2-7): 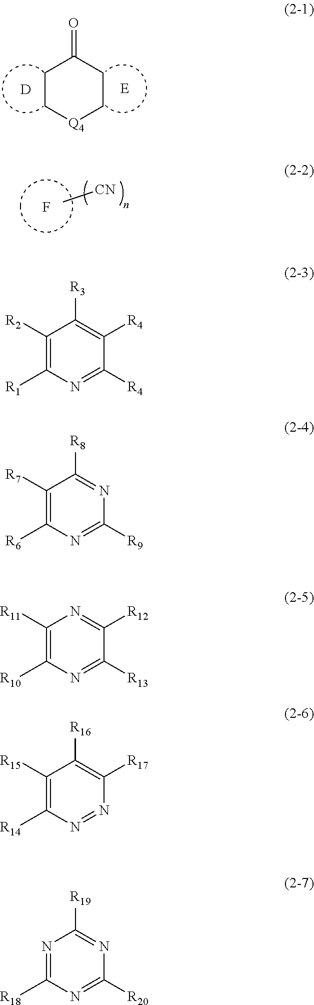
where in formulas (2-1) and (2-2), cyclic units D to F are each independently selected from a substituted or unsubstituted aryl group and a substituted or unsubstituted heteroaryl group; Q₄ is selected from a direct bond, C(R_{D})(R_{E}), an oxygen atom, a sulfur atom, a selenium atom, and a tellurium atom; R_{D} and R_{E} are each independently selected from a hydrogen atom, a deuterium atom, a halogen atom, a substituted or unsubstituted alkyl group, a substituted or unsubstituted alkoxy group, a substituted or unsubstituted aryl group, and a substituted or unsubstituted heteroaryl group; and n is an integer of 1 to 5, and
in formulas (2-3) to (2-7), R₁ to R₂₀ are each independently selected from a hydrogen atom, a deuterium atom, a halogen atom, a substituted or unsubstituted alkyl group, and a substituted or unsubstituted aryl group; and among R₁ to R₂₀, substituents adjacent to each other may be bonded together to form a fused ring.

10. The organic light-emitting element according to claim 9, wherein the second organic compound has a skeleton represented by any of structural formulas:

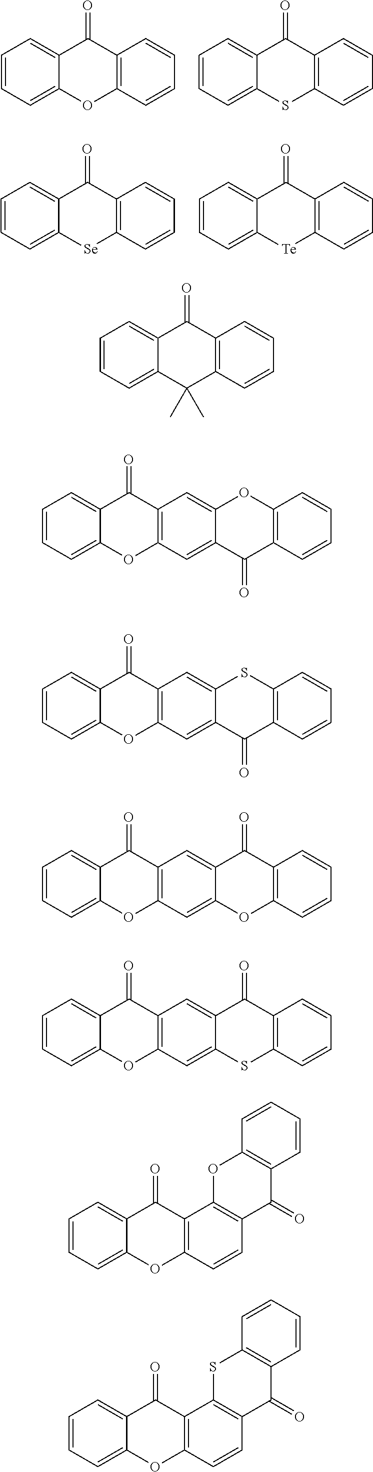

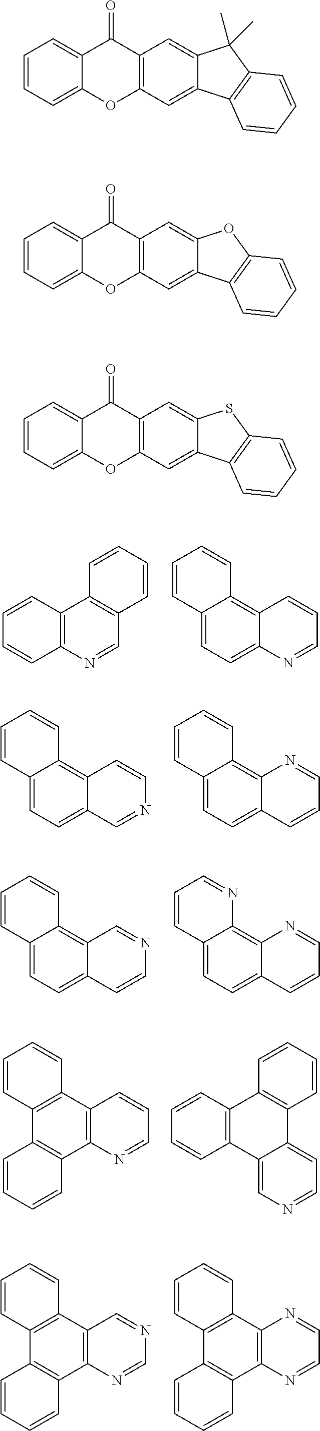

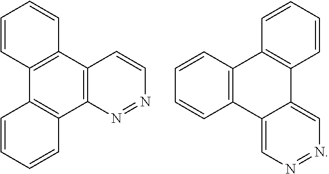

11. The organic light-emitting element according to claim 1, wherein the organic compound layer is constituted by a plurality of layers,
the plurality of layers are constituted by at least the light-emitting layer and a second layer different from the light-emitting layer,
the second layer contains at least one organic compound, and
a lowest excited triplet energy of the organic compound is higher than the lowest excited triplet energies of the first organic compound and the second organic compound.

12. The organic light-emitting element according to claim 1, wherein the light-emitting layer is a first light-emitting layer,
a second light-emitting layer different from the first light-emitting layer is further disposed between the first light-emitting layer and the first electrode or between the first light-emitting layer and the second electrode, and
the second light-emitting layer emits light with a color different from a color of light emitted from the first light-emitting layer.

13. A display apparatus comprising a plurality of pixels, wherein at least one of the plurality of pixels includes the organic light-emitting element according to claim 1, and a transistor connected to the organic light-emitting element.

14. A photoelectric conversion apparatus comprising:
an optical unit including a plurality of lenses;
an image pickup element configured to receive light that has passed through the optical unit; and
a display unit configured to display an image captured by the image pickup element,
wherein the display unit includes the organic light-emitting element according to claim 1.

15. An electronic apparatus comprising:
a display unit including the organic light-emitting element according to claim 1;
a housing provided with the display unit; and a communication unit provided in the housing and configured to communicate with an external device.

16. A lighting apparatus comprising:
a light source including the organic light-emitting element according to claim 1; and
a light diffusion unit or an optical film configured to transmit light emitted from the light source.

17. A moving object comprising:
a lighting fixture including the organic light-emitting element according to claim 1; and
a body provided with the lighting fixture.

18. An image-forming apparatus comprising:
a photoreceptor; and
an exposure light source configured to expose the photoreceptor,
wherein the exposure light source includes the organic light-emitting element according to claim 1.

19. An organic light-emitting element comprising:
a first electrode and a second electrode; and
an organic compound layer disposed between the first electrode and the second electrode,
wherein the organic compound layer includes a light-emitting layer,
the light-emitting layer contains at least a first organic compound, a second organic compound, and a luminescent compound that emits phosphorescence,
lowest excited triplet energies of the first organic compound and the second organic compound are higher than a lowest excited triplet energy of the luminescent compound,
all freely rotatable single bonds in the first organic compound are carbon-carbon bonds,
the organic light-emitting element satisfies a relation of formula (1):

|HOMO(H2)|>|HOMO(H1)| (1)
where in formula (1), HOMO (H1) and HOMO (H2) represent a HOMO of the first organic compound and a HOMO of the second organic compound, respectively, and
the first organic compound has a skeleton represented by formula (1-1) or (1-2): 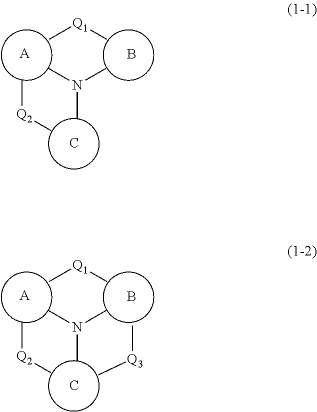
where in formulas (1-1) and (1-2), cyclic units A to C are each independently selected from a substituted or unsubstituted aryl group and a substituted or unsubstituted heteroaryl group; Q₁ to Q₃ are each independently selected from a direct bond, C(R_{A})(R_{B}), N(R_{C}), an oxygen atom, a sulfur atom, a selenium atom, and a tellurium atom; R_{A} to R_{C} are each independently selected from a hydrogen atom, a deuterium atom, a halogen atom, a substituted or unsubstituted alkyl group, a substituted or unsubstituted alkoxy group, a substituted or unsubstituted aryl group, and a substituted or unsubstituted heteroaryl group; and R_{C} forms a ring together with adjacent one of the cyclic units A to C.

20. The organic light-emitting element according to claim 19, wherein the organic light-emitting element further satisfies a relation of formula (2):

|LUMO(H2)|>|LUMO(D)| (2)
where in formula (2), LUMO (H2) and LUMO (D) represent a LUMO of the second organic compound and a LUMO of the luminescent compound, respectively.

21. The organic light-emitting element according to claim 19, wherein the organic light-emitting element further satisfies a relation of formula (3):

|LUMO(H1)|>|LUMO(D)| (3)
where in formula (3), LUMO (H1) represents a LUMO of the first organic compound.

22. The organic light-emitting element according to claim 19, wherein the organic light-emitting element further satisfies a relation of formula (4):

|LUMO(H1)|>|LUMO(H2)| (4).

23. The organic light-emitting element according to claim 19, wherein the organic light-emitting element further satisfies a relation of formula (5):

|HOMO(D)|>|HOMO(H1)| (5)
where in formula (5), HOMO (D) and HOMO (H1) represent a HOMO of the luminescent compound and a HOMO of the first organic compound, respectively.

24. The organic light-emitting element according to claim 19, wherein all the freely rotatable single bonds in the first organic compound are bonds between sp2 carbons.

25. The organic light-emitting element according to claim 19, wherein all the freely rotatable single bonds in the second organic compound are carbon-carbon bonds.

26. The organic light-emitting element according to claim 25, wherein all the freely rotatable single bonds in the second organic compound are bonds between sp2 carbons.

27. The organic light-emitting element according to claim 19, wherein the first organic compound has a skeleton represented by any of structural formulas:

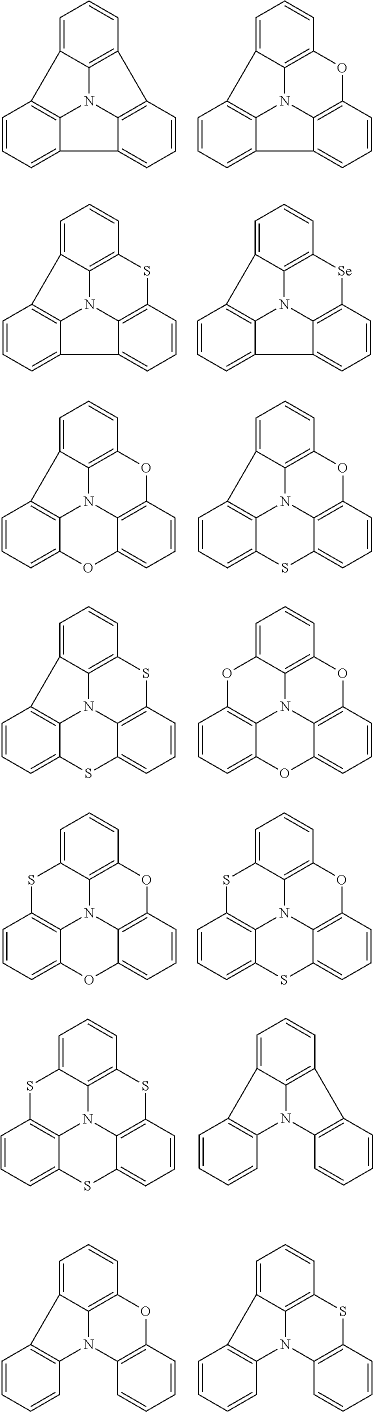

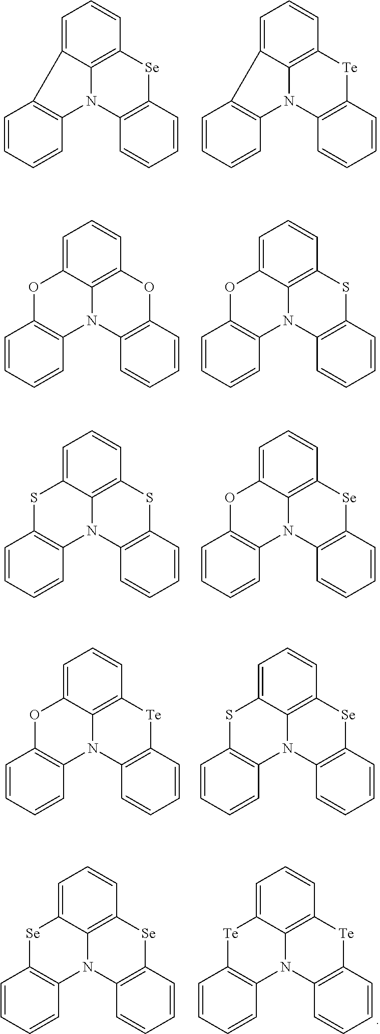

28. The organic light-emitting element according to claim 19, wherein the second organic compound has a skeleton represented by any of formulas (2-1) to (2-7): 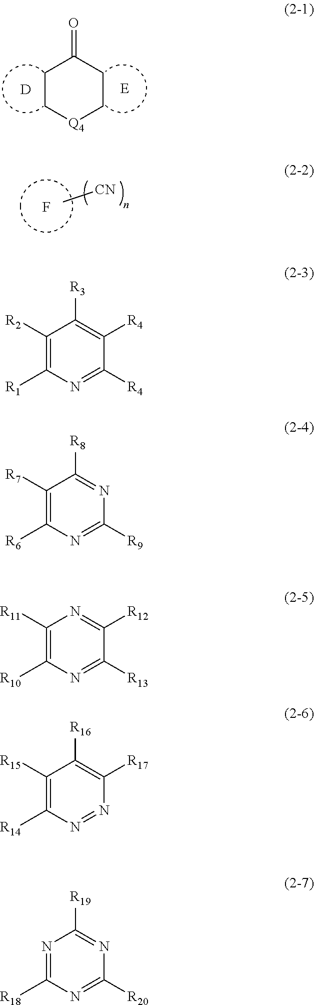
where in formulas (2-1) and (2-2), cyclic units D to F are each independently selected from a substituted or unsubstituted aryl group and a substituted or unsubstituted heteroaryl group; Q₄ is selected from a direct bond, C(R_{D})(R_{E}), an oxygen atom, a sulfur atom, a selenium atom, and a tellurium atom; R_{D} and R_{E} are each independently selected from a hydrogen atom, a deuterium atom, a halogen atom, a substituted or unsubstituted alkyl group, a substituted or unsubstituted alkoxy group, a substituted or unsubstituted aryl group, and a substituted or unsubstituted heteroaryl group; and n is an integer of 1 to 5, and
in formulas (2-3) to (2-7), R₁ to R₂₀ are each independently selected from a hydrogen atom, a deuterium atom, a halogen atom, a substituted or unsubstituted alkyl group, and a substituted or unsubstituted aryl group; and among R₁ to R₂₀, substituents adjacent to each other may be bonded together to form a fused ring.

29. The organic light-emitting element according to claim 28, wherein the second organic compound has a skeleton represented by any of structural formulas:

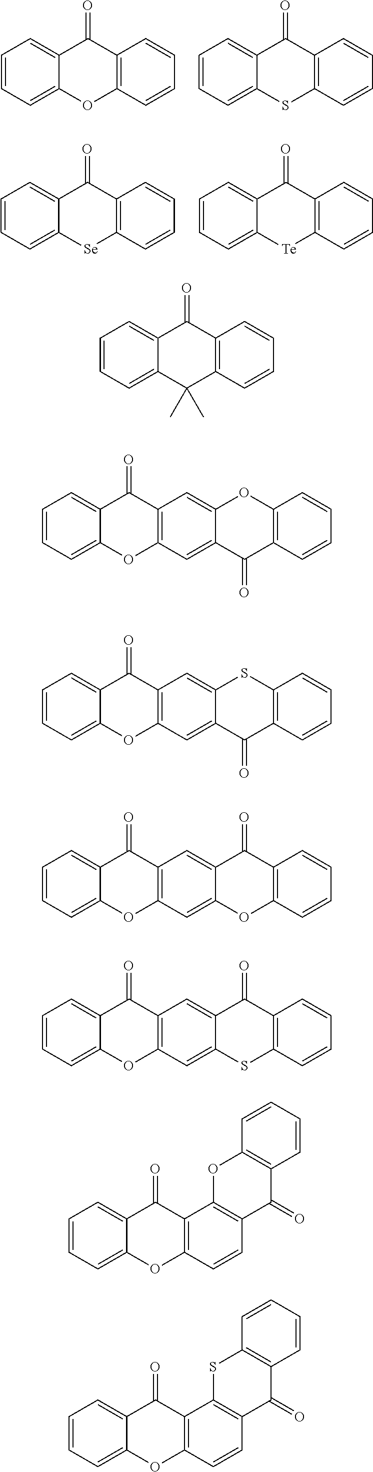

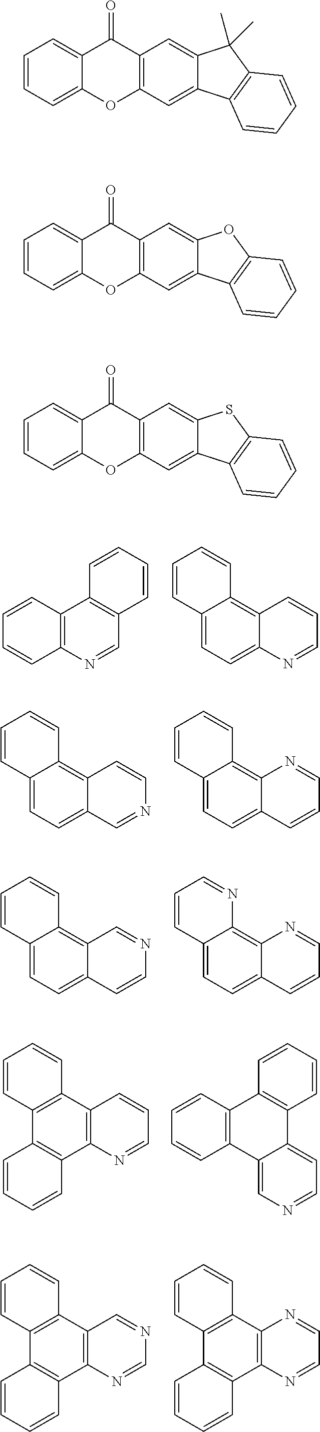

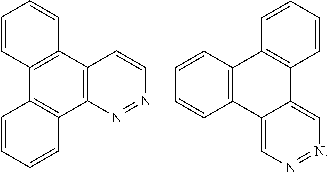

30. A display apparatus comprising a plurality of pixels, wherein at least one of the plurality of pixels includes the organic light-emitting element according to claim 19 and a transistor connected to the organic light-emitting element.

31. A photoelectric conversion apparatus comprising:
an optical unit including a plurality of lenses;
an image pickup element configured to receive light that has passed through the optical unit; and
a display unit configured to display an image captured by the image pickup element,
wherein the display unit includes the organic light-emitting element according to claim 19.

32. An electronic apparatus comprising:
a display unit including the organic light-emitting element according to claim 19;
a housing provided with the display unit; and
a communication unit provided in the housing and configured to communicate with an external device.

33. A lighting apparatus comprising:
a light source including the organic light-emitting element according to claim 19; and
a light diffusion unit or an optical film configured to transmit light emitted from the light source.

34. A moving object comprising:
a lighting fixture including the organic light-emitting element according to claim 19; and
a body provided with the lighting fixture.

35. An image-forming apparatus comprising:
a photoreceptor; and
an exposure light source configured to expose the photoreceptor,
wherein the exposure light source includes the organic light-emitting element according to claim 19.
